(19) United States
(12) Patent Application Publication
(10) Pub. No.: US 2014/0312340 A1
(43) Pub. Date: Oct. 23, 2014

(54) AROMATIC AMINE DERIVATIVE AND ORGANIC ELECTROLUMINESCENCE DEVICE USING SAME

(71) Applicants: Masakazu Funahashi, Sodegaura-shi (JP); Hirokatsu Ito, Sodegaura-shi (JP)

(72) Inventors: Masakazu Funahashi, Sodegaura-shi (JP); Hirokatsu Ito, Sodegaura-shi (JP)

(73) Assignee: IDEMITSU KOSAN CO., LTD., Tokyo (JP)

(21) Appl. No.: 14/360,566

(22) PCT Filed: Nov. 21, 2012
(86) PCT No.: PCT/JP2012/080244

§ 371 Date: May 23, 2014

(30) Foreign Application Priority Data
Nov. 25, 2011 (JP) 2011-258292

(51) Int. Cl. H01L 51/00

(52) U.S. Cl. CPC H01L 51/0073; H01L 51/0054; H01L 51/0061; H01L 51/0058
USPC 257/40; 549/460

(57) ABSTRACT

An aromatic amine derivative is represented by the following formula (1), in which R₁ to R₅ and R₇ to R₁₁ are each independently a hydrogen atom or a substituent. In the formula (1), R₆ and R₁₂ are each represented by the following formula (2) and L₁ to L₃ are each independently a single bond, a divalent residue of an aryl group, or the like. Ar₁ in the formula (2) is a monovalent substituent having a moiety represented by the following formula (3), in which X is an oxygen atom or a sulfur atom. Ar₂ in the formula (2) is a substituted or unsubstituted aryl group or the like.

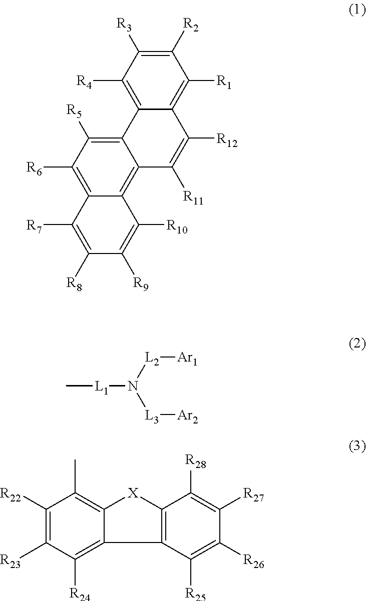

### TECHNICAL FIELD

The present invention relates to an aromatic amine derivative and an organic electroluminescence device using the same.

### BACKGROUND ART

An organic electroluminescence device (hereinafter, occasionally abbreviated as “organic EL device”) using an organic substance is expected to be used as a cost-friendly full-color display device (solid light-emitting device) with a large area and thus many developments thereof have been made. A general organic EL device includes an emitting layer and a pair of opposing electrodes between which the emitting layer is interposed. When an electric field is applied between the electrodes, electrons are injected from a cathode, while holes are injected from an anode. Subsequently, the electrons are recombined with the holes in the emitting layer to generate an excited state and energy generated when the excited state returns to a ground state is emitted in the form of light.

As compared with an inorganic light-emitting diode, a typical organic EL device requires a high drive voltage and the luminescence intensity and luminous efficiency thereof are relatively low. Further, such an organic EL device has not been practically usable because of a considerable characteristic deterioration thereof. Although having been gradually improved these days, organic EL devices are still required to be further improved in terms of luminous efficiency, lifetime, color reproducibility and the like.

The performance of an organic EL device has been gradually improved by improving an organic-EL-device material. In particular, improvement in the color purity of a blue-emitting organic EL device (i.e., decrease in an emission wavelength) is considered as an important technique for improving the color reproducibility of a display.

As an example of a material usable for an emitting layer, Patent Literature 1 discloses a luminescent material containing dibenzofuran, which contributes to emission of blue light with a short wavelength. However, the luminous efficiency is low and thus further improvement has been required.

Patent Literature 2 discloses an aromatic amine derivative with a diphenylamino group bonded in each of the 6-position and 12-position of a chrysene skeleton. This aromatic amine derivative, which is intended to be used as a blue-luminescent material, has been required to be further improved in terms of color purity and luminous efficiency for practical use.

### CITATION LIST

### Patent Literatures

Patent Literature 1: WO 2006/128800
Patent Literature 2: JP-A-2006-256979

### SUMMARY OF THE INVENTION

### Problems to be Solved by the Invention

An object of the invention is to provide an organic EL device capable of emitting blue light and an aromatic amine derivative usable for an organic thin-film layer in the organic EL device.

### Means for Solving the Problems

According to the invention, the following aromatic amine derivative and organic

EL device are provided.

[1] According to an aspect of the invention, an aromatic amine derivative is represented by the following formula (1).

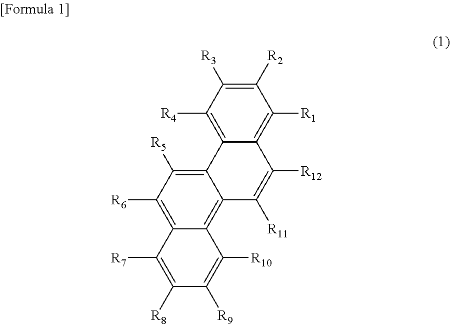

In the formula (1):

R₁ to R₅ and R₇ to R₁₁ are each independently a hydrogen atom, a deuterium atom, a halogen atom, a cyano group, a substituted or unsubstituted aryl group having 6 to 30 ring carbon atoms, a substituted or unsubstituted heterocyclic group having 5 to 30 ring atoms, a substituted or unsubstituted alkyl group having 1 to 30 carbon atoms, a substituted or unsubstituted alkenyl group having 2 to 30 carbon atoms, a substituted or unsubstituted alkynyl group having 2 to 30 carbon atoms, a substituted or unsubstituted alkylsilyl group having 3 to 30 carbon atoms, a substituted or unsubstituted arylsilyl group having 6 to 30 ring carbon atoms, a substituted or unsubstituted alkoxy group having 1 to 30 carbon atoms, a substituted or unsubstituted aralkyl group having 6 to 30 ring carbon atoms, or a substituted or unsubstituted aryloxy group having 6 to 30 ring carbon atoms; and

R₆ and R₁₂ are each independently represented by the following formula (2),

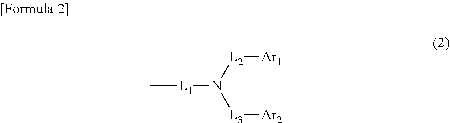

In the formula (2):

L₁, L₂ and L₃ are each independently a single bond, a divalent residue of a substituted or unsubstituted aryl group having 6 to 30 ring carbon atoms, or a divalent residue of a substituted or unsubstituted heterocyclic group having 5 to 30 ring atoms;

Ar₁ is a monovalent substituent represented by the following formula (3);

Ar₂ is a substituted or unsubstituted aryl group having 6 to 30 ring carbon atoms, a substituted or unsubstituted heterocyclic group having 5 to 30 ring atoms, or a monovalent residue derived from the ring structure of the following formula (4); and

a substituent for the aryl group or the heterocyclic group for Ar₂ is a deuterium atom, a halogen atom, a cyano group, a substituted or unsubstituted aryl group having 6 to 30 ring carbon atoms, a substituted or unsubstituted heterocyclic group having 5 to 30 ring atoms, a substituted or unsubstituted alkyl group having 1 to 30 carbon atoms, a substituted or unsubstituted alkenyl group having 2 to 30 carbon atoms, a substituted or unsubstituted alkynyl group having 2 to 30 carbon atoms, a substituted or unsubstituted alkylsilyl group having 3 to 30 carbon atoms, a substituted or unsubstituted arylsilyl group having 6 to 30 ring carbon atoms, a substituted or unsubstituted alkoxy group having 1 to 30 carbon atoms, a substituted or unsubstituted aralkyl group having 6 to 30 ring carbon atoms, or a substituted or unsubstituted aryloxy group having 6 to 30 ring carbon atoms.

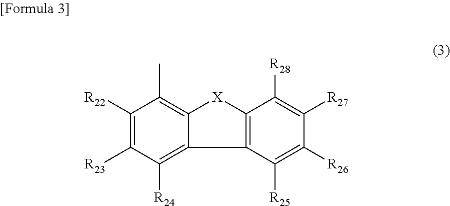

In the formula (3):

X is an oxygen atom or a sulfur atom;

R₂₂ to R₂₈ are each independently a hydrogen atom, a deuterium atom, a halogen atom, a cyano group, a substituted or unsubstituted aryl group having 6 to 30 ring carbon atoms, a substituted or unsubstituted heterocyclic group having 5 to 30 ring atoms, a substituted or unsubstituted alkyl group having 1 to 30 carbon atoms, a substituted or unsubstituted alkenyl group having 2 to 30 carbon atoms, a substituted or unsubstituted alkynyl group having 2 to 30 carbon atoms, a substituted or unsubstituted alkylsilyl group having 3 to 30 carbon atoms, a substituted or unsubstituted arylsilyl group having 6 to 30 ring carbon atoms, a substituted or unsubstituted alkoxy group having 1 to 30 carbon atoms, a substituted or unsubstituted aralkyl group having 6 to 30 ring carbon atoms, or a substituted or unsubstituted aryloxy group having 6 to 30 ring carbon atoms;

at least one combination of R₂₂ and R₂₃, R₂₃ and R₂₄, R₂₅ and R₂₆, R₂₆ and R₂₇, and R₂₇ and R₂₈ optionally forms a saturated or unsaturated ring; and the monovalent substituent of the formula (3) is bonded to L₂ at a bond where R₂₂ to R₂₈ are not bonded.

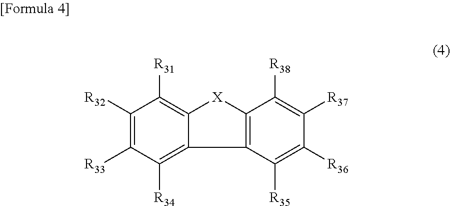

In the formula (4):

X is an oxygen atom or a sulfur atom;

R₃₁ to R₃₈ are each independently a hydrogen atom, a deuterium atom, a halogen atom, a cyano group, a substituted or unsubstituted aryl group having 6 to 30 ring carbon atoms, a substituted or unsubstituted heterocyclic group having 5 to 30 ring atoms, a substituted or unsubstituted alkyl group having 1 to 30 carbon atoms, a substituted or unsubstituted alkenyl group having 2 to 30 carbon atoms, a substituted or unsubstituted alkynyl group having 2 to 30 carbon atoms, a substituted or unsubstituted alkylsilyl group having 3 to 30 carbon atoms, a substituted or unsubstituted arylsilyl group having 6 to 30 ring carbon atoms, a substituted or unsubstituted alkoxy group having 1 to 30 carbon atoms, a substituted or unsubstituted aralkyl group having 6 to 30 ring carbon atoms, or a substituted or unsubstituted aryloxy group having 6 to 30 ring carbon atoms;

at least one combination of R₃₁ and R₃₂, R₃₂ and R₃₃, R₃₃ and R₃₄, R₃₅ and R₃₆, R₃₆ and R₃₇, and R₃₇ and R₃₈ optionally forms a saturated or unsaturated ring; and

one of R₃₁ to R₃₈ is a single bond to L₃.

[2] In the aromatic amine derivative, Ar₂ in the formula (2) is a substituted or unsubstituted aryl group having 6 to 30 ring carbon atoms.

[3] In the aromatic amine derivative, Ar₂ in the formula (2) is a monovalent residue derived from a ring structure of the formula (4).

[4] In the aromatic amine derivative, X in the formula (3) is an oxygen atom.

[5] In the aromatic amine derivative, at least one of R₂₂ to R₂₈ in the formula (3) is a substituted or unsubstituted aryl group having 6 to 30 ring carbon atoms, a substituted or unsubstituted heterocyclic group having 5 to 30 ring atoms, a substituted or unsubstituted alkyl group having 1 to 30 carbon atoms, a substituted or unsubstituted alkylsilyl group having 3 to 30 carbon atoms, a substituted or unsubstituted arylsilyl group having 6 to 30 ring carbon atoms, or a substituted or unsubstituted aralkyl group having 6 to 30 ring carbon atoms.

[6] In the aromatic amine derivative, R₂₈ in the formula (3) is a substituted or unsubstituted aryl group having 6 to 30 ring carbon atoms, a substituted or unsubstituted heterocyclic group having 5 to 30 ring atoms, a substituted or unsubstituted alkyl group having 1 to 30 carbon atoms, a substituted or unsubstituted alkylsilyl group having 3 to 30 carbon atoms, a substituted or unsubstituted arylsilyl group having 6 to 30 ring carbon atoms, or a substituted or unsubstituted aralkyl group having 6 to 30 ring carbon atoms.

[7] In the aromatic amine derivative, Ar₂ in the formula (2) is a phenyl group having an alkyl group in a para position.

[8] In the aromatic amine derivative, Ar₂ in the formula (2) is a phenyl group having an aryl group in a meta position.

[9] In the aromatic amine derivative, Ar₂ in the formula (2) is a phenyl group having an alkyl group in an ortho position.

[10] In the aromatic amine derivative, L₁ in the formula (2) is a single bond.

[11] In the aromatic amine derivative, L₂ in the formula (2) is a single bond.

[12] In the aromatic amine derivative, L₃ in the formula (2) is a single bond.

[13] According to another aspect of the invention, an organic electroluminescence device includes: a cathode; an anode; and an organic compound layer being provided between the cathode and the anode, the organic compound layer containing the aromatic amine derivative as described above.

[14] According to still another aspect of the invention, an organic electroluminescence device includes: a cathode; an anode; and one or more organic thin-film layers being interposed between the cathode and the anode, the organic thin-film layers including at least an emitting layer, the organic thin-film layers including at least one layer that contains the aromatic amine derivative as described above.

[15] According to yet another aspect of the invention, an organic electroluminescence device includes: a cathode; an anode; and one or more organic thin-film layers being interposed between the cathode and the anode, the organic thin-film layers including at least an emitting layer, the organic thin-film layers including at least one layer that contains the aromatic amine derivative as described above and an anthracene derivative of the following formula (20).

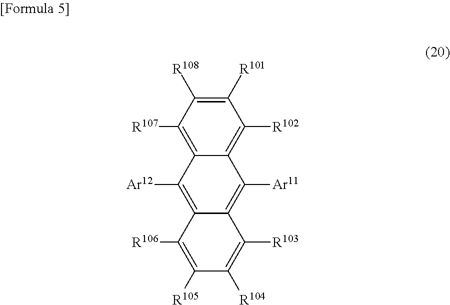

In the formula (20):

Ar¹¹ and Ar¹² are each independently a substituted or unsubstituted monocyclic group having 5 to 30 ring atoms, a substituted or unsubstituted fused ring group having 8 to 30 ring atoms, ora group formed by combining the monocyclic group and the fused ring group; and

R¹⁰¹ to R¹⁰⁸ are each independently a hydrogen atom, a halogen atom, a cyano group, a substituted or unsubstituted monocyclic group having 5 to 30 ring atoms, a substituted or unsubstituted fused ring group having 8 to 30 ring atoms, a group formed by combining the monocyclic group and the fused ring group, a substituted or unsubstituted alkyl group having 1 to 30 carbon atoms, a substituted or unsubstituted cycloalkyl group having 3 to 30 ring carbon atoms, a substituted or unsubstituted alkoxy group having 1 to 30 carbon atoms, a substituted or unsubstituted aralkyl group having 7 to 30 carbon atoms, a substituted or unsubstituted aryloxy group having 6 to 30 ring carbon atoms, or a substituted or unsubstituted silyl group.

[16] In the organic electroluminescence device, Ar¹¹ and Ar¹² in the formula (20) are each independently a substituted or unsubstituted fused ring group having 10 to 30 ring atoms.

[17] In the organic electroluminescence device, while one of Ar¹¹ and Ar¹² in the formula (20) is a substituted or unsubstituted monocyclic group having 5 to 30 ring atoms, the other of Ar¹¹ and Ar¹² is a substituted or unsubstituted fused ring group having 10 to 30 ring atoms.

[18] In the organic electroluminescence device, Ar¹² in the formula (20) is selected from among a naphthyl group, a phenanthryl group, a benzanthryl group and a dibenzofuranyl group, while Ar¹¹ is a substituted or unsubstituted phenyl group or a substituted or unsubstituted fluorenyl group.

[19] In the organic electroluminescence device, Ar¹² in the formula (20) is a substituted or unsubstituted fused ring group having 8 to 30 ring atoms, while Ar¹¹ is an unsubstituted phenyl group.

[20] In the organic electroluminescence device, Ar¹¹ and Ar¹² in the formula (20) are each independently a substituted or unsubstituted monocyclic group having 5 to 30 ring atoms.

[21] In the organic electroluminescence device, Ar¹¹ and Ar¹² in the formula (20) are each independently a substituted or unsubstituted phenyl group.

[22] In the organic electroluminescence device, Ar¹¹ in the formula (20) is an unsubstituted phenyl group, while Ar¹² is a phenyl group having at least one of a monocyclic group and a fused ring group as a substituent.

[23] In the organic electroluminescence device, Ar¹¹ and Ar¹² in the formula (20) are each independently a phenyl group having at least one of a monocyclic group and a fused ring group as a substituent.

The aromatic amine derivative and the organic thin-film layers according to the above aspects of the invention contribute to providing an organic EL device capable of emitting blue light.

### BRIEF DESCRIPTION OF DRAWINGS

FIG. 1 schematically shows an exemplary arrangement of an organic electroluminescence device according to an exemplary embodiment of the invention.

### DESCRIPTION OF EMBODIMENT(S)

### Aromatic Amine Derivative

An aromatic amine derivative according to the invention is represented by the above formula (1).

R₁ to R₅ and R₇ to R₁₁ in the formula (1) are described below. R₁ to R₅ and R₇ to R₁₁ are each independently a hydrogen atom, a deuterium atom, a halogen atom, a cyano group, a substituted or unsubstituted aryl group having 6 to 30 ring carbon atoms, a substituted or unsubstituted heterocyclic group having 5 to 30 ring atoms, a substituted or unsubstituted alkyl group having 1 to 30 carbon atoms, a substituted or unsubstituted alkenyl group having 2 to 30 carbon atoms, a substituted or unsubstituted alkynyl group having 2 to 30 carbon atoms, a substituted or unsubstituted alkylsilyl group having 3 to 30 carbon atoms, a substituted or unsubstituted arylsilyl group having 6 to 30 ring carbon atoms, a substituted or unsubstituted alkoxy group having 1 to 30 carbon atoms, a substituted or unsubstituted aralkyl group having 6 to 30 ring carbon atoms, or a substituted or unsubstituted aryloxy group having 6 to 30 ring carbon atoms.

Examples of the aryl group having 6 to 30 ring carbon atoms in the formula (1) are a phenyl group, biphenyl group, terphenyl group, naphthyl group, anthryl group, phenanthryl group, fluorenyl group, pyrenyl group, chrysenyl group, fluoranthenyl group, benzo[a]anthryl group, benzo[c] phenanthryl group, triphenylenyl group, benzo[k]fluoranthenyl group, benzo[g]chrysenyl group, benzo[b]triphenylenyl group, picenyl group and perylenyl group.

The aryl group in the formula (1) preferably has 6 to 20 ring carbon atoms, more preferably 6 to 12 ring carbon atoms. Among the above examples of the aryl group, a phenyl group, biphenyl group, naphthyl group, phenanthryl group, terphenyl group and fluorenyl group are particularly preferable. In the 1-fluorenyl group, 2-fluorenyl group, 3-fluorenyl group and 4-fluorenyl group, it is preferable that a carbon atom in the 9-position is substituted with a later-described substituted or unsubstituted alkyl group having 1 to 30 carbon atoms for the formula (1).

Examples of the heterocyclic group having 5 to 30 ring atoms in the formula (1) are a pyridyl group, pyrimidinyl group, pyrazinyl group, pyridazinyl group, triazinyl group, quinolyl group, isoquinolyl group, naphthyridinyl group, phthalazinyl group, quinoxalinyl group, quinazolinyl group, phenanthridinyl group, acridinyl group, phenanthrolinyl group, pyrrolyl group, imidazolyl group, pyrazolyl group, triazolyl group, tetrazolyl group, indolyl group, benzimidazolyl group, indazolyl group, imidazopyridinyl group, benzotriazolyl group, carbazolyl group, furyl group, thienyl group, oxazolyl group, thiazolyl group, isoxazolyl group, isothiazolyl group, oxadiazolyl group, thiadiazolyl group, benzofuranyl group, benzothiophenyl group, benzoxazolyl group, benzothiazolyl group, benzisoxazolyl group, benzisothiazolyl group, benzoxadiazolyl group, benzothiadiazolyl group, dibenzofuranyl group, dibenzothiophenyl group, piperidinyl group, pyrrolidinyl group, piperazinyl group, morpholyl group, phenazinyl group, phenothiazinyl group and phenoxazinyl group.

The number of the ring atoms of the heterocyclic group in the formula (1) is preferably 5 to 20, more preferably 5 to 14. Among the above examples of the heterocyclic group, a 1-dibenzofuranyl group, 2-dibenzofuranyl group, 3-dibenzofuranyl group, 4-dibenzofuranyl group, 1-dibenzothiophenyl group, 2-dibenzothiophenyl group, 3-dibenzothiophenyl group, 4-dibenzothiophenyl group, 1-carbazolyl group, 2-carbazolyl group, 3-carbazolyl group, 4-carbazolyl group and 9-carbazolyl group are particularly preferable. In a 1-carbazolyl group, 2-carbazolyl group, 3-carbazolyl group and 4-carbazolyl group, it is preferable that a nitrogen atom in the 9-position is substituted with the substituted or unsubstituted aryl group having 6 to 30 ring carbon atoms or the substituted or unsubstituted heterocyclic group having 5 to 30 ring atoms for the formula (1).

The alkyl group having 1 to 30 carbon atoms in the formula (1) may be linear, branched or cyclic. Examples of the linear or branched alkyl group are a methyl group, ethyl group, n-propyl group, isopropyl group, n-butyl group, s-butyl group, isobutyl group, t-butyl group, n-pentyl group, n-hexyl group, n-heptyl group, n-octyl group, n-nonyl group, n-decyl group, n-undecyl group, n-dodecyl group, n-tridecyl group, n-tetradecyl group, n-pentadecyl group, n-hexadecyl group, n-heptadecyl group, n-octadecyl group, neo-pentyl group, amyl group, isoamyl group, 1-methylpentyl group, 2-methylpentyl group, 1-pentylhexyl group, 1-butylpentyl group, 1-heptyloctyl group and 3-methylpentyl group.

The number of the carbon atoms of the linear or branched alkyl group in the formula (1) is preferably 1 to 10, more preferably 1 to 6. Among the above examples of the linear or branched alkyl group, a methyl group, ethyl group, propyl group, isopropyl group, n-butyl group, s-butyl group, isobutyl group, t-butyl group, n-pentyl group, n-hexyl group, amyl group, isoamyl group and neo-pentyl group are particularly preferable.

Examples of the cycloalkyl group in the formula (1) are a cyclopropyl group, cyclobutyl group, cyclopentyl group, cyclohexyl group, 4-methylcyclohexyl group, adamantly group and norbornyl group. The number of the ring carbon atoms of the cycloalkyl group is preferably 3 to 10, more preferably 5 to 8. Among the above examples of the cycloalkyl group, a cyclopentyl group and a cyclohexyl group are particularly preferable.

An example of a halogenated alkyl group obtained by substituting an alkyl group with a halogen atom is one obtained by substituting the above alkyl group having 1 to 30 carbon atoms with one or more halogen group(s). Specific examples of the halogenated alkyl group are a fluoromethyl group, difluoromethyl group, trifluoromethyl group, fluoroethyl group, trifluoromethylmethyl group, trifluoroethyl group and pentafluoroethyl group.

The alkenyl group having 2 to 30 carbon atoms in the formula (1) may be linear, branched or cyclic and examples thereof are a vinyl group, propenyl group, butenyl group, oleyl group, eicosapentaenyl group, docosahexaenyl group, styryl group, 2,2-diphenylvinyl group, 1,2,2-triphenylvinyl group, 2-phenyl-2-propenyl group, cyclopentadienyl group, cyclopentenyl group, cyclohexenyl group and cyclohexadienyl group.

The alkynyl group having 2 to 30 carbon atoms in the formula (1) may be linear, branched or cyclic and examples thereof are ethynyl, propynyl and 2-phenylethynyl.

The alkylsilyl group having 3 to 30 carbon atoms in the formula (1) is exemplified by a trialkylsilyl group having an exemplary alkyl group listed for the above alkyl group having 1 to 30 carbon atoms. Specific examples of the alkylsilyl group are a trimethylsilyl group, triethylsilyl group, tri-n-butylsilyl group, tri-n-octylsilyl group, triisobutylsilyl group, dimethylethylsilyl group, dimethylisopropylsilyl group, dimethyl-n-propylsilyl group, dimethyl-n-butylsilyl group, dimethyl-t-butylsilyl group, diethylisopropylsilyl group, vinyldimethylsilyl group, propyldimethylsilyl group and triisopropylsilyl group. The three alkyl groups in the trialkylsilyl group may be mutually the same or different.

Examples of the arylsilyl group having 6 to 30 ring carbon atoms in the formula (1) are a dialkylarylsilyl group, alkyldiarylsilyl group and triarylsilyl group.

An example of the dialkylarylsilyl group is a dialkylarylsilyl group having two of the exemplary alkyl groups listed for the above alkyl group having 1 to 30 carbon atoms and one of the above aryl groups having 6 to 30 ring carbon atoms. The number of the carbon atoms of the dialkylarylsilyl group is preferably 8 to 30.

An example of the alkyldiarylsilyl group is an alkyldiarylsilyl group having one of the exemplary alkyl groups listed for the above alkyl group having 1 to 30 carbon atoms and two of the above aryl groups having 6 to 30 ring carbon atoms. The number of the carbon atoms of the alkyldiarylsilyl group is preferably 13 to 30.

An example of the triarylsilyl group is a triarylsilyl group having three of the above aryl groups having 6 to 30 ring carbon atoms. The number of the carbon atoms of the triarylsilyl group is preferably 18 to 30.

The alkoxy group having 1 to 30 carbon atoms in the formula (1) is represented by —OY. An example of Y is the above alkyl group having 1 to 30 carbon atoms. Examples of the alkoxy group are a methoxy group, ethoxy group, propoxy group, butoxy group, pentyloxy group and hexyloxy group.

An example of a halogenated alkoxy group obtained by substituting an alkoxy group with a halogen atom is one obtained by substituting the above alkoxy group having 1 to 30 carbon atoms with one or more halogen group(s).

The aralkyl group having 6 to 30 ring carbon atoms in the formula (1) is represented by —Y—Z₁. An example of Y is an alkylene group related to the above alkyl group having 1 to 30 carbon atoms. Examples of Z₁ are the same as those of the above aryl group having 6 to 30 ring carbon atoms. The aralkyl group is preferably an aralkyl group having 7 to 30 carbon atoms, in which an aryl part has 6 to 30 carbon atoms, preferably 6 to 20 carbon atoms, more preferably 6 to 12 carbon atoms, while an alkyl part has 1 to 30 carbon atoms, preferably 1 to 20 carbon atoms, more preferably 1 to 10 carbon atoms, further more preferably 1 to 6 carbon atoms. Example of such an aralkyl group are a benzyl group, 2-phenylpropane-2-yl group, 1-phenylethyl group, 2-phenylehyl group, 1-phenylisopropyl group, 2-phenylisopropyl group, phenyl-t-butyl group, alpha-naphthylmethyl group, 1-alpha-naphthylethyl group, 2-alpha-naphthylethyl group, 1-alpha-naphthylisopropyl group, 2-alpha-naphthylisopropyl group, beta-naphthylmethyl group, 1-beta-naphthylethyl group, 2-beta-naphthylethyl group, 1-beta-naphthylisopropyl group and 2-beta-naphthylisopropyl group.

The aryloxy group having 6 to 30 ring carbon atoms in the formula (1) is represented by —OZ₂. Examples of Z₂ are the above aryl group having 6 to 30 ring carbon atoms and later-described monocyclic group and fused ring group. An example of the aryloxy group is a phenoxy group.

Examples of the halogen atom in the formula (1) are fluorine, chlorine, bromine and iodine, among which a fluorine atom is preferable.

According to the invention, “ring carbon atoms (i.e., carbon atoms forming a ring)” means carbon atoms forming a saturated ring, unsaturated ring or aromatic ring. “Ring atoms (i.e., atoms forming a ring)” means carbon atoms and hetero atoms (e.g., nitrogen atoms, oxygen atoms, sulfur atoms and phosphorus atoms) forming a hetero ring including a saturated ring, unsaturated ring and aromatic ring.

When the expression “substituted or unsubstituted” is used, examples of the intended substituent include an aryl group, heterocyclic group, alkyl group (e.g., a linear or branched alkyl group, cycloalkyl group and halogenated alkyl group), alkenyl group, alkynyl group, alkylsilyl group, arylsilyl group, alkoxy group, halogenated alkoxy group, aralkyl group, aryloxy group, halogen atom, deuterium atom and cyano group as described above and further include a hydroxyl group, nitro group and carboxy group. Among the above examples of the substituent, an aryl group, heterocyclic group, alkyl group, halogen atom, alkylsilyl group, arylsilyl group, cyano group and deuterium atom are preferable and specific preferable examples of these exemplary substituents are further preferable.

When a substance is “substituted or unsubstituted”, “unsubstituted” means that the substance is not substituted with any of the above substituents but bonded to a hydrogen atom.

Similarly, when the expression “substituted or unsubstituted” is used in relation to later-described compounds and moieties thereof, the intended substituent is the same as described above.

R₆ and R₁₂ in the formula (1) are each independently represented by the above formula (2).

In the formula (2), L₁, L₂ and L₃ are each independently a single bond, a divalent residue of a substituted or unsubstituted aryl group having 6 to 30 ring carbon atoms, or a divalent residue of a substituted or unsubstituted heterocyclic group having 5 to 30 ring atoms.

The divalent residue of the aryl group having 6 to 30 ring carbon atoms is exemplified by a divalent group derived from the above aryl group having 6 to 30 ring carbon atoms.

The divalent residue of the heterocyclic group having 5 to 30 ring atoms is exemplified by a divalent group derived from the above heterocyclic group having 5 to 30 ring atoms.

L¹ in the formula (2) is preferably a single bond.

L₂ in the formula (2) is preferably a single bond.

L₃ in the formula (2) is preferably a single bond.

Ar₁ in the formula (2) is a monovalent substituent represented by the above formula (3).

In the formula (2), Ar₂ is a substituted or unsubstituted aryl group having 6 to 30 ring carbon atoms, a substituted or unsubstituted heterocyclic group having 5 to 30 ring atoms, or a monovalent residue derived from a ring structure represented by the above formula (4). Examples of the aryl group and the heterocyclic group for Ar₂ are the same as ones listed for R₁ to R₅ and R₇ to R₁₁ in the formula (1).

When Ar₂ in the formula (2) is a substituted aryl group, preferable groups as Ar₂ can be exemplified as follows depending on the substitution site.

Ar₂ in the formula (2) is preferably a phenyl group having an alkyl group in a para position. Specifically, the aryl group bonded to L₂ is a phenyl group that is preferably substituted with an alkyl group in a para position relative to a carbon atom bonded to L₂. Such substitution with the alkyl group in the para position is expected to contribute to blocking an active site in a molecular structure, thereby increasing the lifetime of the organic EL device. In the above case, examples of the alkyl group are the same as ones listed above for the alkyl group having 1 to 30 carbon atoms in the formula (1), among which a propyl group, an isopropyl group, an n-butyl group and a t-butyl group are preferable.

Ar₂ in the formula (2) is preferably a phenyl group having an aryl group in a meta position. Specifically, the aryl group bonded to L₂ is a phenyl group that is preferably substituted with an aryl group in a meta position relative to a carbon atom bonded to L₂. Such substitution with the aryl group in the meta position contributes to increasing the area of a π-plane while suppressing extension of a conjugation length of an amine-part to a low level. As a result, redshift resulting from an increased conjugation length can be minimized. Further, when the aromatic amine derivative with an increased area of the π-plane is used as a dopant material for an emitting layer, it is expected that an organic EL device can emit light with a high efficiency due to a smooth energy transfer from a host material to the dopant material. In the above case, examples of the aryl group are the same as ones listed above for the aryl group having 6 to 30 ring carbon atoms in the formula (1), among which a phenyl group is preferable.

Ar₂ in the formula (2) is preferably a phenyl group having an alkyl group in an ortho position. Specifically, the aryl group bonded to L₂ is a phenyl group that is preferably substituted with an alkyl group in a meta position relative to a carbon atom bonded to L₂. Such substitution with the alkyl group in the ortho position contributes to emission of further blue-shifted light. In the above case, examples of the alkyl group are the same as ones listed above for the alkyl group having 1 to 30 carbon atoms in the formula (1), among which a methyl group is preferable.

A substituent for the aryl group or the heterocyclic group for Ar₂ in the formula (2) is a deuterium atom, a halogen atom, a cyano group, a substituted or unsubstituted aryl group having 6 to 30 ring carbon atoms, a substituted or unsubstituted heterocyclic group having 5 to 30 ring atoms, a substituted or unsubstituted alkyl group having 1 to 30 carbon atoms, a substituted or unsubstituted alkenyl group having 2 to 30 carbon atoms, a substituted or unsubstituted alkynyl group having 2 to 30 carbon atoms, a substituted or unsubstituted alkylsilyl group having 3 to 30 carbon atoms, a substituted or unsubstituted arylsilyl group having 6 to 30 ring carbon atoms, a substituted or unsubstituted alkoxy group having 1 to 30 carbon atoms, a substituted or unsubstituted aralkyl group having 6 to 30 ring carbon atoms, or a substituted or unsubstituted aryloxy group having 6 to 30 ring carbon atoms. Examples of the aryl group, heterocyclic group, alkyl group, alkenyl group, alkynyl group, alkylsilyl group, arylsilyl group, alkoxy group, aralkyl group or aryloxy group (i.e., a substituent for the aryl group for Ar₂ in the formula (2)) are the same as ones listed above for R₁ to R₅ and R₇ to R₁₁ in the formula (1).

In the formula (3), X is an oxygen atom or a sulfur atom.

In the formula (3), R₂₂ to R₂₈ are each independently a hydrogen atom, a deuterium atom, a halogen atom, a cyano group, a substituted or unsubstituted aryl group having 6 to 30 ring carbon atoms, a substituted or unsubstituted heterocyclic group having 5 to 30 ring atoms, a substituted or unsubstituted alkyl group having 1 to 30 carbon atoms, a substituted or unsubstituted alkenyl group having 2 to 30 carbon atoms, a substituted or unsubstituted alkynyl group having 2 to 30 carbon atoms, a substituted or unsubstituted alkylsilyl group having 3 to 30 carbon atoms, a substituted or unsubstituted arylsilyl group having 6 to 30 ring carbon atoms, a substituted or unsubstituted alkoxy group having 1 to 30 carbon atoms, a substituted or unsubstituted aralkyl group having 6 to 30 ring carbon atoms, or a substituted or unsubstituted aryloxy group having 6 to 30 ring carbon atoms. Examples of the aryl group, heterocyclic group, alkyl group, alkenyl group, alkynyl group, alkylsilyl group, arylsilyl group, alkoxy group, aralkyl group and aryloxy group for R₂₂ to R₂₈ in the formula (3) are the same as ones listed above for R₁ to R₅ and R₇ to R₁₁ in the formula (1).

The monovalent substituent of the formula (3) is bonded to L₂ at a bond where R₂₂ to R₂₈ are not bonded.

At least one of R₂₂ to R₂₈ in the formula (3) is preferably a substituted or unsubstituted aryl group having 6 to 30 ring carbon atoms, a substituted or unsubstituted heterocyclic group having 5 to 30 ring atoms, a substituted or unsubstituted alkyl group having 1 to 30 carbon atoms, a substituted or unsubstituted alkylsilyl group having 3 to 30 carbon atoms, a substituted or unsubstituted arylsilyl group having 6 to 30 ring carbon atoms, or a substituted or unsubstituted aralkyl group having 6 to 30 ring carbon atoms.

R₂₈ in the formula (3) is preferably a substituted or unsubstituted aryl group having 6 to 30 ring carbon atoms, a substituted or unsubstituted heterocyclic group having 5 to 30 ring atoms, a substituted or unsubstituted alkyl group having 1 to 30 carbon atoms, a substituted or unsubstituted alkylsilyl group having 3 to 30 carbon atoms, a substituted or unsubstituted arylsilyl group having 6 to 30 ring carbon atoms, or a substituted or unsubstituted aralkyl group having 6 to 30 ring carbon atoms.

At least one combination of R₂₂ and R₂₃, R₂₃ and R₂₄, R₂₅ and R₂₆, R₂₆ and R₂₇, and R₂₇ and R₂₈ in the formula (3) optionally forms a saturated or unsaturated ring. When such a ring is optionally formed, the structure of the formula (3) is represented by, for instance, one of the following formulae (3A) to (31). In the formulae (3A) to (31), R₂₂ to R₃₀ are each independently exemplified in the same manner as R₁ to R₅ and R₇ to R₁₁ in the formula (1).

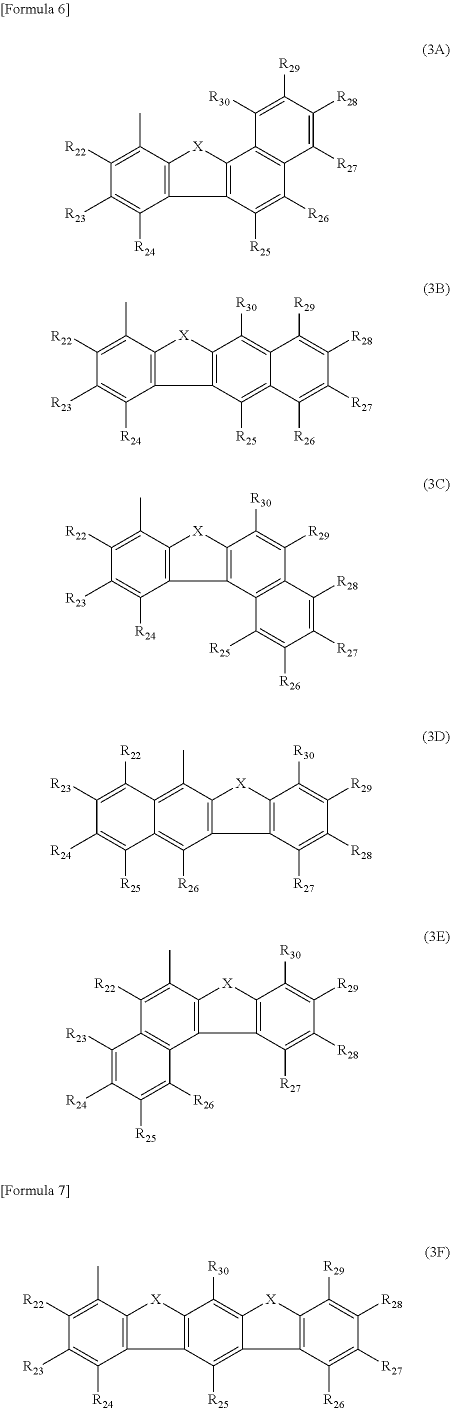

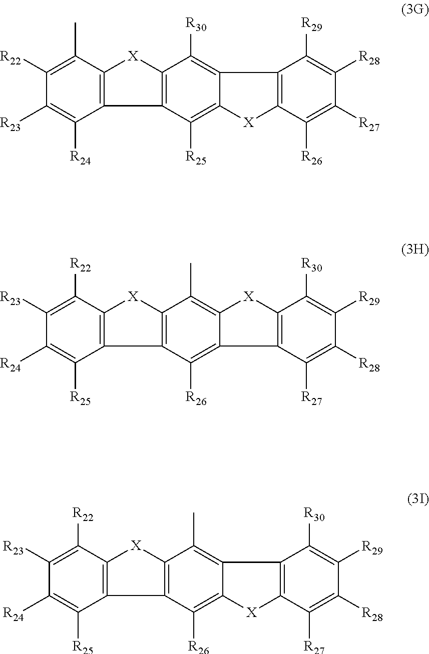

In the formula (4), X is an oxygen atom or a sulfur atom.

R₃₁ to R₃₈ in the formula (4) are each independently a hydrogen atom, a deuterium atom, a halogen atom, a cyano group, a substituted or unsubstituted aryl group having 6 to 30 ring carbon atoms, a substituted or unsubstituted heterocyclic group having 5 to 30 ring atoms, a substituted or unsubstituted alkyl group having 1 to 30 carbon atoms, a substituted or unsubstituted alkenyl group having 2 to 30 carbon atoms, a substituted or unsubstituted alkynyl group having 2 to 30 carbon atoms, a substituted or unsubstituted alkylsilyl group having 3 to 30 carbon atoms, a substituted or unsubstituted arylsilyl group having 6 to 30 ring carbon atoms, a substituted or unsubstituted alkoxy group having 1 to 30 carbon atoms, a substituted or unsubstituted aralkyl group having 6 to 30 ring carbon atoms, or a substituted or unsubstituted aryloxy group having 6 to 30 ring carbon atoms. Examples of the aryl group, heterocyclic group, alkyl group, alkenyl group, alkynyl group, alkylsilyl group, arylsilyl group, alkoxy group, aralkyl group and aryloxy group for R₂₂ to R₂₈ in the formula (4) are the same as ones listed above for R₁ to R₅ and R₇ to R₁₁ in the formula (1).

One of R₃₁ to R₃₈ in the formula (4) is a single bond to L₃. When one of R₃₁ to R₃₈ is a single bond as described above, the structure of the formula (4) is represented by, for instance, one of the following formulae (4A) to (4D). In the formula (4A), a portion as labeled by R₃₁ in the formula (4) is a single bond instead of a methyl group. The same is applicable to the other formulae (4B) to (4D). Among the above formulae (4A) to (4D), the formula (4A), in which R₃₁ is a single bond, and the formulae (4C), in which R₃₃ is a single bond, are preferable. Additionally, a structure in which R₃₈ or R₃₆ is a single bond is also preferable.

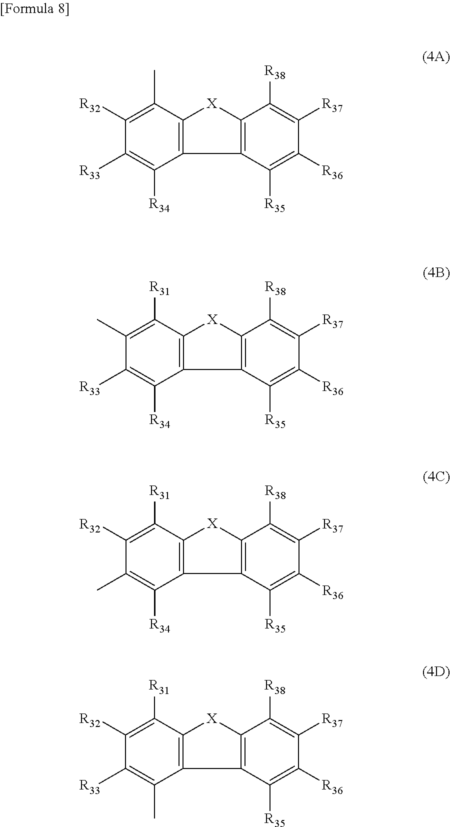

At least one combination of R₃₁ and R₃₂, R₃₂ and R₃₃, R₃₃ and R₃₄, R₃₅ and R₃₆, R₃₆ and R₃₇, and R₃₇ and R₃₈ optionally forms a saturated or unsaturated ring. When such a ring is optionally formed, the structure of the formula (4) is represented by, for instance, one of the following formulae (4E), (4F) and (4G). In the formulae (4E), (4F) and (4G), R₃₁ to R₄₀ are each independently exemplified in the same manner as R₁ to R₅ and R₇ to R₁₁ in the formula (1).

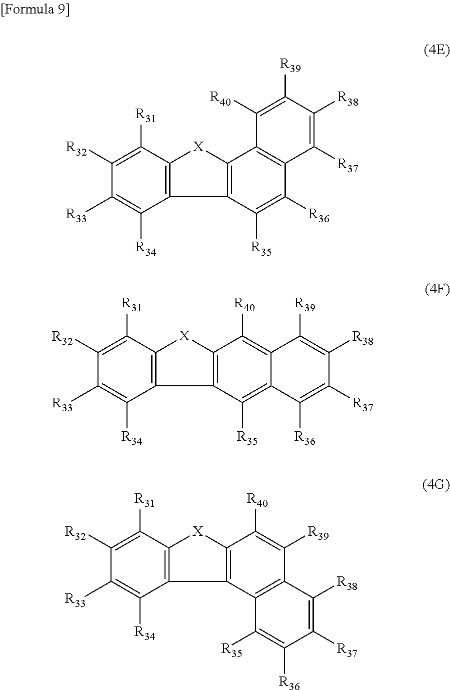

Specific examples of the structure of the aromatic amine derivative according to the invention are shown below. It should be understood that these examples of the structure of the aromatic amine derivative are not exhaustive.

The aromatic amine derivative according to the invention has such a structure that R₆ and R₁₂ in the formula (1) are each represented by the formula (2), the structure being represented by the following formula (1A).

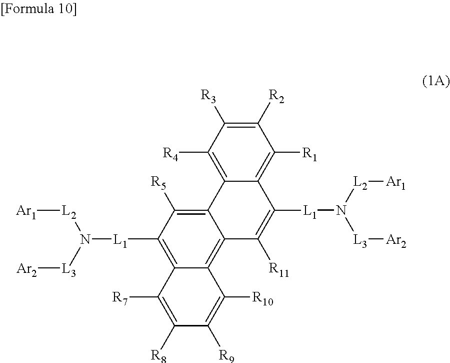

The aromatic amine derivative according to the invention is preferably a compound represented by the following formula (5).

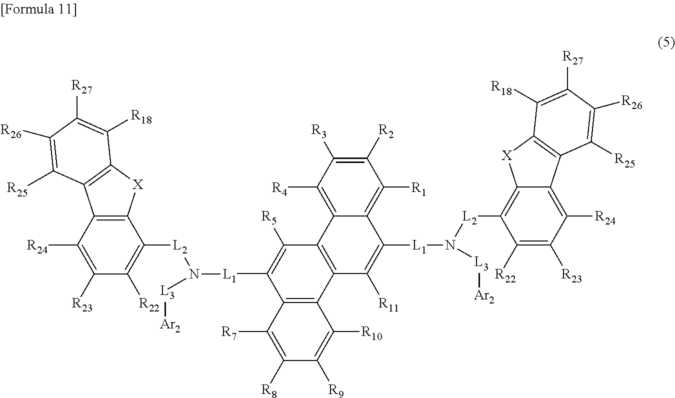

In the formula (5), R₁ to R₅ and R₇ to R₁₁ are each independently a hydrogen atom, a deuterium atom, a halogen atom, a cyano group, a substituted or unsubstituted aryl group having 6 to 30 ring carbon atoms, a substituted or unsubstituted heterocyclic group having 5 to 30 ring atoms, a substituted or unsubstituted alkyl group having 1 to 30 carbon atoms, a substituted or unsubstituted alkenyl group having 2 to 30 carbon atoms, a substituted or unsubstituted alkynyl group having 2 to 30 carbon atoms, a substituted or unsubstituted alkylsilyl group having 3 to 30 carbon atoms, a substituted or unsubstituted arylsilyl group having 6 to 30 ring carbon atoms, a substituted or unsubstituted alkoxy group having 1 to 30 carbon atoms, a substituted or unsubstituted aralkyl group having 6 to 30 ring carbon atoms, or a substituted or unsubstituted aryloxy group having 6 to 30 ring carbon atoms.

L₁ to L₃ are each independently a single bond, a divalent residue of a substituted or unsubstituted aryl group having 6 to 30 ring carbon atoms, or a divalent residue of a substituted or unsubstituted heterocyclic group having 5 to 30 ring atoms.

Ar₂ is a substituted or unsubstituted aryl group having 6 to 30 ring carbon atoms. R₂₂ to R₂₈ are each independently a hydrogen atom, a deuterium atom, a halogen atom, a cyano group, a substituted or unsubstituted aryl group having 6 to 30 ring carbon atoms, a substituted or unsubstituted heterocyclic group having 5 to 30 ring atoms, a substituted or unsubstituted alkyl group having 1 to 30 carbon atoms, a substituted or unsubstituted alkenyl group having 2 to 30 carbon atoms, a substituted or unsubstituted alkynyl group having 2 to 30 carbon atoms, a substituted or unsubstituted alkylsilyl group having 3 to 30 carbon atoms, a substituted or unsubstituted arylsilyl group having 6 to 30 ring carbon atoms, a substituted or unsubstituted alkoxy group having 1 to 30 carbon atoms, a substituted or unsubstituted aralkyl group having 6 to 30 ring carbon atoms, or a substituted or unsubstituted aryloxy group having 6 to 30 ring carbon atoms.

X is an oxygen atom or a sulfur atom.

Among compounds represented by the formula (5), a compound represented by the following formula (5a) is preferable.

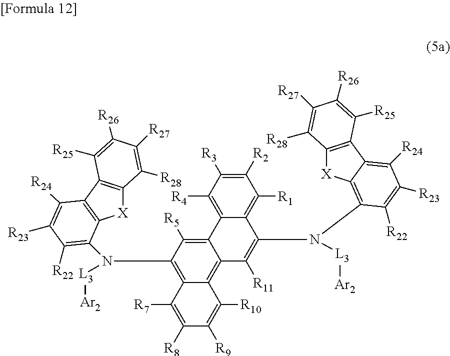

In the formula (5a), R₁ to R₅ and R₇ to R₁₁ are each independently a hydrogen atom, a deuterium atom, a halogen atom, a cyano group, a substituted or unsubstituted aryl group having 6 to 30 ring carbon atoms, a substituted or unsubstituted heterocyclic group having 5 to 30 ring atoms, a substituted or unsubstituted alkyl group having 1 to 30 carbon atoms, a substituted or unsubstituted alkenyl group having 2 to 30 carbon atoms, a substituted or unsubstituted alkynyl group having 2 to 30 carbon atoms, a substituted or unsubstituted alkylsilyl group having 3 to 30 carbon atoms, a substituted or unsubstituted arylsilyl group having 6 to 30 ring carbon atoms, a substituted or unsubstituted alkoxy group having 1 to 30 carbon atoms, a substituted or unsubstituted aralkyl group having 6 to 30 ring carbon atoms, or a substituted or unsubstituted aryloxy group having 6 to 30 ring carbon atoms.

L₃ is a single bond, a divalent residue of a substituted or unsubstituted aryl group having 6 to 30 ring carbon atoms, or a divalent residue of a substituted or unsubstituted heterocyclic group having 5 to 30 ring atoms.

Ar₂ is a substituted or unsubstituted aryl group having 6 to 30 ring carbon atoms.

R₂₂ to R₂₈ are each independently a hydrogen atom, a deuterium atom, a halogen atom, a cyano group, a substituted or unsubstituted aryl group having 6 to 30 ring carbon atoms, a substituted or unsubstituted heterocyclic group having 5 to 30 ring atoms, a substituted or unsubstituted alkyl group having 1 to 30 carbon atoms, a substituted or unsubstituted alkenyl group having 2 to 30 carbon atoms, a substituted or unsubstituted alkynyl group having 2 to 30 carbon atoms, a substituted or unsubstituted alkylsilyl group having 3 to 30 carbon atoms, a substituted or unsubstituted arylsilyl group having 6 to 30 ring carbon atoms, a substituted or unsubstituted alkoxy group having 1 to 30 carbon atoms, a substituted or unsubstituted aralkyl group having 6 to 30 ring carbon atoms, or a substituted or unsubstituted aryloxy group having 6 to 30 ring carbon atoms.

X is an oxygen atom or a sulfur atom.

In compounds represented by the formula (5) or (5a), it is preferable that any one of R₂₂ to R₂₈ is selected from among a substituted or unsubstituted aryl group having 6 to 30 ring carbon atoms, a substituted or unsubstituted heterocyclic group having 5 to 30 ring atoms, a substituted or unsubstituted alkyl group having 1 to 30 carbon atoms, a substituted or unsubstituted alkylsilyl group having 3 to 30 carbon atoms, a substituted or unsubstituted arylsilyl group having 6 to 30 ring carbon atoms, and a substituted or unsubstituted aralkyl group having 6 to 30 ring carbon atoms. It is more preferable that R₂₈ is selected from among a substituted or unsubstituted aryl group having 6 to 30 ring carbon atoms, a substituted or unsubstituted heterocyclic group having 5 to 30 ring atoms, a substituted or unsubstituted alkyl group having 1 to 30 carbon atoms, a substituted or unsubstituted alkylsilyl group having 3 to 30 carbon atoms, a substituted or unsubstituted arylsilyl group having 6 to 30 ring carbon atoms, and a substituted or unsubstituted aralkyl group having 6 to 30 ring carbon atoms.

When R₂₈ is a substituent as exemplified above, the compound according to the invention has a structure with an increased steric bulk. Therefore, when being used for an emitting layer, the aromatic amine derivative according to the invention is less likely to be affected by coexisting host atoms and the like, so that a light-emitting device can emit blue light with a higher purity.

In compounds represented by the formula (5) or (5a), it is preferable that the rest of R₂₂ to R₂₈ are each a hydrogen atom, a substituted or unsubstituted aryl group having 6 to 30 ring carbon atoms, a substituted or unsubstituted heterocyclic group having 5 to 30 ring atoms, a substituted or unsubstituted alkyl group having 1 to 30 carbon atoms, a substituted or unsubstituted alkylsilyl group having 3 to 30 carbon atoms, a substituted or unsubstituted arylsilyl group having 6 to 30 ring carbon atoms, or a substituted or unsubstituted aralkyl group having 6 to 30 ring carbon atoms. It is more preferable that the rest of R₂₂ to R₂₈ are each a hydrogen atom, a substituted or unsubstituted aryl group having 6 to 30 ring carbon atoms, a substituted or unsubstituted alkyl group having 1 to 30 carbon atoms, ora substituted or unsubstituted alkylsilyl group having 3 to 30 carbon atoms.

X preferably represents an oxygen atom.

Ar₂ is preferably a substituted or unsubstituted aryl group having 6 to 18 ring carbon atoms and more preferably a substituted or unsubstituted phenyl group, a substituted or unsubstituted biphenylyl group or a substituted or unsubstituted terphenylyl group.

L₁ to L₃ are each preferably a single bond or a substituted or unsubstituted phenylenyl group and more preferably a single bond.

The aromatic amine derivative according to the invention is preferably a compound represented by the following formula (6).

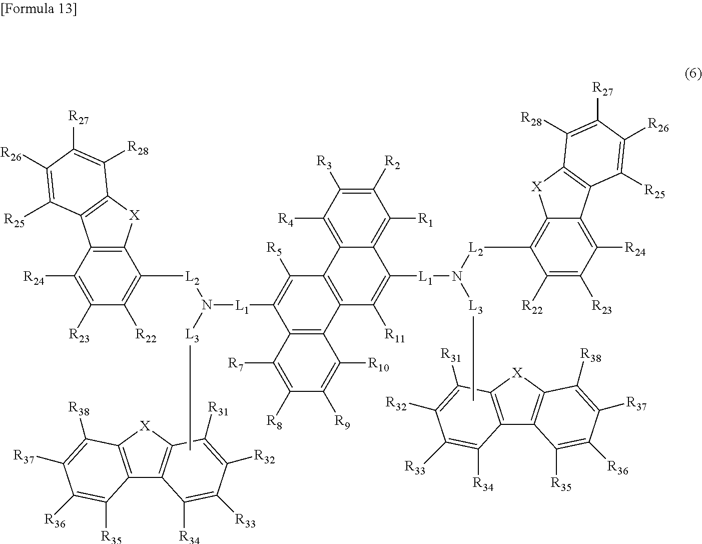

In the formula (6), R₁ to R₅ and R₇ to R₁₁ are each independently a hydrogen atom, a deuterium atom, a halogen atom, a cyano group, a substituted or unsubstituted aryl group having 6 to 30 ring carbon atoms, a substituted or unsubstituted heterocyclic group having 5 to 30 ring atoms, a substituted or unsubstituted alkyl group having 1 to 30 carbon atoms, a substituted or unsubstituted alkenyl group having 2 to 30 carbon atoms, a substituted or unsubstituted alkynyl group having 2 to 30 carbon atoms, a substituted or unsubstituted alkylsilyl group having 3 to 30 carbon atoms, a substituted or unsubstituted arylsilyl group having 6 to 30 ring carbon atoms, a substituted or unsubstituted alkoxy group having 1 to 30 carbon atoms, a substituted or unsubstituted aralkyl group having 6 to 30 ring carbon atoms, or a substituted or unsubstituted aryloxy group having 6 to 30 ring carbon atoms.

L₁ to L₃ are each independently a single bond, a divalent residue of a substituted or unsubstituted aryl group having 6 to 30 ring carbon atoms, or a divalent residue of a substituted or unsubstituted heterocyclic group having 5 to 30 ring atoms.

Ar₂ is a substituted or unsubstituted aryl group having 6 to 30 ring carbon atoms.

R₂₂ to R₂₈ are each independently a hydrogen atom, a deuterium atom, a halogen atom, a cyano group, a substituted or unsubstituted aryl group having 6 to 30 ring carbon atoms, a substituted or unsubstituted heterocyclic group having 5 to 30 ring atoms, a substituted or unsubstituted alkyl group having 1 to 30 carbon atoms, a substituted or unsubstituted alkenyl group having 2 to 30 carbon atoms, a substituted or unsubstituted alkynyl group having 2 to 30 carbon atoms, a substituted or unsubstituted alkylsilyl group having 3 to 30 carbon atoms, a substituted or unsubstituted arylsilyl group having 6 to 30 ring carbon atoms, a substituted or unsubstituted alkoxy group having 1 to 30 carbon atoms, a substituted or unsubstituted aralkyl group having 6 to 30 ring carbon atoms, or a substituted or unsubstituted aryloxy group having 6 to 30 ring carbon atoms.

One of R₃₁ to R₃₈ is a single bond to L₃ and the rest of R₃₁ to R₃₈ are each independently a hydrogen atom, a deuterium atom, a halogen atom, a cyano group, a substituted or unsubstituted aryl group having 6 to 30 ring carbon atoms, a substituted or unsubstituted heterocyclic group having 5 to 30 ring atoms, a substituted or unsubstituted alkyl group having 1 to 30 carbon atoms, a substituted or unsubstituted alkenyl group having 2 to 30 carbon atoms, a substituted or unsubstituted alkynyl group having 2 to 30 carbon atoms, a substituted or unsubstituted alkylsilyl group having 3 to 30 carbon atoms, a substituted or unsubstituted arylsilyl group having 6 to 30 ring carbon atoms, a substituted or unsubstituted alkoxy group having 1 to 30 carbon atoms, a substituted or unsubstituted aralkyl group having 6 to 30 ring carbon atoms, or a substituted or unsubstituted aryloxy group having 6 to 30 ring carbon atoms.

X is an oxygen atom or a sulfur atom.

Among compounds represented by the formula (6), a compound represented by the following formula (6a) is preferable.

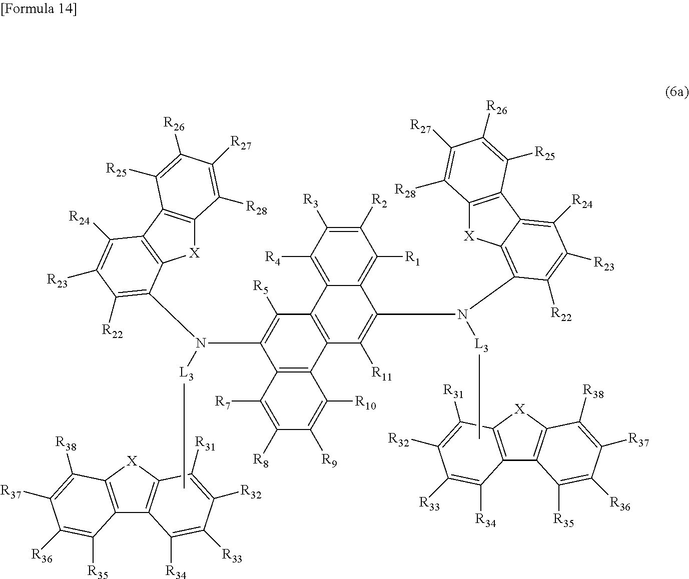

In the formula (6a), R₁ to R₅ and R₇ to R₁₁ are each independently a hydrogen atom, a deuterium atom, a halogen atom, a cyano group, a substituted or unsubstituted aryl group having 6 to 30 ring carbon atoms, a substituted or unsubstituted heterocyclic group having 5 to 30 ring atoms, a substituted or unsubstituted alkyl group having 1 to 30 carbon atoms, a substituted or unsubstituted alkenyl group having 2 to 30 carbon atoms, a substituted or unsubstituted alkynyl group having 2 to 30 carbon atoms, a substituted or unsubstituted alkylsilyl group having 3 to 30 carbon atoms, a substituted or unsubstituted arylsilyl group having 6 to 30 ring carbon atoms, a substituted or unsubstituted alkoxy group having 1 to 30 carbon atoms, a substituted or unsubstituted aralkyl group having 6 to 30 ring carbon atoms, or a substituted or unsubstituted aryloxy group having 6 to 30 ring carbon atoms.

L₃ is a single bond, a divalent residue of a substituted or unsubstituted aryl group having 6 to 30 ring carbon atoms, or a divalent residue of a substituted or unsubstituted heterocyclic group having 5 to 30 ring atoms.

Ar₂ is a substituted or unsubstituted aryl group having 6 to 30 ring carbon atoms.

R₂₂ to R₂₈ are each independently a hydrogen atom, a deuterium atom, a halogen atom, a cyano group, a substituted or unsubstituted aryl group having 6 to 30 ring carbon atoms, a substituted or unsubstituted heterocyclic group having 5 to 30 ring atoms, a substituted or unsubstituted alkyl group having 1 to 30 carbon atoms, a substituted or unsubstituted alkenyl group having 2 to 30 carbon atoms, a substituted or unsubstituted alkynyl group having 2 to 30 carbon atoms, a substituted or unsubstituted alkylsilyl group having 3 to 30 carbon atoms, a substituted or unsubstituted arylsilyl group having 6 to 30 ring carbon atoms, a substituted or unsubstituted alkoxy group having 1 to 30 carbon atoms, a substituted or unsubstituted aralkyl group having 6 to 30 ring carbon atoms, or a substituted or unsubstituted aryloxy group having 6 to 30 ring carbon atoms.

One of R₃₁ to R₃₈ is a single bond to L₃ and the rest of R₃₁ to R₃₈ are each independently a hydrogen atom, a deuterium atom, a halogen atom, a cyano group, a substituted or unsubstituted aryl group having 6 to 30 ring carbon atoms, a substituted or unsubstituted heterocyclic group having 5 to 30 ring atoms, a substituted or unsubstituted alkyl group having 1 to 30 carbon atoms, a substituted or unsubstituted alkenyl group having 2 to 30 carbon atoms, a substituted or unsubstituted alkynyl group having 2 to 30 carbon atoms, a substituted or unsubstituted alkylsilyl group having 3 to 30 carbon atoms, a substituted or unsubstituted arylsilyl group having 6 to 30 ring carbon atoms, a substituted or unsubstituted alkoxy group having 1 to 30 carbon atoms, a substituted or unsubstituted aralkyl group having 6 to 30 ring carbon atoms, or a substituted or unsubstituted aryloxy group having 6 to 30 ring carbon atoms.

X is an oxygen atom or a sulfur atom.

In compounds represented by the formula (6) or (6a), X is preferably an oxygen atom.

Ar₂ is preferably a substituted or unsubstituted aryl group having 6 to 18 ring carbon atoms and more preferably a substituted or unsubstituted phenyl group, a substituted or unsubstituted biphenylyl group, or a substituted or unsubstituted terphenylyl group.

L₁ to L₃ are each preferably a single bond or a substituted or unsubstituted phenylenyl group and more preferably a single bond.

R₂₂ to R₂₈ and R₃₁ to R₃₈ are each preferably a hydrogen atom, a substituted or unsubstituted aryl group having 6 to 30 ring carbon atoms, a substituted or unsubstituted heterocyclic group having 5 to 30 ring atoms, a substituted or unsubstituted alkyl group having 1 to 30 carbon atoms, a substituted or unsubstituted alkylsilyl group having 3 to 30 carbon atoms, a substituted or unsubstituted arylsilyl group having 6 to 30 ring carbon atoms, or a substituted or unsubstituted aralkyl group having 6 to 30 ring carbon atoms, and more preferably a hydrogen atom, a substituted or unsubstituted aryl group having 6 to 30 ring carbon atoms, a substituted or unsubstituted alkyl group having 1 to 30 carbon atoms, or a substituted or unsubstituted alkylsilyl group having 3 to 30 carbon atoms.

Specific examples of the aromatic amine derivative according to the invention are aromatic amine derivatives in which R₁ to R₅, R₇ to R₁₁, L₁ to L₃ and Ar₁ to Ar₂ in the formula (1A) are exemplified shown in Tables 1 to 76. Incidentally, “−” shown in the columns of L₁ to L₃ in Tables denotes a single bond. Further, in the columns of L₁ to L₃ and Ar₁ and Ar₂, a line that extends outwardly from a ring structure and has no chemical formula (e.g., CH₃, Ph and CN) at an end thereof denotes not a methyl group but a single bond. For instance, in a compound D1 shown below, Ar₁ represents a substance having a single bond in the 4-position of a dibenzofuran ring. Similarly, in the compound D1, Ar₂ represents a phenyl group.

TABLE 1

| Com- | | | | | | | | | | | | | | | |
|---|---|---|---|---|---|---|---|---|---|---|---|---|---|---|---|
| pound | R₁ | R₂ | R₃ | R₄ | R₅ | R₇ | R₈ | R₉ | R₁₀ | R₁₁ | L₁ | L₂ | L₃ | Ar₁ | Ar₂ |
| D1 | H | H | H | H | H | H | H | H | H | H | — | — | — | 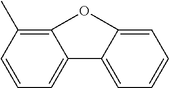 | 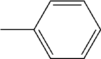 |
| D2 | H | H | H | H | H | H | H | H | H | H | — | — | — | 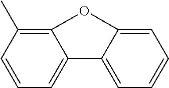 | 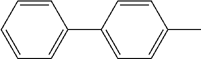 |
| D3 | H | H | H | H | H | H | H | H | H | H | — | — | — | 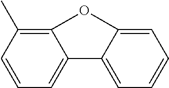 | 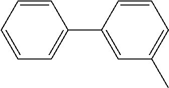 |
| D4 | H | H | H | H | H | H | H | H | H | H | — | — | — | 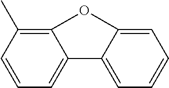 | 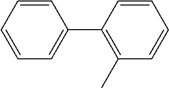 |
| D5 | H | H | H | H | H | H | H | H | H | H | — | — | — | 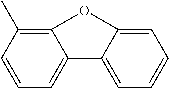 | 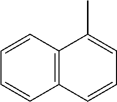 |
| D6 | H | H | H | H | H | H | H | H | H | H | — | — | — | 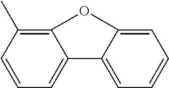 | 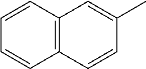 |
| D7 | H | H | H | H | H | H | H | H | H | H | — | — | — | 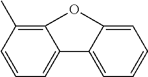 | 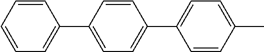 |

TABLE 2

| Compound | R₁ | R₂ | R₃ | R₄ | R₅ | R₇ | R₈ | R₉ | R₁₀ | R₁₁ | L₁ | L₂ | L₃ | Ar₁ | Ar₂ |
|---|---|---|---|---|---|---|---|---|---|---|---|---|---|---|---|
| D8 | H | H | H | H | H | H | H | H | H | H | — | — | — | 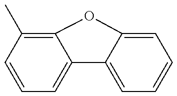 | 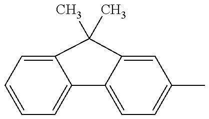 |
| D9 | H | H | H | H | H | H | H | H | H | H | — | — | — | 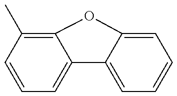 | 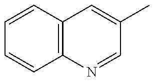 |
| D10 | H | H | H | H | H | H | H | H | H | H | — | — | — | 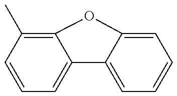 | 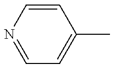 |
| D11 | H | H | H | H | H | H | H | H | H | H | — | — | — | 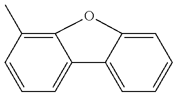 | 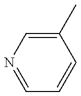 |
| D12 | H | H | H | H | H | H | H | H | H | H | — | — | — | 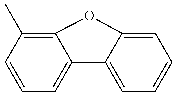 | 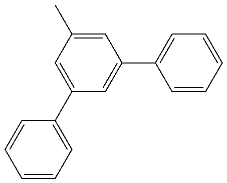 |

TABLE 3

| Compound | R₁ | R₂ | R₃ | R₄ | R₅ | R₇ | R₈ | R₉ | R₁₀ | R₁₁ | L₁ | L₂ | L₃ | Ar₁ | Ar₂ |
|---|---|---|---|---|---|---|---|---|---|---|---|---|---|---|---|
| D13 | H | H | H | H | H | H | H | H | H | H | — | — | — | 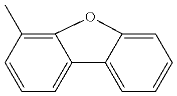 | 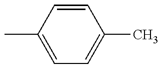 |
| D14 | H | H | H | H | H | H | H | H | H | H | — | — | — | 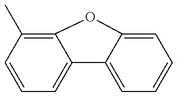 | 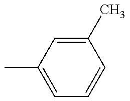 |
| D15 | H | H | H | H | H | H | H | H | H | H | — | — | — | 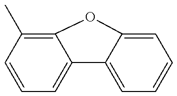 | 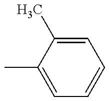 |
| D16 | H | H | H | H | H | H | H | H | H | H | — | — | — | 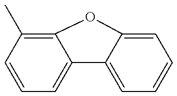 | 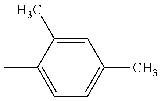 |
| D17 | H | H | H | H | H | H | H | H | H | H | — | — | — | 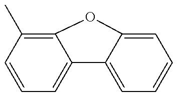 | 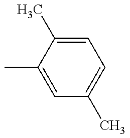 |
| D18 | H | H | H | H | H | H | H | H | H | H | — | — | — | 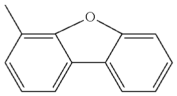 | 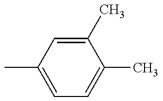 |
| D19 | H | H | H | H | H | H | H | H | H | H | — | — | — | 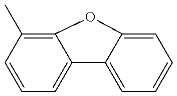 | 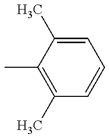 |

TABLE 4

| Compound | R₁ | R₂ | R₃ | R₄ | R₅ | R₇ | R₈ | R₉ | R₁₀ | R₁₁ | L₁ | L₂ | L₃ | Ar₁ | Ar₂ |
|---|---|---|---|---|---|---|---|---|---|---|---|---|---|---|---|
| D20 | H | H | H | H | H | H | H | H | H | H | — | — | — | 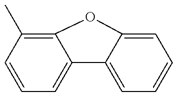 | 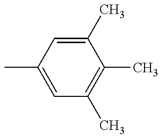 |
| D21 | H | H | H | H | H | H | H | H | H | H | — | — | — | 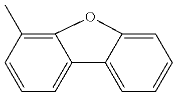 | 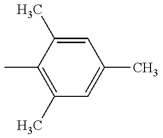 |
| D22 | H | H | H | H | H | H | H | H | H | H | — | — | — | 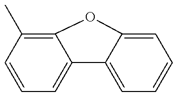 | 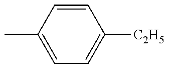 |
| D23 | H | H | H | H | H | H | H | H | H | H | — | — | — | 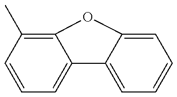 | 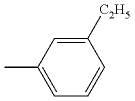 |
| D24 | H | H | H | H | H | H | H | H | H | H | — | — | — | 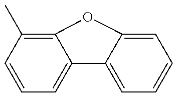 | 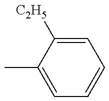 |

TABLE 5

| Compound | R₁ | R₂ | R₃ | R₄ | R₅ | R₇ | R₈ | R₉ | R₁₀ | R₁₁ | L₁ | L₂ | L₃ | Ar₁ | Ar₂ |
|---|---|---|---|---|---|---|---|---|---|---|---|---|---|---|---|
| D25 | H | H | H | H | H | H | H | H | H | H | — | — | — | 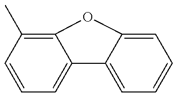 | 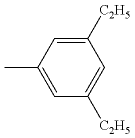 |
| D26 | H | H | H | H | H | H | H | H | H | H | — | — | — | 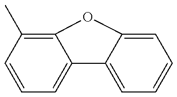 | 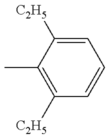 |
| D27 | H | H | H | H | H | H | H | H | H | H | — | — | — | 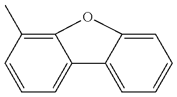 | 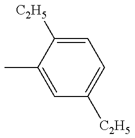 |
| D28 | H | H | H | H | H | H | H | H | H | H | — | — | — | 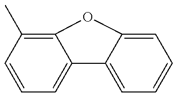 | 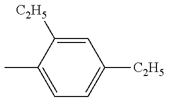 |
| D29 | H | H | H | H | H | H | H | H | H | H | — | — | — | 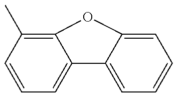 | 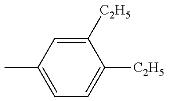 |

TABLE 6

| Compound | R₁ | R₂ | R₃ | R₄ | R₅ | R₇ | R₈ | R₉ | R₁₀ | R₁₁ | L₁ | L₂ | L₃ | Ar₁ | Ar₂ |
|---|---|---|---|---|---|---|---|---|---|---|---|---|---|---|---|
| D30 | H | H | H | H | H | H | H | H | H | H | — | — | — | 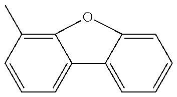 | 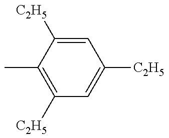 |
| D31 | H | H | H | H | H | H | H | H | H | H | — | — | — | 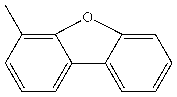 | 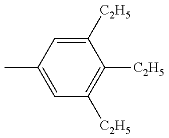 |
| D32 | H | H | H | H | H | H | H | H | H | H | — | — | — | 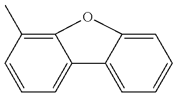 | 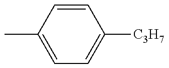 |
| D33 | H | H | H | H | H | H | H | H | H | H | — | — | — | 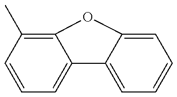 | 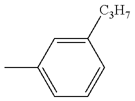 |
| D34 | H | H | H | H | H | H | H | H | H | H | — | — | — | 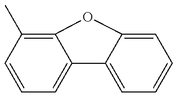 | 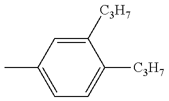 |
| D35 | H | H | H | H | H | H | H | H | H | H | — | — | — | 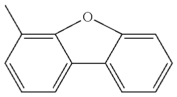 | 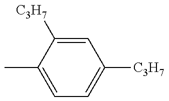 |
| D36 | H | H | H | H | H | H | H | H | H | H | — | — | — | 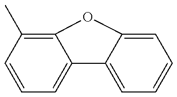 | 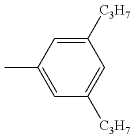 |

TABLE 7

| Compound | R₁ | R₂ | R₃ | R₄ | R₅ | R₇ | R₈ | R₉ | R₁₀ | R₁₁ | L₁ | L₂ | L₃ | Ar₁ | Ar₂ |
|---|---|---|---|---|---|---|---|---|---|---|---|---|---|---|---|
| D37 | H | H | H | H | H | H | H | H | H | H | — | — | — | 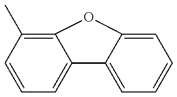 | 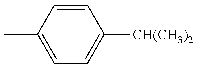 |
| D38 | H | H | H | H | H | H | H | H | H | H | — | — | — | 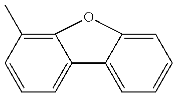 | 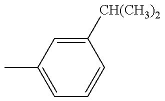 |
| D39 | H | H | H | H | H | H | H | H | H | H | — | — | — | 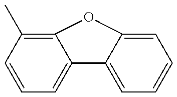 | 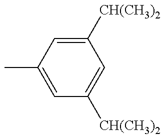 |
| D40 | H | H | H | H | H | H | H | H | H | H | — | — | — | 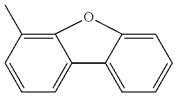 | 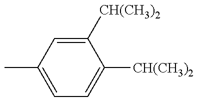 |
| D41 | H | H | H | H | H | H | H | H | H | H | — | — | — | 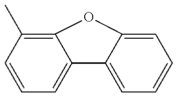 | 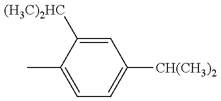 |

TABLE 8

| Compound | R₁ | R₂ | R₃ | R₄ | R₅ | R₇ | R₈ | R₉ | R₁₀ | R₁₁ | L₁ | L₂ | L₃ | Ar₁ | Ar₂ |
|---|---|---|---|---|---|---|---|---|---|---|---|---|---|---|---|
| D42 | H | H | H | H | H | H | H | H | H | H | — | — | — | 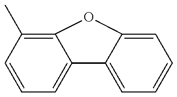 | 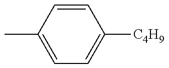 |
| D43 | H | H | H | H | H | H | H | H | H | H | — | — | — | 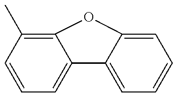 | 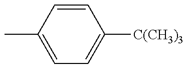 |
| D44 | H | H | H | H | H | H | H | H | H | H | — | — | — | 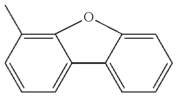 | 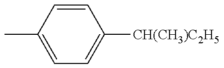 |
| D45 | H | H | H | H | H | H | H | H | H | H | — | — | — | 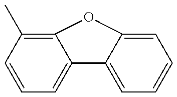 | 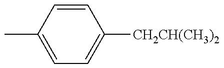 |

TABLE 9

| Compound | R₁ | R₂ | R₃ | R₄ | R₅ | R₇ | R₈ | R₉ | R₁₀ | R₁₁ | L₁ | L₂ | L₃ | Ar₁ | Ar₂ |
|---|---|---|---|---|---|---|---|---|---|---|---|---|---|---|---|
| D46 | H | H | H | H | H | H | H | H | H | H | — | — | — | 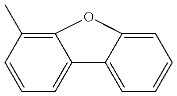 | 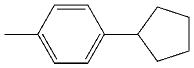 |
| D47 | H | H | H | H | H | H | H | H | H | H | — | — | — | 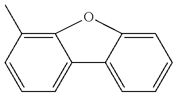 | 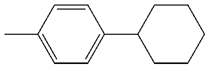 |
| D48 | H | H | H | H | H | H | H | H | H | H | — | — | — | 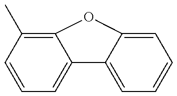 | 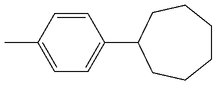 |
| D49 | H | H | H | H | H | H | H | H | H | H | — | — | — | 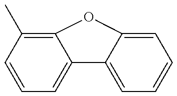 | 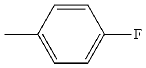 |
| D50 | H | H | H | H | H | H | H | H | H | H | — | — | — | 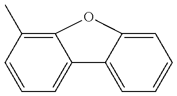 | 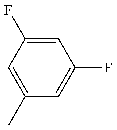 |
| D51 | H | H | H | H | H | H | H | H | H | H | — | — | — | 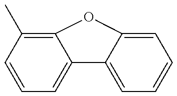 | 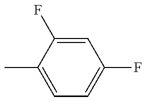 |

TABLE 10

| Compound | R₁ | R₂ | R₃ | R₄ | R₅ | R₇ | R₈ | R₉ | R₁₀ | R₁₁ | L₁ | L₂ | L₃ | Ar₁ | Ar₂ |
|---|---|---|---|---|---|---|---|---|---|---|---|---|---|---|---|
| D52 | H | H | H | H | H | H | H | H | H | H | — | — | — | 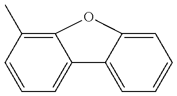 | 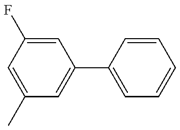 |
| D53 | H | H | H | H | H | H | H | H | H | H | — | — | — | 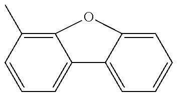 | 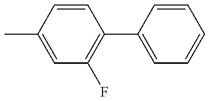 |
| D54 | H | H | H | H | H | H | H | H | H | H | — | — | — | 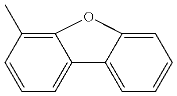 | 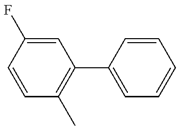 |
| D55 | H | H | H | H | H | H | H | H | H | H | — | — | — | 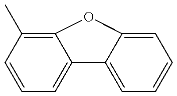 | 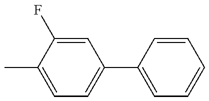 |
| D56 | H | H | H | H | H | H | H | H | H | H | — | — | — | 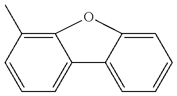 | 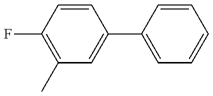 |
| D57 | H | H | H | H | H | H | H | H | H | H | — | — | — | 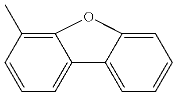 | 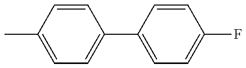 |

TABLE 11

| Compound | R₁ | R₂ | R₃ | R₄ | R₅ | R₇ | R₈ | R₉ | R₁₀ | R₁₁ | L₁ | L₂ | L₃ | Ar₁ | Ar₂ |
|---|---|---|---|---|---|---|---|---|---|---|---|---|---|---|---|
| D58 | H | H | H | H | H | H | H | H | H | H | — | — | — | 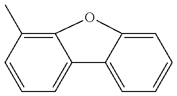 | 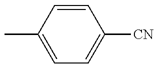 |
| D59 | H | H | H | H | H | H | H | H | H | H | — | — | — | 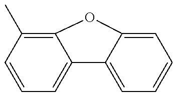 | 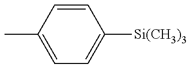 |
| D60 | H | H | H | H | H | H | H | H | H | H | — | — | — | 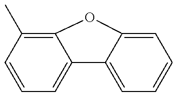 | 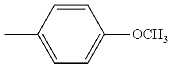 |
| D61 | H | H | H | H | H | H | H | H | H | H | — | — | — | 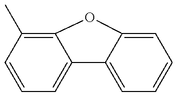 | 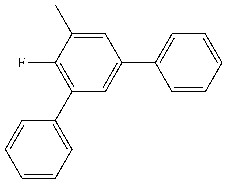 |
| D62 | H | H | H | H | H | H | H | H | H | H | — | — | — | 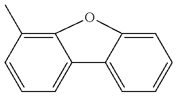 | 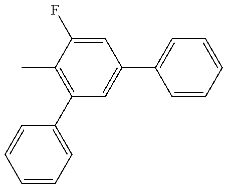 |
| D63 | H | H | H | H | H | H | H | H | H | H | — | — | — | 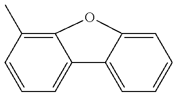 | 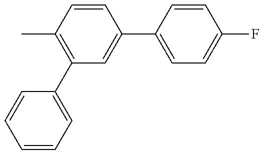 |

TABLE 12

| Compound | R₁ | R₂ | R₃ | R₄ | R₅ | R₇ | R₈ | R₉ | R₁₀ | R₁₁ | L₁ | L₂ | L₃ | Ar₁ | Ar₂ |
|---|---|---|---|---|---|---|---|---|---|---|---|---|---|---|---|
| D64 | H | H | H | H | H | H | H | H | H | H | — | — | — | 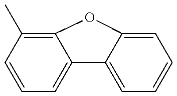 | 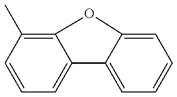 |
| D65 | H | H | H | H | H | H | H | H | H | H | — | — | — | 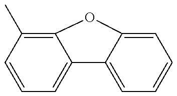 | 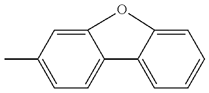 |
| D66 | H | H | H | H | H | H | H | H | H | H | — | — | — | 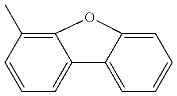 | 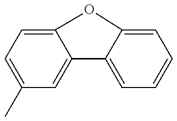 |
| D67 | H | H | H | H | H | H | H | H | H | H | — | — | — | 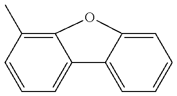 | 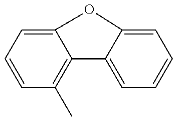 |

TABLE 13

| Com- | | | | | | | | | | | | | | | |
|---|---|---|---|---|---|---|---|---|---|---|---|---|---|---|---|
| pound | R₁ | R₂ | R₃ | R₄ | R₅ | R₇ | R₈ | R₉ | R₁₀ | R₁₁ | L₁ | L₂ | L₃ | Ar₁ | Ar₂ |
| D68 | H | H | H | H | H | H | H | H | H | H | — | — | — | 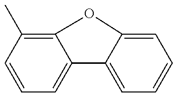 | 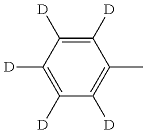 |
| D69 | H | H | H | H | H | H | H | H | H | H | — | — | — | 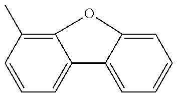 | 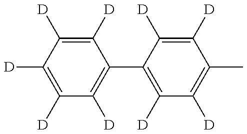 |
| D70 | H | H | H | H | H | H | H | H | H | H | — | — | — | 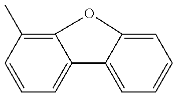 | 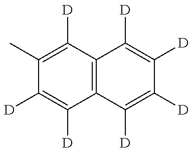 |
| D71 | H | H | H | H | H | H | H | H | H | H | — | — | — | 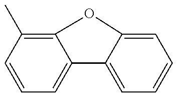 | 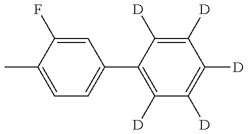 |
| D72 | H | H | H | H | H | H | H | H | H | H | — | — | — | 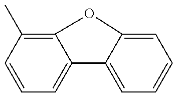 | 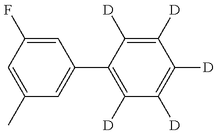 |
| D73 | H | H | H | H | H | H | H | H | H | H | — | — | — | 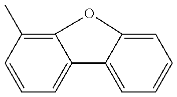 | 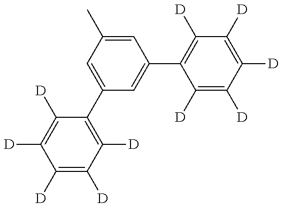 |
| D74 | H | H | H | H | H | H | H | H | H | H | — | — | — | 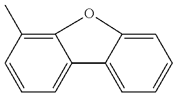 | 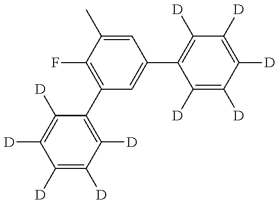 |

TABLE 14

| Comp. | R₁ | R₂ | R₃ | R₄ | R₅ | R₇ | R₈ | R₉ | R₁₀ | R₁₁ | L₁ | L₂ | L₃ | Ar₁ | Ar₂ |
|---|---|---|---|---|---|---|---|---|---|---|---|---|---|---|---|
| D75 | H | H | H | H | H | H | H | H | H | H | 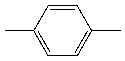 | — | — | 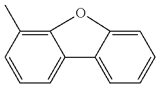 | 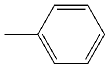 |
| D76 | H | H | H | H | H | H | H | H | H | H | 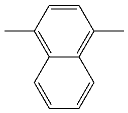 | — | — | 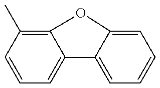 | 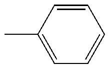 |
| D77 | H | H | H | H | H | H | H | H | H | H | 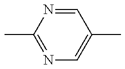 | — | — | 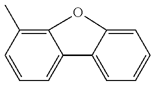 | 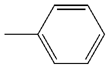 |
| D78 | H | H | H | H | H | H | H | H | H | H | 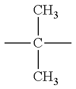 | — | — | 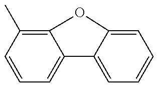 | 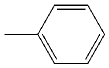 |
| C79 | H | H | H | H | H | H | H | H | H | H | — | 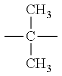 | — | 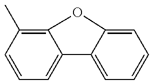 | 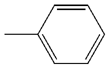 |

TABLE 15

| Comp. | R₁ | R₂ | R₃ | R₄ | R₅ | R₇ | R₈ | R₉ | R₁₀ | R₁₁ | L₁ |
|---|---|---|---|---|---|---|---|---|---|---|---|
| D80 | H | H | H | H | H | H | H | H | H | H | — |
| D81 | H | H | H | H | H | H | H | H | H | H | — |
| D82 | H | H | H | H | H | H | H | H | H | H | — |
| D83 | H | H | H | H | H | H | H | H | H | H | 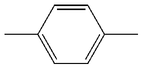 |
| D84 | H | H | H | H | H | H | H | H | H | H | 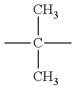 |
| D85 | H | H | H | H | H | H | H | H | H | H | — |

| Comp. | L₂ | L₃ | Ar₁ | Ar₂ |
|---|---|---|---|---|
| D80 | — | 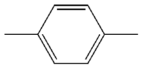 | 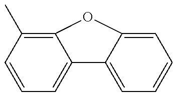 | 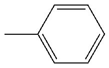 |
| D81 | — | 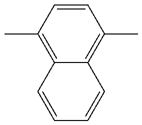 | 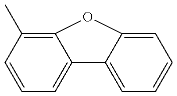 | 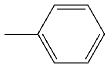 |
| D82 | — | 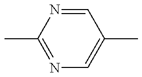 | 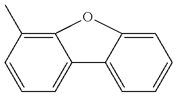 | 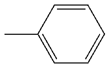 |
| D83 | 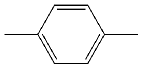 | — | 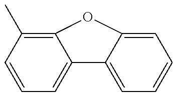 | 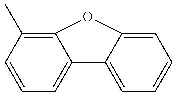 |
| D84 | 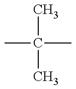 | — | 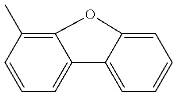 | 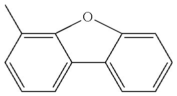 |
| D85 | — | 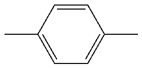 | 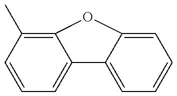 | 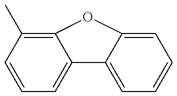 |

TABLE 16

| Compound | R₁ | R₂ | R₃ | R₄ | R₅ | R₇ | R₈ | R₉ | R₁₀ | R₁₁ | L₁ | L₂ | L₃ | Ar₁ | Ar₂ |
|---|---|---|---|---|---|---|---|---|---|---|---|---|---|---|---|
| D86 | H | H | H | H | H | H | H | H | H | H | — | — | — | 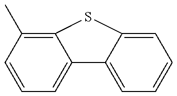 | 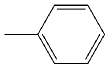 |
| D87 | H | H | H | H | H | H | H | H | H | H | — | — | — | 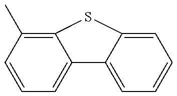 | 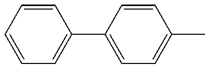 |
| D88 | H | H | H | H | H | H | H | H | H | H | — | — | — | 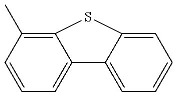 | 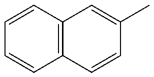 |
| D89 | H | H | H | H | H | H | H | H | H | H | — | — | — | 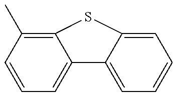 | 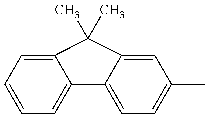 |
| D90 | H | H | H | H | H | H | H | H | H | H | — | — | — | 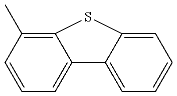 | 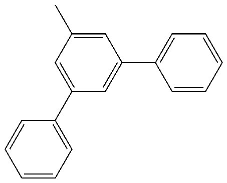 |

TABLE 17

| Compound | R₁ | R₂ | R₃ | R₄ | R₅ | R₇ | R₈ | R₉ | R₁₀ | R₁₁ | L₁ | L₂ | L₃ | Ar₁ | Ar₂ |
|---|---|---|---|---|---|---|---|---|---|---|---|---|---|---|---|
| D91 | H | H | H | H | H | H | H | H | H | H | — | — | — | 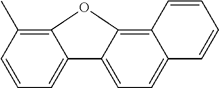 | 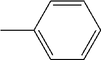 |
| D92 | H | H | H | H | H | H | H | H | H | H | — | — | — | 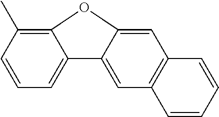 | 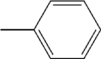 |
| D93 | H | H | H | H | H | H | H | H | H | H | — | — | — | 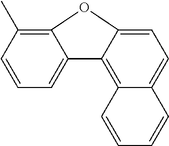 | 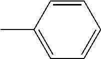 |
| D94 | H | H | H | H | H | H | H | H | H | H | — | — | — | 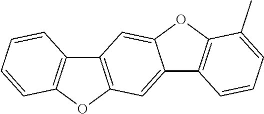 | 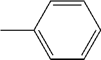 |
| D95 | H | H | H | H | H | H | H | H | H | H | — | — | — | 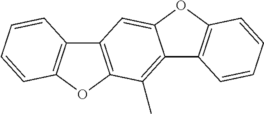 | 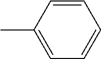 |
| D96 | H | H | H | H | H | H | H | H | H | H | — | — | — | 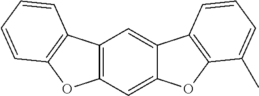 | 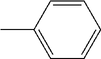 |
| D97 | H | H | H | H | H | H | H | H | H | H | — | — | — | 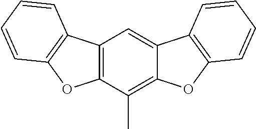 | 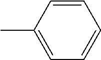 |

TABLE 18

| Compound | R₁ | R₂ | R₃ | R₄ | R₅ | R₇ | R₈ | R₉ | R₁₀ | R₁₁ | L₁ | L₂ | L₃ | Ar₁ | Ar₂ |
|---|---|---|---|---|---|---|---|---|---|---|---|---|---|---|---|
| D101 | H | H | H | H | H | H | H | H | H | H | — | — | — | 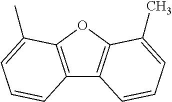 | 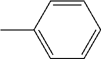 |
| D102 | H | H | H | H | H | H | H | H | H | H | — | — | — | 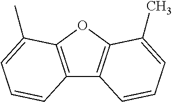 | 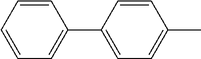 |
| D103 | H | H | H | H | H | H | H | H | H | H | — | — | — | 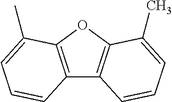 | 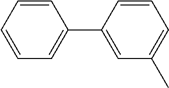 |
| D104 | H | H | H | H | H | H | H | H | H | H | — | — | — | 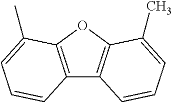 | 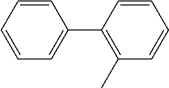 |
| D105 | H | H | H | H | H | H | H | H | H | H | — | — | — | 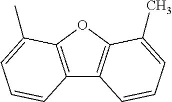 | 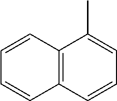 |

TABLE 19

| Com- | | | | | | | | | | | | | | | |
|---|---|---|---|---|---|---|---|---|---|---|---|---|---|---|---|
| pound | R₁ | R₂ | R₃ | R₄ | R₅ | R₇ | R₈ | R₉ | R₁₀ | R₁₁ | L₁ | L₂ | L₃ | Ar₁ | Ar₂ |
| D106 | H | H | H | H | H | H | H | H | H | H | — | — | — | 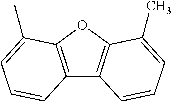 | 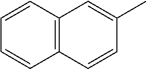 |
| D107 | H | H | H | H | H | H | H | H | H | H | — | — | — | 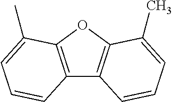 | 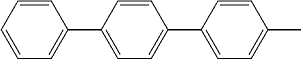 |
| D108 | H | H | H | H | H | H | H | H | H | H | — | — | — | 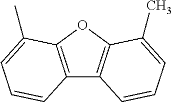 | 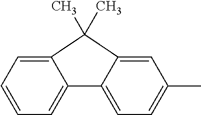 |
| D109 | H | H | H | H | H | H | H | H | H | H | — | — | — | 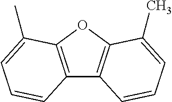 | 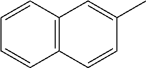 |
| D110 | H | H | H | H | H | H | H | H | H | H | — | — | — | 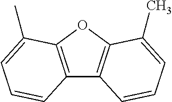 | 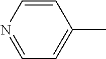 |

TABLE 20

| Compound | R₁ | R₂ | R₃ | R₄ | R₅ | R₇ | R₈ | R₉ | R₁₀ | R₁₁ | L₁ | L₂ | L₃ | Ar₁ | Ar₂ |
|---|---|---|---|---|---|---|---|---|---|---|---|---|---|---|---|
| D111 | H | H | H | H | H | H | H | H | H | H | — | — | — | 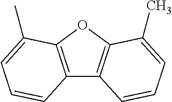 | 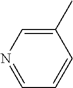 |
| D112 | H | H | H | H | H | H | H | H | H | H | — | — | — | 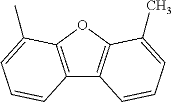 | 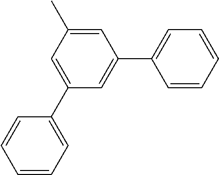 |
| D113 | H | H | H | H | H | H | H | H | H | H | — | — | — | 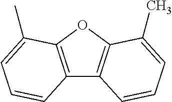 | 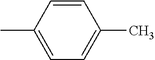 |
| D114 | H | H | H | H | H | H | H | H | H | H | — | — | — | 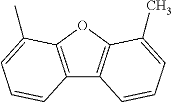 | 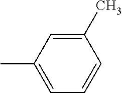 |
| D115 | H | H | H | H | H | H | H | H | H | H | — | — | — | 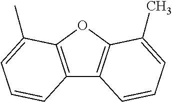 | 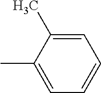 |

TABLE 21

| Compound | R₁ | R₂ | R₃ | R₄ | R₅ | R₇ | R₈ | R₉ | R₁₀ | R₁₁ | L₁ | L₂ | L₃ | Ar₁ | Ar₂ |
|---|---|---|---|---|---|---|---|---|---|---|---|---|---|---|---|
| D116 | H | H | H | H | H | H | H | H | H | H | — | — | — | 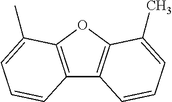 | 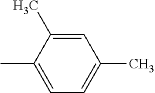 |
| D117 | H | H | H | H | H | H | H | H | H | H | — | — | — | 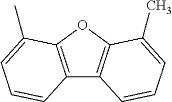 | 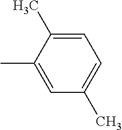 |
| D118 | H | H | H | H | H | H | H | H | H | H | — | — | — | 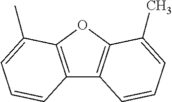 | 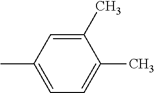 |
| D119 | H | H | H | H | H | H | H | H | H | H | — | — | — | 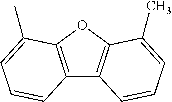 | 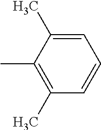 |
| D120 | H | H | H | H | H | H | H | H | H | H | — | — | — | 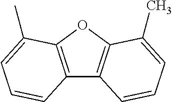 | 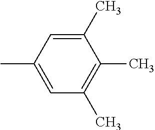 |

TABLE 22

| Compound | R₁ | R₂ | R₃ | R₄ | R₅ | R₇ | R₈ | R₉ | R₁₀ | R₁₁ | L₁ | L₂ | L₃ | Ar₁ | Ar₂ |
|---|---|---|---|---|---|---|---|---|---|---|---|---|---|---|---|
| D121 | H | H | H | H | H | H | H | H | H | H | — | — | — | 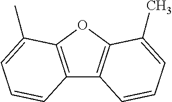 | 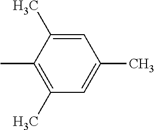 |
| D122 | H | H | H | H | H | H | H | H | H | H | — | — | — | 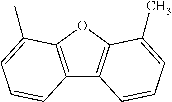 | 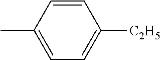 |
| D123 | H | H | H | H | H | H | H | H | H | H | — | — | — | 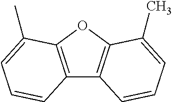 | 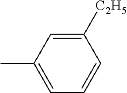 |
| D124 | H | H | H | H | H | H | H | H | H | H | — | — | — | 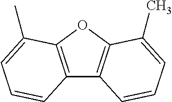 | 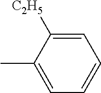 |
| D125 | H | H | H | H | H | H | H | H | H | H | — | — | — | 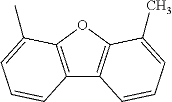 | 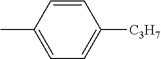 |

TABLE 23

| Compound | R₁ | R₂ | R₃ | R₄ | R₅ | R₇ | R₈ | R₉ | R₁₀ | R₁₁ | L₁ | L₂ | L₃ | Ar₁ | Ar₂ |
|---|---|---|---|---|---|---|---|---|---|---|---|---|---|---|---|
| D126 | H | H | H | H | H | H | H | H | H | H | — | — | — | 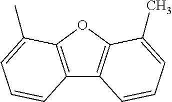 | 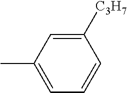 |
| D127 | H | H | H | H | H | H | H | H | H | H | — | — | — | 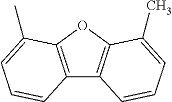 | 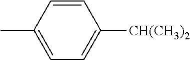 |
| D128 | H | H | H | H | H | H | H | H | H | H | — | — | — | 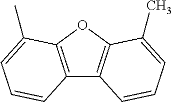 | 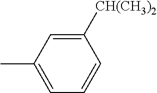 |
| D129 | H | H | H | H | H | H | H | H | H | H | — | — | — | 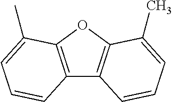 | 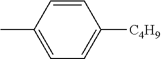 |
| D130 | H | H | H | H | H | H | H | H | H | H | — | — | — | 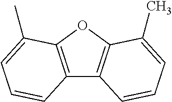 | 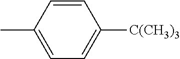 |

TABLE 24

| Compound | R₁ | R₂ | R₃ | R₄ | R₅ | R₇ | R₈ | R₉ | R₁₀ | R₁₁ | L₁ | L₂ | L₃ | Ar₁ | Ar₂ |
|---|---|---|---|---|---|---|---|---|---|---|---|---|---|---|---|
| D131 | H | H | H | H | H | H | H | H | H | H | — | — | — | 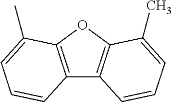 | 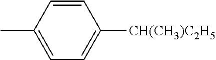 |
| D132 | H | H | H | H | H | H | H | H | H | H | — | — | — | 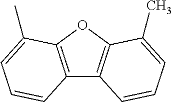 | 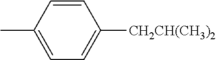 |
| D133 | H | H | H | H | H | H | H | H | H | H | — | — | — | 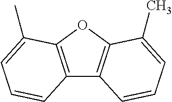 | 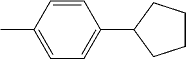 |
| D134 | H | H | H | H | H | H | H | H | H | H | — | — | — | 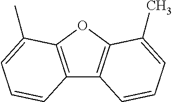 | 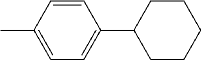 |
| D135 | H | H | H | H | H | H | H | H | H | H | — | — | — | 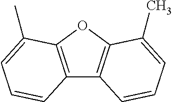 | 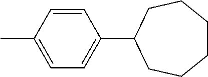 |

TABLE 25

| Compound | R₁ | R₂ | R₃ | R₄ | R₅ | R₇ | R₈ | R₉ | R₁₀ | R₁₁ | L₁ | L₂ | L₃ | Ar₁ | Ar₂ |
|---|---|---|---|---|---|---|---|---|---|---|---|---|---|---|---|
| D136 | H | H | H | H | H | H | H | H | H | H | — | — | — | 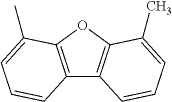 | 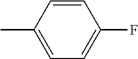 |
| D137 | H | H | H | H | H | H | H | H | H | H | — | — | — | 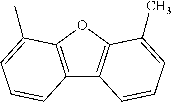 | 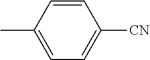 |
| D138 | H | H | H | H | H | H | H | H | H | H | — | — | — | 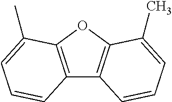 | 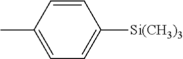 |
| D139 | H | H | H | H | H | H | H | H | H | H | — | — | — | 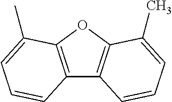 | 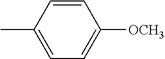 |
| D140 | H | H | H | H | H | H | H | H | H | H | — | — | — | 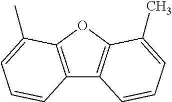 | 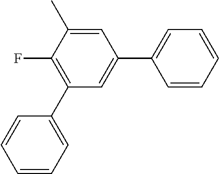 |

TABLE 26

| Compound | R₁ | R₂ | R₃ | R₄ | R₅ | R₇ | R₈ | R₉ | R₁₀ | R₁₁ | L₁ | L₂ | L₃ | Ar₁ | Ar₂ |
|---|---|---|---|---|---|---|---|---|---|---|---|---|---|---|---|
| D141 | H | H | H | H | H | H | H | H | H | H | — | — | — | 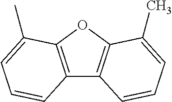 | 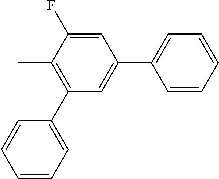 |
| D142 | H | H | H | H | H | H | H | H | H | H | — | — | — | 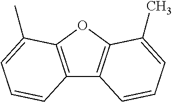 | 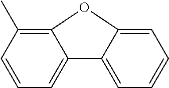 |
| D143 | H | H | H | H | H | H | H | H | H | H | — | — | — | 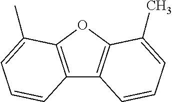 | 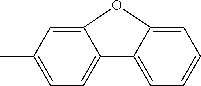 |
| D144 | H | H | H | H | H | H | H | H | H | H | — | — | — | 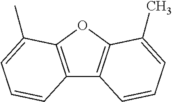 | 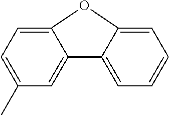 |
| D145 | H | H | H | H | H | H | H | H | H | H | — | — | — | 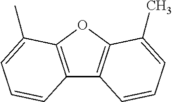 | 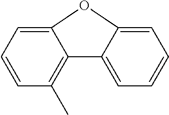 |

TABLE 27

| Com- | | | | | | | | | | | | | | | |
|---|---|---|---|---|---|---|---|---|---|---|---|---|---|---|---|
| pound | R₁ | R₂ | R₃ | R₄ | R₅ | R₇ | R₈ | R₉ | R₁₀ | R₁₁ | L₁ | L₂ | L₃ | Ar₁ | Ar₂ |
| D146 | H | H | H | H | H | H | H | H | H | H | — | — | — | 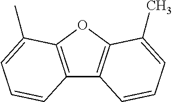 | 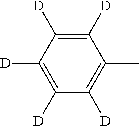 |
| D147 | H | H | H | H | H | H | H | H | H | H | — | — | — | 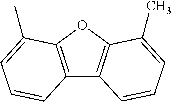 | 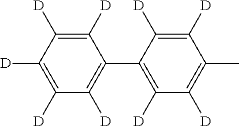 |
| D148 | H | H | H | H | H | H | H | H | H | H | — | — | — | 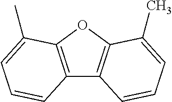 | 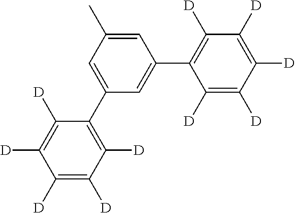 |
| D149 | H | H | H | H | H | H | H | H | H | H | — | — | — | 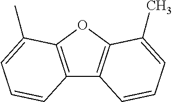 | 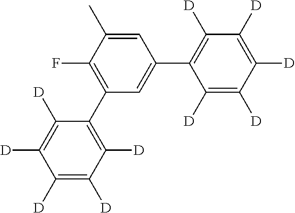 |

TABLE 28

| Compound | R₁ | R₂ | R₃ | R₄ | R₅ | R₇ | R₈ | R₉ | R₁₀ | R₁₁ | L₁ | L₂ | L₃ |
|---|---|---|---|---|---|---|---|---|---|---|---|---|---|
| D150 | H | H | H | H | H | H | H | H | H | H | 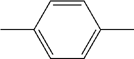 | — | — |
| D151 | H | H | H | H | H | H | H | H | H | H | 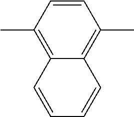 | — | — |
| D152 | H | H | H | H | H | H | H | H | H | H | 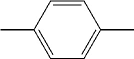 | 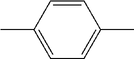 | — |
| D153 | H | H | H | H | H | H | H | H | H | H | — | — | 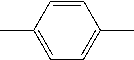 |

| Compound | Ar₁ | Ar₂ |
|---|---|---|
| D150 | 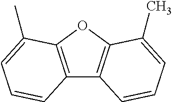 | 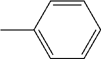 |
| D151 | 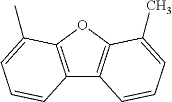 | 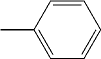 |
| D152 | 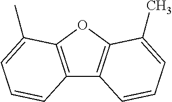 | 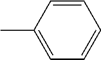 |
| D153 | 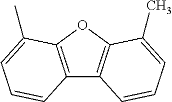 | 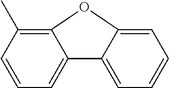 |

TABLE 29

| Comp. | R₁ | R₂ | R₃ | R₄ | R₅ | R₇ | R₈ | R₉ | R₁₀ | R₁₁ | L₁ | L₂ | L₃ | Ar₁ | Ar₂ |
|---|---|---|---|---|---|---|---|---|---|---|---|---|---|---|---|
| D201 | H | H | H | H | H | H | H | H | H | H | — | — | — | 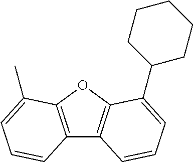 | 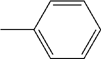 |
| D202 | H | H | H | H | H | H | H | H | H | H | — | — | — | 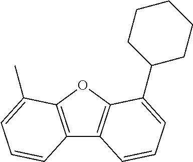 | 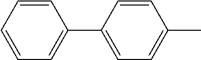 |
| D203 | H | H | H | H | H | H | H | H | H | H | — | — | — | 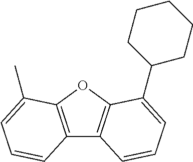 | 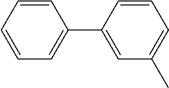 |
| D204 | H | H | H | H | H | H | H | H | H | H | — | — | — | 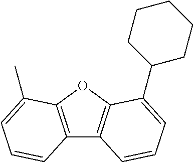 | 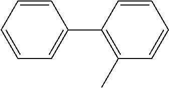 |
| D205 | H | H | H | H | H | H | H | H | H | H | — | — | — | 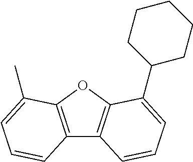 | 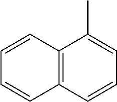 |

TABLE 30

| Comp. | R₁ | R₂ | R₃ | R₄ | R₅ | R₇ | R₈ | R₉ | R₁₀ | R₁₁ | L₁ | L₂ | L₃ | Ar₁ | Ar₂ |
|---|---|---|---|---|---|---|---|---|---|---|---|---|---|---|---|
| D206 | H | H | H | H | H | H | H | H | H | H | — | — | — | 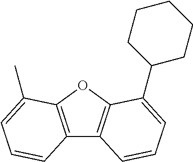 | 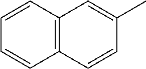 |
| D207 | H | H | H | H | H | H | H | H | H | H | — | — | — | 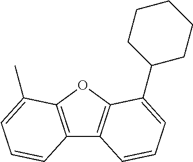 | 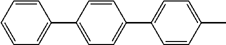 |
| D208 | H | H | H | H | H | H | H | H | H | H | — | — | — | 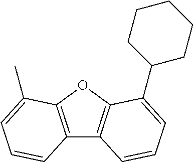 | 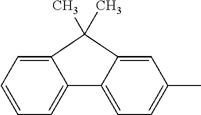 |
| D209 | H | H | H | H | H | H | H | H | H | H | — | — | — | 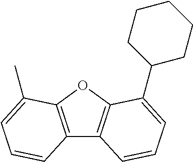 | 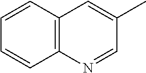 |
| D210 | H | H | H | H | H | H | H | H | H | H | — | — | — | 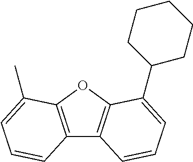 | 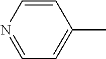 |

TABLE 31

| Comp. | R₁ | R₂ | R₃ | R₄ | R₅ | R₇ | R₈ | R₉ | R₁₀ | R₁₁ | L₁ | L₂ | L₃ | Ar₁ | Ar₂ |
|---|---|---|---|---|---|---|---|---|---|---|---|---|---|---|---|
| D211 | H | H | H | H | H | H | H | H | H | H | — | — | — | 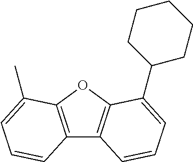 | 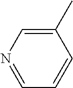 |
| D212 | H | H | H | H | H | H | H | H | H | H | — | — | — | 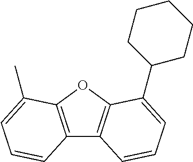 | 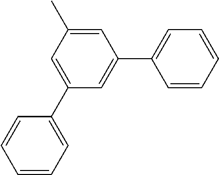 |
| D213 | H | H | H | H | H | H | H | H | H | H | — | — | — | 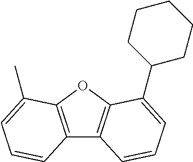 | 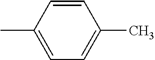 |
| D214 | H | H | H | H | H | H | H | H | H | H | — | — | — | 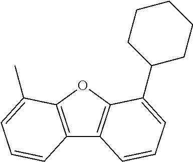 | 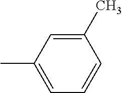 |
| D215 | H | H | H | H | H | H | H | H | H | H | — | — | — | 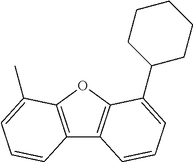 | 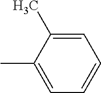 |

TABLE 32

| Comp. | R₁ | R₂ | R₃ | R₄ | R₅ | R₇ | R₈ | R₉ | R₁₀ | R₁₁ | L₁ | L₂ | L₃ |
|---|---|---|---|---|---|---|---|---|---|---|---|---|---|
| D216 | H | H | H | H | H | H | H | H | H | H | — | — | — |
| D217 | H | H | H | H | H | H | H | H | H | H | — | — | — |
| D218 | H | H | H | H | H | H | H | H | H | H | — | — | — |
| D219 | H | H | H | H | H | H | H | H | H | H | — | — | — |
| D220 | H | H | H | H | H | H | H | H | H | H | — | — | — |

| Comp. | Ar₁ | Ar₂ |
|---|---|---|
| D216 | 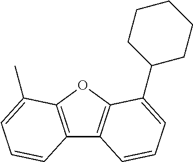 | 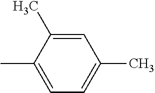 |
| D217 | 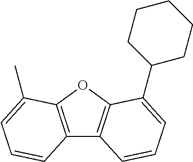 | 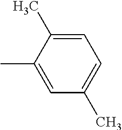 |
| D218 | 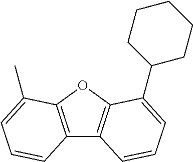 | 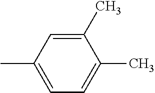 |
| D219 | 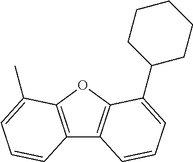 | 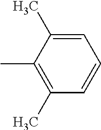 |
| D220 | 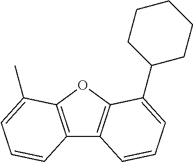 | 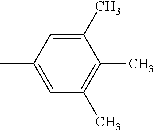 |

TABLE 33

| Comp. | R₁ | R₂ | R₃ | R₄ | R₅ | R₇ | R₈ | R₉ | R₁₀ | R₁₁ | L₁ | L₂ | L₃ |
|---|---|---|---|---|---|---|---|---|---|---|---|---|---|
| D221 | H | H | H | H | H | H | H | H | H | H | — | — | — |
| D222 | H | H | H | H | H | H | H | H | H | H | — | — | — |
| D223 | H | H | H | H | H | H | H | H | H | H | — | — | — |
| D224 | H | H | H | H | H | H | H | H | H | H | — | — | — |
| D225 | H | H | H | H | H | H | H | H | H | H | — | — | — |

| Comp. | Ar₁ | Ar₂ |
|---|---|---|
| D221 | 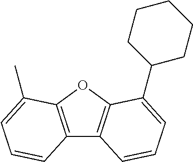 | 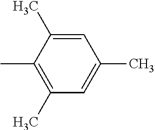 |
| D222 | 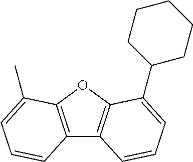 | 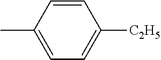 |
| D223 | 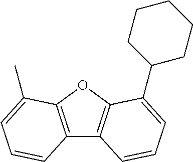 | 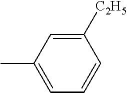 |
| D224 | 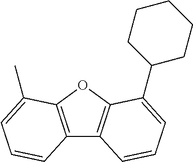 | 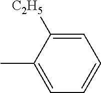 |
| D225 | 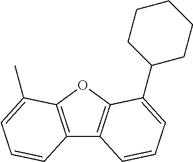 | 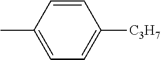 |

TABLE 34

| Comp. | R₁ | R₂ | R₃ | R₄ | R₅ | R₇ | R₈ | R₉ | R₁₀ | R₁₁ | L₁ | L₂ | L₃ |
|---|---|---|---|---|---|---|---|---|---|---|---|---|---|
| D226 | H | H | H | H | H | H | H | H | H | H | — | — | — |
| D227 | H | H | H | H | H | H | H | H | H | H | — | — | — |
| D228 | H | H | H | H | H | H | H | H | H | H | — | — | — |
| D229 | H | H | H | H | H | H | H | H | H | H | — | — | — |
| D230 | H | H | H | H | H | H | H | H | H | H | — | — | — |

| Comp. | Ar₁ | Ar₂ |
|---|---|---|
| D226 | 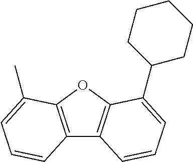 | 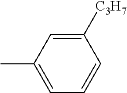 |
| D227 | 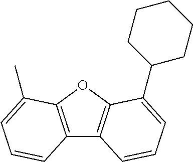 | 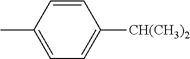 |
| D228 | 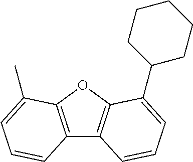 | 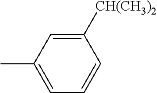 |
| D229 | 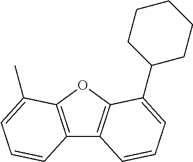 | 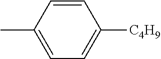 |
| D230 | 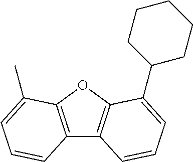 | 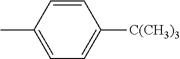 |

TABLE 35

| Comp. | R₁ | R₂ | R₃ | R₄ | R₅ | R₇ | R₈ | R₉ | R₁₀ | R₁₁ | L₁ | L₂ | L₃ |
|---|---|---|---|---|---|---|---|---|---|---|---|---|---|
| D231 | H | H | H | H | H | H | H | H | H | H | — | — | — |
| D232 | H | H | H | H | H | H | H | H | H | H | — | — | — |
| D233 | H | H | H | H | H | H | H | H | H | H | — | — | — |
| D234 | H | H | H | H | H | H | H | H | H | H | — | — | — |
| D235 | H | H | H | H | H | H | H | H | H | H | — | — | — |

| Comp. | Ar₁ | Ar₂ |
|---|---|---|
| D231 | 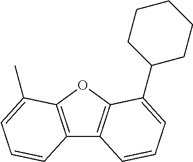 | 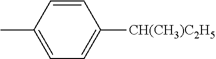 |
| D232 | 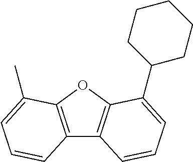 | 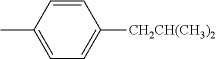 |
| D233 | 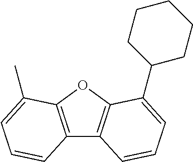 | 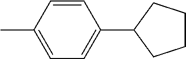 |
| D234 | 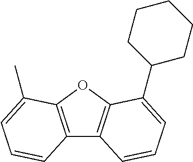 | 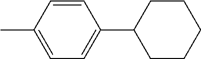 |
| D235 | 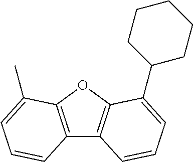 | 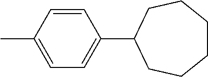 |

TABLE 36

| Comp. | R₁ | R₂ | R₃ | R₄ | R₅ | R₇ | R₈ | R₉ | R₁₀ | R₁₁ | L₁ | L₂ | L₃ |
|---|---|---|---|---|---|---|---|---|---|---|---|---|---|
| D236 | H | H | H | H | H | H | H | H | H | H | — | — | — |
| D237 | H | H | H | H | H | H | H | H | H | H | — | — | — |
| D238 | H | H | H | H | H | H | H | H | H | H | — | — | — |
| D239 | H | H | H | H | H | H | H | H | H | H | — | — | — |
| D240 | H | H | H | H | H | H | H | H | H | H | — | — | — |

| Comp. | Ar₁ | Ar₂ |
|---|---|---|
| D236 | 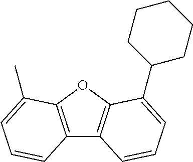 | 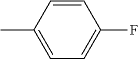 |
| D237 | 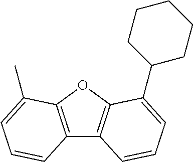 | 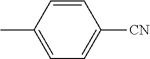 |
| D238 | 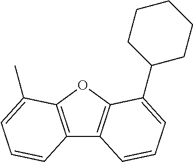 | 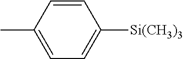 |
| D239 | 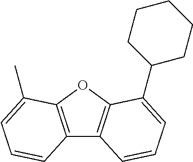 | 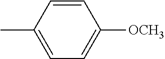 |
| D240 | 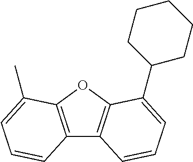 | 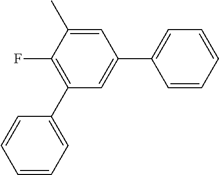 |

TABLE 37

| Comp. | R₁ | R₂ | R₃ | R₄ | R₅ | R₇ | R₈ | R₉ | R₁₀ | R₁₁ | L₁ | L₂ | L₃ |
|---|---|---|---|---|---|---|---|---|---|---|---|---|---|
| D241 | H | H | H | H | H | H | H | H | H | H | — | — | — |
| D242 | H | H | H | H | H | H | H | H | H | H | — | — | — |
| D243 | H | H | H | H | H | H | H | H | H | H | — | — | — |
| D244 | H | H | H | H | H | H | H | H | H | H | — | — | — |
| D245 | H | H | H | H | H | H | H | H | H | H | — | — | — |

| Comp. | Ar₁ | Ar₂ |
|---|---|---|
| D241 | 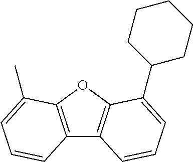 | 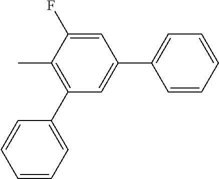 |
| D242 | 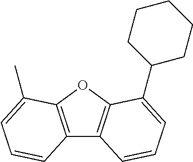 | 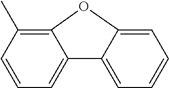 |
| D243 | 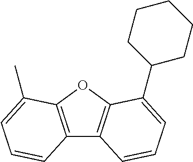 | 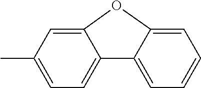 |
| D244 | 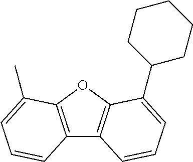 | 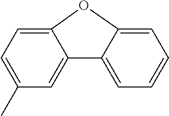 |
| D245 | 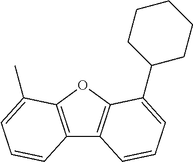 | 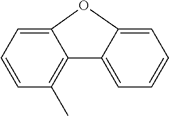 |

TABLE 38

| Comp. | R₁ | R₂ | R₃ | R₄ | R₅ | R₇ | R₈ | R₉ | R₁₀ | R₁₁ | L₁ | L₂ | L₃ |
|---|---|---|---|---|---|---|---|---|---|---|---|---|---|
| D246 | H | H | H | H | H | H | H | H | H | H | — | — | — |
| D247 | H | H | H | H | H | H | H | H | H | H | — | — | — |
| D248 | H | H | H | H | H | H | H | H | H | H | — | — | — |
| D249 | H | H | H | H | H | H | H | H | H | H | — | — | — |

| Comp. | Ar₁ | Ar₂ |
|---|---|---|
| D246 | 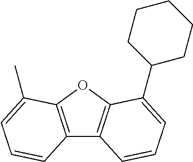 | 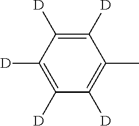 |
| D247 | 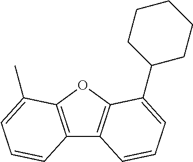 | 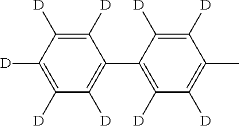 |
| D248 | 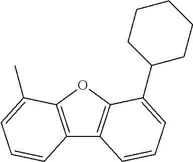 | 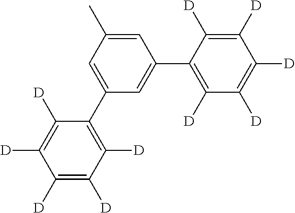 |
| D249 | 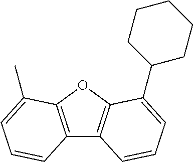 | 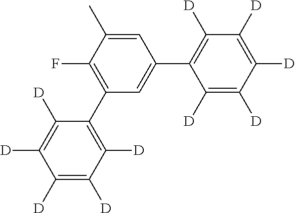 |

TABLE 39

| Comp. | R₁ | R₂ | R₃ | R₄ | R₅ | R₇ | R₈ | R₉ | R₁₀ | R₁₁ | L₁ |
|---|---|---|---|---|---|---|---|---|---|---|---|
| D250 | H | H | H | H | H | H | H | H | H | H | 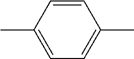 |
| D251 | H | H | H | H | H | H | H | H | H | H | 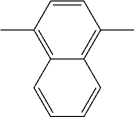 |
| D252 | H | H | H | H | H | H | H | H | H | H | 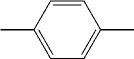 |
| D253 | H | H | H | H | H | H | H | H | H | H | — |

| Comp. | L₂ | L₃ | Ar₁ | Ar₂ |
|---|---|---|---|---|
| D250 | — | — | 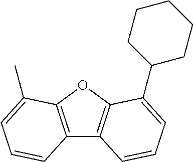 | 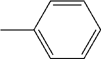 |
| D251 | — | — | 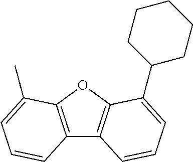 | 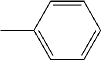 |
| D252 | 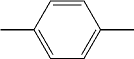 | — | 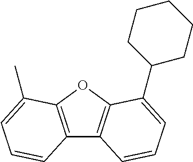 | 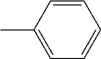 |
| D253 | — | 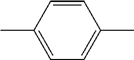 | 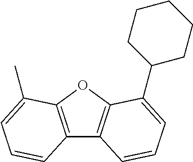 | 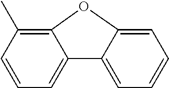 |

TABLE 40

| Compound | R₁ | R₂ | R₃ | R₄ | R₅ | R₇ | R₈ | R₉ | R₁₀ | R₁₁ | L₁ | L₂ | L₃ |
|---|---|---|---|---|---|---|---|---|---|---|---|---|---|
| D301 | H | H | H | H | H | H | H | H | H | H | — | — | — |
| D302 | H | H | H | H | H | H | H | H | H | H | — | — | — |
| D303 | H | H | H | H | H | H | H | H | H | H | — | — | — |
| D304 | H | H | H | H | H | H | H | H | H | H | — | — | — |
| D305 | H | H | H | H | H | H | H | H | H | H | — | — | — |

| Compound | Ar₁ | Ar₂ |
|---|---|---|
| D301 | 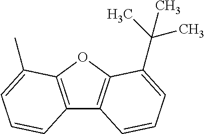 | 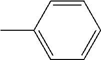 |
| D302 | 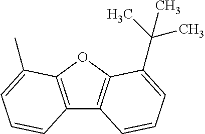 | 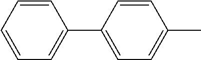 |
| D303 | 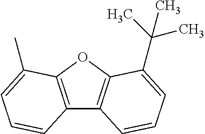 | 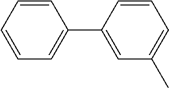 |
| D304 | 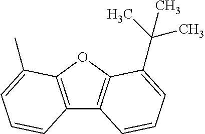 | 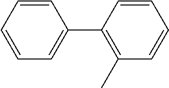 |
| D305 | 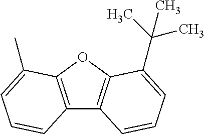 | 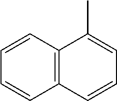 |

TABLE 41

| Compound | R₁ | R₂ | R₃ | R₄ | R₅ | R₇ | R₈ | R₉ | R₁₀ | R₁₁ | L₁ | L₂ | L₃ |
|---|---|---|---|---|---|---|---|---|---|---|---|---|---|
| D306 | H | H | H | H | H | H | H | H | H | H | — | — | — |
| D307 | H | H | H | H | H | H | H | H | H | H | — | — | — |
| D308 | H | H | H | H | H | H | H | H | H | H | — | — | — |
| D309 | H | H | H | H | H | H | H | H | H | H | — | — | — |
| D310 | H | H | H | H | H | H | H | H | H | H | — | — | — |

| Compound | Ar₁ | Ar₂ |
|---|---|---|
| D306 | 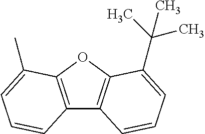 | 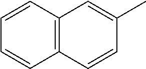 |
| D307 | 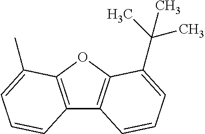 | 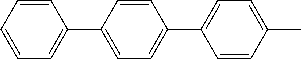 |
| D308 | 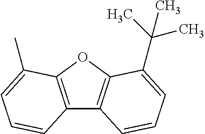 | 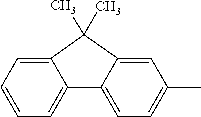 |
| D309 | 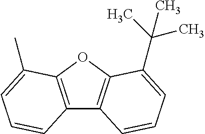 | 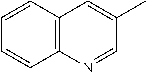 |
| D310 | 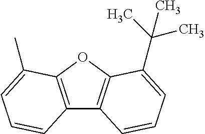 | 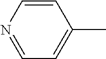 |

TABLE 42

| Compound | R₁ | R₂ | R₃ | R₄ | R₅ | R₇ | R₈ | R₉ | R₁₀ | R₁₁ | L₁ | L₂ | L₃ |
|---|---|---|---|---|---|---|---|---|---|---|---|---|---|
| D311 | H | H | H | H | H | H | H | H | H | H | — | — | — |
| D312 | H | H | H | H | H | H | H | H | H | H | — | — | — |
| D313 | H | H | H | H | H | H | H | H | H | H | — | — | — |
| D314 | H | H | H | H | H | H | H | H | H | H | — | — | — |
| D315 | H | H | H | H | H | H | H | H | H | H | — | — | — |

| Compound | Ar₁ | Ar₂ |
|---|---|---|
| D311 | 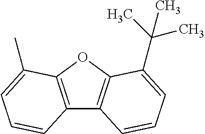 | 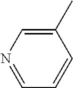 |
| D312 | 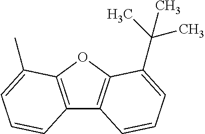 | 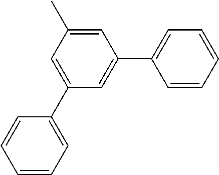 |
| D313 | 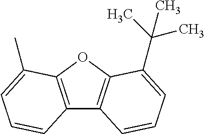 | 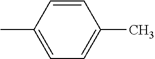 |
| D314 | 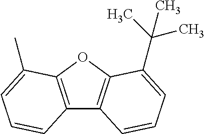 | 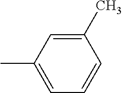 |
| D315 | 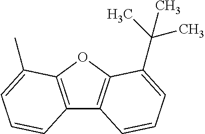 | 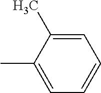 |

TABLE 43

| Compound | R₁ | R₂ | R₃ | R₄ | R₅ | R₇ | R₈ | R₉ | R₁₀ | R₁₁ | L₁ | L₂ | L₃ |
|---|---|---|---|---|---|---|---|---|---|---|---|---|---|
| D316 | H | H | H | H | H | H | H | H | H | H | — | — | — |
| D317 | H | H | H | H | H | H | H | H | H | H | — | — | — |
| D318 | H | H | H | H | H | H | H | H | H | H | — | — | — |
| D319 | H | H | H | H | H | H | H | H | H | H | — | — | — |
| D320 | H | H | H | H | H | H | H | H | H | H | — | — | — |

| Compound | Ar₁ | Ar₂ |
|---|---|---|
| D316 | 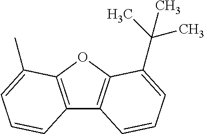 | 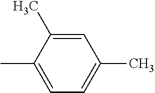 |
| D317 | 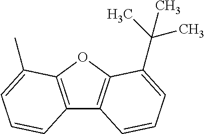 | 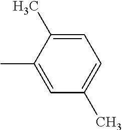 |
| D318 | 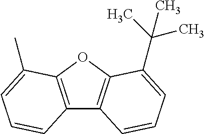 | 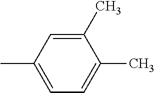 |
| D319 | 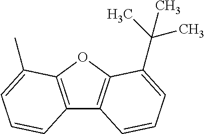 | 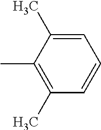 |
| D320 | 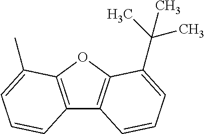 | 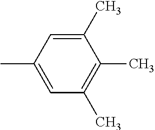 |

TABLE 44

| Compound | R₁ | R₂ | R₃ | R₄ | R₅ | R₇ | R₈ | R₉ | R₁₀ | R₁₁ | L₁ | L₂ | L₃ |
|---|---|---|---|---|---|---|---|---|---|---|---|---|---|
| D321 | H | H | H | H | H | H | H | H | H | H | — | — | — |
| D322 | H | H | H | H | H | H | H | H | H | H | — | — | — |
| D323 | H | H | H | H | H | H | H | H | H | H | — | — | — |
| D324 | H | H | H | H | H | H | H | H | H | H | — | — | — |
| D325 | H | H | H | H | H | H | H | H | H | H | — | — | — |

| Compound | Ar₁ | Ar₂ |
|---|---|---|
| D321 | 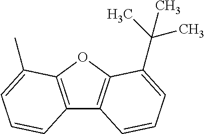 | 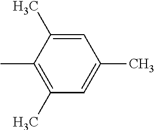 |
| D322 | 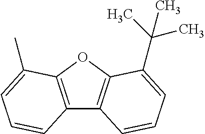 | 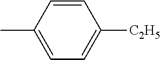 |
| D323 | 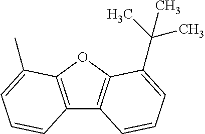 | 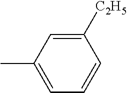 |
| D324 | 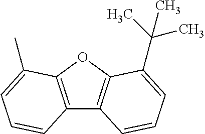 | 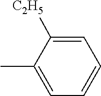 |
| D325 | 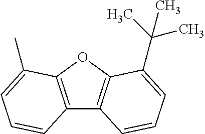 | 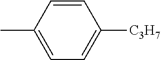 |

TABLE 45

| Compound | R₁ | R₂ | R₃ | R₄ | R₅ | R₇ | R₈ | R₉ | R₁₀ | R₁₁ | L₁ | L₂ | L₃ |
|---|---|---|---|---|---|---|---|---|---|---|---|---|---|
| D326 | H | H | H | H | H | H | H | H | H | H | — | — | — |
| D327 | H | H | H | H | H | H | H | H | H | H | — | — | — |
| D328 | H | H | H | H | H | H | H | H | H | H | — | — | — |
| D329 | H | H | H | H | H | H | H | H | H | H | — | — | — |
| D330 | H | H | H | H | H | H | H | H | H | H | — | — | — |

| Compound | Ar₁ | Ar₂ |
|---|---|---|
| D326 | 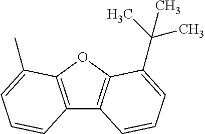 | 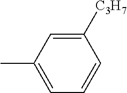 |
| D327 | 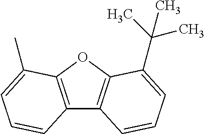 | 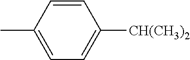 |
| D328 | 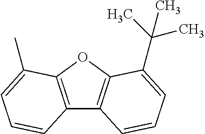 | 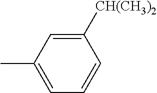 |
| D329 | 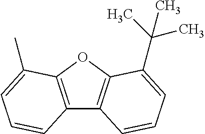 | 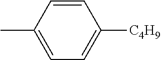 |
| D330 | 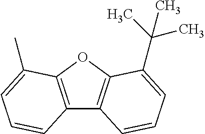 | 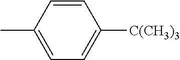 |

TABLE 46

| Compound | R₁ | R₂ | R₃ | R₄ | R₅ | R₇ | R₈ | R₉ | R₁₀ | R₁₁ | L₁ | L₂ | L₃ |
|---|---|---|---|---|---|---|---|---|---|---|---|---|---|
| D331 | H | H | H | H | H | H | H | H | H | H | — | — | — |
| D332 | H | H | H | H | H | H | H | H | H | H | — | — | — |
| D333 | H | H | H | H | H | H | H | H | H | H | — | — | — |
| D334 | H | H | H | H | H | H | H | H | H | H | — | — | — |
| D335 | H | H | H | H | H | H | H | H | H | H | — | — | — |

| Compound | Ar₁ | Ar₂ |
|---|---|---|
| D331 | 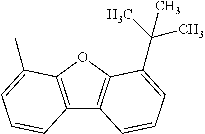 | 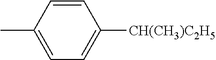 |
| D332 | 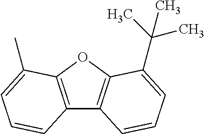 | 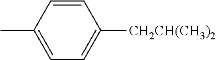 |
| D333 | 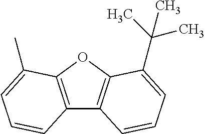 | 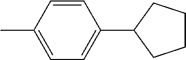 |
| D334 | 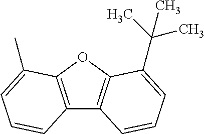 | 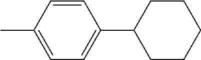 |
| D335 | 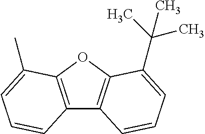 | 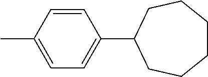 |

TABLE 47

| Com- | | | | | | | | | | | | | | | |
|---|---|---|---|---|---|---|---|---|---|---|---|---|---|---|---|
| pound | R₁ | R₂ | R₃ | R₄ | R₅ | R₇ | R₈ | R₉ | R₁₀ | R₁₁ | L₁ | L₂ | L₃ | Ar₁ | Ar₂ |
| D336 | H | H | H | H | H | H | H | H | H | H | — | — | — | 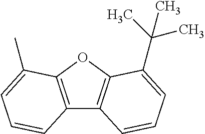 | 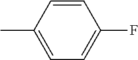 |
| D337 | H | H | H | H | H | H | H | H | H | H | — | — | — | 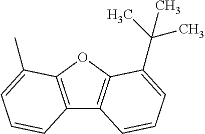 | 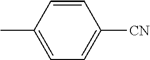 |
| D338 | H | H | H | H | H | H | H | H | H | H | — | — | — | 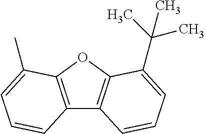 | 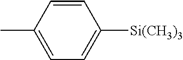 |
| D339 | H | H | H | H | H | H | H | H | H | H | — | — | — | 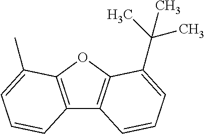 | 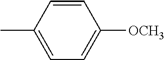 |
| D340 | H | H | H | H | H | H | H | H | H | H | — | — | — | 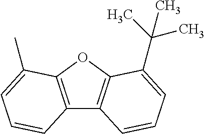 | 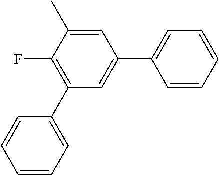 |

TABLE 48

| Com- | | | | | | | | | | | | | | | |
|---|---|---|---|---|---|---|---|---|---|---|---|---|---|---|---|
| pound | R₁ | R₂ | R₃ | R₄ | R₅ | R₇ | R₈ | R₉ | R₁₀ | R₁₁ | L₁ | L₂ | L₃ | Ar₁ | Ar₂ |
| D341 | H | H | H | H | H | H | H | H | H | H | — | — | — | 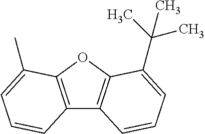 | 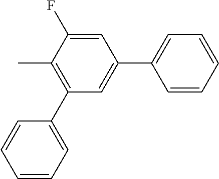 |
| D342 | H | H | H | H | H | H | H | H | H | H | — | — | — | 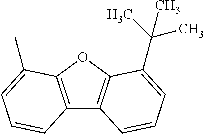 | 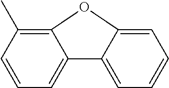 |
| D343 | H | H | H | H | H | H | H | H | H | H | — | — | — | 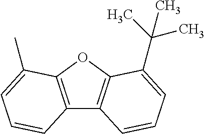 | 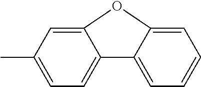 |
| D344 | H | H | H | H | H | H | H | H | H | H | — | — | — | 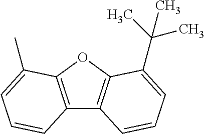 | 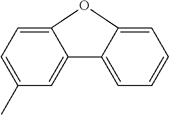 |
| D345 | H | H | H | H | H | H | H | H | H | H | — | — | — | 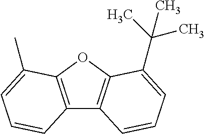 | 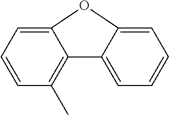 |

TABLE 49

| Com- | | | | | | | | | | | | | | | |
|---|---|---|---|---|---|---|---|---|---|---|---|---|---|---|---|
| pound | R₁ | R₂ | R₃ | R₄ | R₅ | R₇ | R₈ | R₉ | R₁₀ | R₁₁ | L₁ | L₂ | L₃ | Ar₁ | Ar₂ |
| D346 | H | H | H | H | H | H | H | H | H | H | — | — | — | 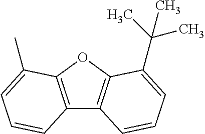 | 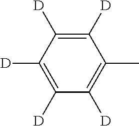 |
| D347 | H | H | H | H | H | H | H | H | H | H | — | — | — | 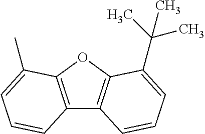 | 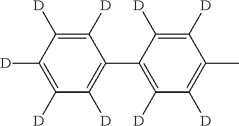 |
| D348 | H | H | H | H | H | H | H | H | H | H | — | — | — | 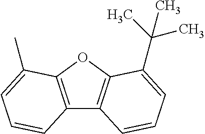 | 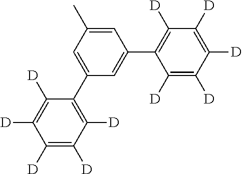 |
| D349 | H | H | H | H | H | H | H | H | H | H | — | — | — | 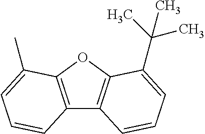 | 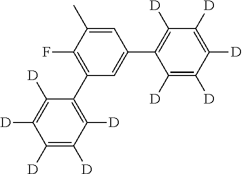 |

TABLE 50

| Com- | | | | | | | | | | | | | | | |
|---|---|---|---|---|---|---|---|---|---|---|---|---|---|---|---|
| pound | R₁ | R₂ | R₃ | R₄ | R₅ | R₇ | R₈ | R₉ | R₁₀ | R₁₁ | L₁ | L₂ | L₃ | Ar₁ | Ar₂ |
| D350 | H | H | H | H | H | H | H | H | H | H | 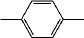 | — | — | 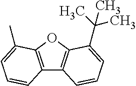 | 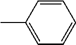 |
| D351 | H | H | H | H | H | H | H | H | H | H | 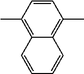 | — | — | 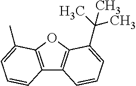 | 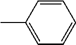 |
| D352 | H | H | H | H | H | H | H | H | H | H | 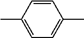 | 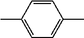 | — | 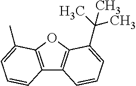 | 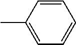 |
| D353 | H | H | H | H | H | H | H | H | H | H | — | — | 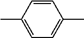 | 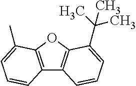 | 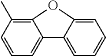 |

TABLE 51

| Com- | | | | | | | | | | | | | | | |
|---|---|---|---|---|---|---|---|---|---|---|---|---|---|---|---|
| pound | R₁ | R₂ | R₃ | R₄ | R₅ | R₇ | R₈ | R₉ | R₁₀ | R₁₁ | L₁ | L₂ | L₃ | Ar₁ | Ar₂ |
| D401 | H | H | H | H | H | H | H | H | H | H | — | — | — | 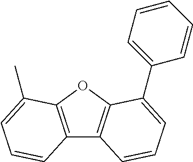 | 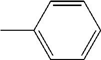 |
| D402 | H | H | H | H | H | H | H | H | H | H | — | — | — | 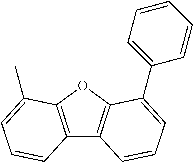 | 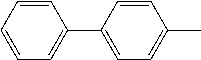 |
| D403 | H | H | H | H | H | H | H | H | H | H | — | — | — | 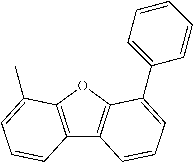 | 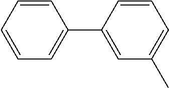 |
| D404 | H | H | H | H | H | H | H | H | H | H | — | — | — | 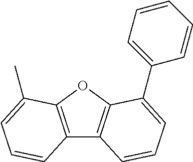 | 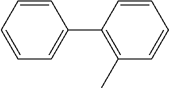 |
| D405 | H | H | H | H | H | H | H | H | H | H | — | — | — | 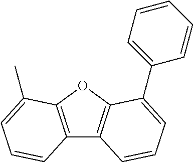 | 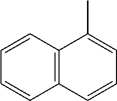 |

TABLE 52

| Com- | | | | | | | | | | | | | | | |
|---|---|---|---|---|---|---|---|---|---|---|---|---|---|---|---|
| pound | R₁ | R₂ | R₃ | R₄ | R₅ | R₇ | R₈ | R₉ | R₁₀ | R₁₁ | L₁ | L₂ | L₃ | Ar₁ | Ar₂ |
| D406 | H | H | H | H | H | H | H | H | H | H | — | — | — | 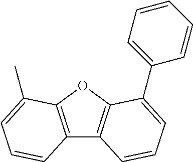 | 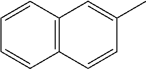 |
| D407 | H | H | H | H | H | H | H | H | H | H | — | — | — | 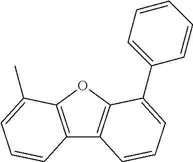 | 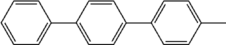 |
| D408 | H | H | H | H | H | H | H | H | H | H | — | — | — | 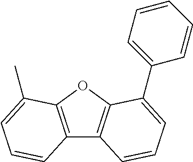 | 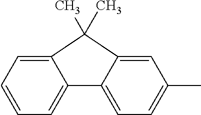 |
| D409 | H | H | H | H | H | H | H | H | H | H | — | — | — | 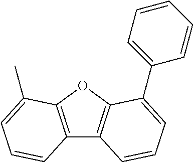 | 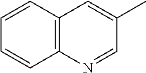 |
| D410 | H | H | H | H | H | H | H | H | H | H | — | — | — | 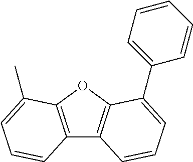 | 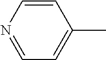 |

TABLE 53

| Com- | | | | | | | | | | | | | | | |
|---|---|---|---|---|---|---|---|---|---|---|---|---|---|---|---|
| pound | R₁ | R₂ | R₃ | R₄ | R₅ | R₇ | R₈ | R₉ | R₁₀ | R₁₁ | L₁ | L₂ | L₃ | Ar₁ | Ar₂ |
| D411 | H | H | H | H | H | H | H | H | H | H | — | — | — | 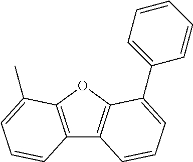 | 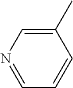 |
| D412 | H | H | H | H | H | H | H | H | H | H | — | — | — | 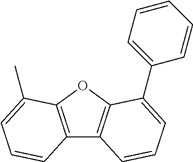 | 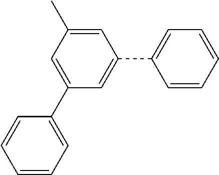 |
| D413 | H | H | H | H | H | H | H | H | H | H | — | — | — | 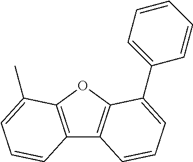 | 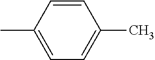 |
| D414 | H | H | H | H | H | H | H | H | H | H | — | — | — | 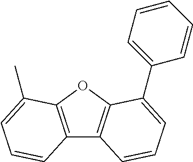 | 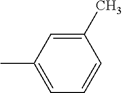 |
| D415 | H | H | H | H | H | H | H | H | H | H | — | — | — | 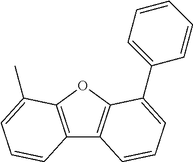 | 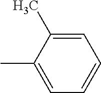 |

TABLE 54

| Com- | | | | | | | | | | | | | | | |
|---|---|---|---|---|---|---|---|---|---|---|---|---|---|---|---|
| pound | R₁ | R₂ | R₃ | R₄ | R₅ | R₇ | R₈ | R₉ | R₁₀ | R₁₁ | L₁ | L₂ | L₃ | Ar₁ | Ar₂ |
| D416 | H | H | H | H | H | H | H | H | H | H | — | — | — | 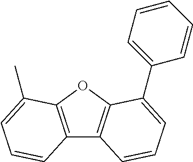 | 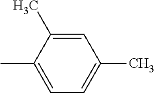 |
| D417 | H | H | H | H | H | H | H | H | H | H | — | — | — | 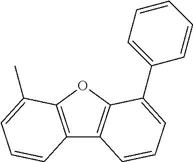 | 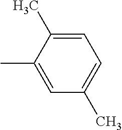 |
| D418 | H | H | H | H | H | H | H | H | H | H | — | — | — | 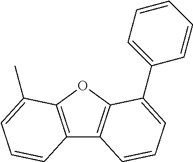 | 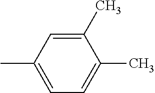 |
| D419 | H | H | H | H | H | H | H | H | H | H | — | — | — | 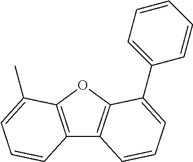 | 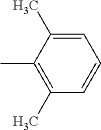 |
| D420 | H | H | H | H | H | H | H | H | H | H | — | — | — | 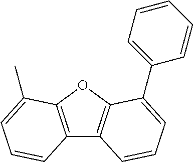 | 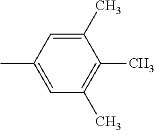 |

TABLE 55

| Com- | | | | | | | | | | | | | | | |
|---|---|---|---|---|---|---|---|---|---|---|---|---|---|---|---|
| pound | R₁ | R₂ | R₃ | R₄ | R₅ | R₇ | R₈ | R₉ | R₁₀ | R₁₁ | L₁ | L₂ | L₃ | Ar₁ | Ar₂ |
| D421 | H | H | H | H | H | H | H | H | H | H | — | — | — | 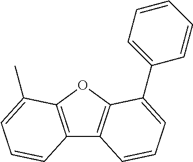 | 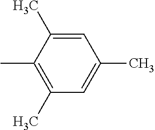 |
| D422 | H | H | H | H | H | H | H | H | H | H | — | — | — | 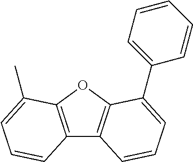 | 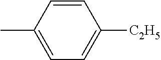 |
| D423 | H | H | H | H | H | H | H | H | H | H | — | — | — | 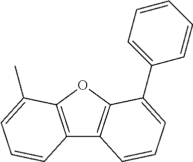 | 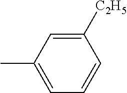 |
| D424 | H | H | H | H | H | H | H | H | H | H | — | — | — | 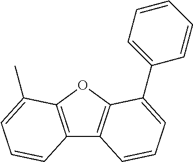 | 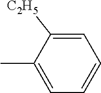 |
| D425 | H | H | H | H | H | H | H | H | H | H | — | — | — | 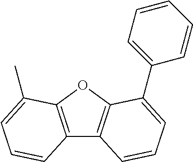 | 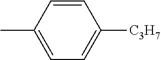 |

TABLE 56

| Com- | | | | | | | | | | | | | | | |
|---|---|---|---|---|---|---|---|---|---|---|---|---|---|---|---|
| pound | R₁ | R₂ | R₃ | R₄ | R₅ | R₇ | R₈ | R₉ | R₁₀ | R₁₁ | L₁ | L₂ | L₃ | Ar₁ | Ar₂ |
| D426 | H | H | H | H | H | H | H | H | H | H | — | — | — | 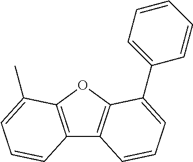 | 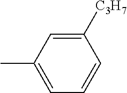 |
| D427 | H | H | H | H | H | H | H | H | H | H | — | — | — | 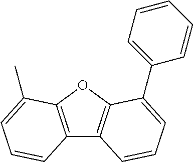 | 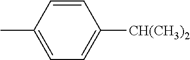 |
| D428 | H | H | H | H | H | H | H | H | H | H | — | — | — | 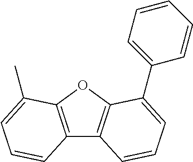 | 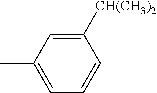 |
| D429 | H | H | H | H | H | H | H | H | H | H | — | — | — | 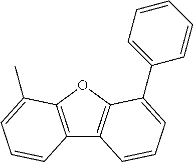 | 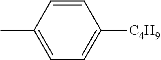 |
| D430 | H | H | H | H | H | H | H | H | H | H | — | — | — | 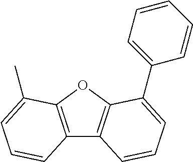 | 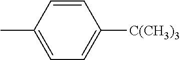 |

TABLE 57

| Com- | | | | | | | | | | | | | | | |
|---|---|---|---|---|---|---|---|---|---|---|---|---|---|---|---|
| pound | R₁ | R₂ | R₃ | R₄ | R₅ | R₇ | R₈ | R₉ | R₁₀ | R₁₁ | L₁ | L₂ | L₃ | Ar₁ | Ar₂ |
| D431 | H | H | H | H | H | H | H | H | H | H | — | — | — | 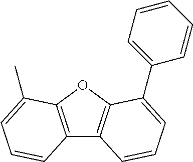 | 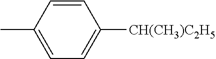 |
| D432 | H | H | H | H | H | H | H | H | H | H | — | — | — | 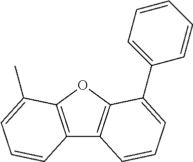 | 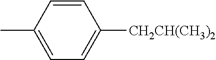 |
| D433 | H | H | H | H | H | H | H | H | H | H | — | — | — | 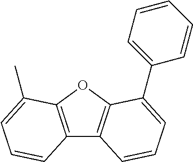 | 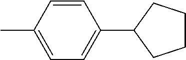 |
| D434 | H | H | H | H | H | H | H | H | H | H | — | — | — | 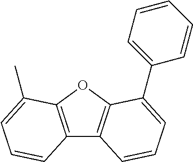 | 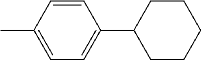 |
| D435 | H | H | H | H | H | H | H | H | H | H | — | — | — | 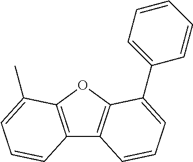 | 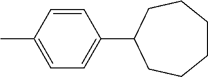 |

TABLE 58

| Com- | | | | | | | | | | | | | | | |
|---|---|---|---|---|---|---|---|---|---|---|---|---|---|---|---|
| pound | R₁ | R₂ | R₃ | R₄ | R₅ | R₇ | R₈ | R₉ | R₁₀ | R₁₁ | L₁ | L₂ | L₃ | Ar₁ | Ar₂ |
| D436 | H | H | H | H | H | H | H | H | H | H | — | — | — | 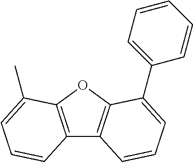 | 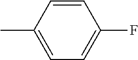 |
| D437 | H | H | H | H | H | H | H | H | H | H | — | — | — | 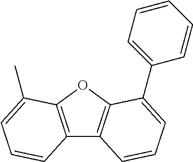 | 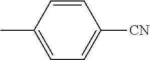 |
| D438 | H | H | H | H | H | H | H | H | H | H | — | — | — | 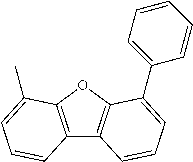 | 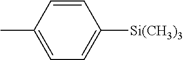 |
| D439 | H | H | H | H | H | H | H | H | H | H | — | — | — | 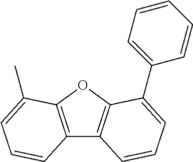 | 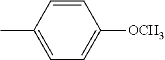 |
| D440 | H | H | H | H | H | H | H | H | H | H | — | — | — | 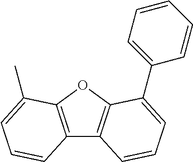 | 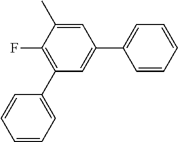 |

TABLE 59

| Com- | | | | | | | | | | | | | | | |
|---|---|---|---|---|---|---|---|---|---|---|---|---|---|---|---|
| pound | R₁ | R₂ | R₃ | R₄ | R₅ | R₇ | R₈ | R₉ | R₁₀ | R₁₁ | L₁ | L₂ | L₃ | Ar₁ | Ar₂ |
| D441 | H | H | H | H | H | H | H | H | H | H | — | — | — | 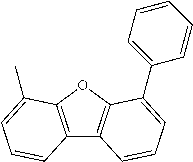 | 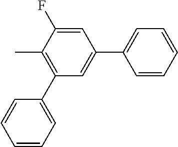 |
| D442 | H | H | H | H | H | H | H | H | H | H | — | — | — | 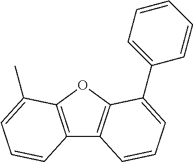 | 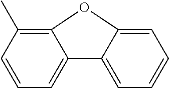 |
| D443 | H | H | H | H | H | H | H | H | H | H | — | — | — | 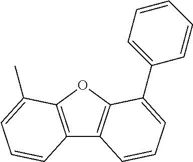 | 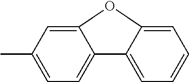 |
| D444 | H | H | H | H | H | H | H | H | H | H | — | — | — | 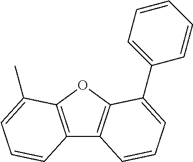 | 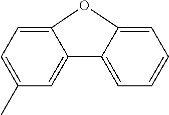 |
| D445 | H | H | H | H | H | H | H | H | H | H | — | — | — | 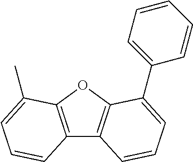 | 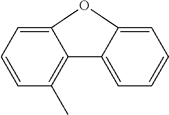 |

TABLE 60

| Com- | | | | | | | | | | | | | | | |
|---|---|---|---|---|---|---|---|---|---|---|---|---|---|---|---|
| pound | R₁ | R₂ | R₃ | R₄ | R₅ | R₇ | R₈ | R₉ | R₁₀ | R₁₁ | L₁ | L₂ | L₃ | Ar₁ | Ar₂ |
| D446 | H | H | H | H | H | H | H | H | H | H | — | — | — | 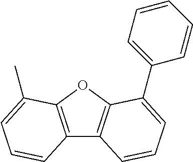 | 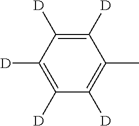 |
| D447 | H | H | H | H | H | H | H | H | H | H | — | — | — | 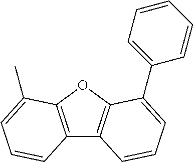 | 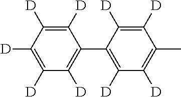 |
| D448 | H | H | H | H | H | H | H | H | H | H | — | — | — | 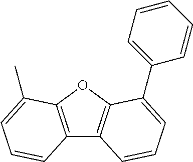 | 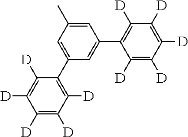 |
| D449 | H | H | H | H | H | H | H | H | H | H | — | — | — | 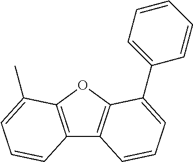 | 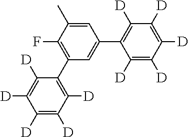 |

TABLE 61

| Com- | | | | | | | | | | | | | | | |
|---|---|---|---|---|---|---|---|---|---|---|---|---|---|---|---|
| pound | R₁ | R₂ | R₃ | R₄ | R₅ | R₇ | R₈ | R₉ | R₁₀ | R₁₁ | L₁ | L₂ | L₃ | Ar₁ | Ar₂ |
| D450 | H | H | H | H | H | H | H | H | H | H | 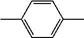 | — | — | 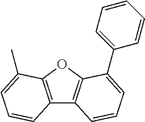 | 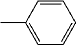 |
| D451 | H | H | H | H | H | H | H | H | H | H | 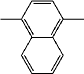 | — | — | 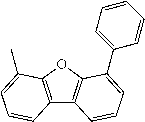 | 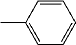 |
| D452 | H | H | H | H | H | H | H | H | H | H | 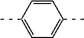 | 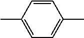 | — | 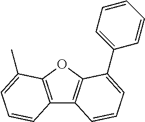 | 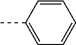 |
| D453 | H | H | H | H | H | H | H | H | H | H | — | — | 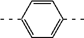 | 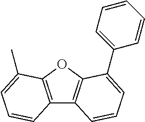 | 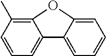 |

TABLE 62

| Com- | | | | | | | | | | | | | | | |
|---|---|---|---|---|---|---|---|---|---|---|---|---|---|---|---|
| pound | R₁ | R₂ | R₃ | R₄ | R₅ | R₇ | R₈ | R₉ | R₁₀ | R₁₁ | L₁ | L₂ | L₃ | Ar₁ | Ar₂ |
| D501 | H | H | H | H | H | H | H | H | H | H | — | — | — | 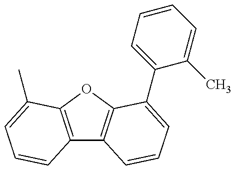 | 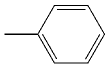 |
| D502 | H | H | H | H | H | H | H | H | H | H | — | — | — | 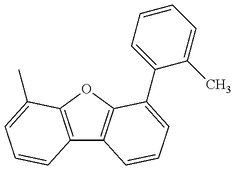 | 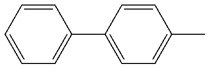 |
| D503 | H | H | H | H | H | H | H | H | H | H | — | — | — | 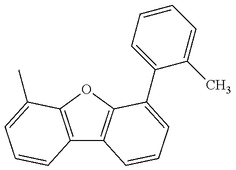 | 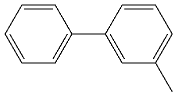 |
| D504 | H | H | H | H | H | H | H | H | H | H | — | — | — | 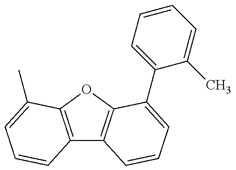 | 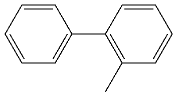 |
| D505 | H | H | H | H | H | H | H | H | H | H | — | — | — | 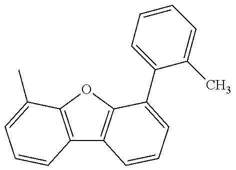 | 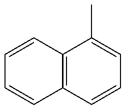 |

TABLE 63

| Com- | | | | | | | | | | | | | | | |
|---|---|---|---|---|---|---|---|---|---|---|---|---|---|---|---|
| pound | R₁ | R₂ | R₃ | R₄ | R₅ | R₇ | R₈ | R₉ | R₁₀ | R₁₁ | L₁ | L₂ | L₃ | Ar₁ | Ar₂ |
| D506 | H | H | H | H | H | H | H | H | H | H | — | — | — | 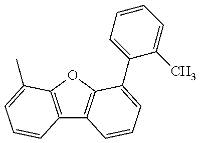 | 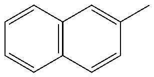 |
| D507 | H | H | H | H | H | H | H | H | H | H | — | — | — | 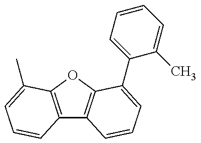 | 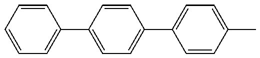 |
| D508 | H | H | H | H | H | H | H | H | H | H | — | — | — | 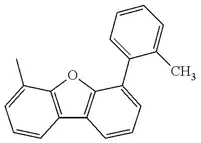 | 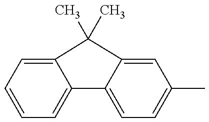 |
| D509 | H | H | H | H | H | H | H | H | H | H | — | — | — | 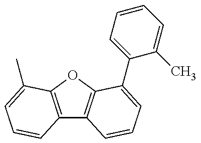 | 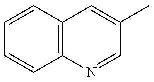 |
| D510 | H | H | H | H | H | H | H | H | H | H | — | — | — | 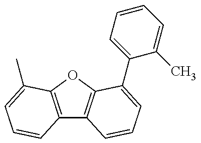 | 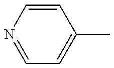 |

TABLE 64

| Com- | | | | | | | | | | | | | | | |
|---|---|---|---|---|---|---|---|---|---|---|---|---|---|---|---|
| pound | R₁ | R₂ | R₃ | R₄ | R₅ | R₇ | R₈ | R₉ | R₁₀ | R₁₁ | L₁ | L₂ | L₃ | Ar₁ | Ar₂ |
| D511 | H | H | H | H | H | H | H | H | H | H | — | — | — | 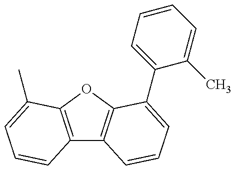 | 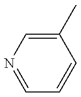 |
| D512 | H | H | H | H | H | H | H | H | H | H | — | — | — | 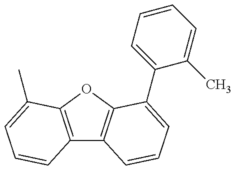 | 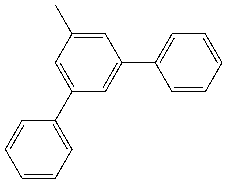 |
| D513 | H | H | H | H | H | H | H | H | H | H | — | — | — | 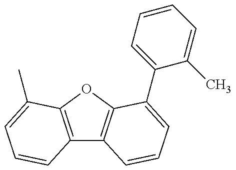 | 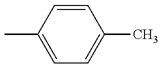 |
| D514 | H | H | H | H | H | H | H | H | H | H | — | — | — | 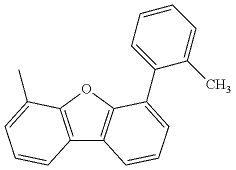 | 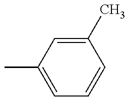 |
| D515 | H | H | H | H | H | H | H | H | H | H | — | — | — | 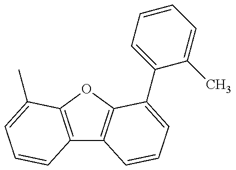 | 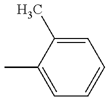 |

TABLE 65

| Compound | R₁ | R₂ | R₃ | R₄ | R₅ | R₇ | R₈ | R₉ | R₁₀ | R₁₁ | L₁ | L₂ | L₃ | Ar₁ | Ar₂ |
|---|---|---|---|---|---|---|---|---|---|---|---|---|---|---|---|
| D516 | H | H | H | H | H | H | H | H | H | H | — | — | — | 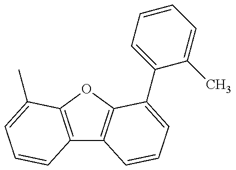 | 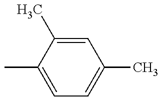 |
| D517 | H | H | H | H | H | H | H | H | H | H | — | — | — | 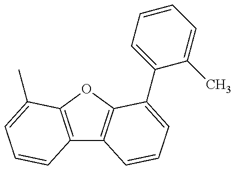 | 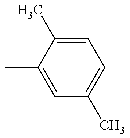 |
| D518 | H | H | H | H | H | H | H | H | H | H | — | — | — | 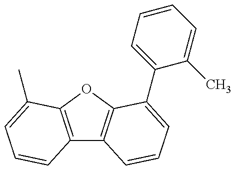 | 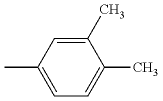 |
| D519 | H | H | H | H | H | H | H | H | H | H | — | — | — | 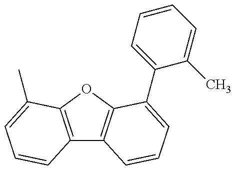 | 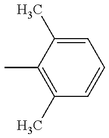 |
| D520 | H | H | H | H | H | H | H | H | H | H | — | — | — | 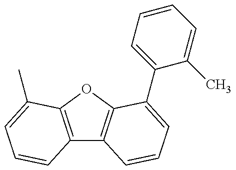 | 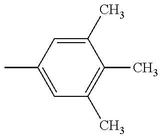 |

TABLE 66

| Compound | R₁ | R₂ | R₃ | R₄ | R₅ | R₇ | R₈ | R₉ | R₁₀ | R₁₁ | L₁ | L₂ | L₃ | Ar₁ | Ar₂ |
|---|---|---|---|---|---|---|---|---|---|---|---|---|---|---|---|
| D521 | H | H | H | H | H | H | H | H | H | H | — | — | — | 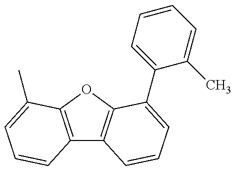 | 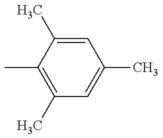 |
| D522 | H | H | H | H | H | H | H | H | H | H | — | — | — | 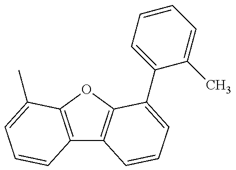 | 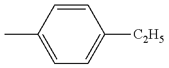 |
| D523 | H | H | H | H | H | H | H | H | H | H | — | — | — | 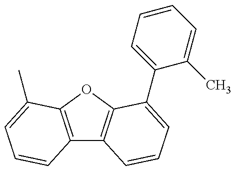 | 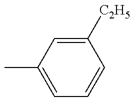 |
| D524 | H | H | H | H | H | H | H | H | H | H | — | — | — | 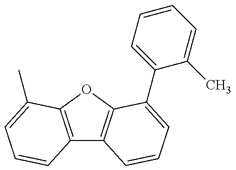 | 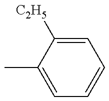 |
| D525 | H | H | H | H | H | H | H | H | H | H | — | — | — | 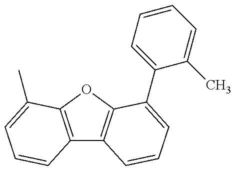 | 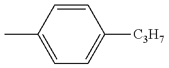 |

TABLE 67

| Compound | R₁ | R₂ | R₃ | R₄ | R₅ | R₇ | R₈ | R₉ | R₁₀ | R₁₁ | L₁ | L₂ | L₃ | Ar₁ | Ar₂ |
|---|---|---|---|---|---|---|---|---|---|---|---|---|---|---|---|
| D526 | H | H | H | H | H | H | H | H | H | H | — | — | — | 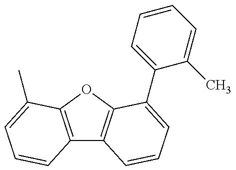 | 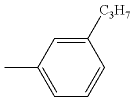 |
| D527 | H | H | H | H | H | H | H | H | H | H | — | — | — | 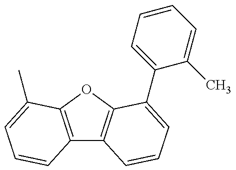 | 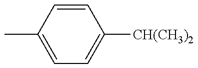 |
| D528 | H | H | H | H | H | H | H | H | H | H | — | — | — | 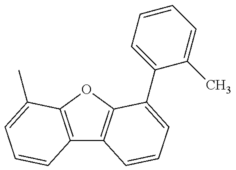 | 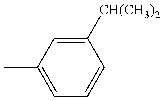 |
| D529 | H | H | H | H | H | H | H | H | H | H | — | — | — | 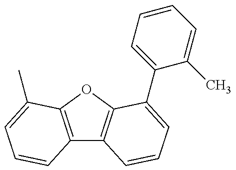 | 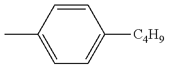 |
| D530 | H | H | H | H | H | H | H | H | H | H | — | — | — | 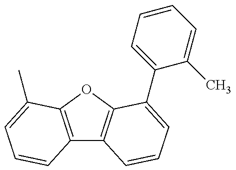 | 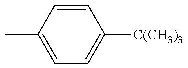 |

TABLE 68

| Com- | | | | | | | | | | | | | | | |
|---|---|---|---|---|---|---|---|---|---|---|---|---|---|---|---|
| pound | R₁ | R₂ | R₃ | R₄ | R₅ | R₇ | R₈ | R₉ | R₁₀ | R₁₁ | L₁ | L₂ | L₃ | Ar₁ | Ar₂ |
| D531 | H | H | H | H | H | H | H | H | H | H | — | — | — | 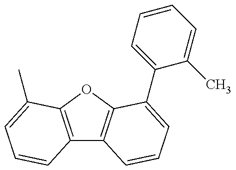 | 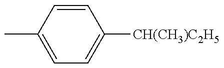 |
| D532 | H | H | H | H | H | H | H | H | H | H | — | — | — | 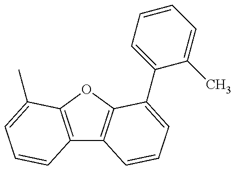 | 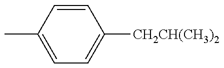 |
| D533 | H | H | H | H | H | H | H | H | H | H | — | — | — | 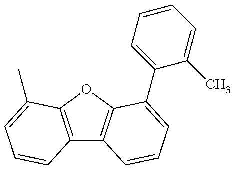 | 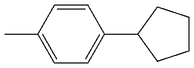 |
| D534 | H | H | H | H | H | H | H | H | H | H | — | — | — | 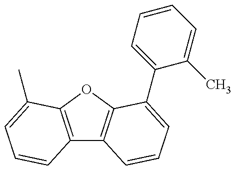 | 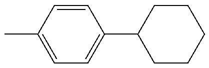 |
| D535 | H | H | H | H | H | H | H | H | H | H | — | — | — | 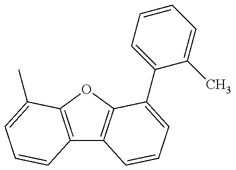 | 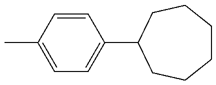 |

TABLE 69

| Com- | | | | | | | | | | | | | | | |
|---|---|---|---|---|---|---|---|---|---|---|---|---|---|---|---|
| pound | R₁ | R₂ | R₃ | R₄ | R₅ | R₇ | R₈ | R₉ | R₁₀ | R₁₁ | L₁ | L₂ | L₃ | Ar₁ | Ar₂ |
| D536 | H | H | H | H | H | H | H | H | H | H | — | — | — | 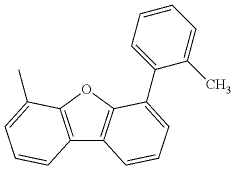 | 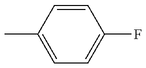 |
| D537 | H | H | H | H | H | H | H | H | H | H | — | — | — | 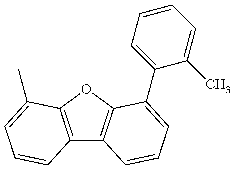 | 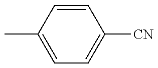 |
| D538 | H | H | H | H | H | H | H | H | H | H | — | — | — | 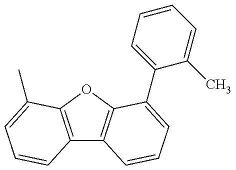 | 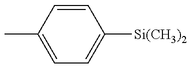 |
| D539 | H | H | H | H | H | H | H | H | H | H | — | — | — | 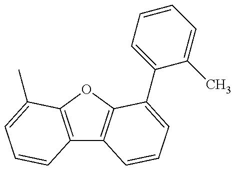 | 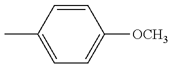 |
| D540 | H | H | H | H | H | H | H | H | H | H | — | — | — | 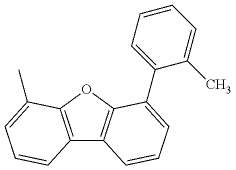 | 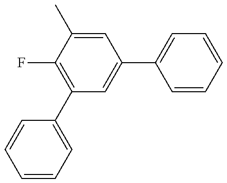 |

TABLE 70

| Com- | | | | | | | | | | | | | | | |
|---|---|---|---|---|---|---|---|---|---|---|---|---|---|---|---|
| pound | R₁ | R₂ | R₃ | R₄ | R₅ | R₇ | R₈ | R₉ | R₁₀ | R₁₁ | L₁ | L₂ | L₃ | Ar₁ | Ar₂ |
| D541 | H | H | H | H | H | H | H | H | H | H | — | — | — | 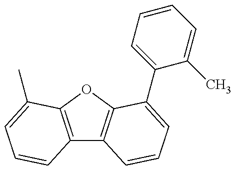 | 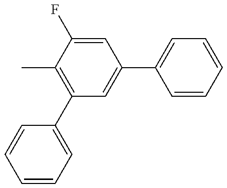 |
| D542 | H | H | H | H | H | H | H | H | H | H | — | — | — | 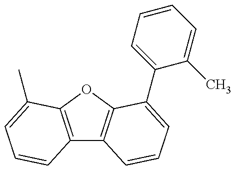 | 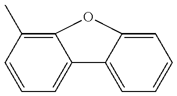 |
| D543 | H | H | H | H | H | H | H | H | H | H | — | — | — | 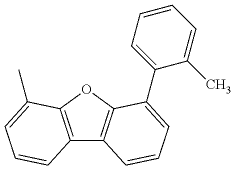 | 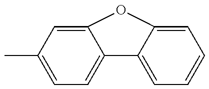 |
| D544 | H | H | H | H | H | H | H | H | H | H | — | — | — | 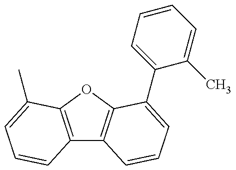 | 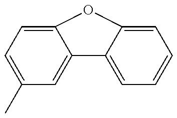 |
| D545 | H | H | H | H | H | H | H | H | H | H | — | — | — | 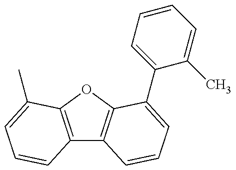 | 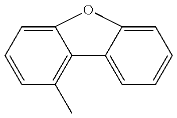 |

TABLE 71

| Com- | | | | | | | | | | | | | | | |
|---|---|---|---|---|---|---|---|---|---|---|---|---|---|---|---|
| pound | R₁ | R₂ | R₃ | R₄ | R₅ | R₇ | R₈ | R₉ | R₁₀ | R₁₁ | L₁ | L₂ | L₃ | Ar₁ | Ar₂ |
| D546 | H | H | H | H | H | H | H | H | H | H | — | — | — | 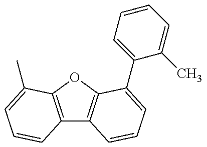 | 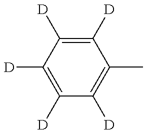 |
| D547 | H | H | H | H | H | H | H | H | H | H | — | — | — | 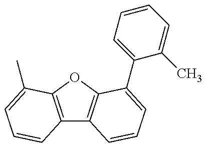 | 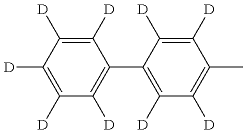 |
| D548 | H | H | H | H | H | H | H | H | H | H | — | — | — | 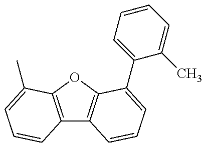 | 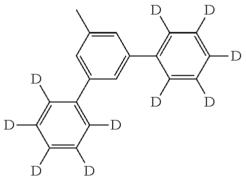 |
| D549 | H | H | H | H | H | H | H | H | H | H | — | — | — | 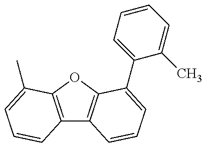 | 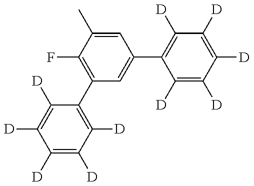 |

TABLE 72

| Compound | R₁ | R₂ | R₃ | R₄ | R₅ | R₇ | R₈ | R₉ | R₁₀ | R₁₁ | L₁ | L₂ |
|---|---|---|---|---|---|---|---|---|---|---|---|---|
| D550 | H | H | H | H | H | H | H | H | H | H | 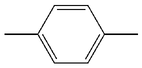 | — |
| D551 | H | H | H | H | H | H | H | H | H | H | 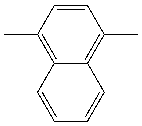 | — |
| D552 | H | H | H | H | H | H | H | H | H | H | 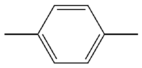 | 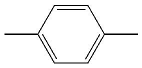 |
| D553 | H | H | H | H | H | H | H | H | H | H | — | — |

| Compound | L₃ | Ar₁ | Ar₂ |
|---|---|---|---|
| D550 | — | 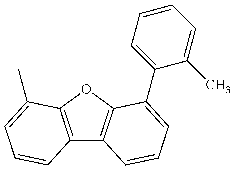 | 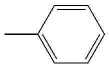 |
| D551 | — | 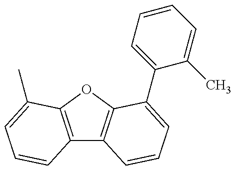 | 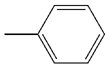 |
| D552 | — | 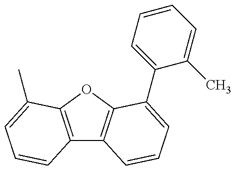 | 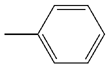 |
| D553 | 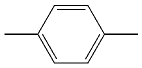 | 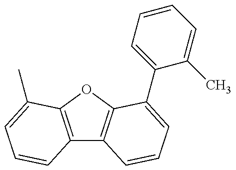 | 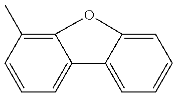 |

TABLE 73

| Com- | | | | | | | | | | | | | | | |
|---|---|---|---|---|---|---|---|---|---|---|---|---|---|---|---|
| pound | R₁ | R₂ | R₃ | R₄ | R₅ | R₇ | R₈ | R₉ | R₁₀ | R₁₁ | L₁ | L₂ | L₃ | Ar₁ | Ar₂ |
| D601 | H | H | H | H | H | H | H | H | H | H | — | — | — | 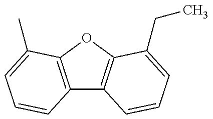 | 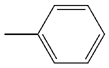 |
| D602 | H | H | H | H | H | H | H | H | H | H | — | — | — | 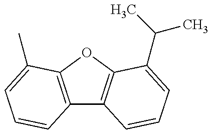 | 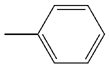 |
| D603 | H | H | H | H | H | H | H | H | H | H | — | — | — | 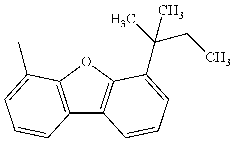 | 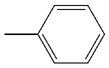 |
| D604 | H | H | H | H | H | H | H | H | H | H | — | — | — | 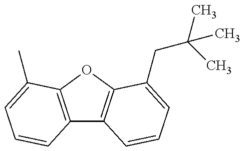 | 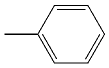 |
| D605 | H | H | H | H | H | H | H | H | H | H | — | — | — | 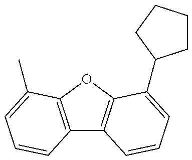 | 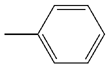 |

TABLE 74

| Compound | R₁ | R₂ | R₃ | R₄ | R₅ | R₇ | R₈ | R₉ | R₁₀ | R₁₁ | L₁ | L₂ | L₃ | Ar₂ | Ar₂ |
|---|---|---|---|---|---|---|---|---|---|---|---|---|---|---|---|
| D606 | H | H | H | H | H | H | H | H | H | H | — | — | — | 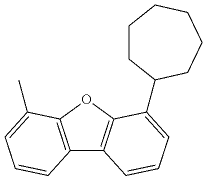 | 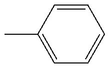 |
| D607 | H | H | H | H | H | H | H | H | H | H | — | — | — | 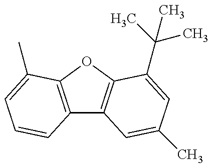 | 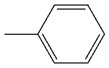 |
| D608 | H | H | H | H | H | H | H | H | H | H | — | — | — | 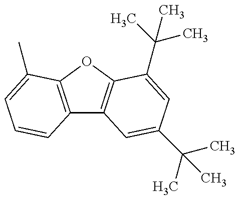 | 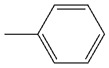 |
| D609 | H | H | H | H | H | H | H | H | H | H | — | — | — | 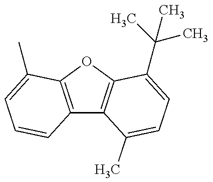 | 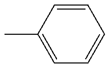 |
| D610 | H | H | H | H | H | H | H | H | H | H | — | — | — | 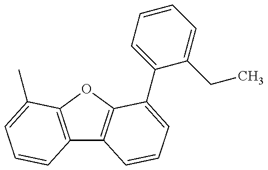 | 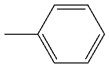 |

TABLE 75

| Compound | R₁ | R₂ | R₃ | R₄ | R₅ | R₇ | R₈ | R₉ | R₁₀ | R₁₁ | L₁ | L₂ | L₃ | Ar₁ | Ar₂ |
|---|---|---|---|---|---|---|---|---|---|---|---|---|---|---|---|
| D611 | H | H | H | H | H | H | H | H | H | H | — | — | — | 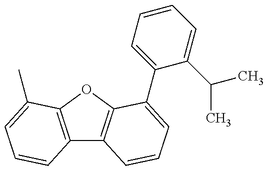 | 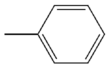 |
| D612 | H | H | H | H | H | H | H | H | H | H | — | — | — | 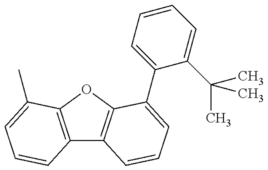 | 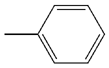 |
| D613 | H | H | H | H | H | H | H | H | H | H | — | — | — | 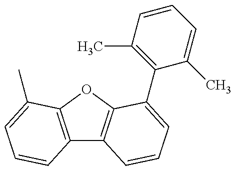 | 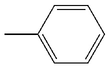 |
| D614 | H | H | H | H | H | H | H | H | H | H | — | — | — | 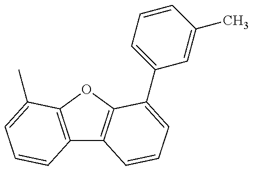 | 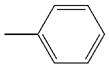 |
| D615 | H | H | H | H | H | H | H | H | H | H | — | — | — | 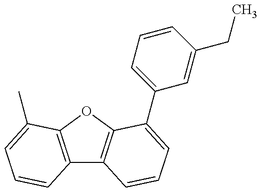 | 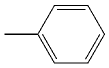 |

TABLE 76

| Compound | R₁ | R₂ | R₃ | R₄ | R₅ | R₇ | R₈ | R₉ | R₁₀ | R₁₁ | L₁ | L₂ | L₃ | Ar₁ | Ar₂ |
|---|---|---|---|---|---|---|---|---|---|---|---|---|---|---|---|
| D616 | H | H | H | H | H | H | H | H | H | H | — | — | — | 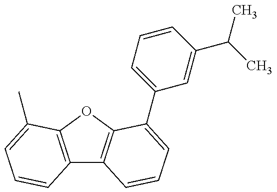 | 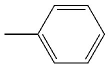 |
| D617 | H | H | H | H | H | H | H | H | H | H | — | — | — | 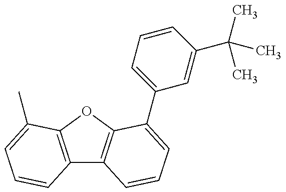 | 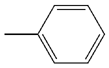 |
| D618 | H | H | H | H | H | H | H | H | H | H | — | — | — | 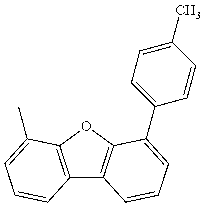 | 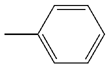 |
| D619 | H | H | H | H | H | H | H | H | H | H | — | — | — | 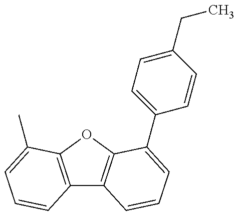 | 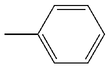 |
| D620 | H | H | H | H | H | H | H | H | H | H | — | — | — | 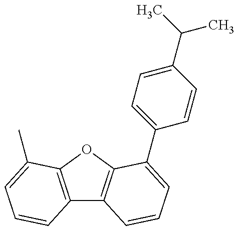 | 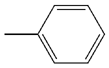 |
| D621 | H | H | H | H | H | H | H | H | H | H | — | — | — | 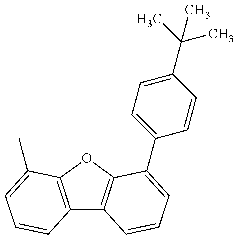 | 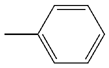 |

In the above specific examples of the aromatic amine derivative, R₆ and R₁₂ are exemplified by compounds having portions represented by the formula (2) that are mutually the same in structure but may be compounds having the portions represented by the formula (2) that are mutually different in structure.

### Organic-EL-Device Material

The aromatic amine derivative according to the invention is usable as an organic-EL-device material. The organic-EL-device material may contain the aromatic amine derivative singularly or in combination with another compound. The organic-EL-device material containing the aromatic amine derivative according to the invention is usable as, for instance, a dopant material.

An example of the organic-EL-device material containing the aromatic amine derivative according to the invention in combination with another compound is an organic-EL-device material containing an anthracene derivative represented by the above formula (20).

Another example is an organic-EL-device material containing the aromatic amine derivative according to the invention in combination with a pyrene derivative represented by the following formula (30) in place of the anthracene derivative.

Still another example is an organic-EL-device material containing the aromatic amine derivative according to the invention in combination with the anthracene derivative represented by the formula (20) and the pyrene derivative represented by the formula (30).

### Organic EL Device

According to the invention, an organic EL device includes a cathode, an anode, and an organic compound layer interposed between the cathode and the anode.

The aromatic amine derivative according to the invention may be contained in the organic compound layer. The organic compound layer is formed of the organic-EL-device material containing the aromatic amine derivative according to the invention.

The organic compound layer includes at least one organic thin-film layer formed of an organic compound. At least one layer forming the organic thin-film layer contains the aromatic amine derivative according to the invention singularly or as a component of a mixture. Incidentally, the organic thin-film layer may contain an inorganic compound.

At least one layer of the organic thin-film layer is an emitting layer. In other words, for instance, the organic compound layer may consist of a single emitting layer or may include another layer usable in a known organic EL device (e.g., a hole injecting layer, a hole transporting layer, an electron injecting layer, an electron transporting layer, a hole blocking layer and an electron blocking layer) as well as the emitting layer. When the organic thin-film layer consists of a plurality of layers, at least one of the layers contains the aromatic amine derivative according to the invention singularly or as a component of a mixture.

The aromatic amine derivative according to the invention is preferably contained in the emitting layer. In this case, the emitting layer may be formed of only the aromatic amine derivative or may contain the aromatic amine derivative as a host material or a dopant material.

Representative arrangement examples of an organic EL device are as follows:

(a) anode/emitting layer/cathode;

(b) anode/hole injecting•transporting layer/emitting layer/cathode;

(c) anode/emitting layer/electron injecting•transporting layer/cathode;

(d) anode/hole injecting•transporting layer/emitting layer/electron injecting•transporting layer/cathode; and

(e) anode/hole injecting•transporting layer/emitting layer/blocking layer/electron injecting•transporting layer/cathode.

Among the above non-exhaustive exemplary arrangements, the arrangement (d) is suitably used.

Incidentally, the “emitting layer”, which is an organic layer having a luminescent function, contains a host material and a dopant material when the device employs a doping system. In this case, the host material has a function to promote recombination mainly of electrons and holes and to trap excitons generated by the recombination within the emitting layer, while the dopant material has a function to efficiently cause light emission of the excitons.

The term “hole injecting/transporting layer (or hole injecting•transporting layer)” means “at least one of hole injecting layer and hole transporting layer”, while the term “electron injecting/transporting layer (or electron injecting•transporting layer)” means “at least one of electron injecting layer and electron transporting layer”. When the hole injecting layer and the hole transporting layer are provided, the hole injecting layer is preferably disposed closer to the anode. When the electron injecting layer and the electron transporting layer are provided, the electron injecting layer is preferably disposed closer to the cathode. The hole injecting layer, the emitting layer and the electron injecting layer may each consist of two or more layers. In this case, regarding the hole injecting layer, a layer into which holes are injected from an electrode is referred to as the hole injecting layer, while a layer that receives the holes from the hole injecting layer and transports the holes to the emitting layer is referred to as the hole transporting layer. Similarly, regarding the electron injecting layer, a layer into which electrons are injected from an electrode is referred to as the electron injecting layer, while a layer that receives the electrons from the electron injecting layer and transports the electrons to the emitting layer is referred to as the electron transporting layer.

When the organic EL device includes the multilayered organic thin-film layer, a decrease in luminescence intensity and lifetime due to quenching can be avoided. A luminescent material, a doping material, a hole injecting material and an electron injecting material may be used in combination as needed. The doping material may help improve luminescence intensity and luminous efficiency.

These layers are selectively usable depending on properties of the materials such as energy level, heat resistance, and adhesiveness to an organic layer or a metallic electrode.

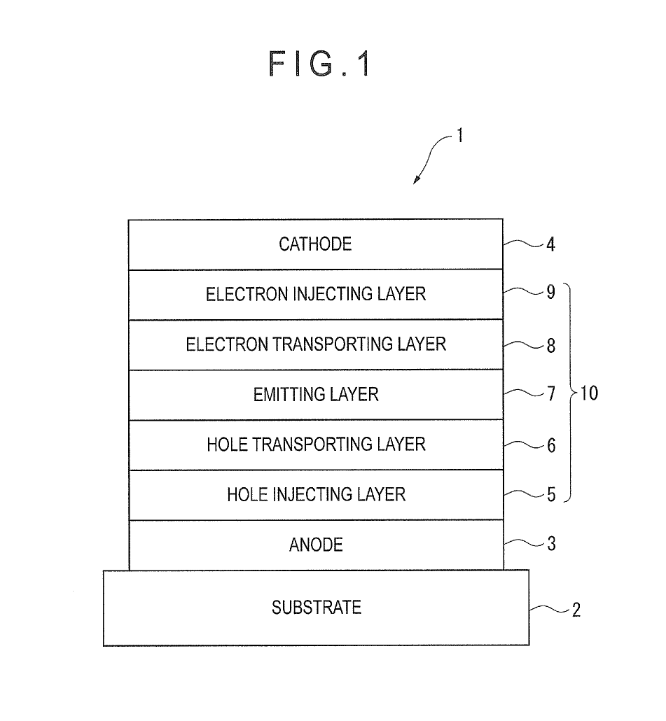

FIG. 1 schematically shows an exemplary arrangement of an organic EL device according to an exemplary embodiment of the invention.

An organic EL device 1 includes a transparent substrate 2, an anode 3, a cathode 4 and an organic compound layer 10 provided between the anode 3 and the cathode 4.

The organic compound layer 10 includes a hole injecting layer 5, a hole transporting layer 6, an emitting layer 7, an electron transporting layer 8 and an electron injecting layer 9 that are arranged on the anode 3 in this sequence.

### Emitting Layer

The emitting layer of the organic EL device has a function to provide conditions for recombination of the electrons and the holes to emit light.

In the organic EL device according to the exemplary embodiment, it is preferable that at least one layer forming the organic thin-film layer contains the aromatic amine derivative according to the invention and at least one of the anthracene derivative represented by the formula (20) and the pyrene derivative represented by the following formula (30). It is particularly preferable that the emitting layer contains the aromatic amine derivative according to the invention as a dopant material and the anthracene derivative represented by the formula (20) as a host material.

### Anthracene Derivative

The anthracene derivative, which may be contained in the emitting layer as a host material, is represented by the formula (20).

In the formula (20), Ar¹¹ and Ar¹² are each independently a substituted or unsubstituted monocyclic group having 5 to 30 ring atoms, a substituted or unsubstituted fused ring group having 10 to 30 ring atoms, or a group formed by combining the monocyclic group and the fused ring group.

In the formula (20), the monocyclic group is a group that has only a ring structure without any fused structure.

The number of the ring atoms of the monocyclic group is 5 to 30, preferably 5 to 20. Examples of the monocyclic group are aromatic groups such as a phenyl group, biphenyl group, terphenyl group and quaterphenyl group and heterocyclic groups such as a pyridyl group, pyrazyl group, pyrimidyl group, triazinyl group, furyl group and thienyl group. Among the above, a phenyl group, a biphenyl group and a terphenyl group are preferable.

In the formula (20), the fused ring group is a group formed by fusing two or more ring structures.

The number of the ring atoms of the fused ring group is 10 to 30, preferably 10 to 20. Examples of the fused ring group are fused aromatic ring groups such as a naphthyl group, phenanthryl group, anthryl group, chrysenyl group, benzanthryl group, benzophenanthryl group, trihenylenyl group, benzochrysenyl group, indenyl group, fluorenyl group, 9,9-dimethylfluorenyl group, benzofluorenyl group, dibenzofluorenyl group, fluoranthenyl group and benzofluoranthenyl group, and fused heterocyclic groups such as a benzofuranyl group, benzothiophenyl group, indolyl group, dibenzofuranyl group, dibenzothiophenyl group, carbazolyl group, quinolyl group and phenanthrolinyl group. Among the above, a naphthyl group, a phenanthryl group, an anthryl group, a 9,9-dimethylfluorenyl group, a fluoranthenyl group, a benzanthryl group, a dibenzothiophenyl group, a dibenzofuranyl group and a carbazolyl group are preferable.

An example of the group formed by combining the monocyclic group and the fused ring group in the formula (20) is a group formed by combining a phenyl group, a naphthyl group and a phenyl group in this sequence next to an anthracene ring (see a compound EM50 and the like shown below).

Specific examples of the alkyl group, silyl group, alkoxy group, aryloxy group, aralkyl group and halogen atom for R¹⁰¹ to R¹⁰⁸ in the formula (20) are the same as ones listed above for R₁ to R₅ and R₇ to R₁₁ in the formula (1) and the cycloalkyl group is likewise exemplified as above. Further, the above explanation of the expression “substituted or unsubstituted” is also applicable to these substituents.

Specific preferable examples of the structure of the formula (20) will be shown below.

Preferable examples of substituents (in the case of “substituted or unsubstituted”) for Ar¹¹, Ar¹² and R¹⁰¹ to R¹⁰⁸ in the formula (20) are a monocyclic group, fused ring group, alkyl group, cycloalkyl group, silyl group, alkoxy group, cyano group and halogen atom (in particular, fluorine). Among the above, a monocyclic group and a fused ring group are particularly preferable and specific preferable examples of the substituent are the same as those of each group listed above for the formula (20) and the formula (1).

The anthracene derivative of the formula (20) is preferably selected from among the following anthracene derivatives (A), (B) and (C) depending on an arrangement and a desired property of an organic EL device in which the anthracene derivative is to be used.

### Anthracene Derivative (A)

In the anthracene derivative (A), Ar¹¹ and Ar¹² in the formula (20) are substituted or unsubstituted fused ring groups having 10 to 30 ring atoms. In the anthracene derivative (A), the substituted or unsubstituted fused ring groups for Ar¹¹ and Ar¹² may be mutually the same or different. When Ar¹¹ and Ar¹² are different from each other, the substitution sites may be different.

The anthracene derivative (A) is particularly preferably an anthracene derivative in which Ar¹¹ and Ar¹² in the formula (20) are different substituted or unsubstituted fused ring groups from each other.

When the anthracene derivative of the formula (20) is the anthracene derivative (A), specific preferable examples of the fused ring group for Ar¹¹ and Ar¹² in the formula (20) are the same as ones listed above. Among the examples, a naphthyl group, phenanthryl group, benzanthryl group, 9,9-dimethylfluorenyl group and dibenzofuranyl group are preferable. Preferably, for instance, while Ar¹² in the formula (20) is selected from among a naphthyl group, a phenanthryl group, a dibenzofuranyl group and a benzanthryl group, Ar¹¹ is a substituted or unsubstituted fluorenyl group.

### Anthracene Derivative (B)

In the anthracene derivative (B), while one of Ar¹¹ and Ar¹² in the formula (20) is a substituted or unsubstituted monocyclic group having 5 to 30 ring atoms, the other of Ar¹¹ and Ar¹² is a substituted or unsubstituted fused ring group having 10 to 30 ring atoms.

In the anthracene derivative (B), it is preferable that, for instance, Ar¹² is selected from among a naphthyl group, a phenanthryl group, a benzanthryl group, a 9,9-dimethylfluorenyl group and a dibenzofuranyl group while Ar¹¹ is an unsubstituted phenyl group or a phenyl group substituted with at least one of the monocyclic group and the fused ring group. Preferably, for instance, while Ar¹² in the formula (20) is selected from among a naphthyl group, a phenanthryl group, a dibenzofuranyl group and a benzanthryl group, Ar¹¹ is a substituted or unsubstituted phenyl group.

When the anthracene derivative of the formula (20) is the anthracene derivative (B), specific preferable examples of the monocyclic group and the fused ring group are the same as ones listed above.

In the anthracene derivative (B), it is also preferable that, for instance, Ar¹² is a substituted or unsubstituted fused ring group having 10 to 30 ring atoms while Ar¹¹ is an unsubstituted phenyl group. In this case, the fused ring group is particularly preferably a phenanthryl group, a 9,9-dimethylfluorenyl group, a dibenzofuranyl group or a benzanthryl group.

### Anthracene Derivative (C)

In the anthracene derivative (C), Ar¹¹ and Ar¹² in the formula (20) are each independently a substituted or unsubstituted monocyclic group having 5 to 30 ring atoms.

In the anthracene derivative (C), it is preferable that, for instance, Ar¹¹ and Ar¹² are each independently a substituted or unsubstituted phenyl group.

In the anthracene derivative (C), it is further preferable that, for instance, Ar¹¹ is an unsubstituted phenyl group while Ar¹² is a phenyl group having at least one of the monocyclic group and the fused ring group as a substituent, or, alternatively, Ar¹¹ and Ar¹² are each independently a phenyl group having at least one of the monocyclic group and the fused ring group as a substituent.

Specific preferable examples of the monocyclic group and the fused ring group (i.e., substituents) in Ar¹¹ and Ar¹² in the formula (20) are the same as ones listed above. The monocyclic group (i.e., substituent) is further preferably a phenyl group or a biphenyl group and the fused ring group (i.e., substituent) is further preferably a naphthyl group, a phenanthryl group, a 9,9-dimethylfluorenyl group, dibenzofuranyl group or a benzanthryl group.

Specific examples of the structure of the anthracene derivative represented by the formula (20) are shown below. It should be noted that these exemplary structures of the anthracene derivative are not intended to limit the scope of the invention.

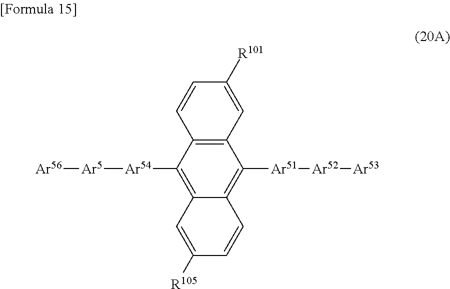

In the formula (20A), R¹⁰¹ and R¹⁰⁵ are each independently a hydrogen atom, a halogen atom, a cyano group, a substituted or unsubstituted monocyclic group having 5 to 30 ring atoms, a substituted or unsubstituted fused ring group having 10 to 30 ring atoms, a group formed by combining the monocyclic group and the fused ring group, a substituted or unsubstituted alkyl group having 1 to 30 carbon atoms, a substituted or unsubstituted cycloalkyl group having 3 to 30 ring carbon atoms, a substituted or unsubstituted alkoxy group having 1 to 30 carbon atoms, a substituted or unsubstituted aralkyl group having 7 to 30 carbon atoms, a substituted or unsubstituted aryloxy group having 6 to 30 ring carbon atoms, or a substituted or unsubstituted silyl group.

In the formula (20A), Ar⁵¹ and Ar⁵⁴ are each independently a substituted or unsubstituted monocyclic divalent residue having 5 to 30 ring atoms or a substituted or unsubstituted fused-cyclic divalent residue having 10 to 30 ring atoms.

In the formula (20A), Ar⁵² and Ar⁵⁵ are each independently a single bond, a substituted or unsubstituted monocyclic divalent residue having 5 to 30 ring atoms or a substituted or unsubstituted fused-cyclic divalent residue having 10 to 30 ring atoms.

In the formula (20A), Ar⁵³ and Ar⁵⁶ are each independently a hydrogen atom, a substituted or unsubstituted monocyclic group having 5 to 30 ring atoms or a substituted or unsubstituted fused ring group having 10 to 30 ring atoms.

In the formula (20A), all or a part of the hydrogen atoms may be deuterium atoms.

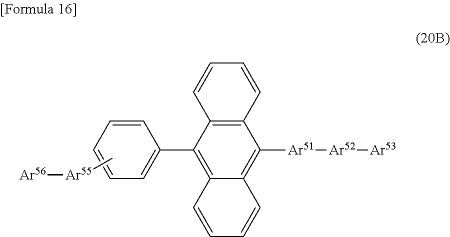

In the formula (20B), Ar⁵¹ is a substituted or unsubstituted monocyclic divalent residue having 5 to 30 ring atoms or a substituted or unsubstituted fused-cyclic divalent residue having 10 to 30 ring atoms.

In the formula (20B), Ar⁵² and Ar⁵⁵ are each independently a single bond, a substituted or unsubstituted monocyclic divalent residue having 5 to 30 ring atoms or a substituted or unsubstituted fused-cyclic divalent residue having 10 to 30 ring atoms.

In the formula (20B), Ar⁵³ and Ar⁵⁶ are each independently a hydrogen atom, a substituted or unsubstituted monocyclic group having 5 to 30 ring atoms or a substituted or unsubstituted fused ring group having 10 to 30 ring atoms.

In the formula (20B), all or a part of the hydrogen atoms may be deuterium atoms.

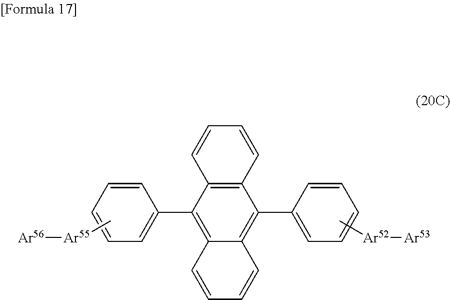

In the formula (20C), Ar⁵² is a substituted or unsubstituted monocyclic divalent residue having 5 to 30 ring atoms or a substituted or unsubstituted fused-cyclic divalent residue having 10 to 30 ring atoms.

In the formula (20C), Ar⁵⁵ is a single bond, a substituted or unsubstituted monocyclic divalent residue having 5 to 30 ring atoms or a substituted or unsubstituted fused-cyclic divalent residue having 10 to 30 ring atoms.

In the formula (20C), Ar⁵³ and Ar⁵⁶ are each independently a hydrogen atom, a substituted or unsubstituted monocyclic group having 5 to 30 ring atoms or a substituted or unsubstituted fused ring group having 10 to 30 ring atoms.

In the formula (20C), all or a part of the hydrogen atoms may be deuterium atoms.

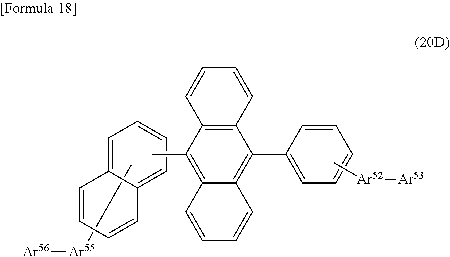

In the formula (20D), Ar⁵² is a substituted or unsubstituted monocyclic divalent residue having 5 to 30 ring atoms or a substituted or unsubstituted fused-cyclic divalent residue having 10 to 30 ring atoms.

In the formula (20D), Ar⁵⁵ is a single bond, a substituted or unsubstituted monocyclic divalent residue having 5 to 30 ring atoms or a substituted or unsubstituted fused-cyclic divalent residue having 10 to 30 ring atoms.

In the formula (20D), Ar⁵³ and Ar⁵⁶ are each independently a hydrogen atom, a substituted or unsubstituted monocyclic group having 5 to 30 ring atoms or a substituted or unsubstituted fused ring group having 10 to 30 ring atoms.

In the formula (20D), all or a part of the hydrogen atoms may be deuterium atoms.

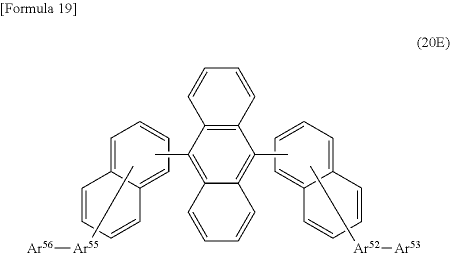

In the formula (20E), Ar⁵² and Ar⁵⁵ are each independently a single bond, a substituted or unsubstituted monocyclic divalent residue having 5 to 30 ring atoms or a substituted or unsubstituted fused-cyclic divalent residue having 10 to 30 ring atoms.

In the formula (20E), Ar⁵³ and Ar⁵⁶ are each independently a hydrogen atom, a substituted or unsubstituted monocyclic group having 5 to 30 ring atoms or a substituted or unsubstituted fused ring group having 10 to 30 ring atoms.

In the formula (20E), all or a part of the hydrogen atoms may be deuterium atoms.

More specific exemplary structures are shown below. It should be noted that these exemplary structures of the anthracene derivative are not intended to limit the scope of the invention.

Incidentally, in compounds EM36, EM44, EM77, EM85, EM86 and the like of the following specific structures of the anthracene derivative, a line extending from the 9-position of a fluorene ring stands for a methyl group, which means that this fluorene ring is a 9,9-dimethylfluorene ring.

In compounds EM151, EM154, EM157, EM161, EM163, EM166, EM169, EM173 and the like of the following specific structures of the anthracene derivative, a cross-shaped line extending outwardly from a ring structure stands for a tertiary butyl group.

In compounds EM152, EM155, EM158, EM164, EM167, EM170, EM171, EM180, EM181, EM182, EM183, EM184, EM185 and the like of the following specific examples of the anthracene derivative, a line extending from a silicon atom (Si) stands for a methyl group, which means that a substituent having this silicon atom is a trimethylsilyl group.

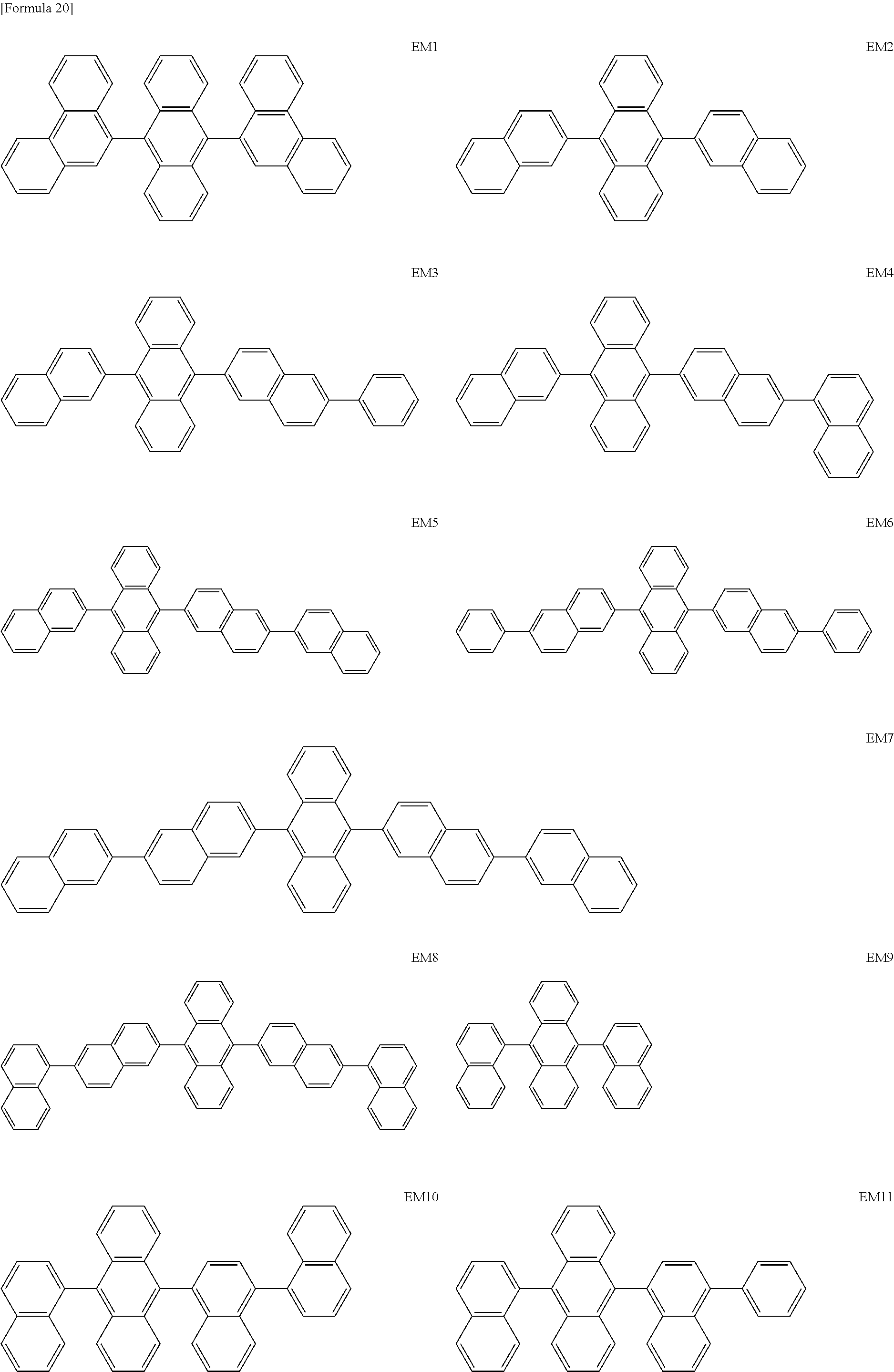

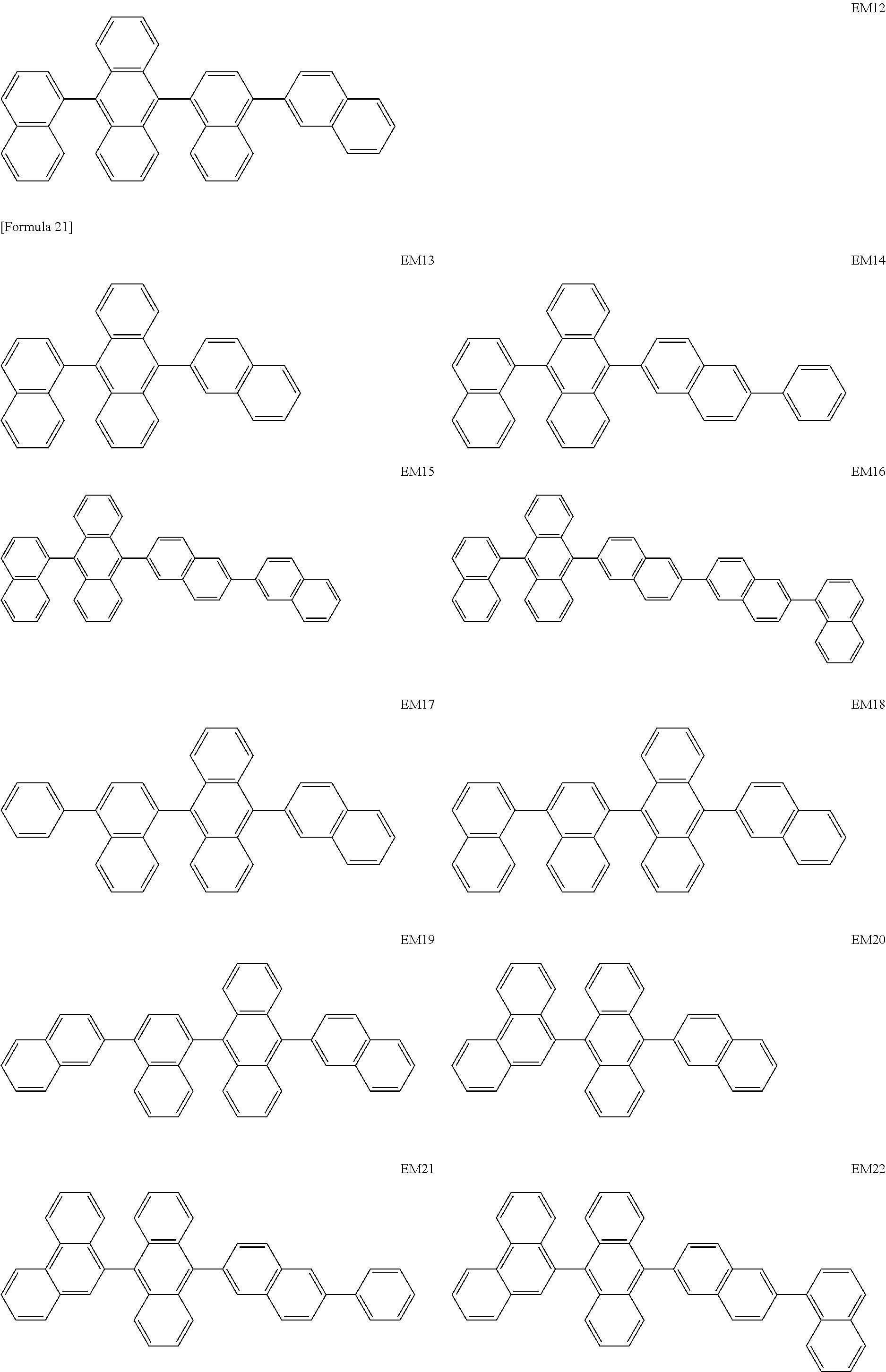

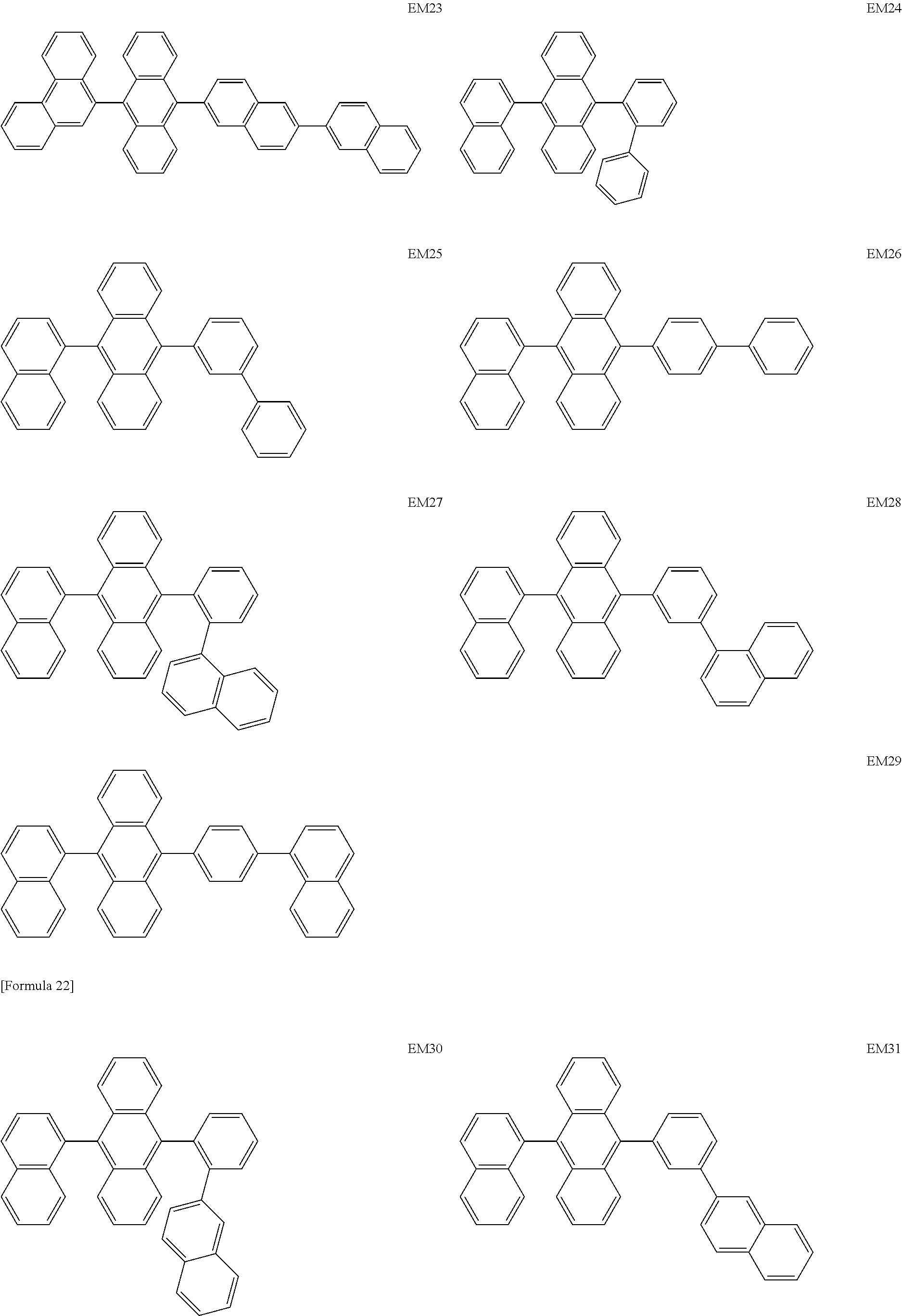

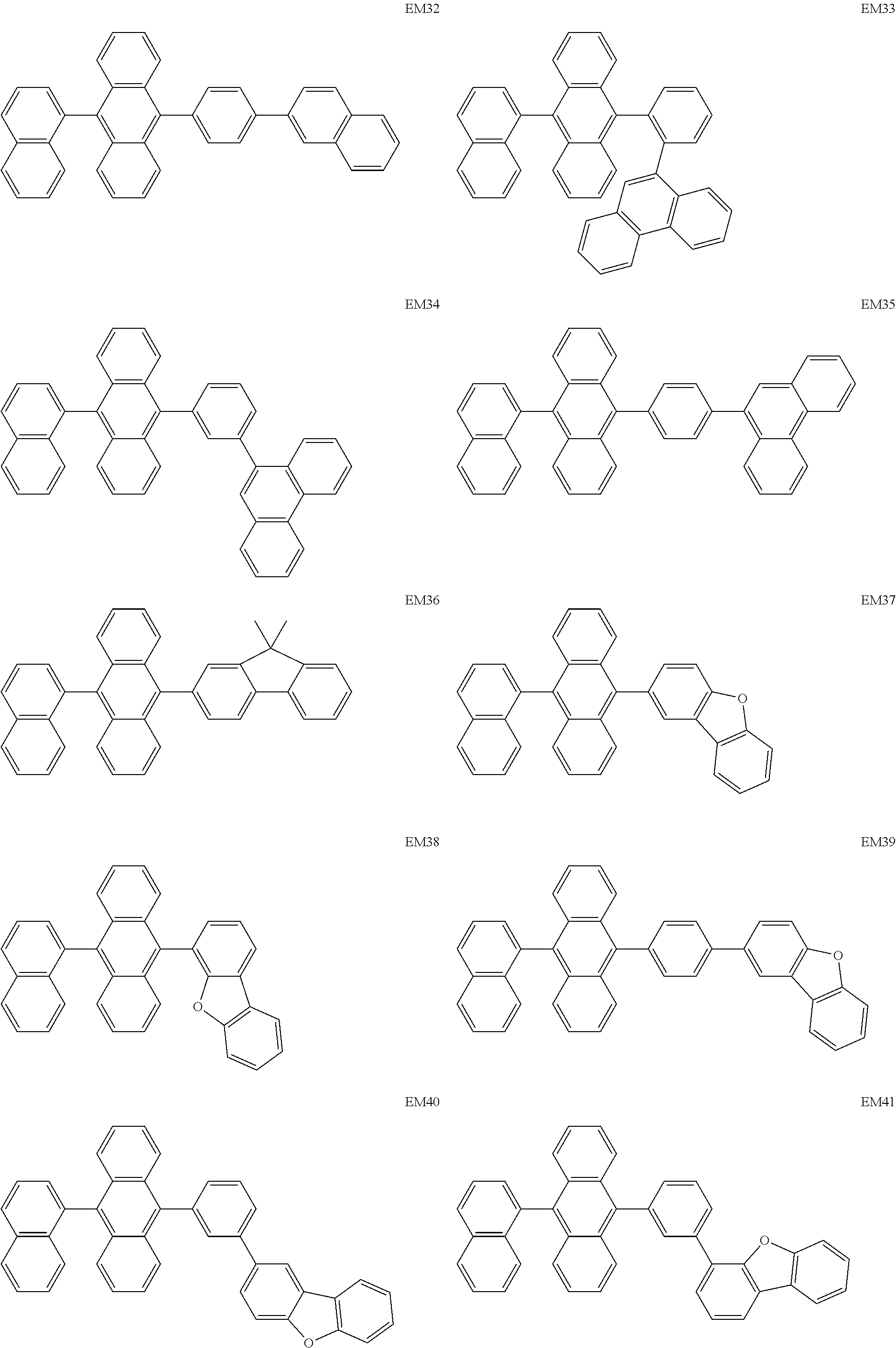

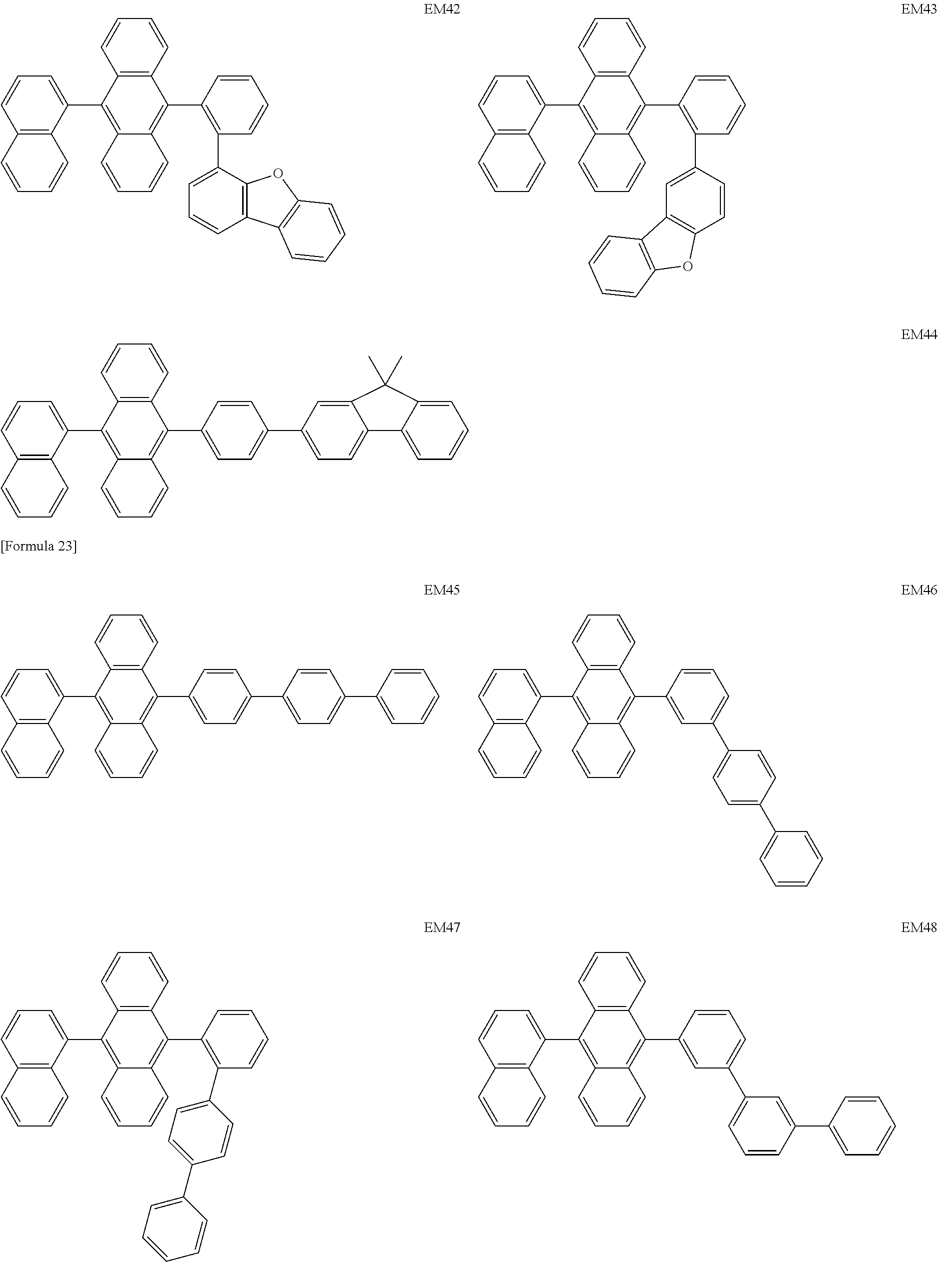

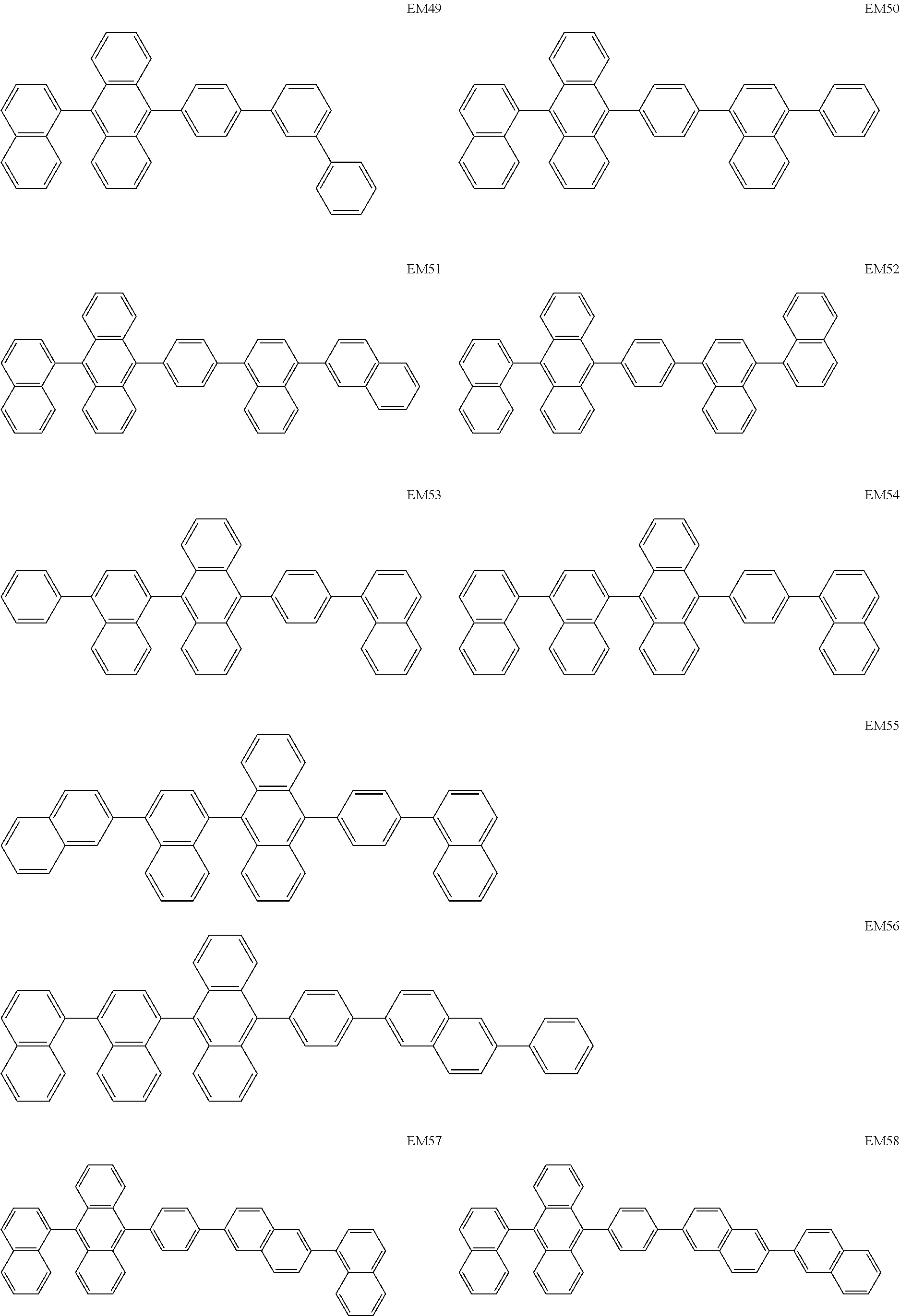

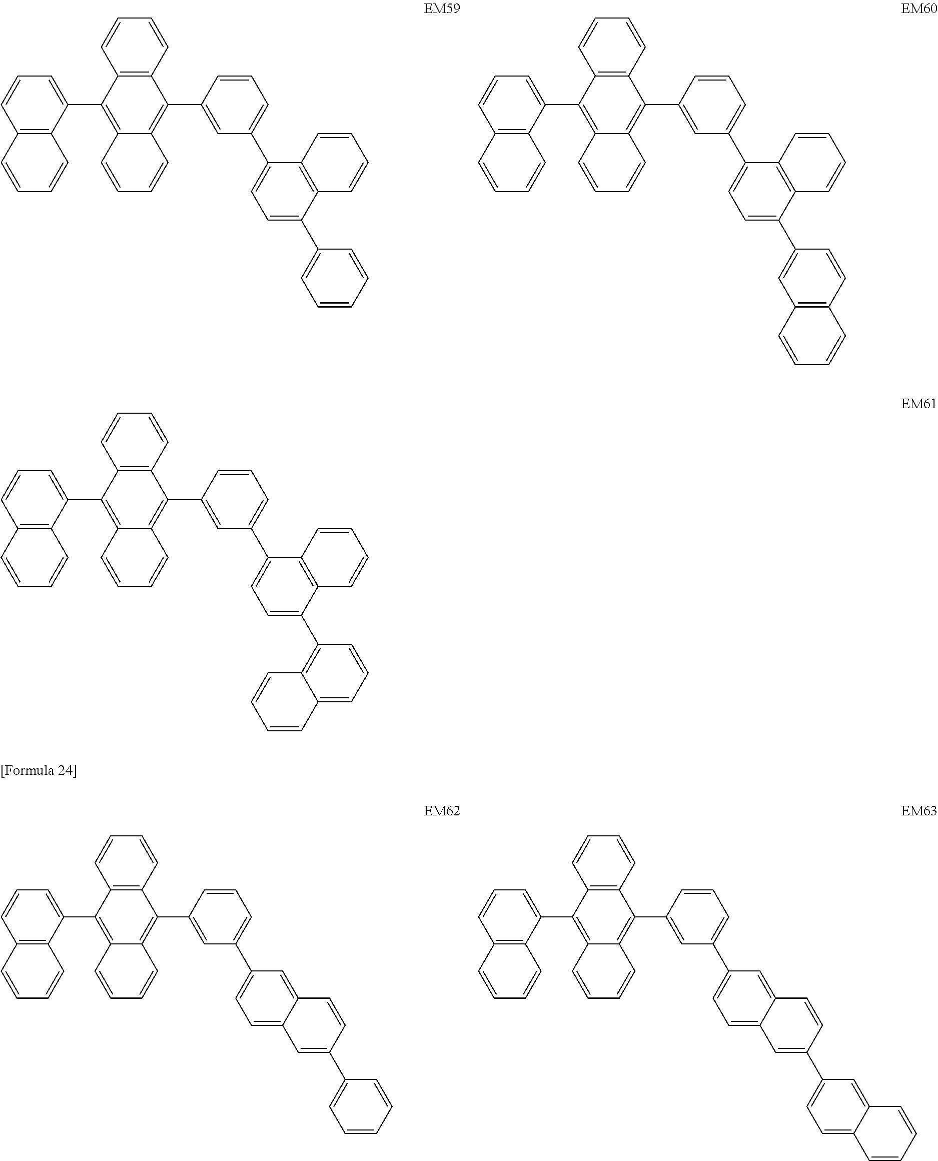

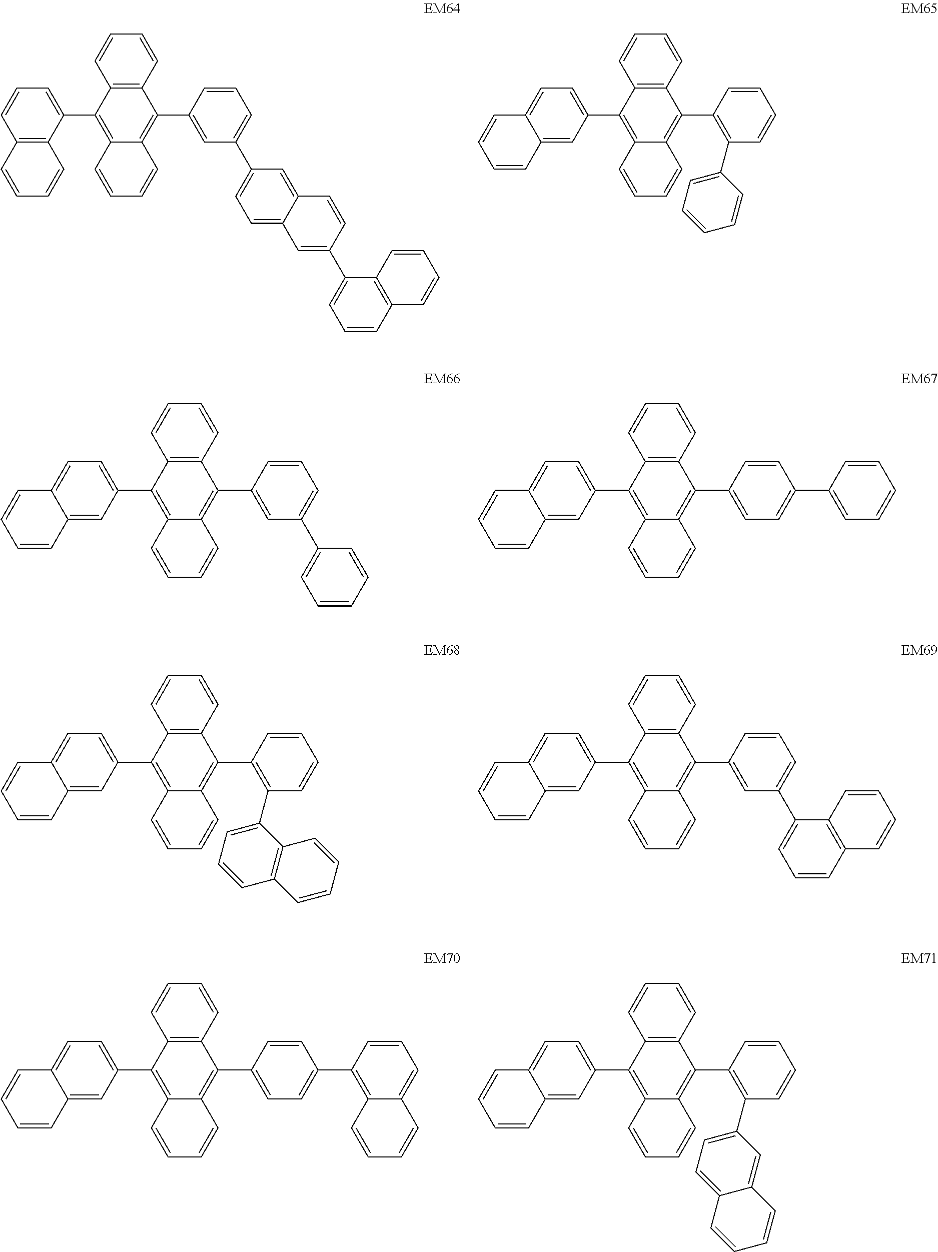

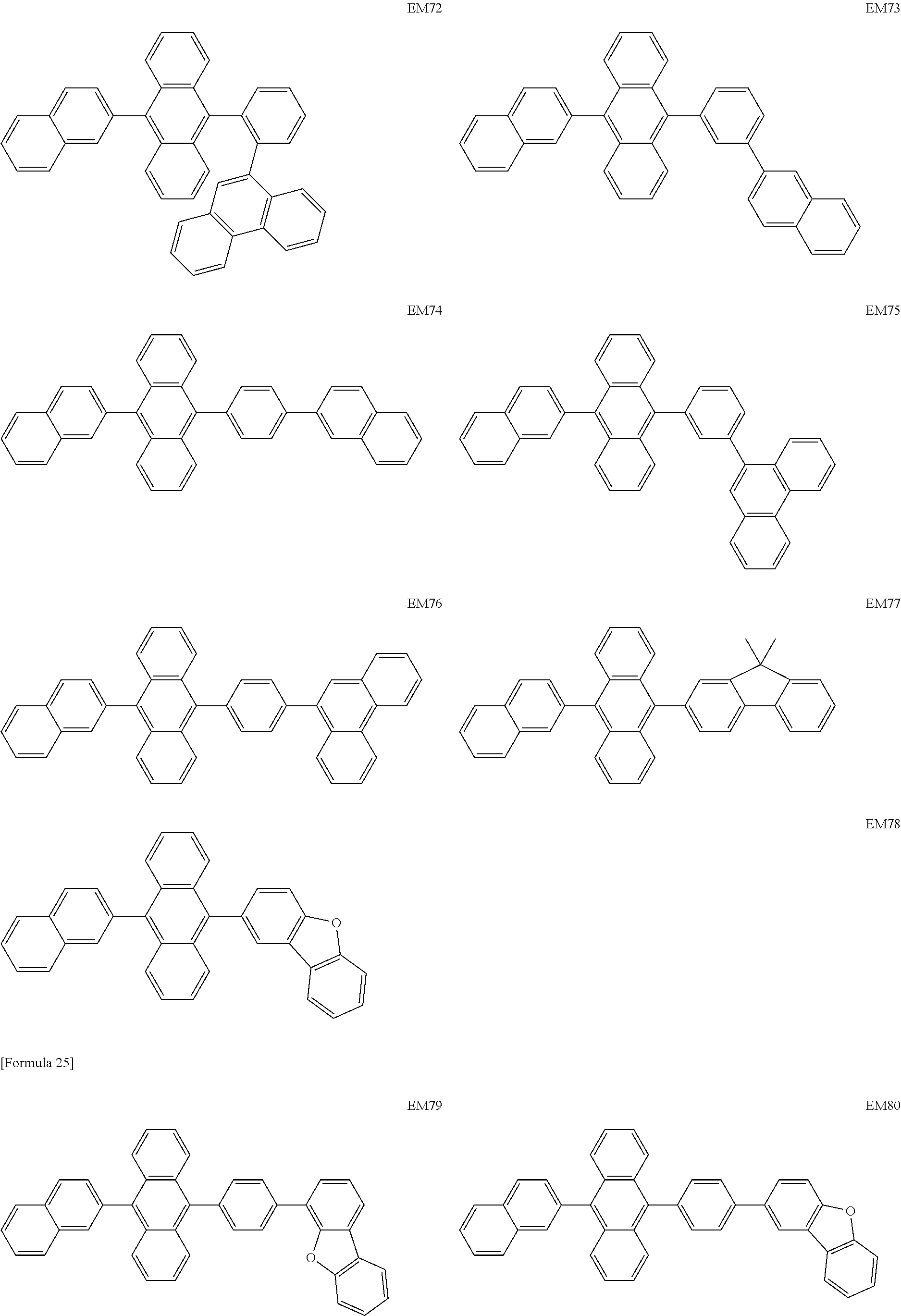

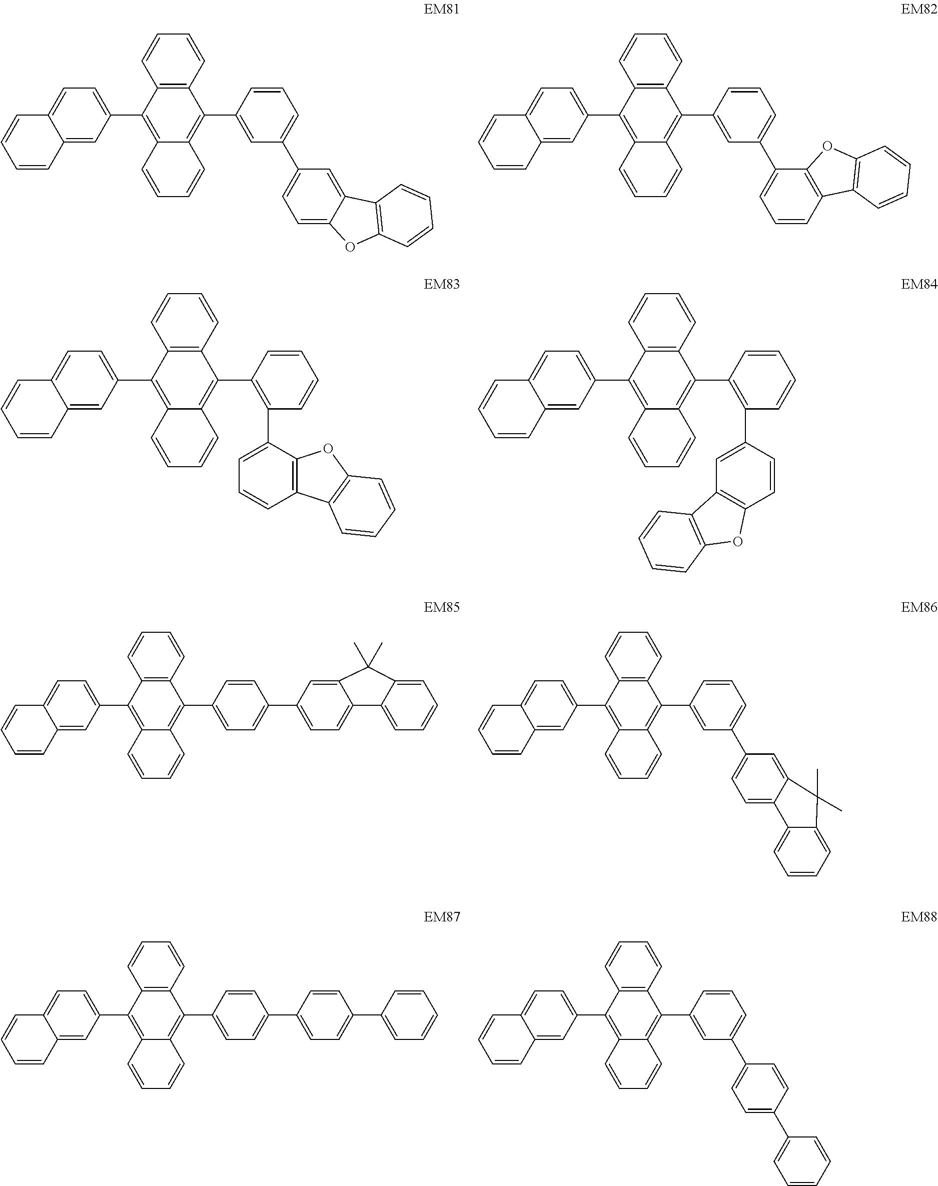

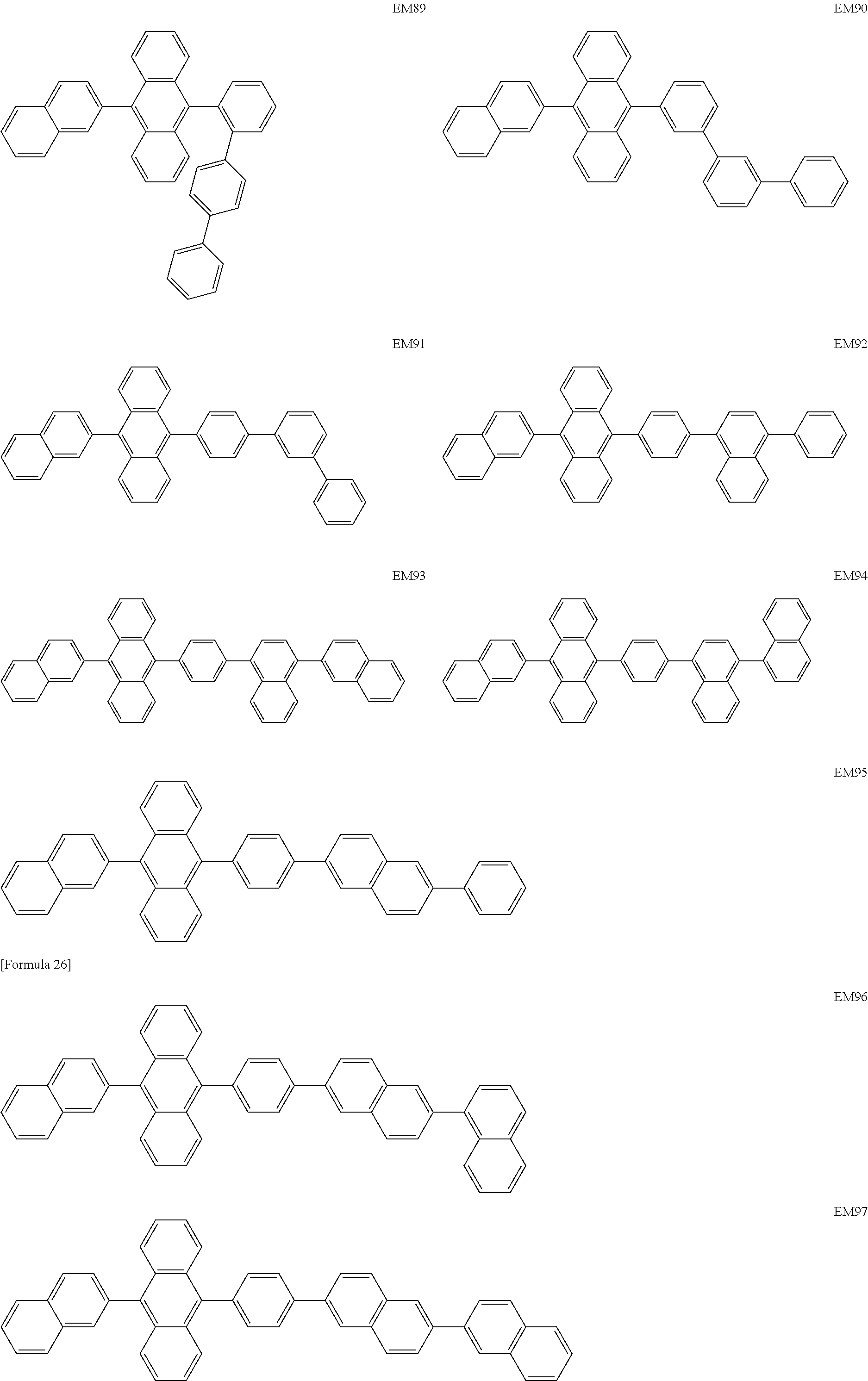

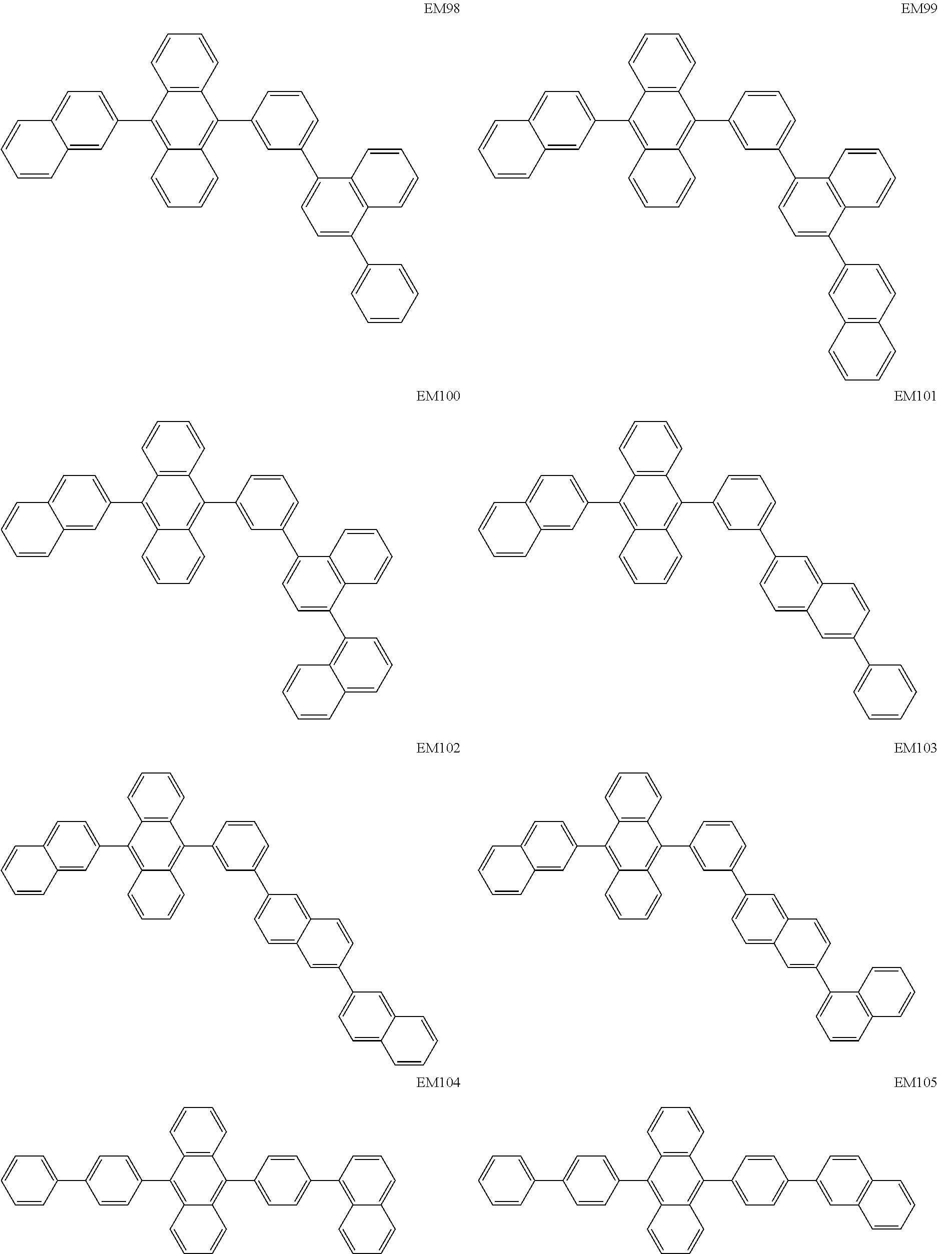

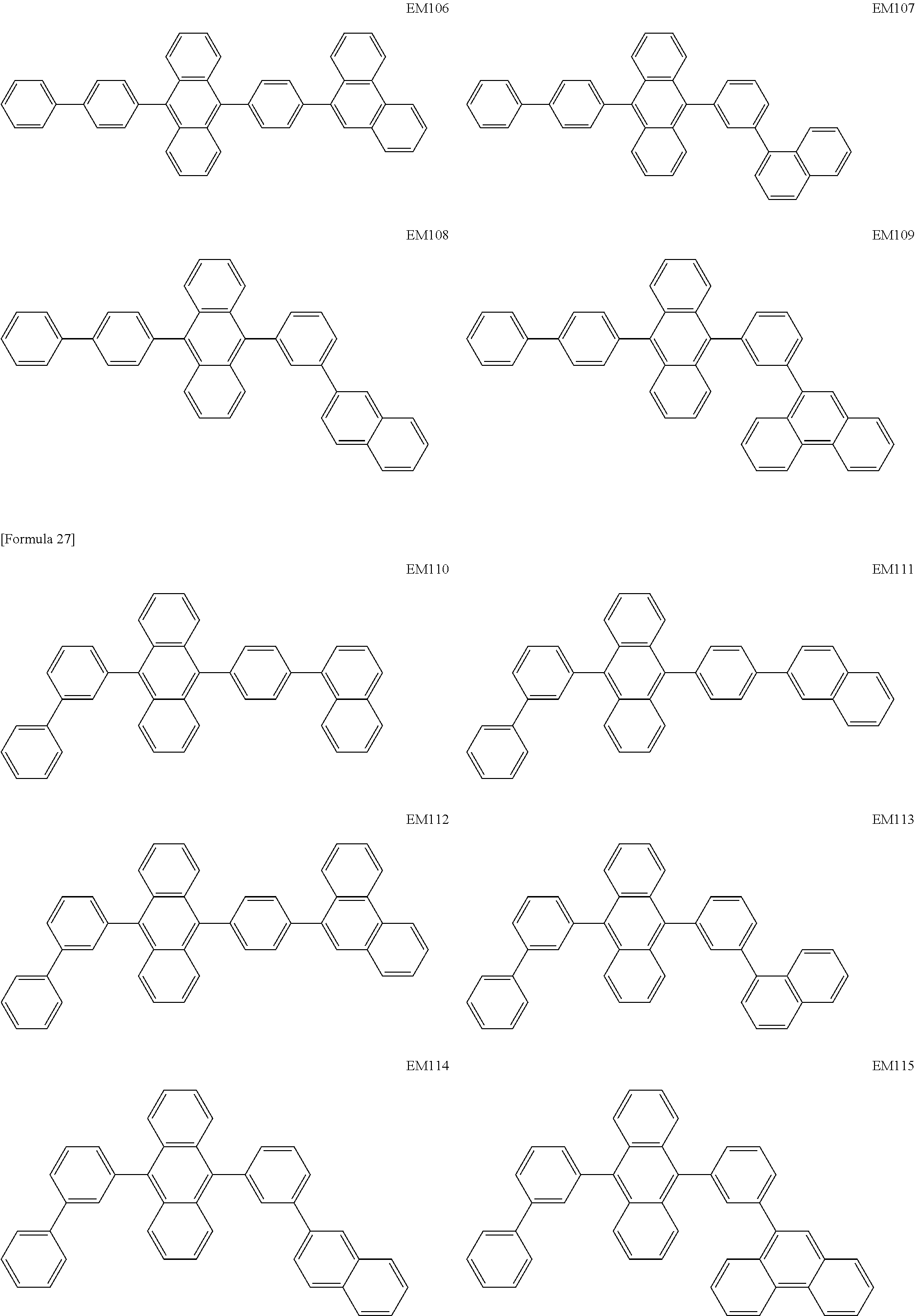

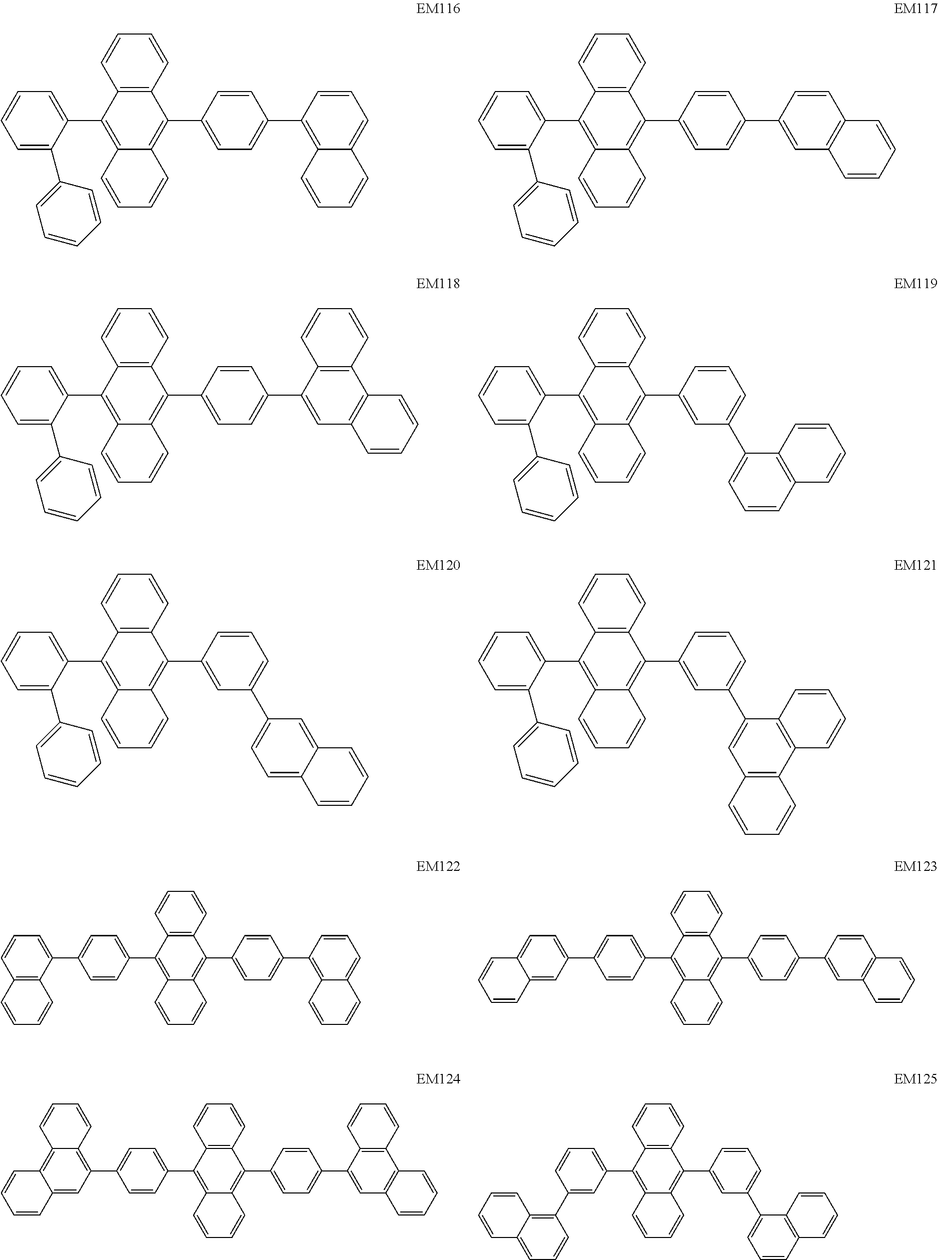

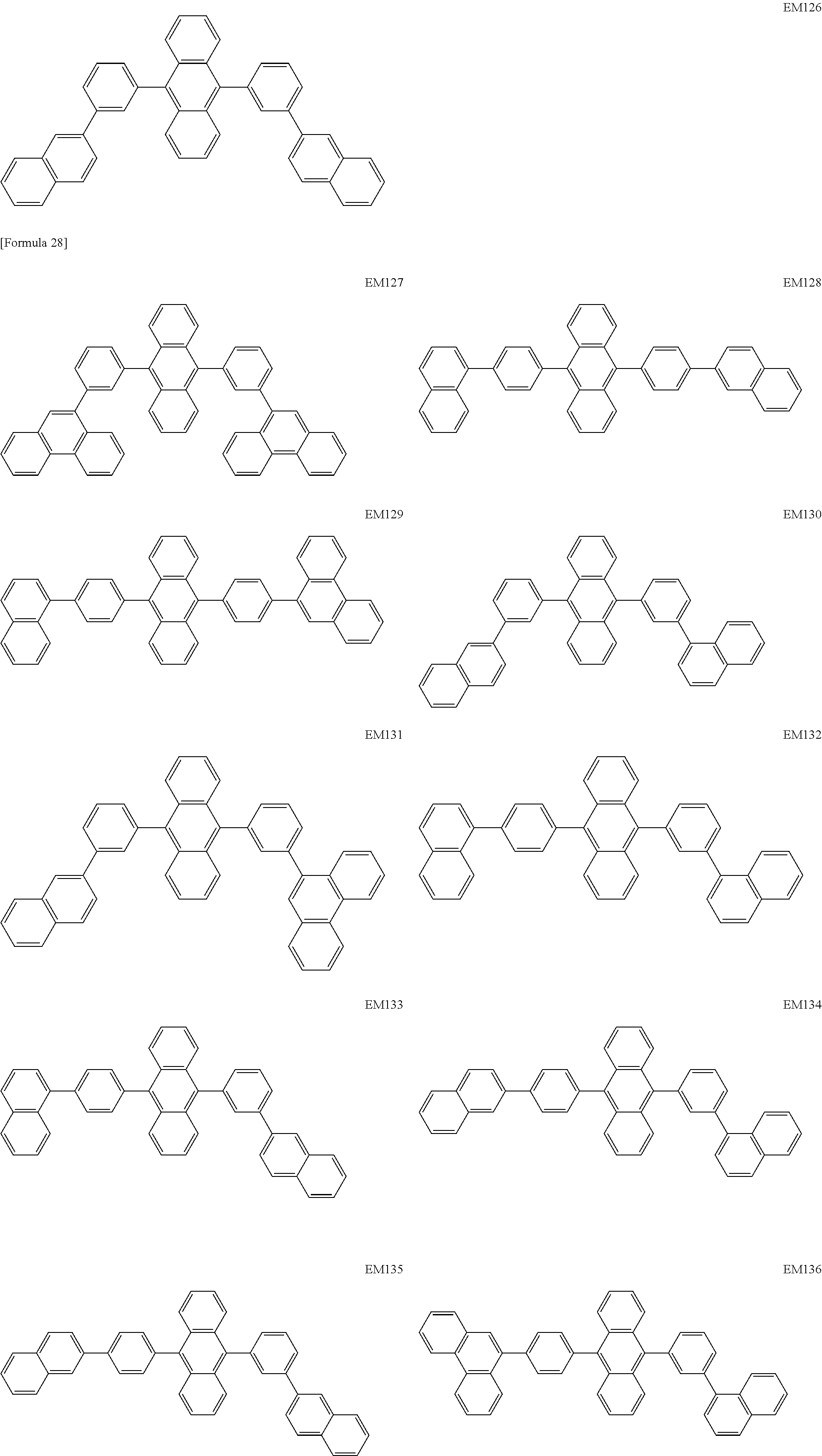

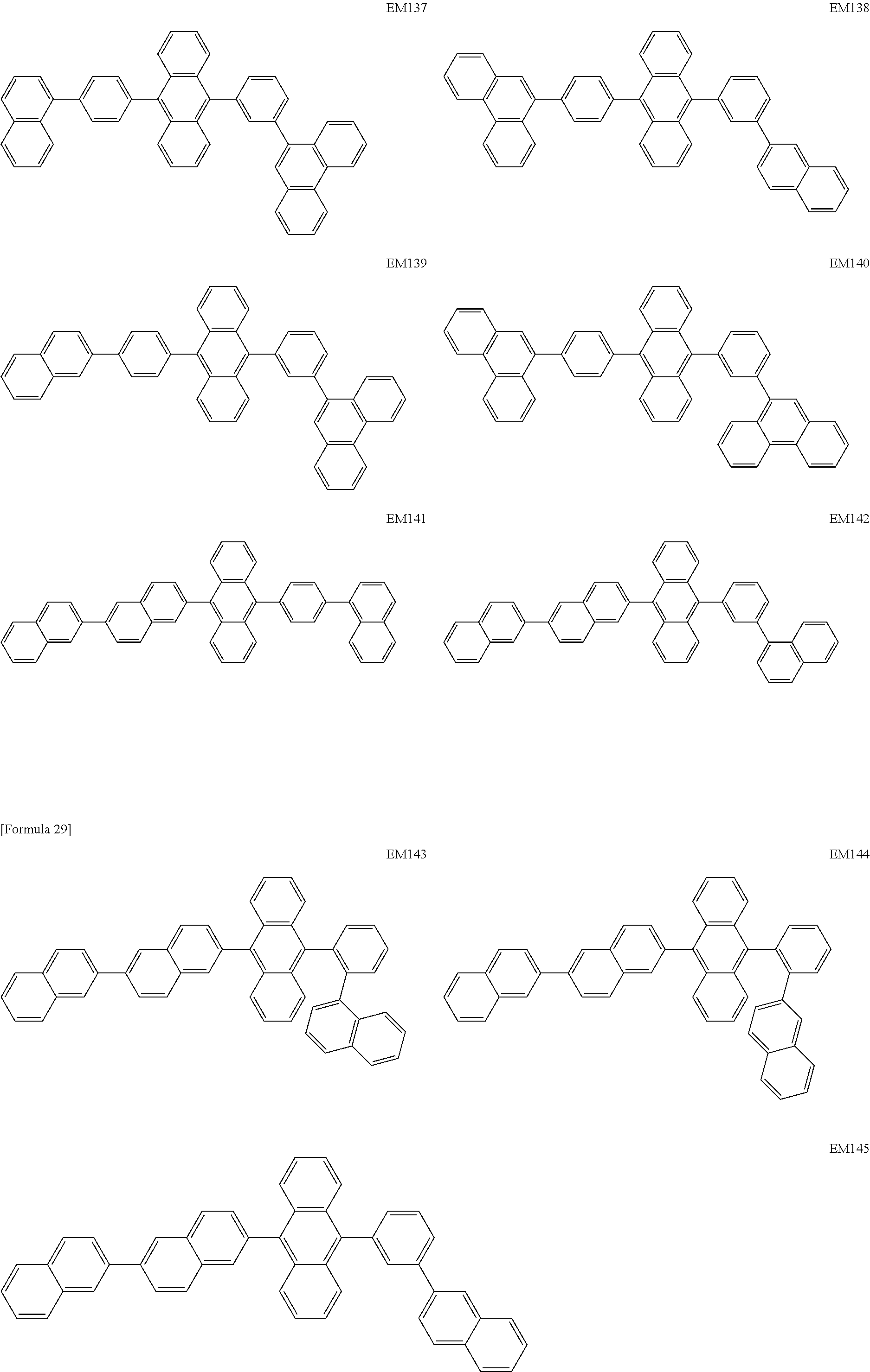

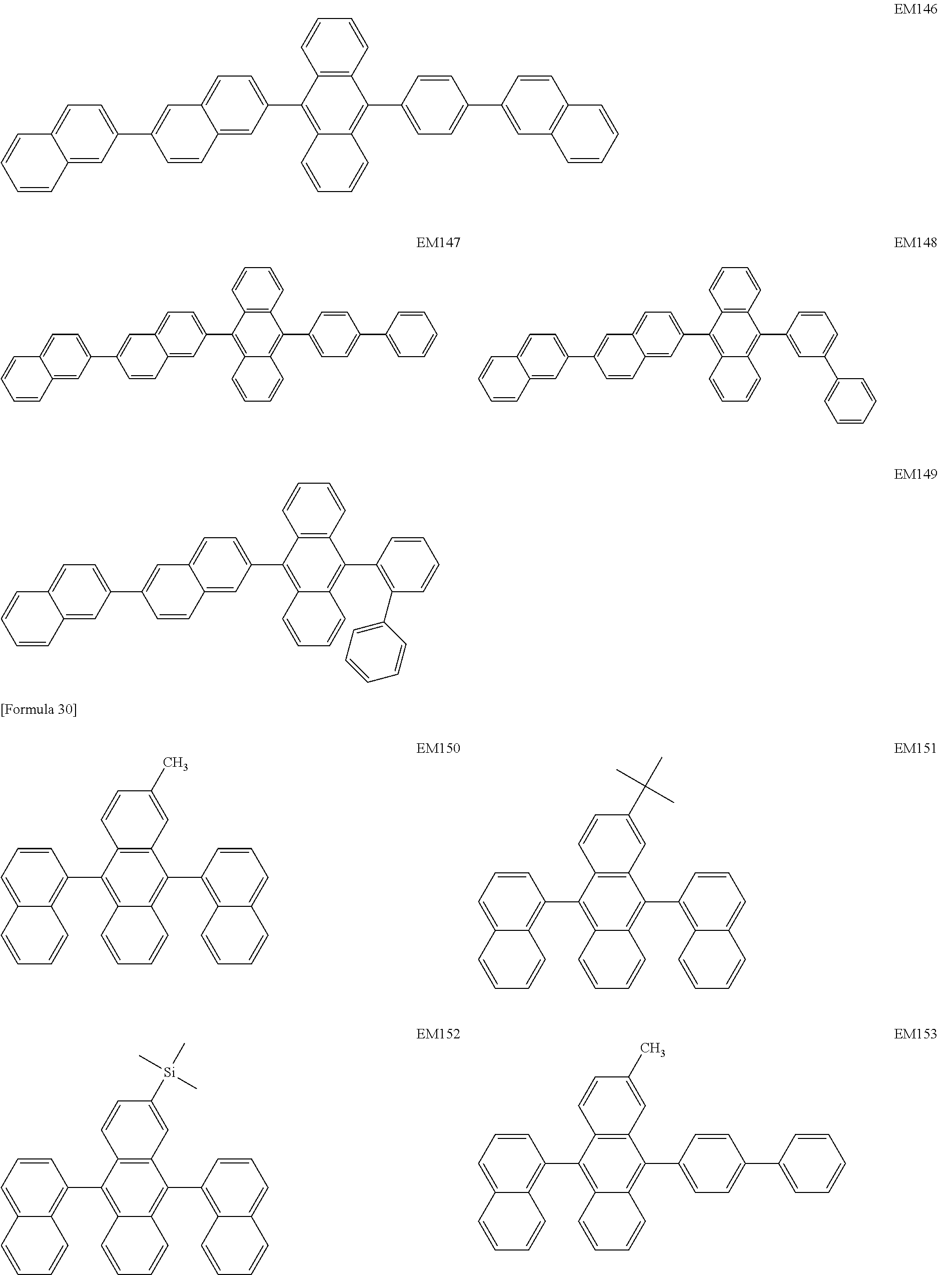

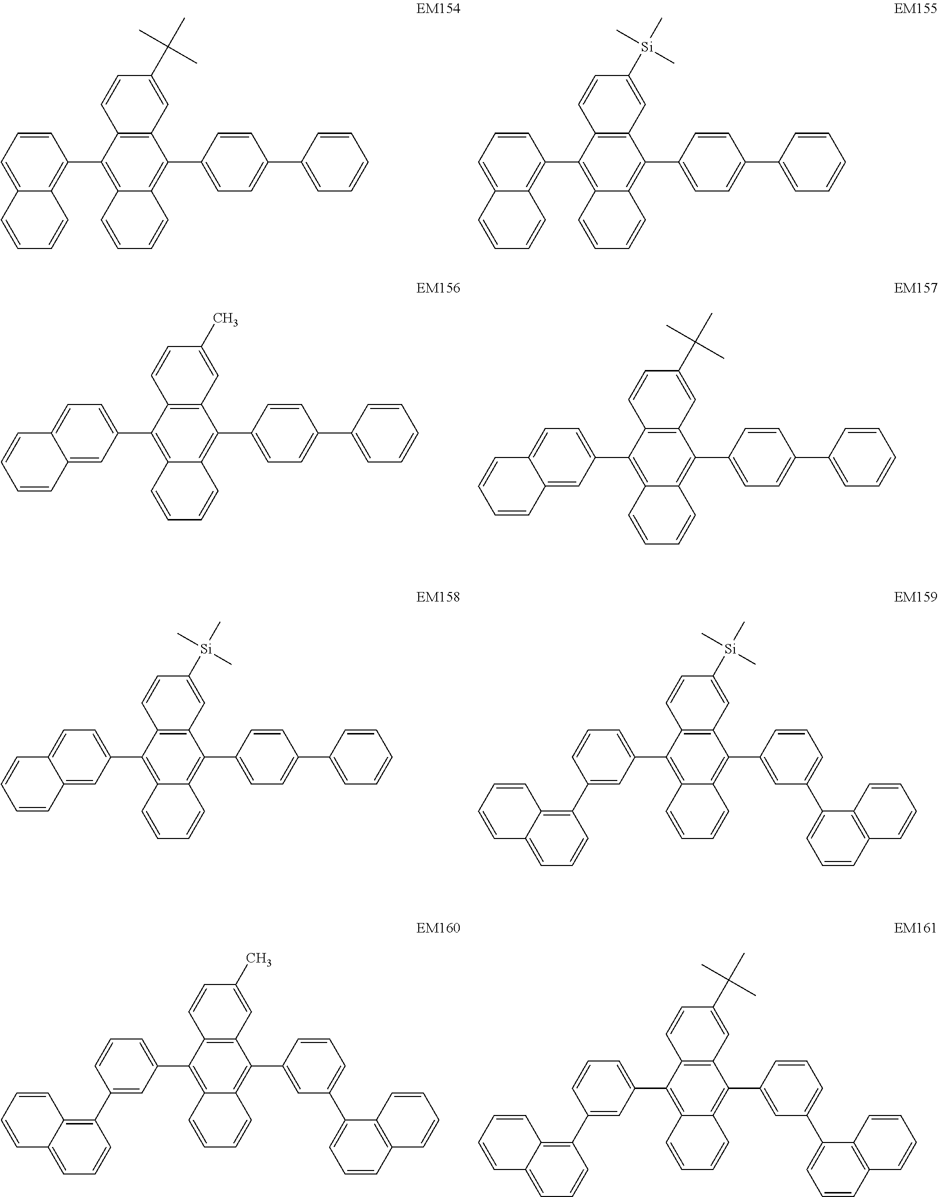

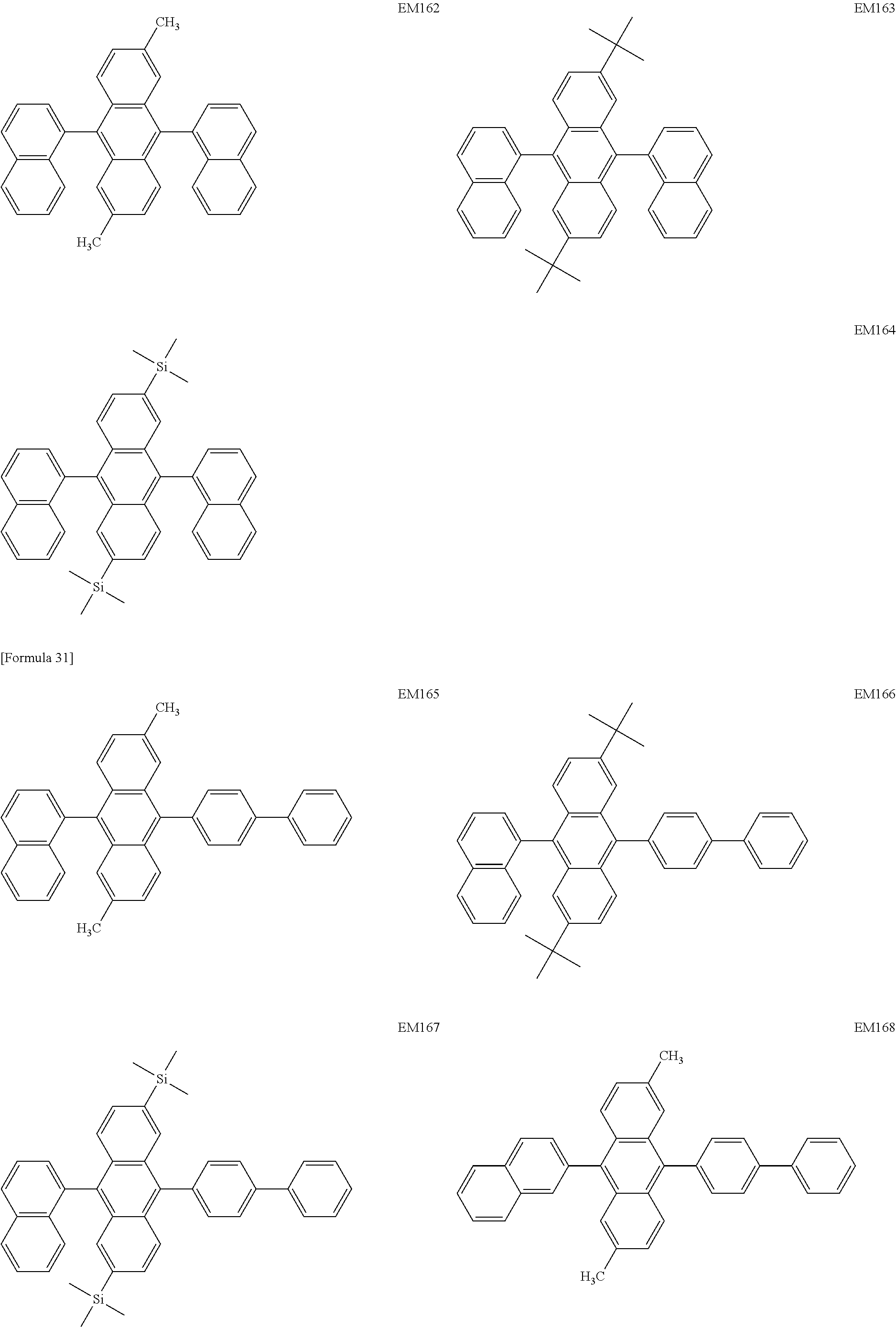

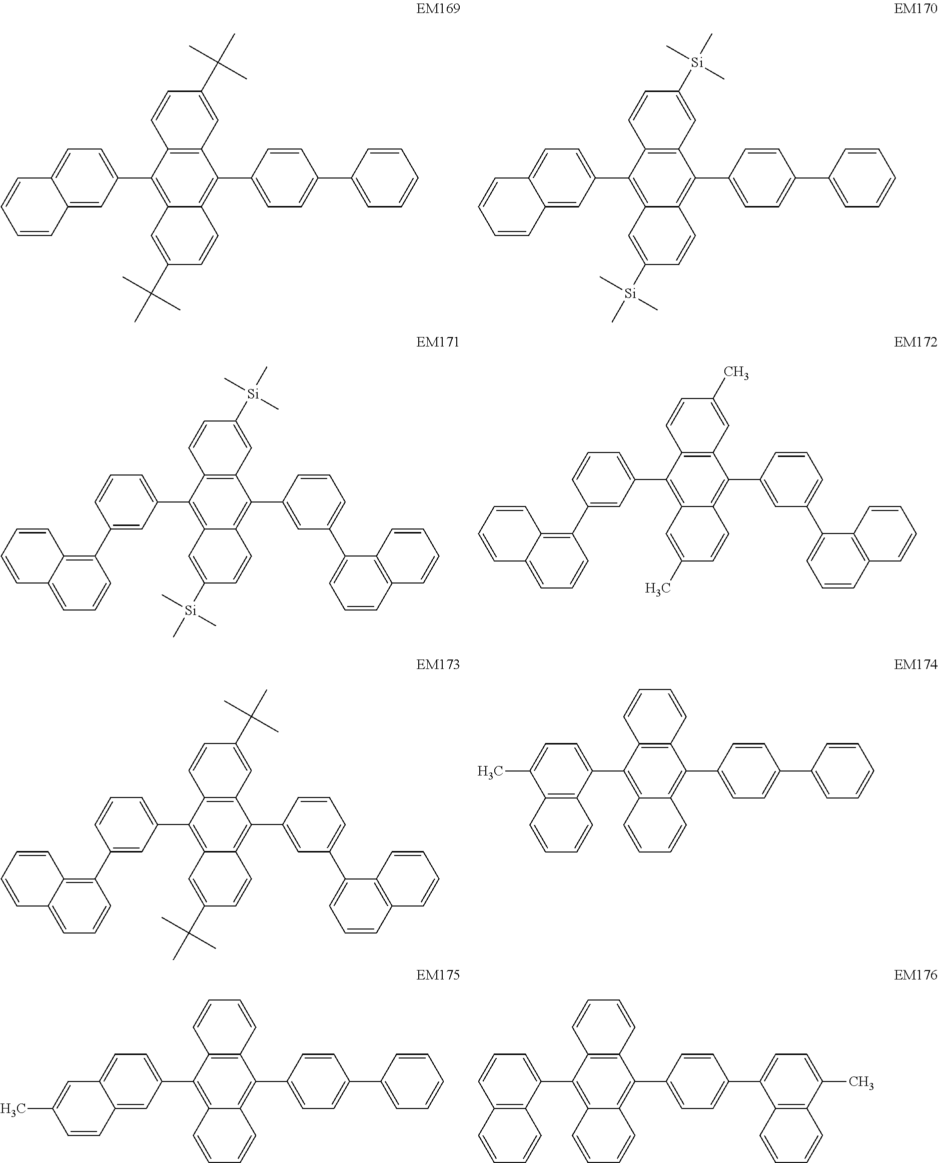

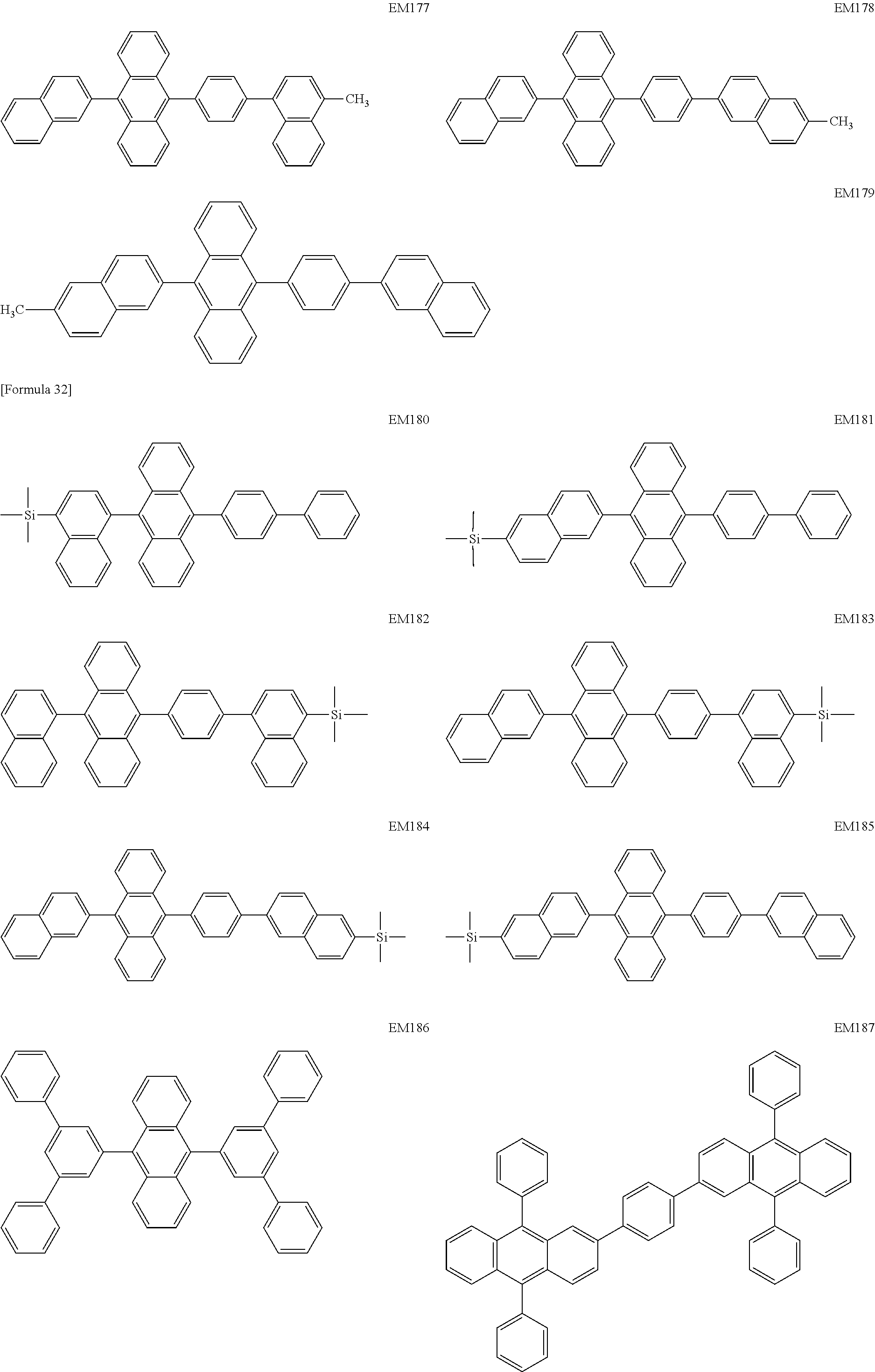

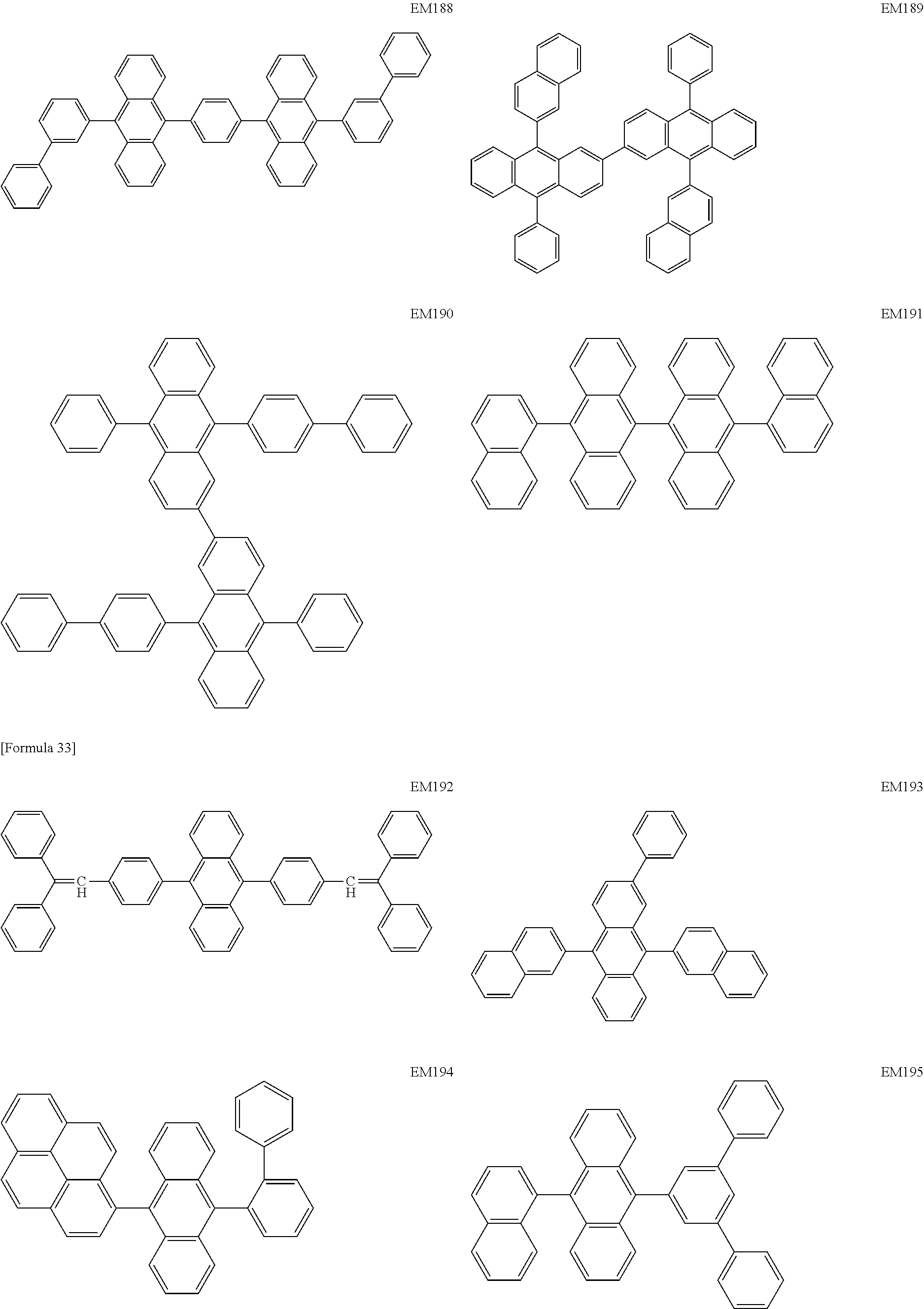

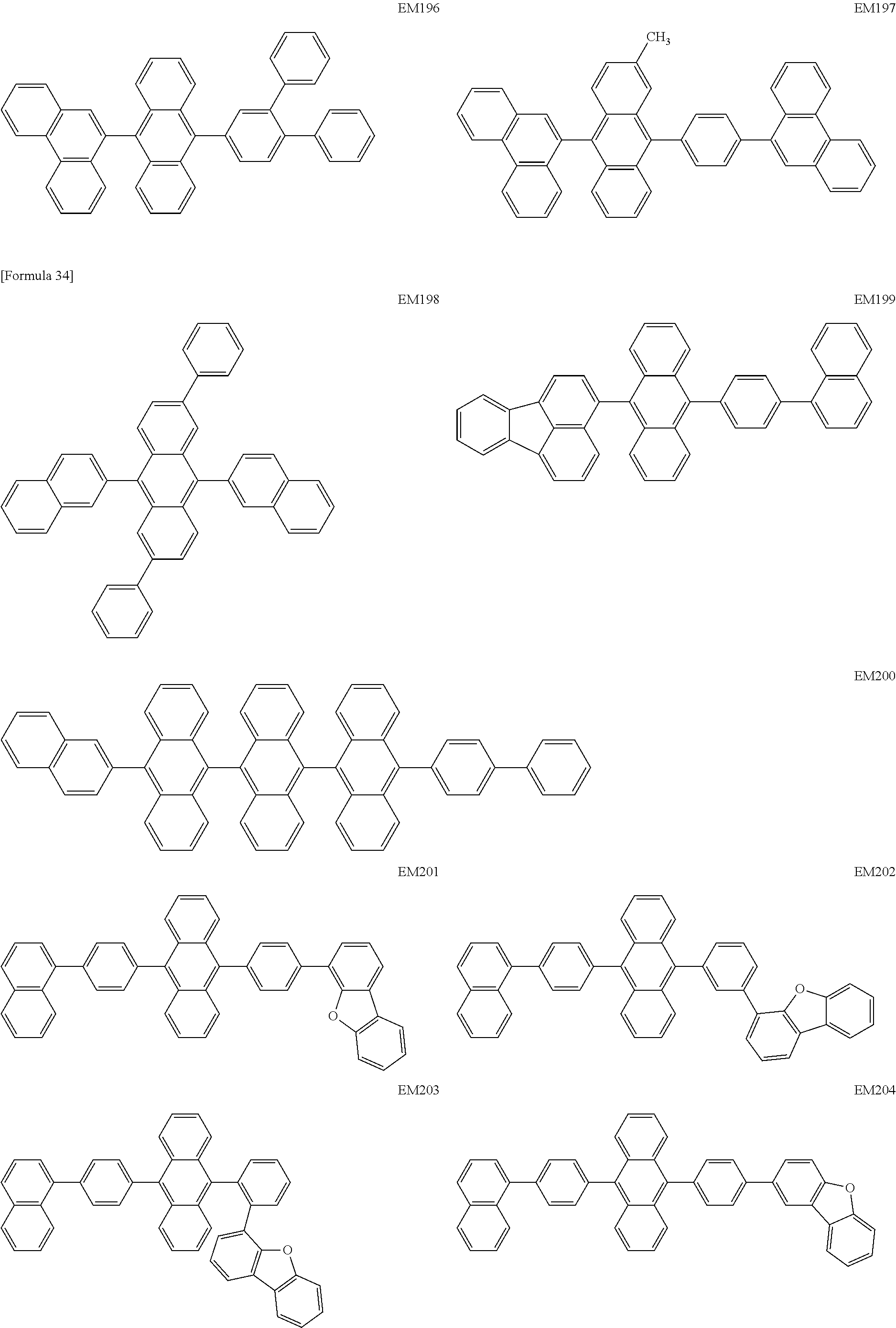

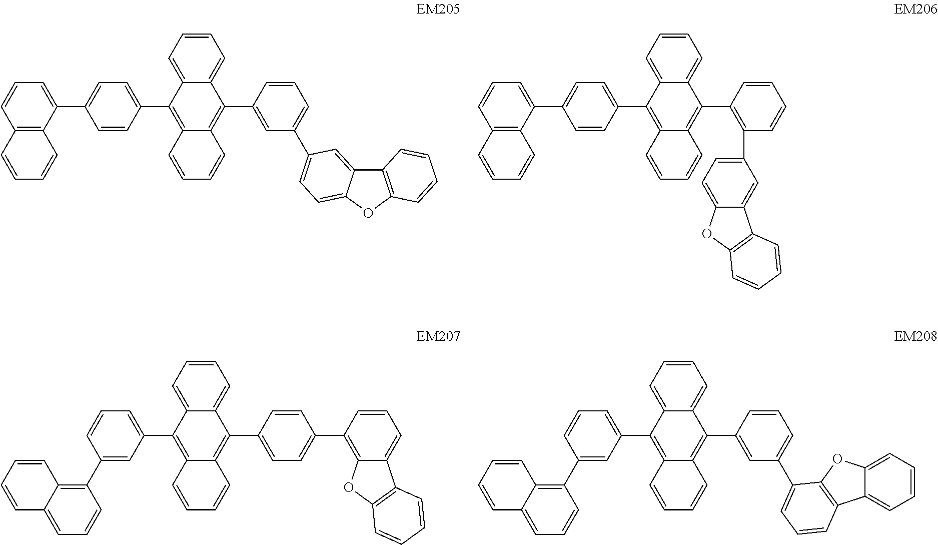 [SMILES: c1cc(-c2ccc3oc4ccccc4c3c2)cc(-c2c3ccccc3c(-c3ccc(-c4cccc5ccccc45)cc3)c3ccccc23)c1 ; c1ccc(-c2c3ccccc3c(-c3ccc(-c4cccc5ccccc45)cc3)c3ccccc23)c(-c2ccc3oc4ccccc4c3c2)c1 ; c1cc(-c2cccc3ccccc23)cc(-c2c3ccccc3c(-c3ccc(-c4cccc5c4oc4ccccc45)cc3)c3ccccc23)c1 ; c1cc(-c2cccc3ccccc23)cc(-c2c3ccccc3c(-c3cccc(-c4cccc5c4oc4ccccc45)c3)c3ccccc23)c1]

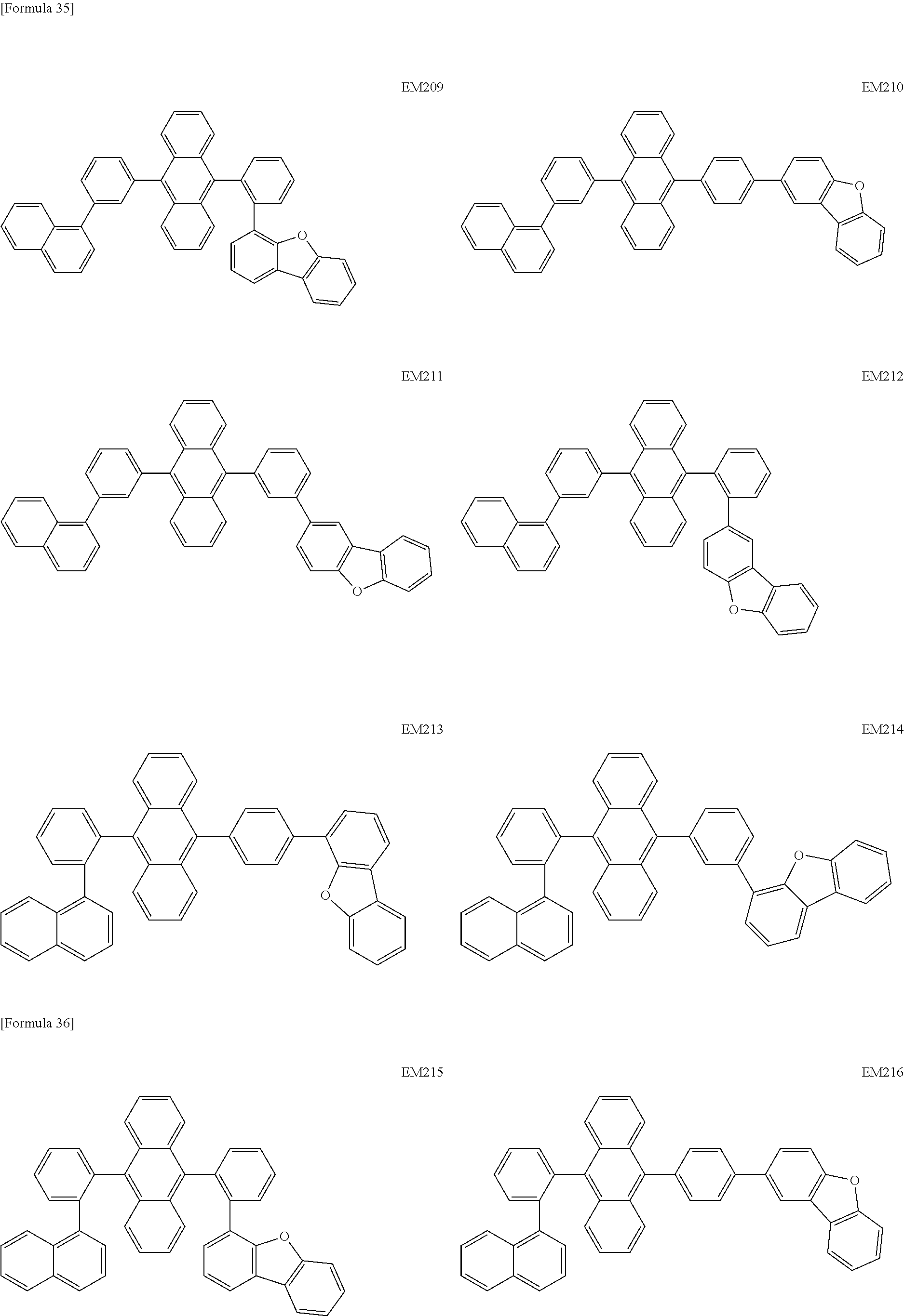

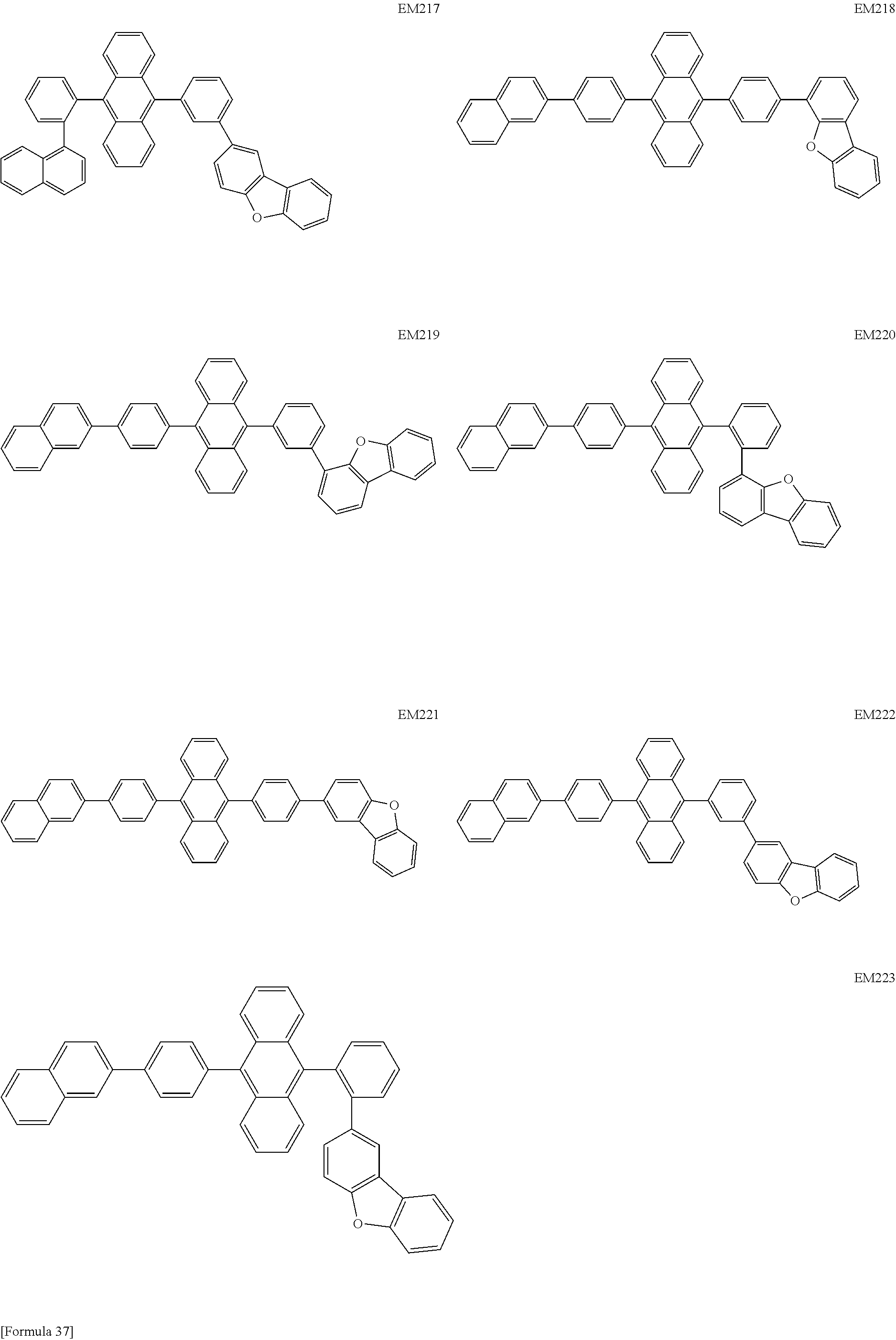

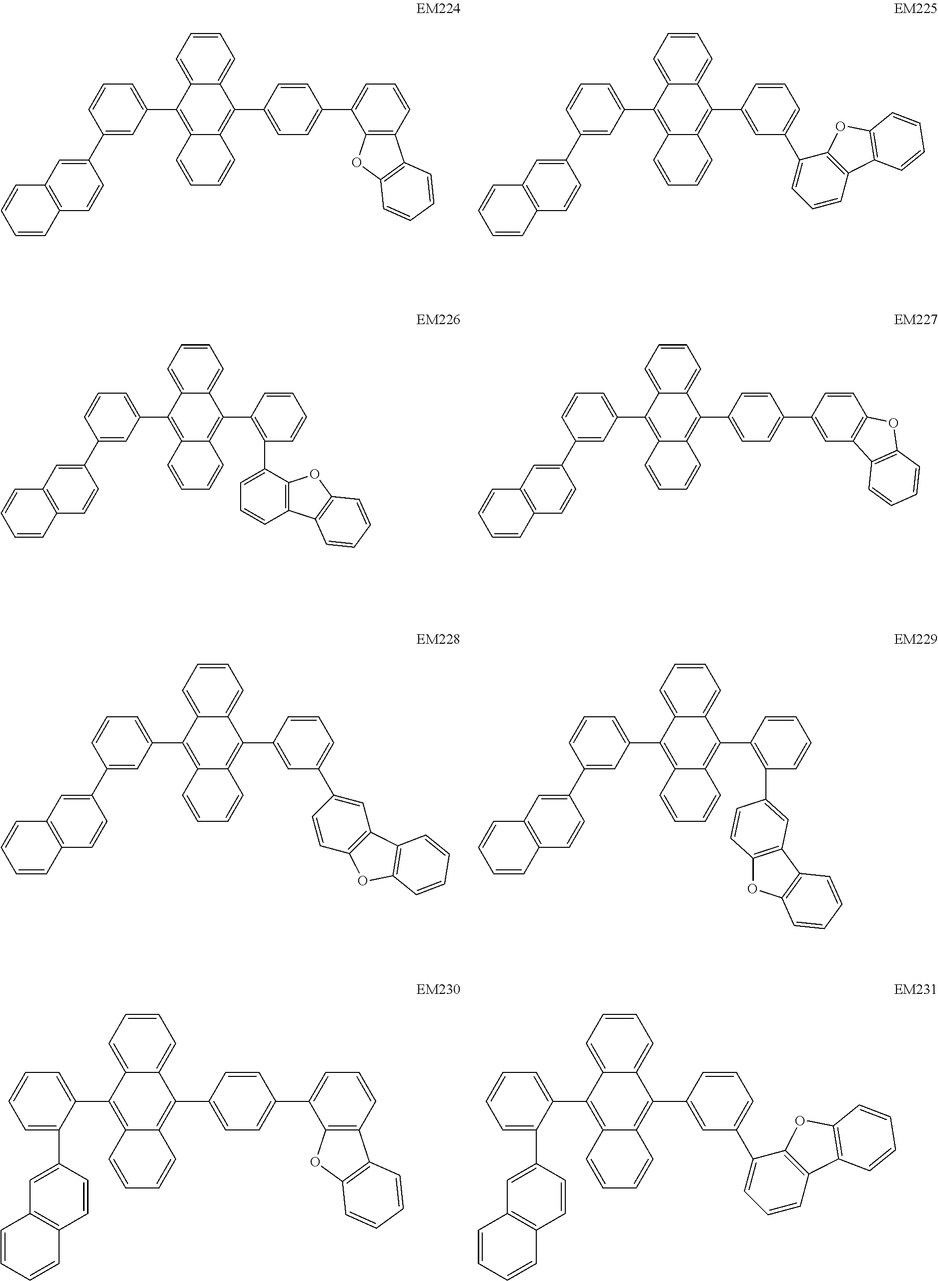

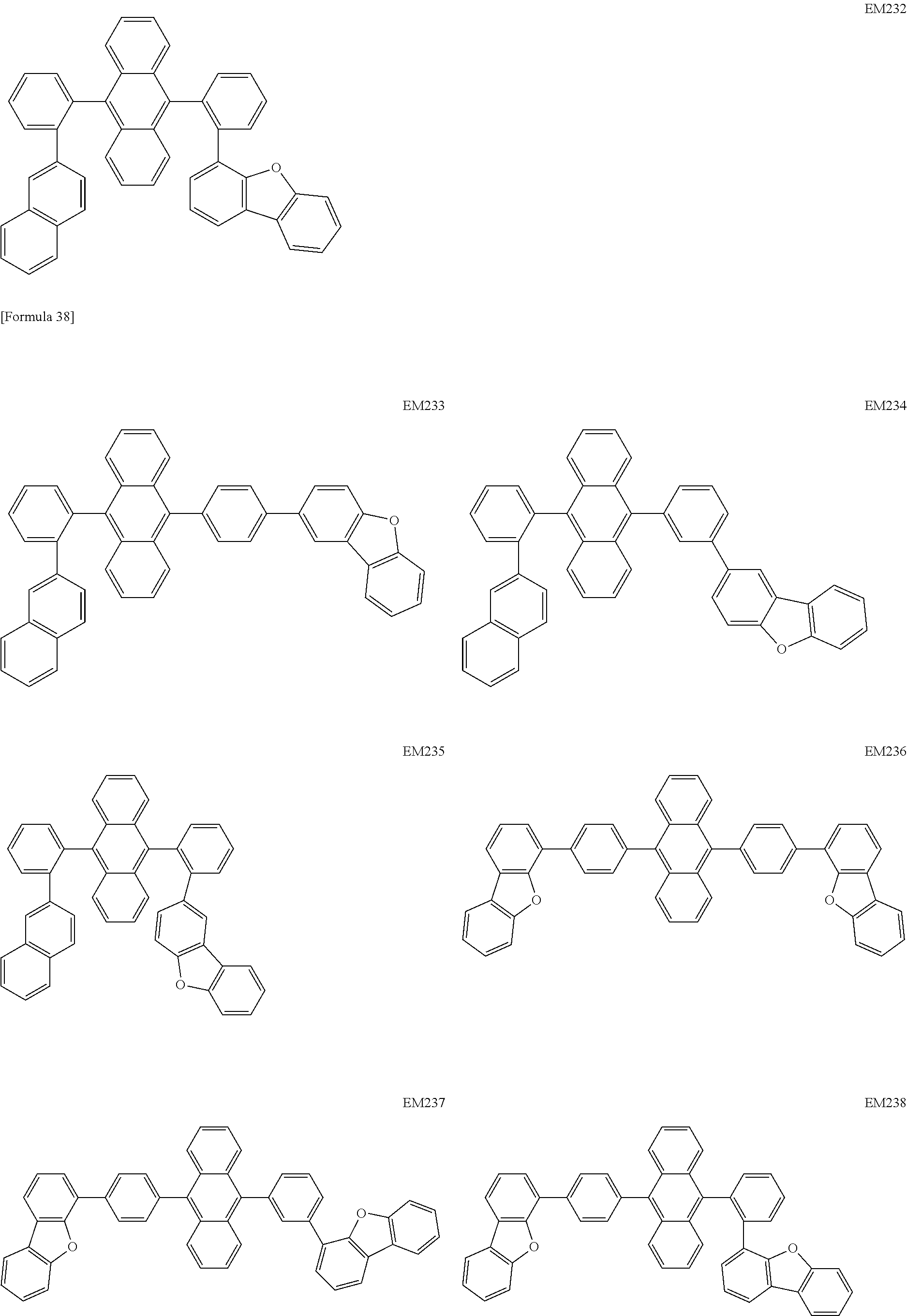

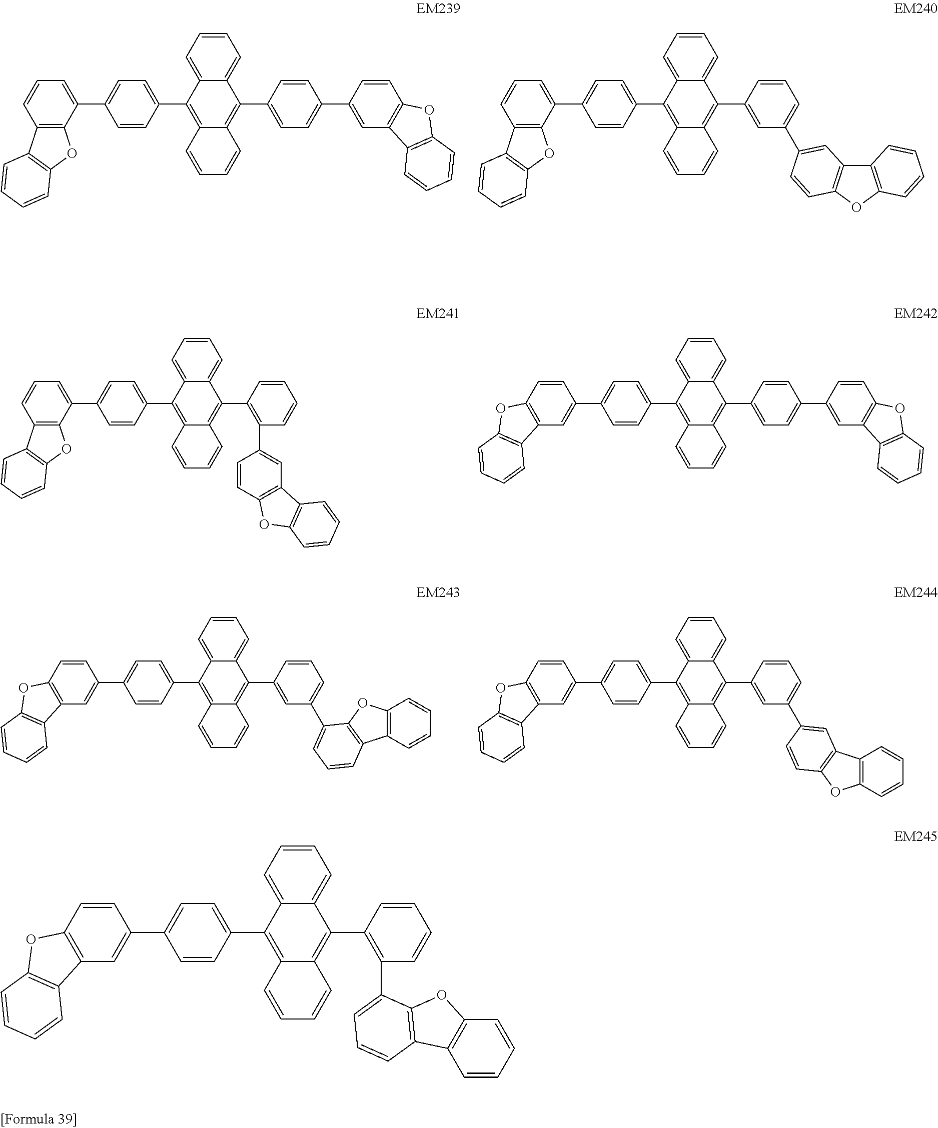

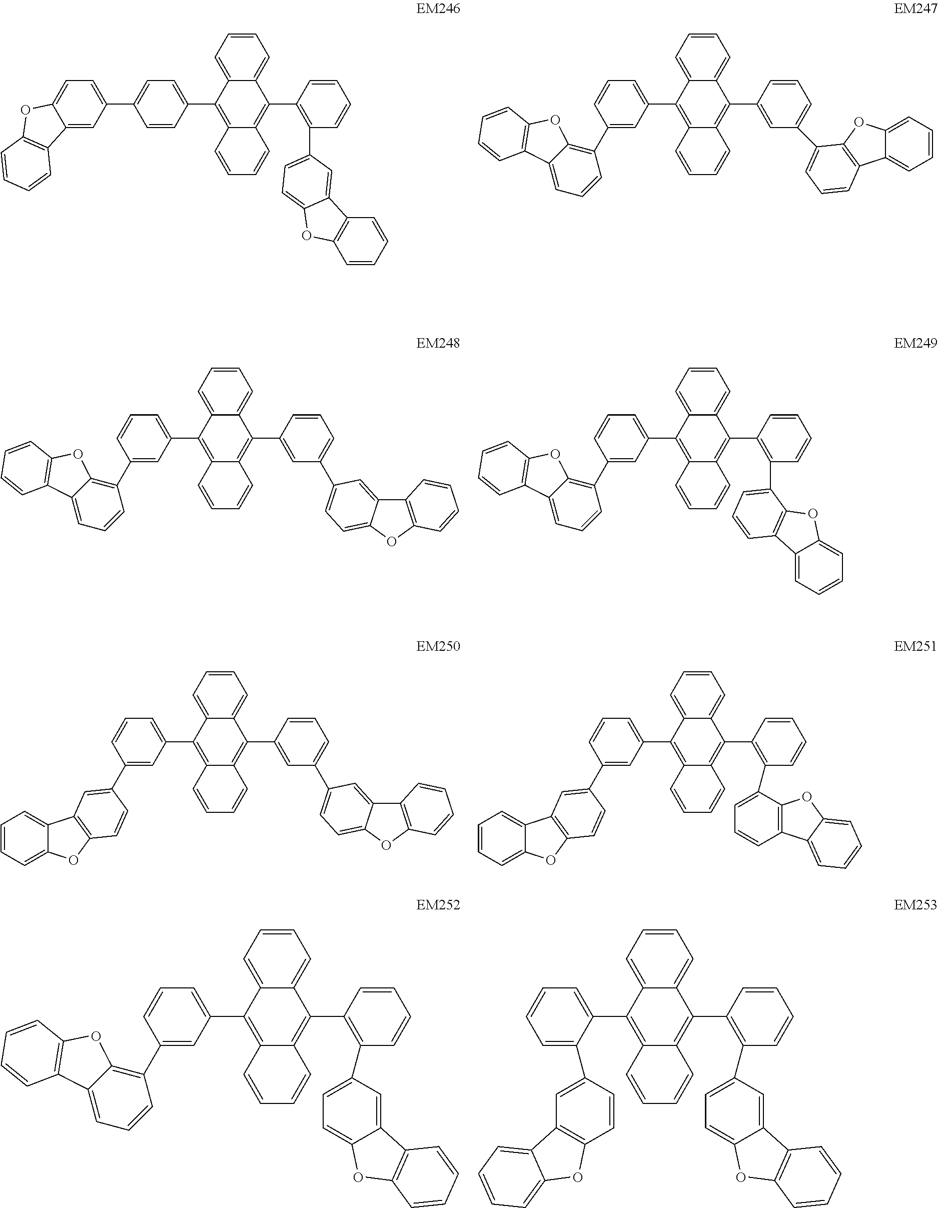

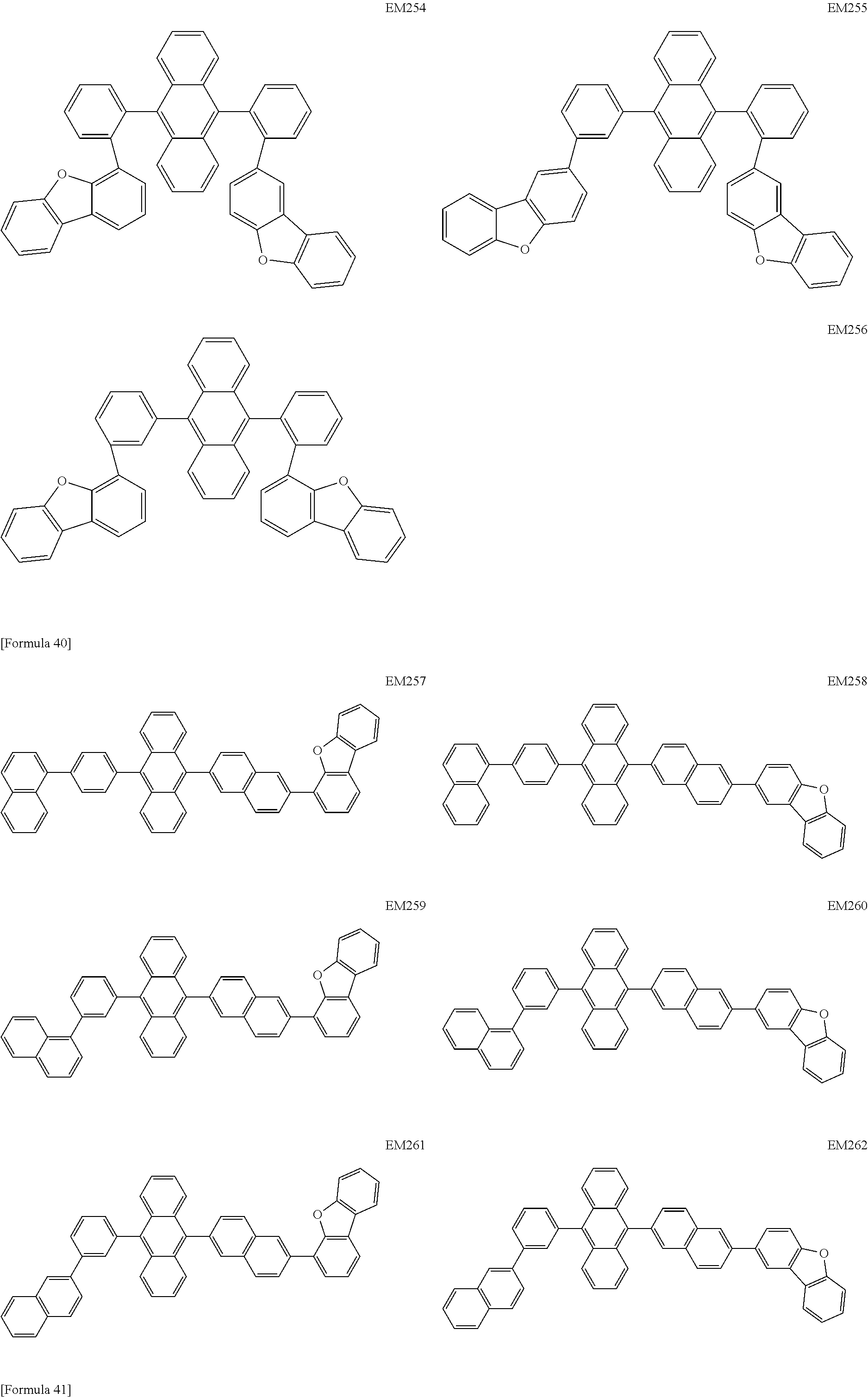

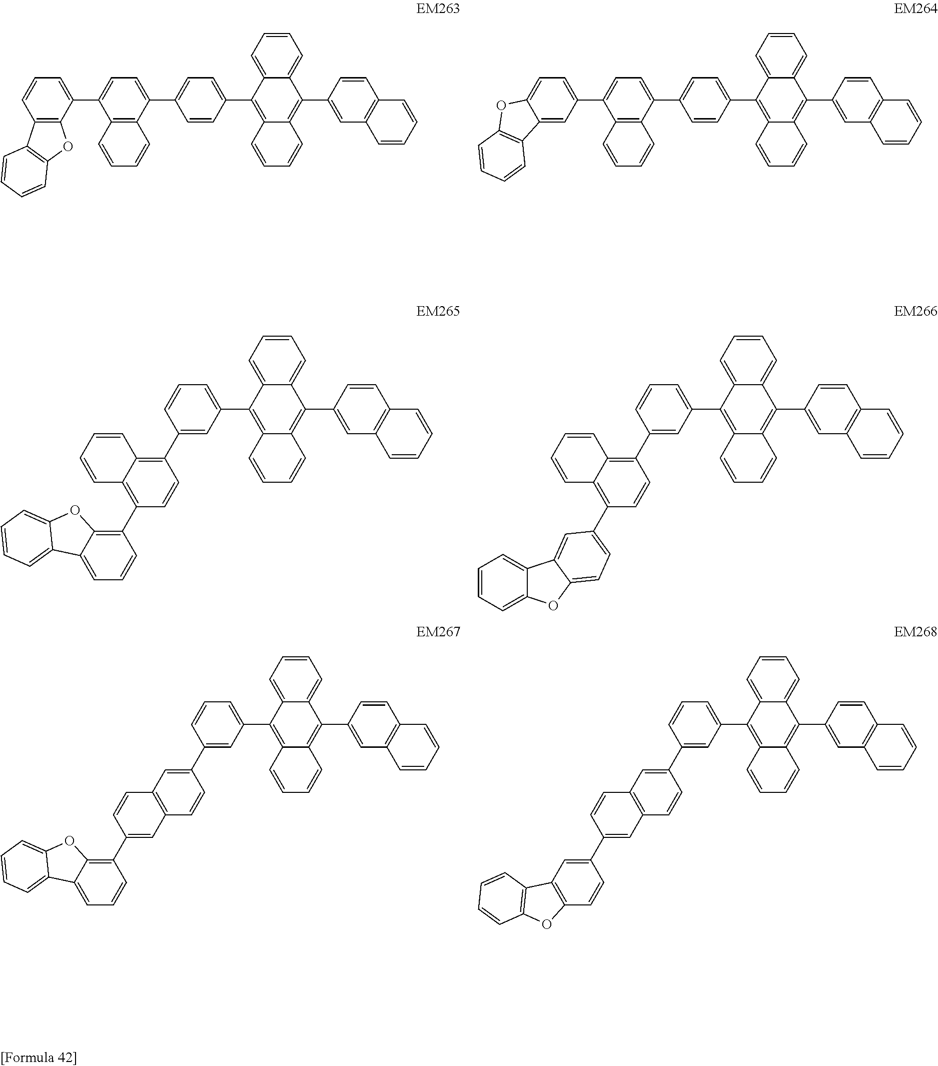

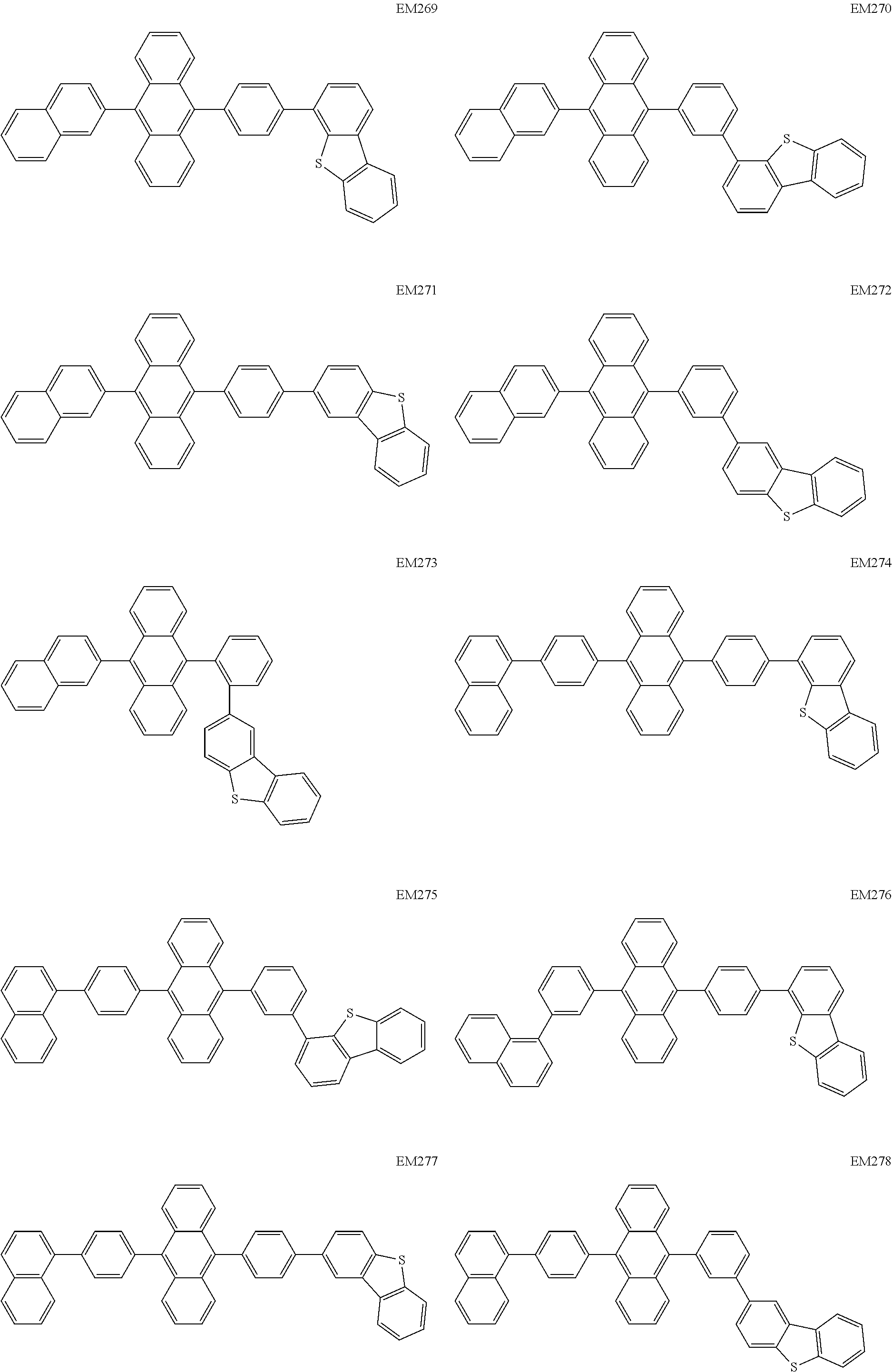

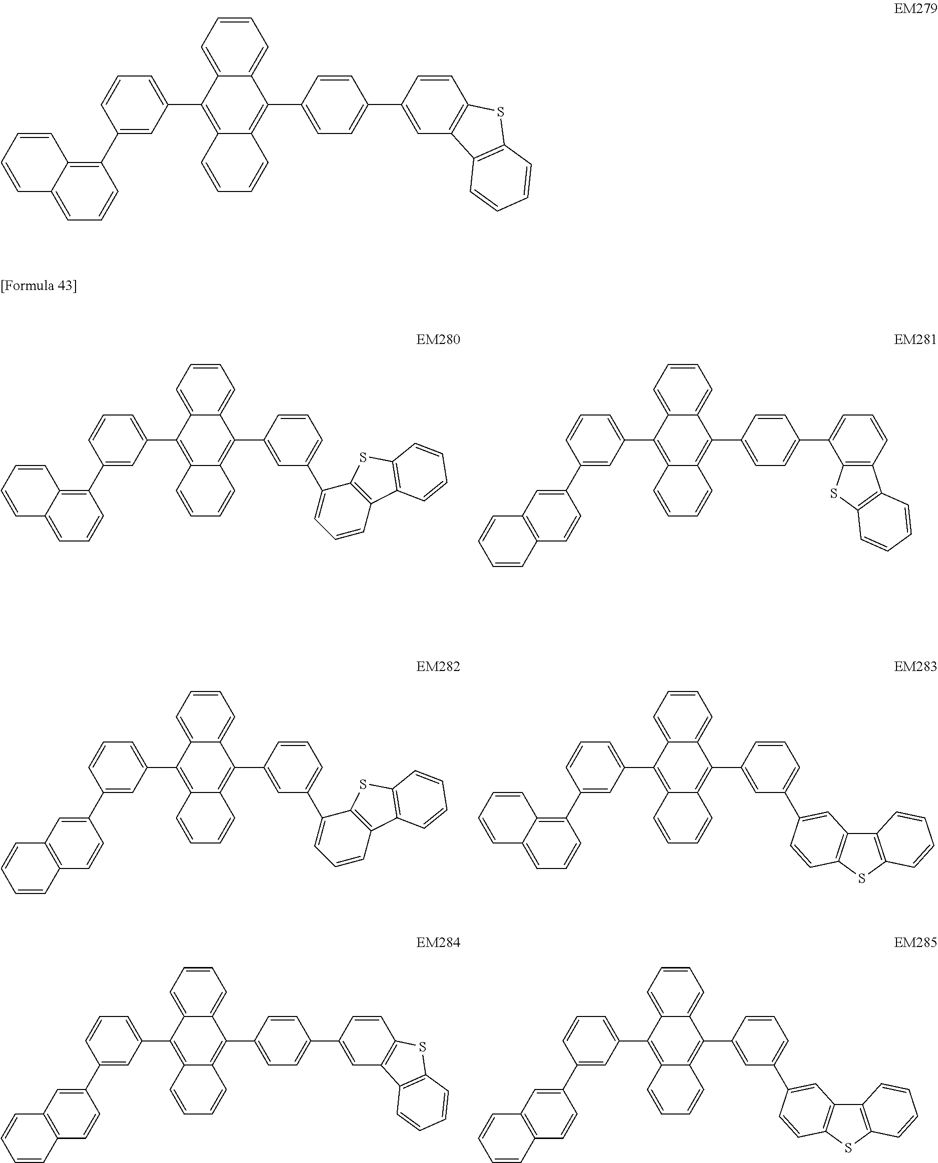

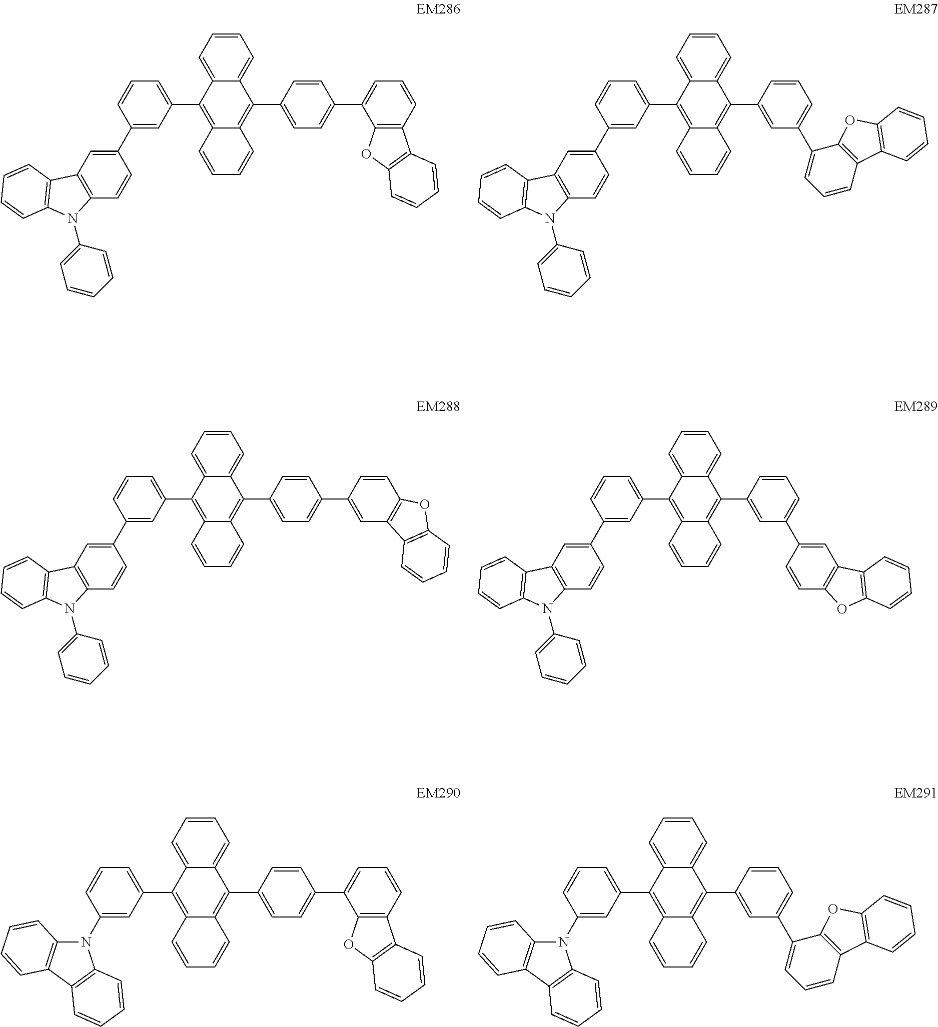

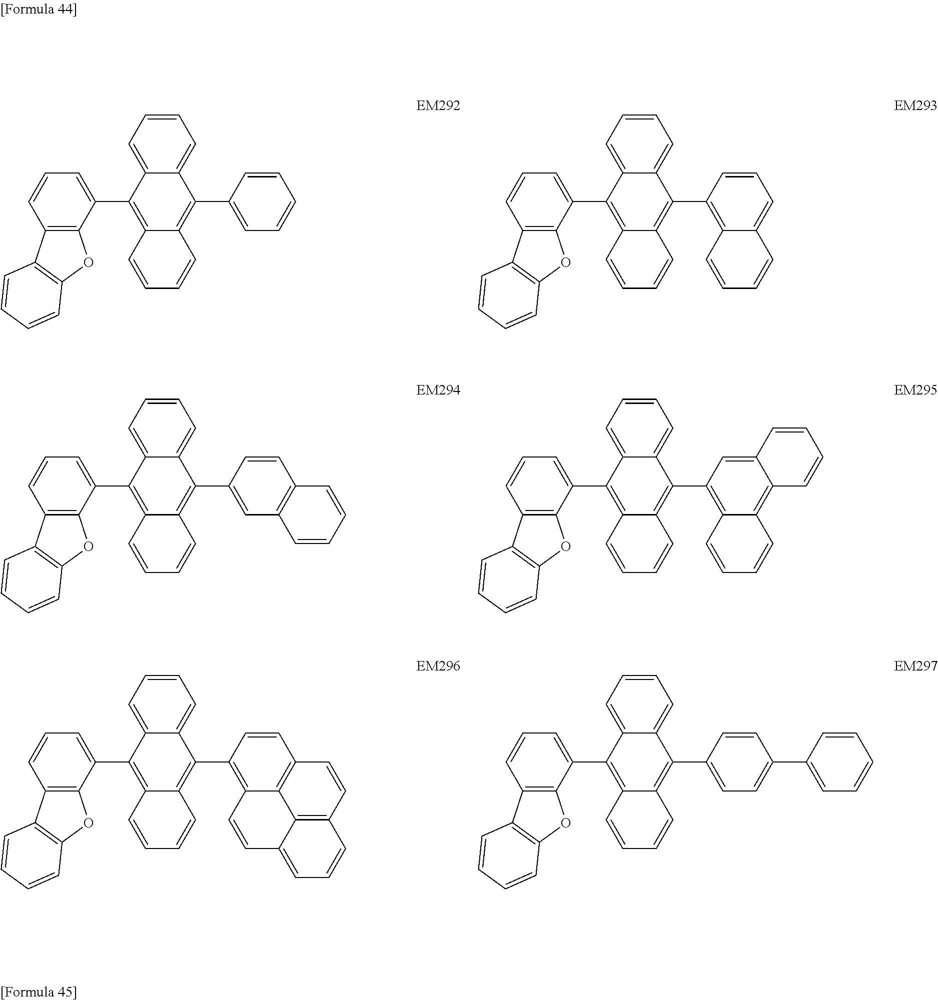 [SMILES: c1ccc(-c2c3ccccc3c(-c3cccc4c3oc3ccccc34)c3ccccc23)cc1 ; c1ccc2c(-c3c4ccccc4c(-c4cccc5c4oc4ccccc45)c4ccccc34)cccc2c1 ; c1ccc2cc(-c3c4ccccc4c(-c4cccc5c4oc4ccccc45)c4ccccc34)ccc2c1 ; c1ccc2c(c1)cc(-c1c3ccccc3c(-c3cccc4c3oc3ccccc34)c3ccccc13)c1ccccc12 ; c1cc2ccc3ccc(-c4c5ccccc5c(-c5cccc6c5oc5ccccc56)c5ccccc45)c4ccc(c1)c2c34 ; c1ccc(-c2ccc(-c3c4ccccc4c(-c4cccc5c4oc4ccccc45)c4ccccc34)cc2)cc1]

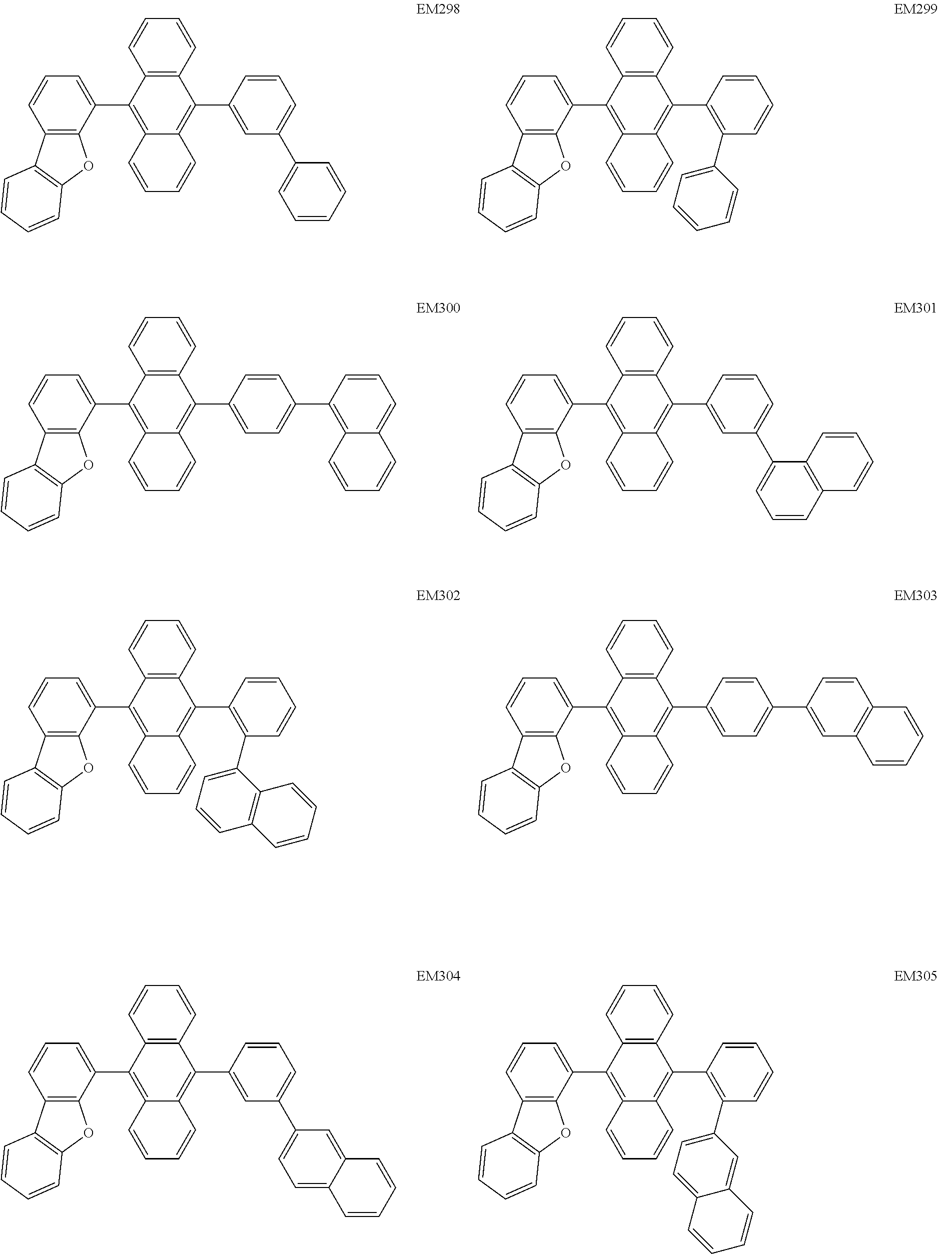

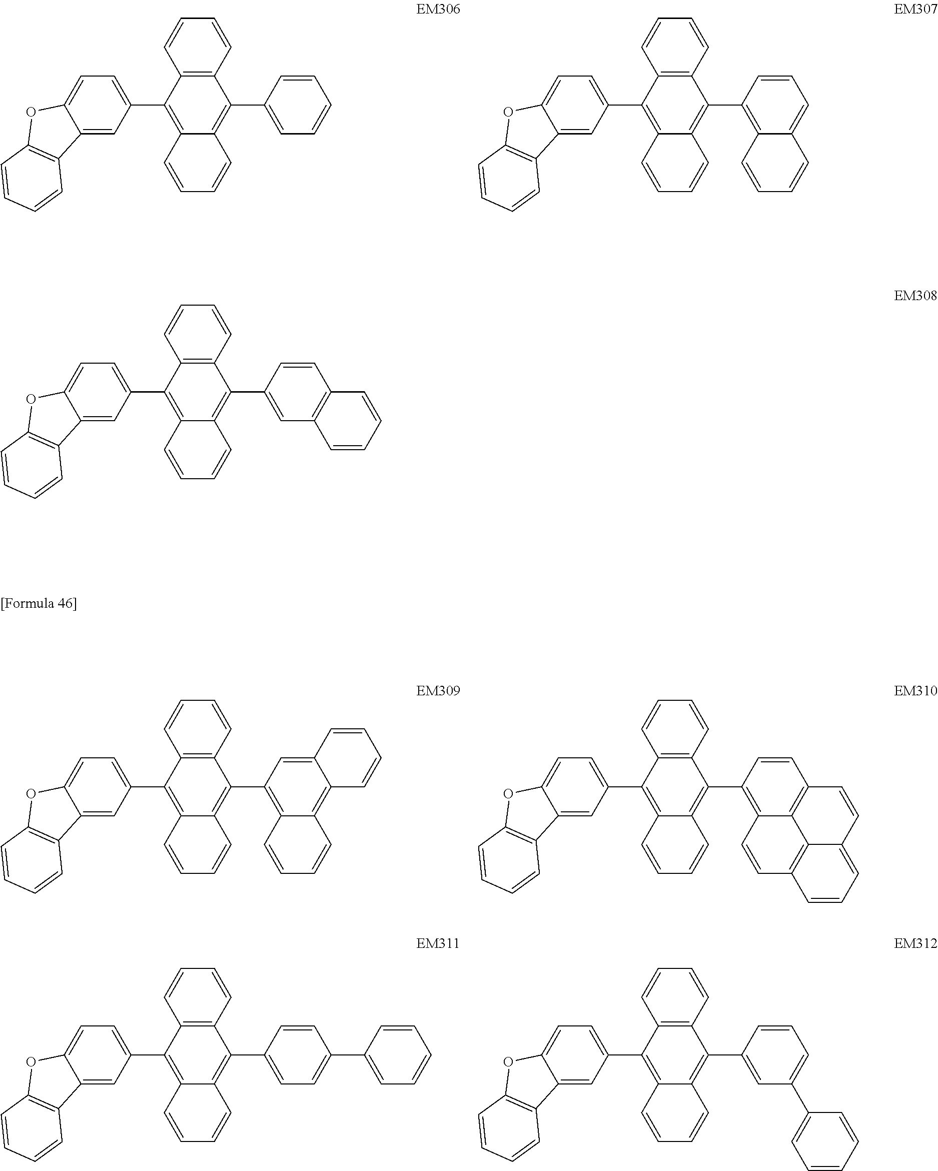

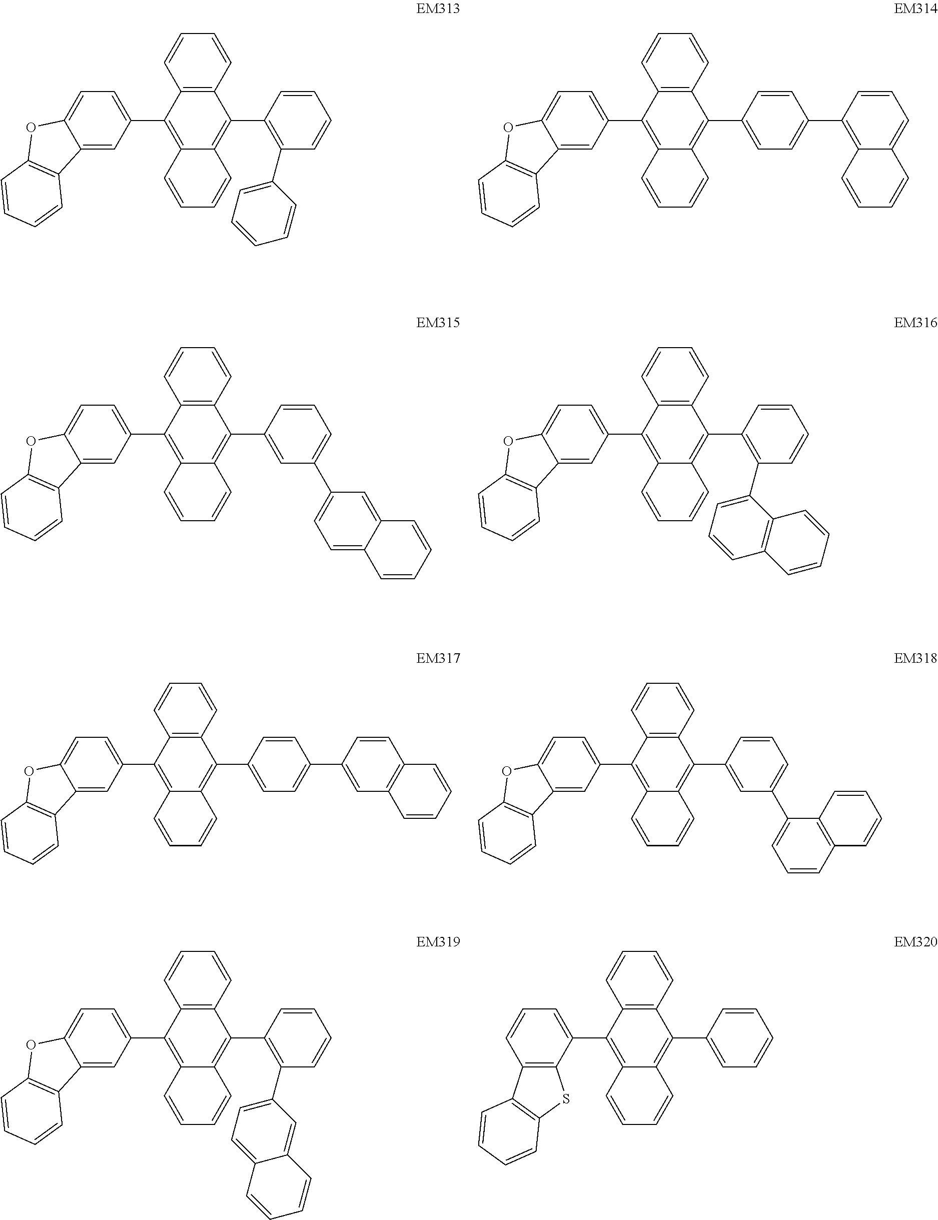

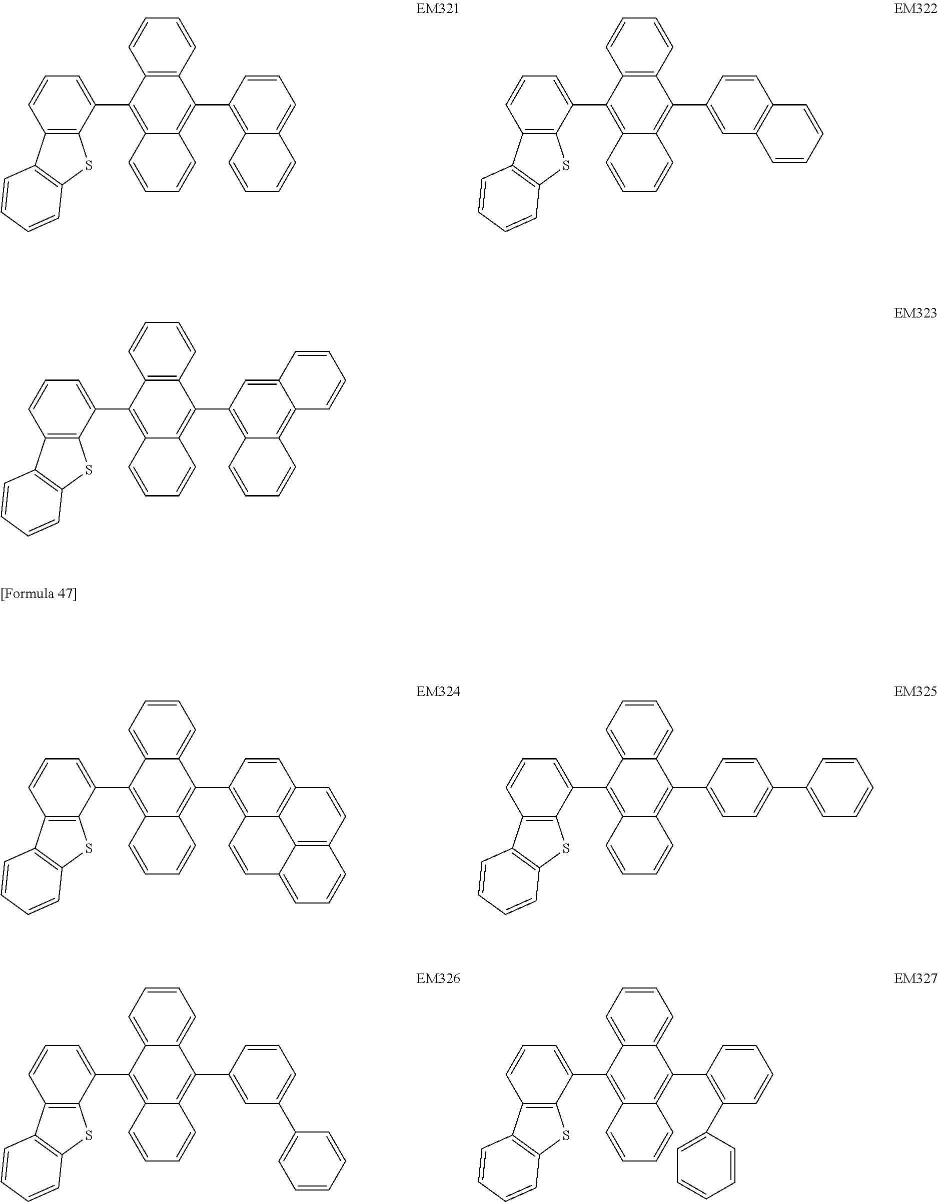

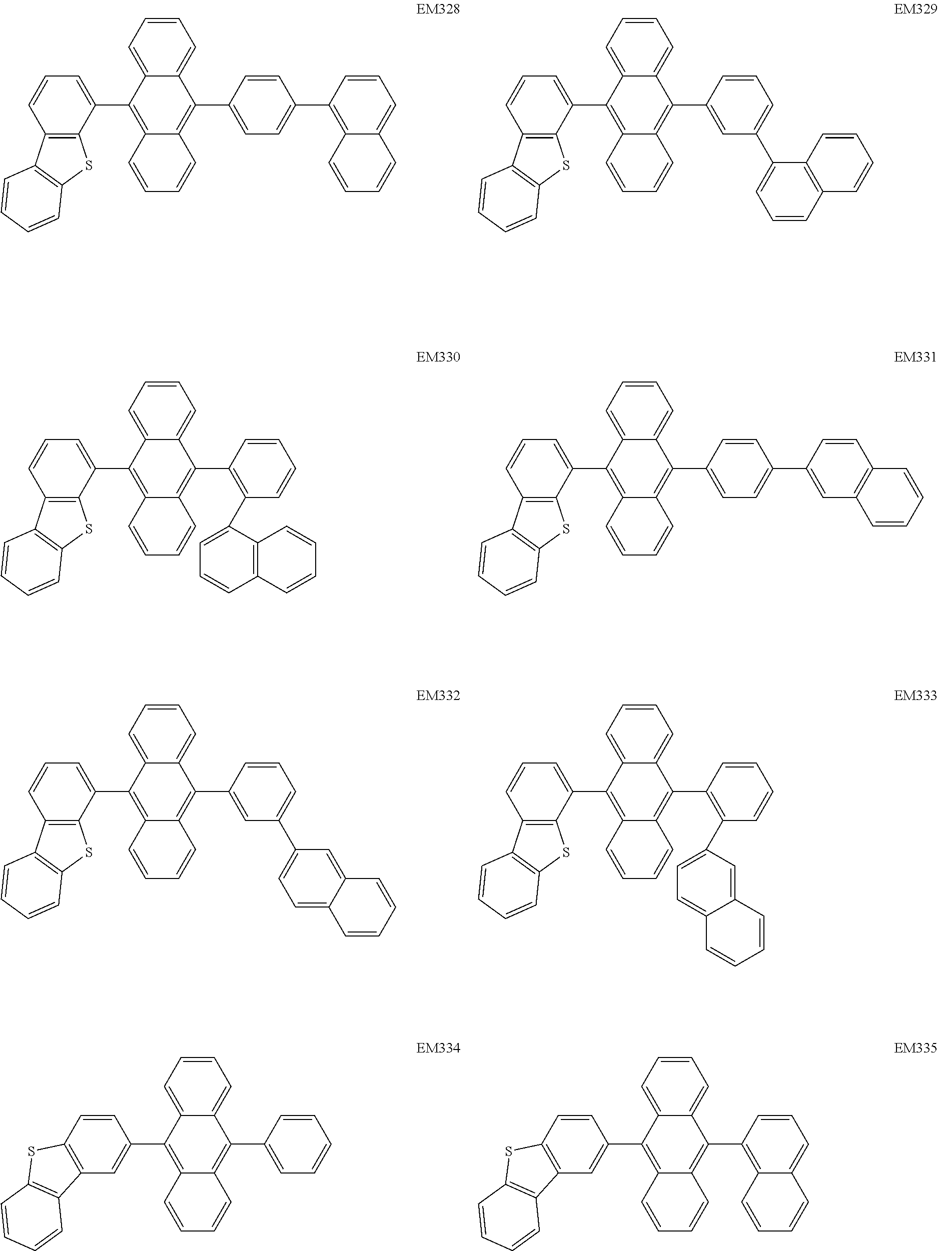

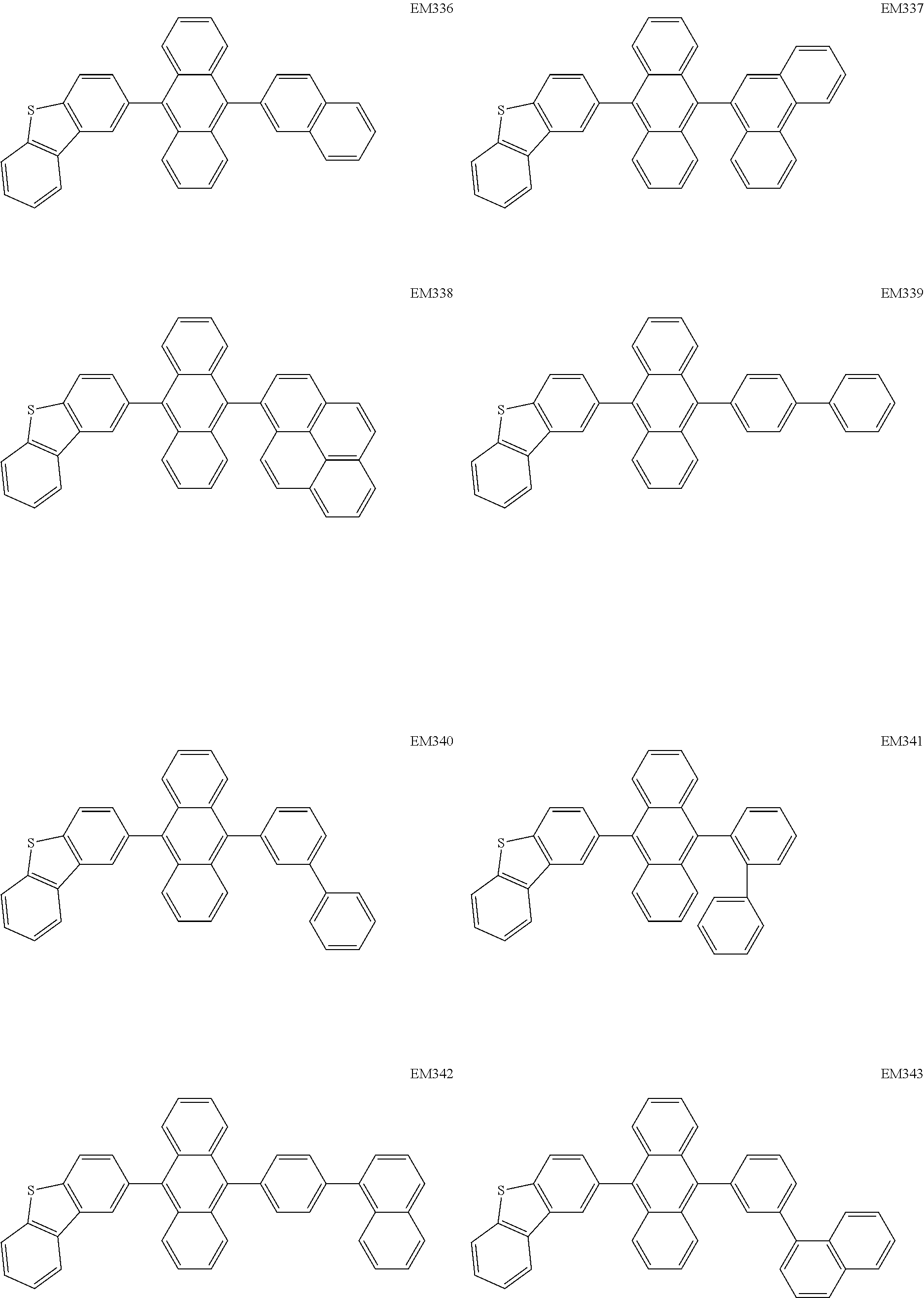

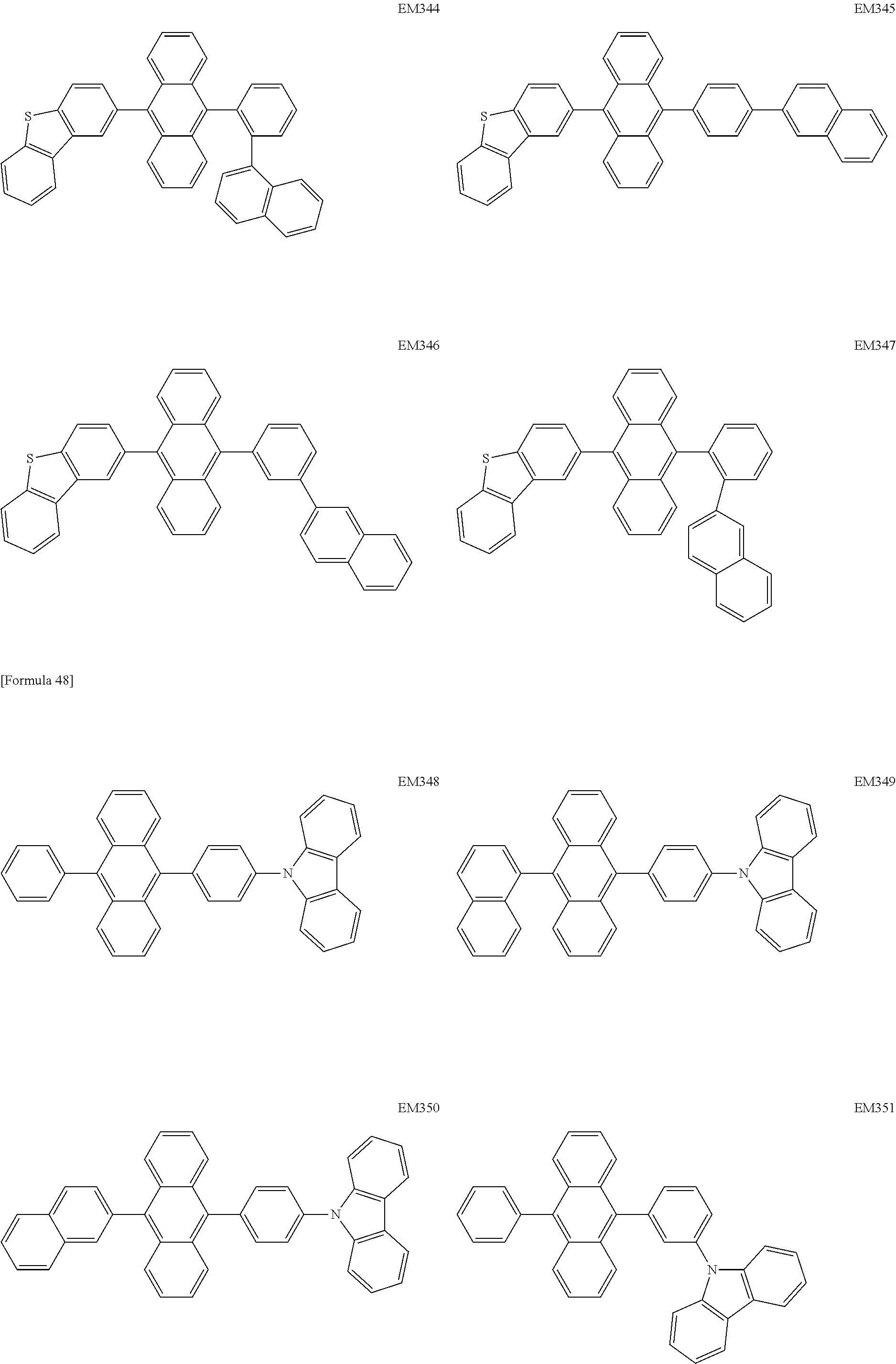

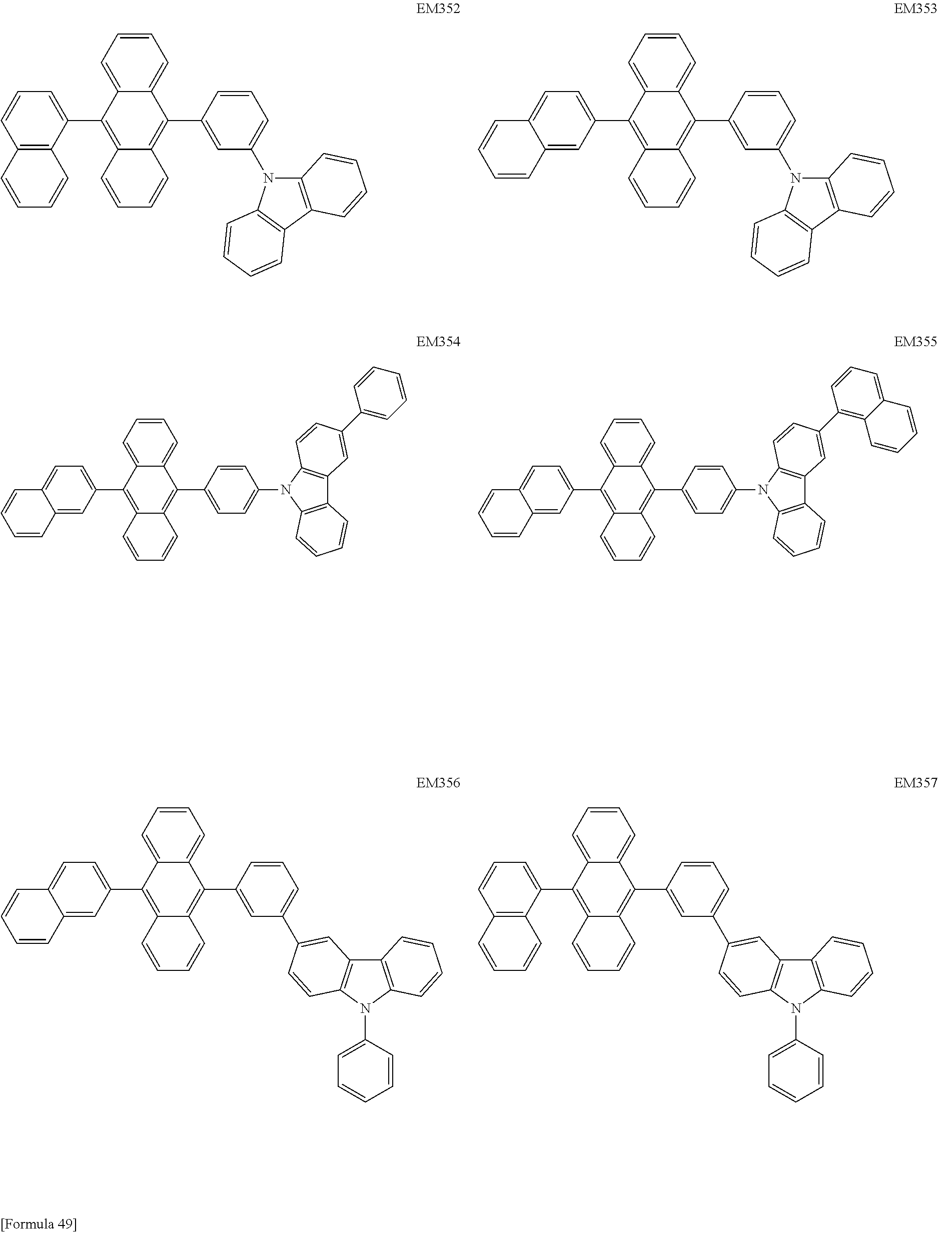 [SMILES: c1cc(-c2c3ccccc3c(-c3cccc4ccccc34)c3ccccc23)cc(-n2c3ccccc3c3ccccc32)c1 ; c1cc(-c2c3ccccc3c(-c3ccc4ccccc4c3)c3ccccc23)cc(-n2c3ccccc3c3ccccc32)c1 ; c1ccc(-c2ccc3c(c2)c2ccccc2n3-c2ccc(-c3c4ccccc4c(-c4ccc5ccccc5c4)c4ccccc34)cc2)cc1 ; c1ccc2cc(-c3c4ccccc4c(-c4ccc(-n5c6ccccc6c6cc(-c7cccc8ccccc78)ccc65)cc4)c4ccccc34)ccc2c1 ; c1ccc(-n2c3ccccc3c3cc(-c4cccc(-c5c6ccccc6c(-c6ccc7ccccc7c6)c6ccccc56)c4)ccc32)cc1 ; c1ccc(-n2c3ccccc3c3cc(-c4cccc(-c5c6ccccc6c(-c6cccc7ccccc67)c6ccccc56)c4)ccc32)cc1]

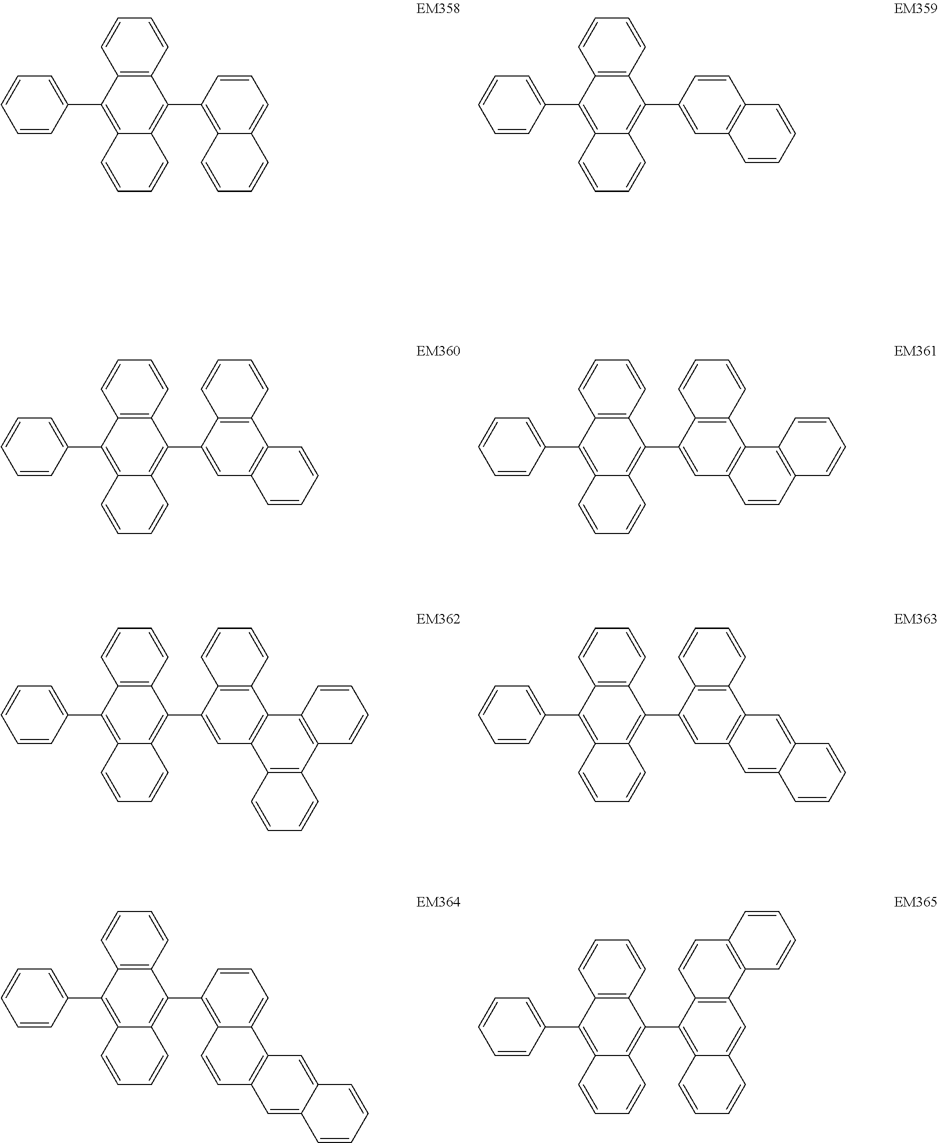

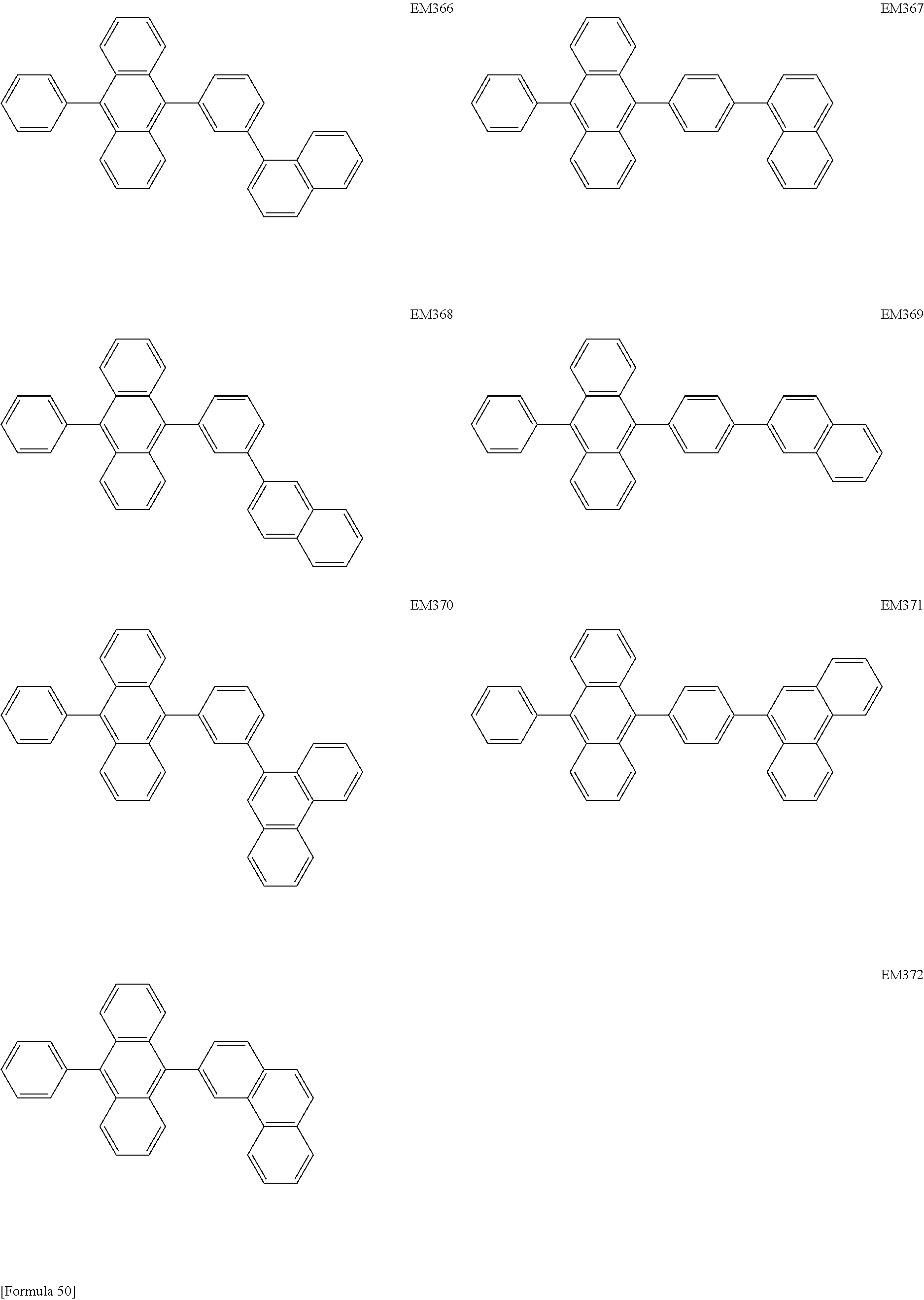

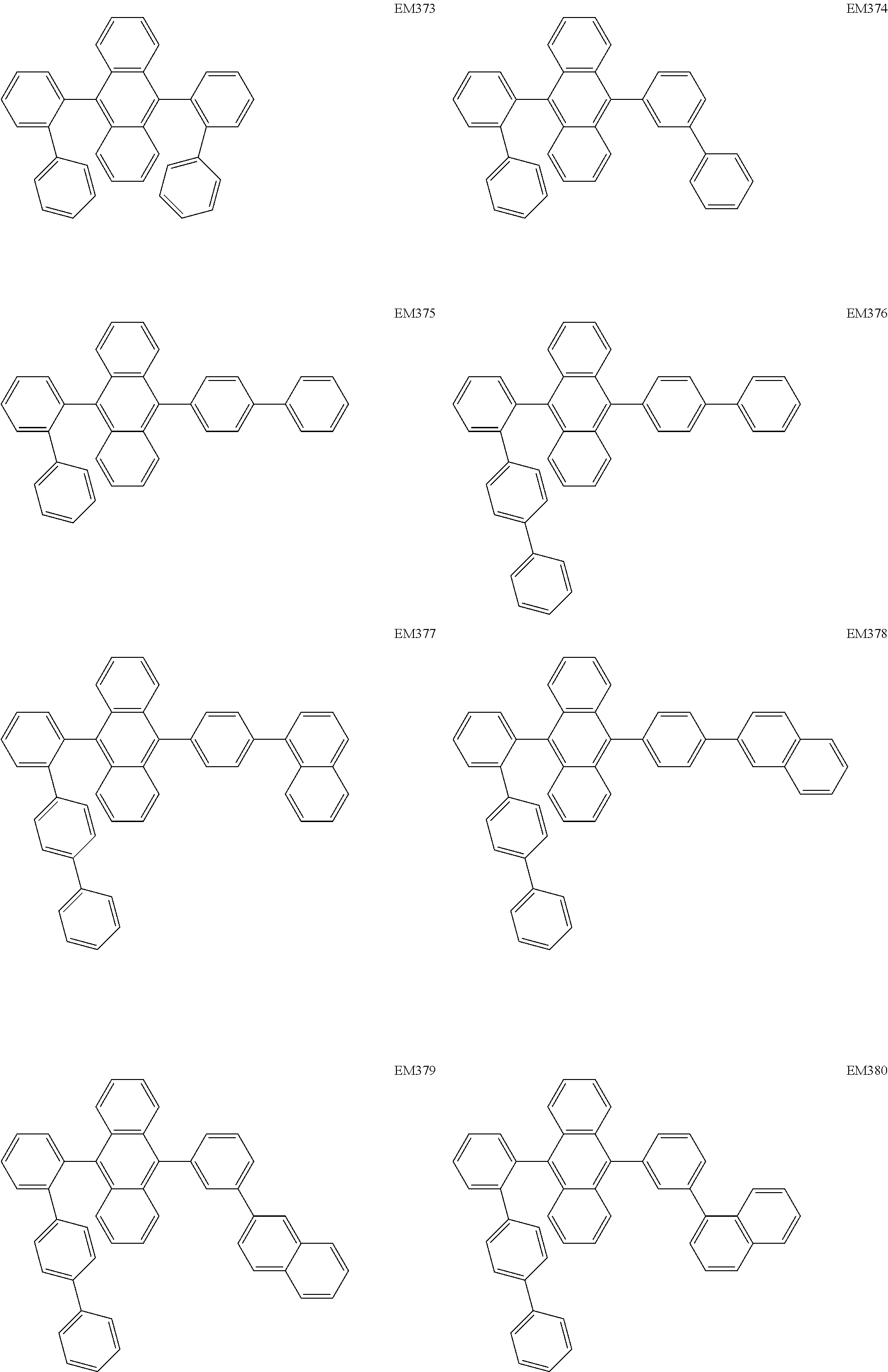

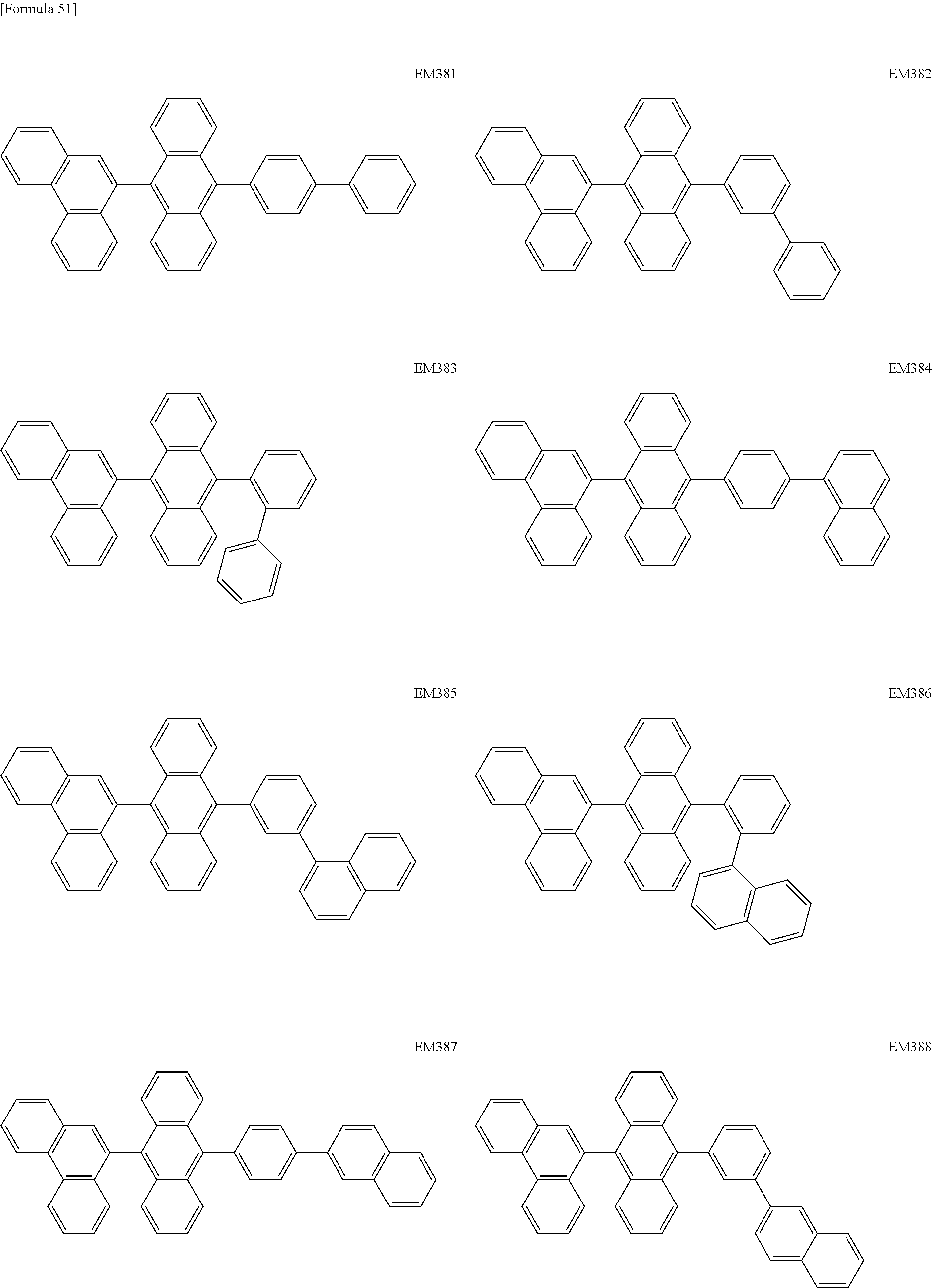

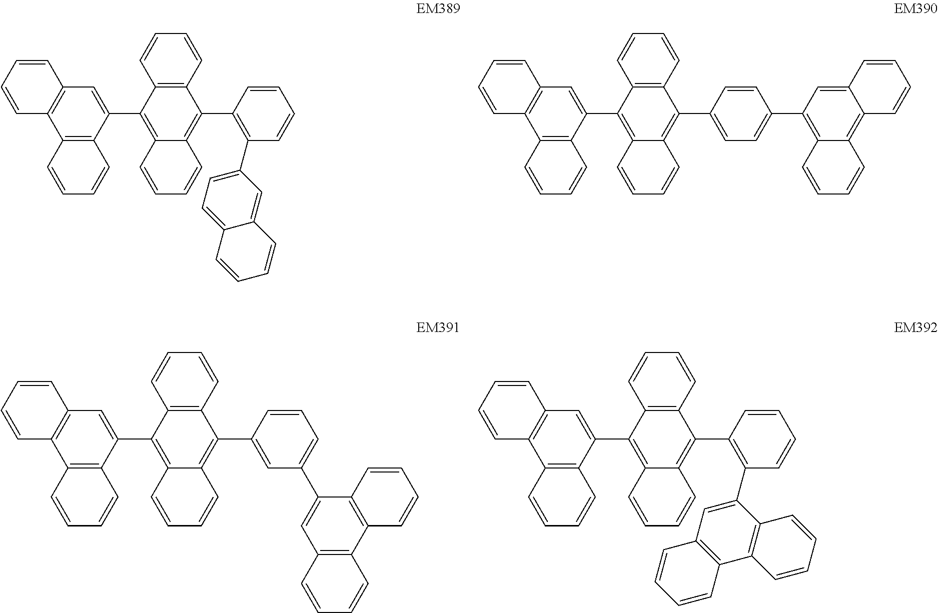

### Pyrene Derivative

In the organic EL device according to the exemplary embodiment, at least one layer forming the organic thin-film layer may contain the aromatic amine derivative represented by the formula (1) and a pyrene derivative represented by the following formula (30). The emitting layer preferably contains the aromatic amine derivative as a dopant material and the pyrene derivative as a host material.

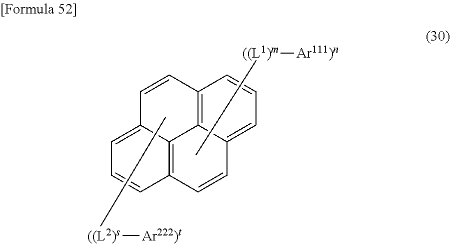

In the formula (30), Ar¹¹¹ and Ar²²² are each independently a substituted or unsubstituted aryl group having 6 to 30 ring carbon atoms.

In the formula (30), L¹ and L² are each independently a substituted or unsubstituted divalent aryl group having 6 to 30 ring carbon atoms or a heterocyclic group.

In the formula (30), m is an integer of 0 to 1, n is an integer of 1 to 4, s is an integer of 0 to 1 and t is an integer of 0 to 3.

In the formula (30), L¹ or Ar¹¹¹ is bonded to any one of the 1- to 5-positions of pyrene while L² or Ar²²² is bonded to any one of the 6- to 10-positions of pyrene.

The above explanation of the expression “substituted or unsubstituted” is also applicable to the substituents for the Ar¹¹¹, Ar²²², L¹ and L² in the formula (30).

In the formula (30), L¹ and L² are each selected from among a substituted or unsubstituted phenylene group, a substituted or unsubstituted biphenylene group, a substituted or unsubstituted naphtylene group, a substituted or unsubstituted terphenylene group, a substituted or unsubstituted fluorenylene group and a divalent aryl group formed by combining the above groups.

In the formula (30), m is preferably an integer of 0 to 1.

In the formula (30), n is preferably an integer of 1 to 2.

In the formula (30), s is preferably an integer of 0 to 1.

In the formula (30), t is preferably an integer of 0 to 2.

Examples of the aryl group for Ar¹¹¹ and Ar²²² in the formula (30) are the same as ones listed for R₁ to R₅ and R₇ to R₁₁ in the formula (1). The aryl group is preferably a substituted or unsubstituted aryl group having 6 to 20 ring carbon atoms and more preferably a substituted or unsubstituted aryl group having 6 to 16 ring carbon atoms. Specific preferable examples of the aryl group are a phenyl group, naphthyl group, phenanthryl group, fluorenyl group, biphenyl group, anthryl group and pyrenyl group.

### Other Applications of Compounds

The aromatic amine derivative, the anthracene derivative of the formula (20) and the pyrene derivative of the formula (30) according to the invention are also usable for the hole injecting layer, the hole transporting layer, the electron injecting layer and the electron transporting layer as well as for the emitting layer.

### Other Materials Usable for Emitting Layer

Examples of a material usable for the emitting layer in combination with the aromatic amine derivative according to the invention in place of the materials of the formulae (20) and (30) are fused polycyclic aromatic compounds such as naphthalene, phenanthrene, rubrene, anthracene, tetracene, pyrene, perylene, chrysene, decacyclene, coronene, tetraphenylcyclopentadiene, pentaphenylcyclopentadiene, fluorene and spirofluorene and derivatives thereof, organic metal complexes such as tris(8-quinolinolate)aluminum, triaryl amine derivative, styrylamine derivative, stilbene derivative, coumarin derivative, pyrane derivative, oxazone derivative, benzothiazole derivative, benzoxazole derivative, benzimidazole derivative, pyrazine derivative, cinnamic acid ester derivative, diketopyrolopyrrol derivative, acridone derivative, and quinacridone derivative. Incidentally, these examples are not exhaustive.

### Content

When the organic thin-film layer contains the aromatic amine derivative according to the invention as a dopant material, the content of the aromatic amine derivative in the organic thin-film layer is preferably in a range from 0.1 mass % to 20 mass %, more preferably from 1 mass % to 10 mass %.

### Substrate

The organic EL device according to the exemplary embodiment is formed on a light-transmissive substrate. The light-transmissive substrate, which is designed to support the organic EL device, is preferably provided by a smoothly shaped substrate that transmits 50% or more of light in a visible region of 400 nm to 700 nm. Further, the substrate preferably has a mechanical and thermal strength.

Specific examples of the substrate are a glass plate and a polymer plate.

For the glass plate, materials such as soda-lime glass, barium/strontium-containing glass, lead glass, aluminosilicate glass, borosilicate glass, barium borosilicate glass and quartz can be used.

For the polymer plate, materials such as polycarbonate, acryl, polyethylene terephthalate, polyether sulfide and polysulfone can be used. Incidentally, polymer film may be used as the substrate.

### Anode and Cathode

An electrically conductive material with a work function more than 4 eV is favorably usable as a material for the anode of the organic EL device according to the exemplary embodiment. Specific examples of the usable electrically conductive material are carbon, aluminum, vanadium, iron, cobalt, nickel, tungsten, silver, gold, platinum and palladium and alloys thereof, metal oxides such as tin oxide and indium oxide that are usable for ITO substrate and NESA substrate, and organic electrically conductive resins such as polythiophene and polypyrrole. The anode can be made by forming a thin film from these electrically conductive materials by vapor deposition, sputtering or the like.

When light from the emitting layer is to be emitted through the anode, the anode preferably transmits more than 10% of the light in the visible region. Sheet resistance of the anode is preferably several hundreds Ω/square or lower. Although depending on the material of the anode, the thickness of the anode is typically in a range from 10 nm to 1 μm, preferably in a range from 10 nm to 200 nm.

An electrically conductive material with a work function less than 4 eV is favorably usable as a material for the cathode of the organic EL device according to the exemplary embodiment. Specific examples of the usable electrically conductive material are magnesium, calcium, tin, zinc, titanium, yttrium, lithium, ruthenium, manganese, aluminum and lithium fluoride and alloys thereof, which are not exhaustive. Typical examples of the alloys are magnesium and silver, magnesium and indium, and lithium and aluminum, which are not exhaustive. The ratio of the alloys is controlled depending on the temperature of a deposition source, atmosphere, vacuum degree and the like to be appropriately adjusted. Like the anode, the cathode may be made by forming a thin film from the above materials through a method such as vapor deposition and sputtering. In addition, the light may be emitted through the cathode.

When light from the emitting layer is to be emitted through the cathode, the cathode preferably transmits more than 10% of the light in the visible region. Sheet resistance of the cathode is preferably several hundreds Ω per square or lower. Although depending on the material of the cathode, the thickness of the cathode is typically in a range from 10 nm to 1 μm, preferably in a range from 50 nm to 200 nm.

The anode and the cathode may be formed in a multilayer structure including two or more layers as needed.

At least one surface of the organic EL device according to the exemplary embodiment preferably has a sufficient transparency in an emission wavelength range of the device so that the device can efficiently emit light. Further, it is preferable that the substrate is also transparent. A transparent electrode is adjusted to exhibit a predetermined light-transmittance through a method such as vapor deposition and sputtering using the above electrically conductive material.

### Hole Injecting/Transporting Layer

For the hole injecting/transporting layer, the following hole injecting material and hole transporting layer are usable.

The hole injecting material is preferably a compound that is capable of transporting holes, has an excellent effect in injecting holes from the anode and in injecting holes into the emitting layer or a light-emitting material, and has an excellent ability to form a thin film. Specific examples of such a compound are a phthalocyanine derivative, naphthalocyanine derivative, porphyrin derivative, benzidine-based triphenylamine, diamine-based triphenylamine and hexacyanohexaazatriphenylene and derivatives thereof as well as polymer materials such as polyvinyl carbazole, polysilane and electrically conductive polymers, which are not exhaustive.

Among hole injecting materials usable for the organic EL device according to the exemplary embodiment, a phthalocyanine derivative is further effective.

Examples of the phthalocyanine (Pc) derivative are phthalocyanine derivatives and naphthalocyanine derivatives such as H2Pc, CuPc, CoPc, NiPc, ZnPc, PdPc, FePc, MnPc, ClAlPc, ClGaPc, ClInPc, ClSnPc, Cl₂SiPc, (HO)AlPc, (HO)GaPc, VOPc, TiOPc, MoOPc and GaPc-O-GaPc, which are not exhaustive.

Carrier may be sensitized by adding the hole injecting material with an electron acceptor substance such as a 7,7,8,8-tetracyanoquinodimethane (TCNQ) derivative.

The hole transporting material usable for the organic EL device according to the exemplary embodiment is preferably an aromatic tertiary amine derivative.

Examples of the aromatic tertiary amine derivative are N,N′-diphenyl-N,N′-dinaphthyl-1,1′-biphenyl-4,4′-diamine, N,N,N′,N′-tetrabiphenyl-1,1′-biphenyl-4,4′-diamine and oligomers and polymers having aromatic tertiary amine skeletons thereof, which are not exhaustive.

### Electron Injecting/Transporting Layer

For the electron injecting/transporting layer, the following electron injecting material and the like are usable.

The electron injecting material is preferably a compound that is capable of transporting electrons, has an excellent effect in injecting electrons from the cathode and in injecting electrons into the emitting layer or a light-emitting material, and has an excellent ability to form a thin film.

Further effective electron injecting materials for the organic EL device according to the exemplary embodiment are a metal complex compound and a nitrogen-containing heterocyclic derivative.

Examples of the metal complex compound are 8-hydroxyquinolinate lithium, bis(8-hydroxyquinolinate)zinc, tris(8-hydroxyquinolinate)aluminum, tris(8-hydroxyquinolinate)gallium, bis(10-hydroxybenzo[h]quinolinate)beryllium and bis(10-hydroxybenzo[h]quinolinate)zinc, which are not exhaustive.

Examples of the nitrogen-containing heterocyclic derivative are oxazole, thiazole, oxadiazole, thiadiazole, triazole, pyridine, pyrimidine, triazine, phenanthroline, benzimidazole and imidazopyridine, among which a benzimidazole derivative, a phenanthroline derivative and an imidazopyridine derivative are preferable.

In the organic EL device according to the exemplary embodiment, it is preferable that, for instance, these electron injecting materials are further added with at least one of an electron-donating dopant and an organic metal complex. More preferably, in order to facilitate reception of electrons from the cathode, at least one of the electron-donating dopant and the organic metal complex is doped in the vicinity of an interface between the organic thin-film layer and the cathode.

With this arrangement, the organic electroluminescence device can emit light with enhanced luminescence intensity and have a longer lifetime.

The electron-donating dopant is exemplified by at least one selected from among alkali metal, alkali metal compound, alkaline earth metal, alkaline earth metal compound, rare earth metal and rare earth metal compound.

The organic metal complex is exemplified by at least one selected from among an organic metal complex containing an alkali metal, an organic metal complex containing an alkaline earth metal, and an organic metal complex containing a rare earth metal.

Examples of the alkali metal are lithium (Li) (work function: 2.93 eV), sodium (Na) (work function: 2.36 eV), potassium (K) (work function: 2.28 eV), rubidium (Rb) (work function: 2.16 eV) and cesium (Cs) (work function: 1.95 eV), among which a substance having a work function of 2.9 eV or less is particularly preferable. Among the above, the reductive dopant is preferably K, Rb or Cs, more preferably Rb or Cs, the most preferably Cs.

Examples of the alkaline earth metal are calcium (Ca) (work function: 2.9 eV), strontium (Sr) (work function: no less than 2.0 eV and no more than 2.5 eV) and barium (Ba)(work function: 2.52 eV), among which a substance having a work function of 2.9 eV or less is particularly preferable.

Examples of the rare earth metal are scandium (Sc), yttrium (Y), cerium (Ce), terbium (Tb) and ytterbium (Yb), among which a substance having a work function of 2.9 eV or less is particularly preferable.

Since the above preferable metals have particularly high reducibility, addition of a relatively small amount of the metals to an electron injecting zone can enhance luminescence intensity and lifetime of the organic EL device.

Examples of the alkali metal compound are alkali oxides such as lithium oxide (Li₂O), cesium oxide (Cs₂O) and potassium oxide (K₂O) and alkali halogenides such as lithium fluoride (LiF), sodium fluoride (NaF), cesium fluoride (CsF) and potassium fluoride (KF), among which lithium fluoride (LiF), lithium oxide (Li₂O) and sodium fluoride (NaF) are preferable.

Examples of the alkaline earth metal compound are barium oxide (BaO), strontium oxide (SrO) and calcium oxide (CaO) and mixtures thereof such as strontium acid barium (BaₓSr₁₋ₓO) (0<x<1) and calcium acid barium (BaₓCa₁₋ₓO) (0<x<1), among which BaO, SrO and CaO are preferable.

Examples of the rare earth metal compound are ytterbium fluoride (YbF₃), scandium fluoride (ScF₃), scandium oxide (ScO₃), yttrium oxide (Y₂O₃), cerium oxide (Ce₂O₃), gadolinium fluoride (GdF₃) and terbium fluoride (TbF₃), among which YbF₃, ScF₃ and TbF₃ are preferable.

The organic metal complex is not subject to a particular limitation as long as the organic metal complex contains at least one of alkali metal ion, alkaline earth metal ion and rare earth metal ion as a metal ion as described above. Preferable examples of a ligand are quinolinol, benzoquinolinol, acridinol, phenanthridinol, hydroxyphenyl oxazole, hydroxyphenyl thiazole, hydroxydiaryl oxadiazole, hydroxydiaryl thiadiazole, hydroxyphenyl pyridine, hydroxyphenyl benzoimidazole, hydroxybenzo triazole, hydroxy fluborane, bipyridyl, phenanthroline, phthalocyanine, porphyrin, cyclopentadiene, β-diketones, azomethines and derivatives thereof, which are not exhaustive.

One of the above examples of the electron-donating dopant and the organic metal complex may be used alone or, alternatively, two or more thereof may be used in combination.

### Method of Forming Each Layer in Organic EL Device

Each layer in the organic EL device according to the exemplary embodiment may be formed by any one of dry film-formation methods such as vacuum deposition, sputtering, plasma and ion plating and wet film-formation methods such as dipping, flow coating and ink jet method.

According to the wet film-formation methods, a material for forming each layer is dissolved or dispersed in any appropriate solvent (e.g., ethanol, chloroform, tetrahydrofuran and dioxane) to form a thin film.

As a solution appropriate for such wet film-formation methods, an organic-EL-material-containing solution that contains the aromatic amine derivative according to the invention as the organic-EL-device material as well as a solvent is usable.

Any appropriate resin and/or additive may be added in each organic thin-film layer in order to improve film-formability and prevent a pin hole or the like from being formed in the film.

### Film Thickness of Each Layer in Organic EL Device

The film thickness is not subject to a particular limitation but needs to be appropriately adjusted. An extremely increased film thickness increases an applied voltage required for obtaining a predetermined optical output, thereby deteriorating efficiency. An extremely reduced film thickness results in generation of a pin hole or the like, so that a sufficient luminescence intensity cannot be obtained when an electric field is applied. The film thickness is appropriately set in a range from 5 nm to 10 μm, more preferably from 10 nm to 0.2 μm.

### Application of Organic EL Device

The organic EL device according to the exemplary embodiment is usable, for instance, for: a planar light-emitting device such as a flat panel display; a light source for a copier, a printer, a backlight for a liquid crystal display, or meters, gauges or the like; a lighting device; an indicator board; and a marker lamp. The compounds according to the invention are usable not only for an organic EL device but also for any fields such as electrophotographic photoreceptor, photoelectric converter, solar battery and image sensor.

### Modifications of Exemplary Embodiment

In the emitting layer of the organic EL device according to the exemplary embodiment, in addition to one selected from among the aromatic amine derivatives represented by the formula (1), at least one of a light-emitting material, a doping material, a hole injecting material, a hole transporting material and an electron injecting material may also be contained in the same layer as the aromatic amine derivative. Further, in order to improve the stability of the organic EL device according to the exemplary embodiment to temperature, humidity, atmosphere or the like, a protection layer may be provided to a surface of the device or, alternatively, the device may be entirely protected with silicon oil, resin or the like.

It should be noted that the invention is not limited to the above exemplary embodiment but may include any modification and improvement as long as such modification and improvement are compatible with the invention.

The arrangement of the organic EL device is not limited to the exemplary arrangement of the organic EL device 1 shown in FIG. 1. For instance, the organic EL device has such an arrangement that an electron blocking layer is provided to an anode-side of the emitting layer while a hole blocking layer is provided to a cathode-side of the emitting layer.

A single emitting layer may be provided alone or a plurality of emitting layers may be provided in a multilayer structure. When the organic EL device includes the plurality of emitting layers, at least one of the emitting layers preferably contains the aromatic amine derivative according to the invention. In such a case, the rest of the emitting layers may be fluorescent emitting layers that contain a fluorescent material to fluoresce or phosphorescent emitting layers that contain a phosphorescent material to phosphoresce.

When the organic EL device includes the plurality of emitting layers, the emitting layers may be adjacently provided or may be layered on one another via a different layer (e.g., a charge generating layer).

### EXAMPLES

Next, the present invention will be described in further detail by exemplifying Example(s) and Comparative(s). However, the invention is not limited by the description of Example(s).

### Synthesis of Compounds

### Synthesis Example 1

### Synthesis of Compound 1

A synthesis scheme of a compound 1 is shown below.

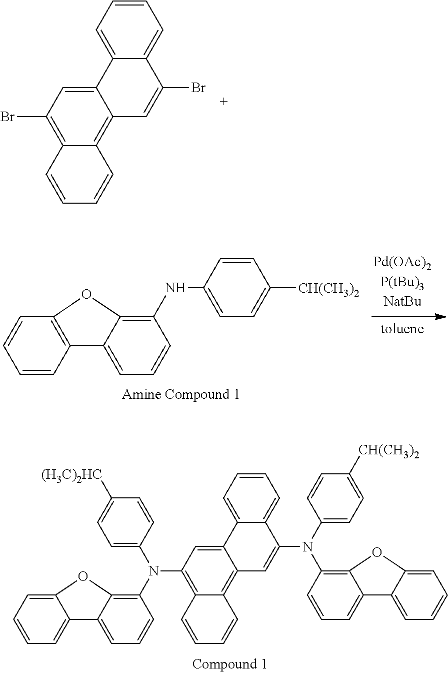

In a 300-mL recovery flask under an argon gas stream, 10.5 g of an amine compound 1 (35 mmol), 5.4 g of 6,12-dibromochrysene (14 mmol), 2.69 g of sodium-tert-butoxide, 0.19 g of palladium acetate, 306 μL of tri-tert-butylphosphine toluene solution (2.746 mmol) and 100 mL of dehydrated toluene were added and reacted at 90 degrees C. for eight hours.

A crude product obtained by filtering a reaction solution was washed with methanol, water, acetone and heated toluene and then an obtained solid was recrystallized with toluene. The obtained solid was then dried under reduced pressure, thereby obtaining 4 g of a compound. The obtained compound was subjected to FD-MS (Field Desorption Mass Spectrometry) analysis. The results are shown below.

FDMS, calcd for C₅₂H₃₂N₂O₂=716. found m/z=716 (M+)

The obtained compound was identified as a compound 1 as a result of the FD-MS analysis.

### Synthesis Examples 2 to 13

### Synthesis of Compounds 2 to 13

Synthesis Examples 2 to 13 were the same as Synthesis Example 1 except that the amine compound 1 in Synthesis Example 1 was replaced with amine compounds 2 to 13 as listed below, respectively. As a result, compounds 2 to 13 shown below were obtained. The obtained compounds were subjected to FD-MS (Field Desorption Mass Spectrometry) analysis. The obtained compounds were identified as the compounds 2 to 13 as a result of the FD-MS analysis. Correspondence relations between an amine compound used in each synthesis example and an obtained compound are shown below.
Synthesis Example 2: Amine Compound 2: compound 2
Synthesis Example 3: Amine Compound 3: Compound 3
Synthesis Example 4: Amine Compound 4: Compound 4
Synthesis Example 5: Amine Compound 5: Compound 5
Synthesis Example 6: Amine Compound 6: Compound 6
Synthesis Example 7: Amine Compound 7: Compound 7
Synthesis Example 8: Amine Compound 8: Compound 8
Synthesis Example 9: Amine Compound 9: Compound 9
Synthesis Example 10: Amine Compound 10: Compound 10
Synthesis Example 11: Amine Compound 11: Compound 11
Synthesis Example 12: Amine Compound 12: Compound 12
Synthesis Example 13: Amine Compound 13: Compound 13

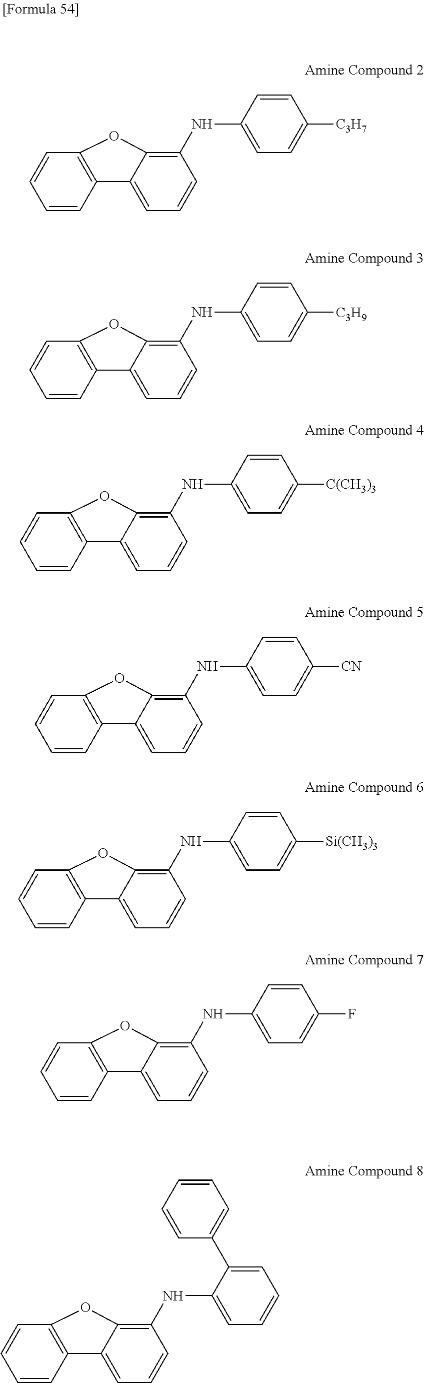

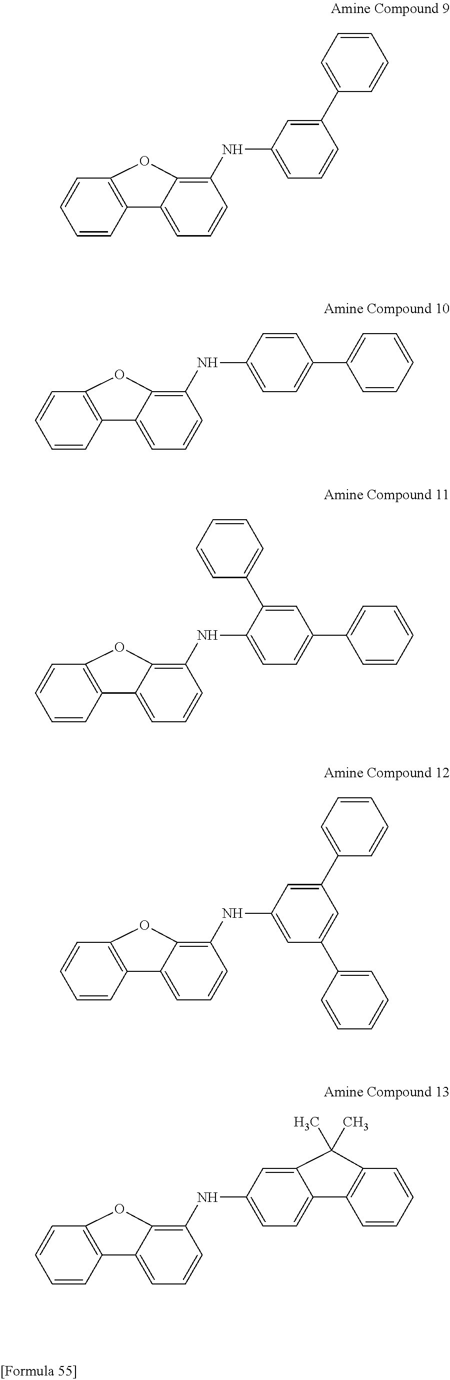 [SMILES: c1ccc(-c2cccc(Nc3cccc4c3oc3ccccc34)c2)cc1 ; c1ccc(-c2ccc(Nc3cccc4c3oc3ccccc34)cc2)cc1 ; c1ccc(-c2ccc(Nc3cccc4c3oc3ccccc34)c(-c3ccccc3)c2)cc1 ; c1ccc(-c2cc(Nc3cccc4c3oc3ccccc34)cc(-c3ccccc3)c2)cc1 ; CC1(C)c2ccccc2-c2ccc(Nc3cccc4c3oc3ccccc34)cc21]

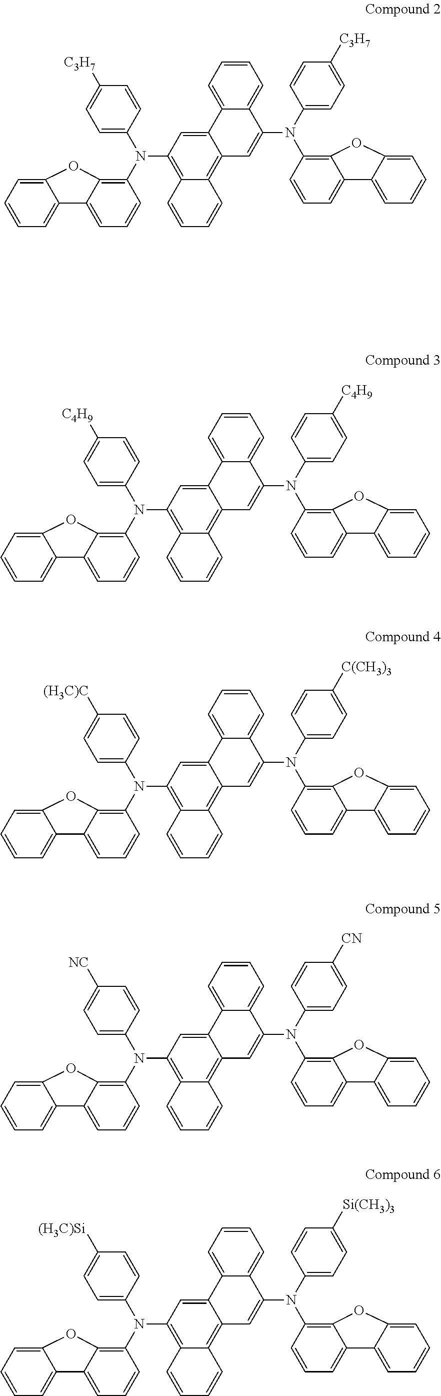

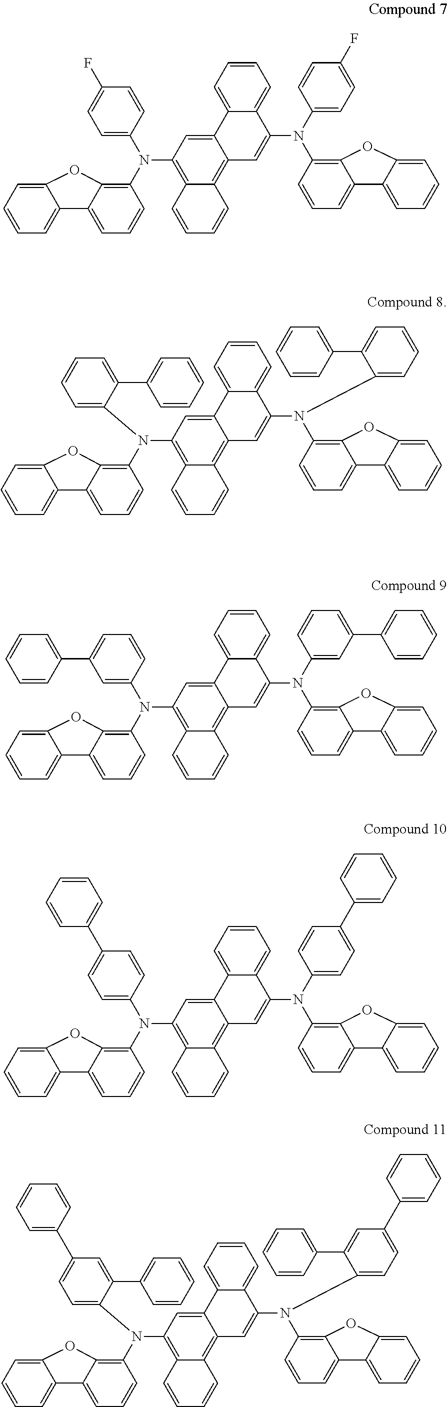

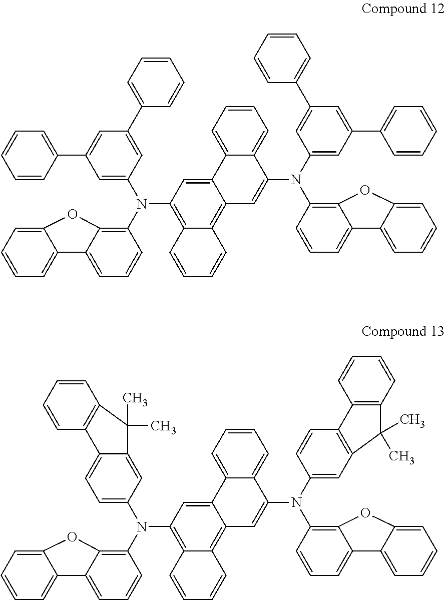 [SMILES: c1ccc(-c2cc(-c3ccccc3)cc(N(c3cc4c5ccccc5c(N(c5cc(-c6ccccc6)cc(-c6ccccc6)c5)c5cccc6c5oc5ccccc56)cc4c4ccccc34)c3cccc4c3oc3ccccc34)c2)cc1 ; CC1(C)c2ccccc2-c2ccc(N(c3cc4c5ccccc5c(N(c5ccc6c(c5)C(C)(C)c5ccccc5-6)c5cccc6c5oc5ccccc56)cc4c4ccccc34)c3cccc4c3oc3ccccc34)cc21]

### Manufacturing of Organic EL Device

### Example 1

A glass substrate (size: 25 mm×75 mm×1.1 mm thick, manufactured by Geomatec Co., Ltd.) having an ITO transparent electrode (anode) was subjected to ultrasonic-cleaning in isopropyl alcohol for five minutes, and UV/ozone-cleaning for 30 minutes. The cleaned glass substrate with the transparent electrode line was mounted on a substrate holder of a vacuum deposition apparatus and initially, a 50-nm-thick film of a compound HT-1 shown below was formed on the transparent electrode line formed side of the glass substrate so as to cover the transparent electrode. The HT-1 film works as a hole injecting layer. After the film formation of the HT-1 film, a compound HT-2 shown below was deposited to form a 45-nm-thick HT-2 film on the HT-1 film. The HT-2 film works as a hole transporting layer. Then, a compound BH-1 shown below (i.e., a host material) and the compound 1 (i.e., a dopant material) were deposited on the HT-2 film (volume ratio of BH-1 to compound 1 was 19:1) to form a 30-nm-thick emitting layer. Further, a compound ET-1 shown below (i.e., an electron transporting material) was deposited to form a 20-nm-thick electron transporting layer on the emitting layer. Subsequently, LiF was formed into a 0.5-nm-thick film. Al metal was deposited on the LiF film to form a 100-nm-thick metal cathode, thereby manufacturing an organic EL device of Example 1.

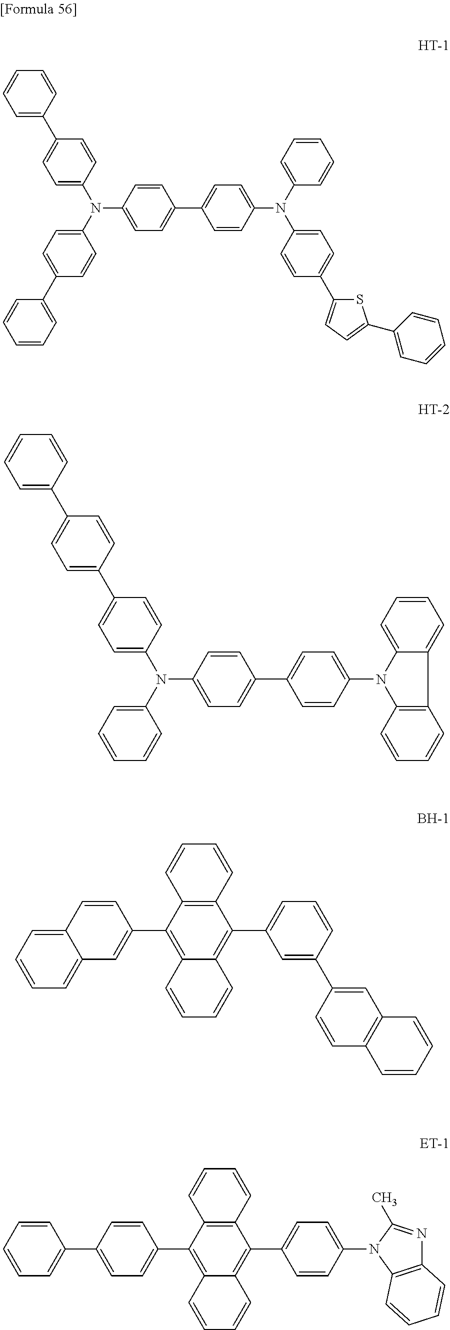

The manufactured organic EL device was driven with a current density of 10 mA/cm² and the device performance such as drive voltage, external quantum efficiency and emission wavelength at that time was evaluated as follows. The results are shown in Table 77.

### Evaluation of Device Performance

Voltage was applied on the organic EL device with a current density becoming 10 mA/cm² and a value of the voltage (V) at that time was measured. An EL spectrum was measured with a spectral radiance meter (CS-1000, manufactured by KONICA MINOLTA). Based on the obtained spectral radiance spectrum, the emission wavelength and the external quantum efficiency; EQE (%) were calculated.

TABLE 77

| | Drive Voltage | EQE | Emission Wavelength |
|---|---|---|---|
| | (V) | (%) | (nm) |
| Device Example 1 | 4.2 | 7.3 | 451 |

As is understandable from the results shown in Table 77, it has been observed that the organic EL device of Example 1 emits blue light and found that the device requires a sufficiently low drive voltage and shows a sufficiently high external quantum efficiency. In view of the above, it has been proven that the compound 1 is usable as an organic-electroluminescence-device material.

### Synthesis of Compounds

### Intermediate-Synthesis Example 1

### Synthesis of Amine Compound 14

A synthesis scheme of an amine compound 14 is shown below.

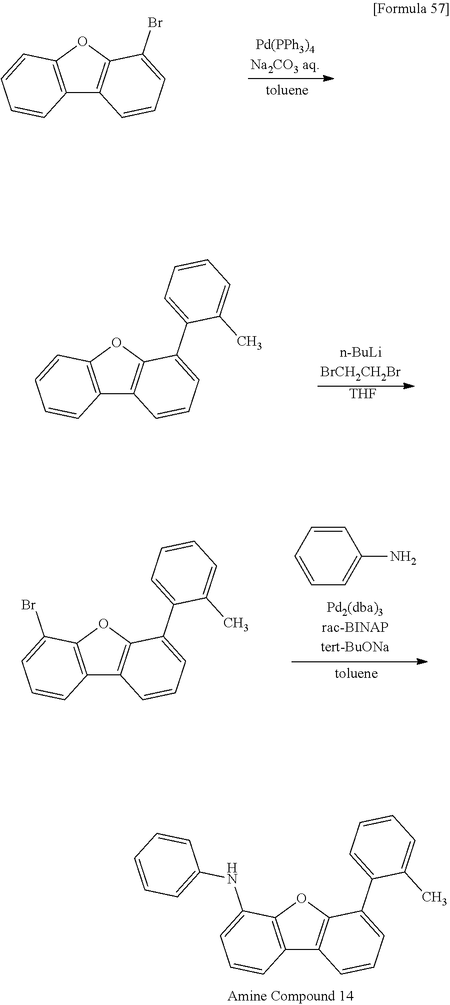 [SMILES: Brc1cccc2c1oc1ccccc12 ; Cc1ccccc1-c1cccc2c1oc1ccccc12 ; Cc1ccccc1-c1cccc2c1oc1c(Br)cccc12 ; Nc1ccccc1 ; "THF" ; Cc1ccccc1-c1cccc2c1oc1c(Nc3ccccc3)cccc12]

### (1-1) Synthesis of 4-(2-Methylphenyl) Dibenzofuran

In a 10-liter recovery flask under an argon gas stream, 199 g of 4-bromodibenzofuran (0.81 mol), 120 g of 2-methylphenyl boronic acid (0.88 mol), 18.4 g of Pd(pph₃)₄, 3.2 L of toluene and 1.2 L of 2M sodium carbonate solution were added and reacted at 85 degrees C. for 15 hours.

After the mixture was cooled down, an organic layer was washed with water and then condensed, thereby obtaining 250 g of a crude product.

The obtained crude product was purified by silica-gel chromatography (eluent: heptane), thereby obtaining 180 g of 4-(2-methylphenyl) dibenzofuran.

### (1-2) Synthesis of 4-Bromo-6-(2-Methylphenyl)Dibenzofuran

Under an argon gas stream, 180 g of 4-(2-methylphenyl) dibenzofuran (0.70 mol) was dissolved in 2 L of dehydrated THF and 479 ml of 1.6M n-BuLi was dropped therein at 5 degrees C.

After the mixture was stirred at a temperature of from 5 degrees C. to 10 degrees C. for one and half hours, 262 g of dibromoethane was dropped therein at minus 60 degrees C. and the mixture was stirred at room temperature for 16 hours.

After 150 ml of water was added, 1 L of ethyl acetate and 1 L of water were further added and an organic substance was extracted.

The separated ethyl acetate layer was washed with saturated saline and dried with anhydrous sodium sulfate and ethyl acetate was removed by distillation thereby obtaining 250 g of a crude product. The obtained crude product was purified by silica-gel chromatography and then recrystallized, thereby obtaining 137 g of 4-bromo-6-(2-methylphenyl) dibenzofuran.

### (1-3) Synthesis of Amine Compound 14

Under an argon gas stream, a solution was prepared by mixing 2.76 g of Pd₂(dba)₃, 500 ml of a dehydrated toluene solution of 3.76 g of rac-BINAP (rac-(aS*)-2,2′-bis(diphenylphosphino)-1,1′-binaphthalene), 68 g (0.20 mol) of 4-bromo-6-(2-methylphenyl) dibenzofuran and 500 ml of a dehydrated toluene solution of 3.75 g of aniline (0.40 mol). After added with 38.7 g of tert-BuONa at 90 degrees C., the solution was stirred at 105 degrees C. for three hours.

After the solution was cooled down, 500 ml of water was added. After an organic layer was separated, toluene was removed by distillation thereby obtaining 86.7 g of a crude product. The obtained crude product was purified by silica-gel chromatography, thereby obtaining 60 g of an amine compound 14.

### Intermediate-Synthesis Example 2

### Synthesis of Amine Compound 15

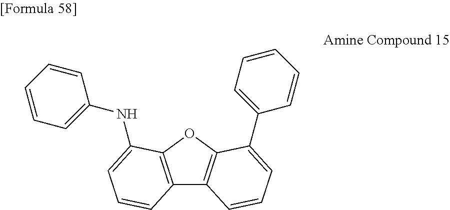 [SMILES: c1ccc(Nc2cccc3c2oc2c(-c4ccccc4)cccc23)cc1]

An amine compound 15 was synthesized in the same manner as in Intermediate-synthesis Example 1 except that the 2-methylphenyl boronic acid as used in Intermediate-synthesis Example 1 was replaced with a phenyl boronic acid.

### Intermediate-Synthesis Example 3

### Synthesis of Amine Compound 16

A synthesis scheme of an amine compound 16 is shown below.

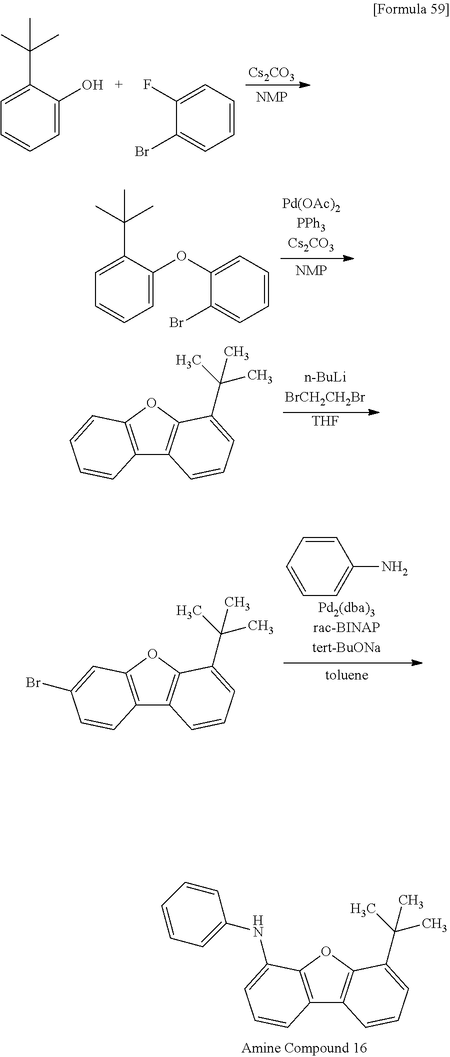

### (3-1) Synthesis of 2-Bromophenyl 2-(Tert-Butyl)Phenyl Ether

In a flask under an argon gas stream, 1.40 g of 2-bromofluorobenzene, 600 mg of 2-(tert-butyl)phenol, 2.61 g of cesium carbonate and 20 ml of dried N-methylpyrrolidone (NMP) were added and reacted at 180 degrees C. for five and half hours.

After the mixture was cooled down, toluene was added therein, an organic layer was washed with water and condensed, and an organic solvent was removed by distillation. The obtained crude product was purified by silica-gel chromatography (eluent: hexane), thereby obtaining 0.93 g of 2-bromophenyl 2-(tert-butyl)phenyl ether.

### (3-2) Synthesis of 4-Tert-Butyldibenzofuran

In a flask under an argon gas stream, 0.40 g of 2-bromophenyl 2-(tert-butyl)phenyl ether, 15 mg of Pd(OAc)₃, 34 mg of PPh₃, 427 mg of cesium carbonate and 8 ml of dried N-methylpyrrolidone (NMP) were added and stirred at 180 degrees C. for five and half hours.

After the mixture was cooled down, water was added therein, and an organic substance was extracted with ethyl acetate and dried with magnesium sulfate. Subsequently, after a solvent was removed by distillation, the mixture was purified by silica-gel chromatography (eluent: hexane), thereby obtaining 0.24 g of 4-tert-butyldibenzofuran.

### (3-3) Synthesis of 4-Bromo-6-Tert-Butyldibenzofuran

Under an argon gas stream, 3.85 g of 4-tert-butyldibenzofuran was dissolved in 36 ml of dried THF and cooled to minus 68 degrees C.

After 11.57 ml of a hexane solution of 1.6M n-BuLi was dropped therein, the mixture was stirred at 10 degrees for one hour. After the mixture was cooled to minus 60 degrees C., 2.22 ml of 1,2-dibromoethane was dropped therein and the mixture was stirred at room temperature for 164 hours and 40 minutes.

After being added with 100 ml of toluene, the mixture was washed with 1N HCl and NaHCO₃ aqueous solution (aq NaHCO₃) and dried with anhydrous sodium sulfate. Subsequently, after a solvent was removed by distillation, the mixture was purified by silica-gel chromatography (eluent: hexane), thereby obtaining 4.73 g of 4-bromo-6-tert-butyldibenzofuran.

### (3-4) Synthesis of Amine Compound 16

In a flask under an argon gas stream, 5.18 g of 4-bromo-6-tert-butyldibenzofuran, 236 mg of Pd₂(dba)₃, 320 mg of BINAP (2,2′-bis(diphenylphosphino)-1,1′-binaphthyl), 3.19 g of aniline, 3.3 g of tert-BuONa, and 86 ml of a dehydrated toluene solution were added and stirred at 90 degrees C. for seven hours.

After the mixture was cooled down, cerite was added therein and a solvent was removed by distillation after the cerite was separated by filtration. The mixture was then purified by silica-gel chromatography (eluent:hexane:toluene=3:1), thereby obtaining 3.94 g of an amine compound 16.

### Intermediate-Synthesis Example 4

### Synthesis of Amine Compound 17

A synthesis scheme of an amine compound 17 is shown below.

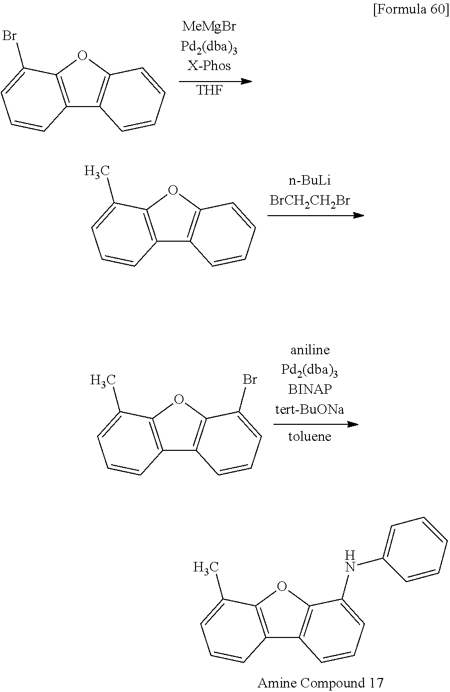

### (4-1) Synthesis of 4-Methyldibenzofuran

In a flask under an argon gas stream, 132 g of 4-bromodibenzofuran, 4.90 g of Pd₂(dba)₃, 5.10 g of X-Phos and 1300 ml of dried THF were added. After the temperature of the mixture was raised to 50 degrees C., 1600 ml of a THF solution (1M) of methylmagnesiumbromide (MeMgBr) was dropped therein and the mixture was stirred at 50 degrees C. for eight hours. After the mixture was cooled down to room temperature, 1200 ml of 3M hydrochloric acid was dropped therein, the mixture was extracted with toluene and dried with anhydrous magnesium sulfate, and a solvent was removed by distillation. Subsequently, the mixture was purified by silica-gel chromatography, thereby obtaining 92.6 g of 4-methyldibenzofuran.

### (4-2) Synthesis of 4-Bromo-6-Methyldibenzofuran

4-bromo-6-methyldibenzofuran was obtained in the same manner as in (3-3) of Intermediate-synthesis Example 3 except that the 4-methyldibenzofuran synthesized in (4-1) was used in place of the 4-tert-butyldibenzofuran as used in (3-3) of Intermediate-synthesis Example 3.

### (4-3) Synthesis of Amine Compound 17

An amine compound 17 was obtained in the same manner as in (3-4) of Intermediate-synthesis Example 3 except that the 4-bromo-6-methyldibenzofuran synthesized in (4-2) was used in place of the 4-bromo-6-tert-butyldibenzofuran as used in (3-4) of Intermediate-synthesis Example 3.

### Intermediate-Synthesis Example 5

### Synthesis of Amine Compound 18

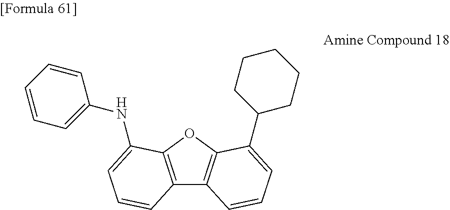 [SMILES: c1ccc(Nc2cccc3c2oc2c(C4CCCCC4)cccc23)cc1]

An amine compound 18 was synthesized in the same manner as in Intermediate-synthesis Example 4 except that a cyclohexylmagnesiumchloride solution was used in place of the methylmagnesiumbromide solution.

### Intermediate-Synthesis Example 6

### Synthesis of Amine Compound 19

A synthesis scheme of an amine compound 19 is shown below.

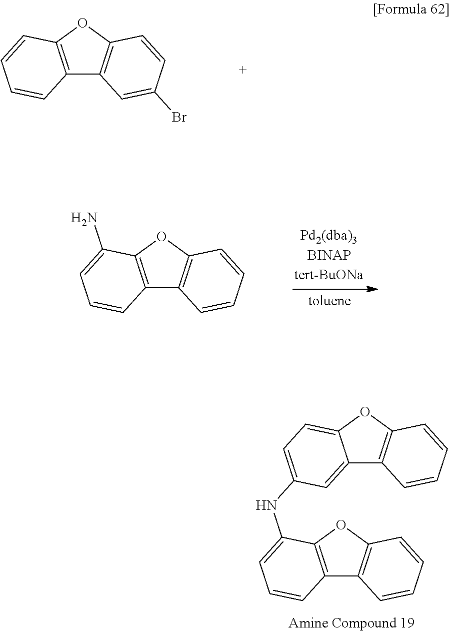 [SMILES: Brc1ccc2oc3ccccc3c2c1 ; Nc1cccc2c1oc1ccccc12 ; c1ccc2c(c1)oc1ccc(Nc3cccc4c3oc3ccccc34)cc12]

In a flask under an argon gas stream, 7.0 g of 2-bromodibenzofuran, 13.0 g of 4-aminodibenzofuran, 0.39 g of Pd₂(dba)₃, 0.53 g of BINAP (2,2′-bis(diphenylphosphino)-1,1′-binaphthyl), 5.44 g of tert-BuONa and 142 ml of a dehydrated toluene solution were added and stirred at 90 degrees C. for four and half hours.

After the mixture was cooled down, cerite was added therein and a solvent was removed by distillation after the cerite was separated by filtration. The mixture was then purified by silica-gel chromatography (eluent:hexane:toluene=3:1), thereby obtaining 10.06 g of an amine compound 19.

### Synthesis Examples 14 to 19

Synthesis Examples 14 to 19 were the same as Synthesis Example 1 except that the amine compound 1 in Synthesis Example 1 was replaced with the amine compounds 14 to 19 synthesized in Intermediate-synthesis Examples 1 to 6. As a result, compounds 14 to 19 shown below were obtained. As a result of mass-spectrum analysis on the obtained compounds, these compounds were identified as the compounds 14 to 19. Correspondence relations between an amine compound used in each synthesis example and an obtained compound are shown below.
Synthesis Example 14: Amine Compound 14: Compound 14
Synthesis Example 15: Amine Compound 15: Compound 15
Synthesis Example 16: Amine Compound 16: Compound 16
Synthesis Example 17: Amine Compound 17: Compound 17
Synthesis Example 18: Amine Compound 18: Compound 18
Synthesis Example 19: Amine Compound 19: Compound 19

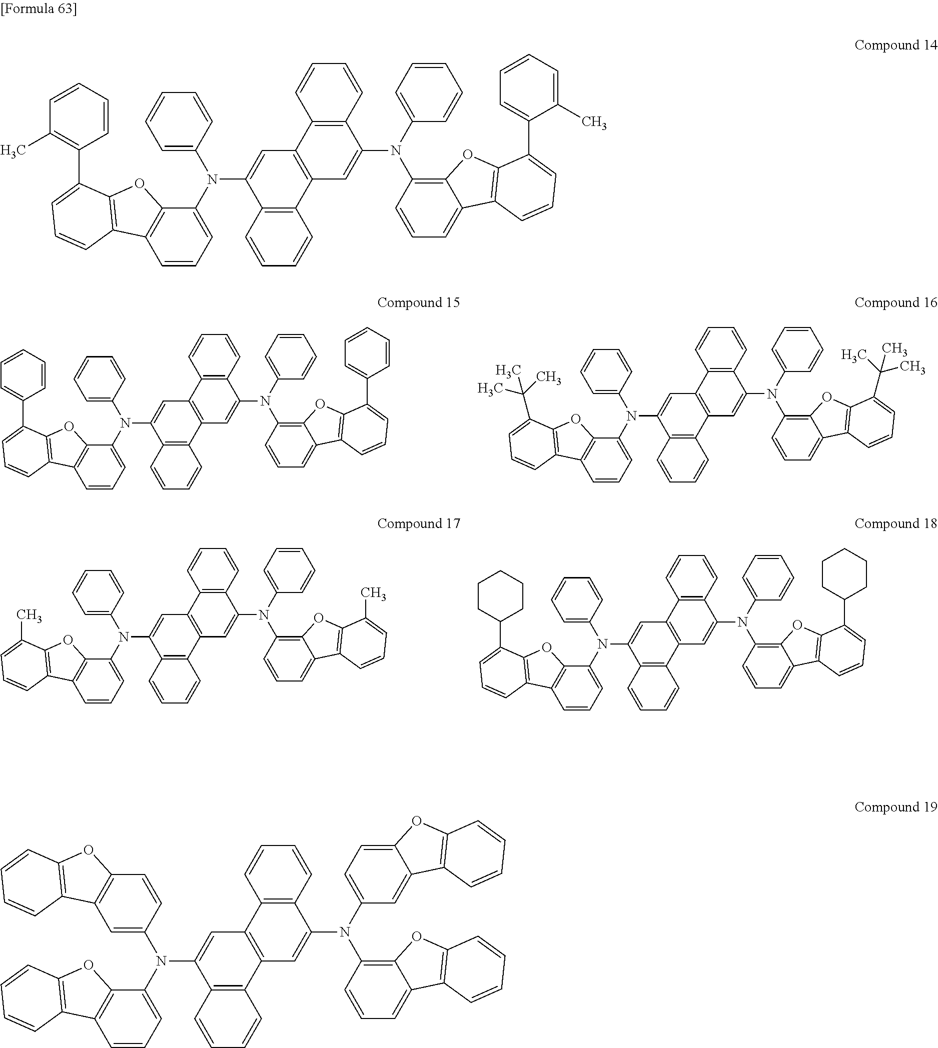

### Manufacturing of Organic EL Device

### Example 2

A glass substrate (size: 25 mm×75 mm×1.1 mm thick) having an ITO transparent electrode (manufactured by GEOMATEC Co., Ltd.) was subjected to ultrasonic-cleaning in isopropyl alcohol for five minutes, and UV/ozone-cleaning for 30 minutes. A thickness of the ITO transparent electrode was 130 nm.

The cleaned glass substrate with the transparent electrode line was mounted on a substrate holder of a vacuum deposition apparatus. Initially, a compound HI-1 shown below was formed on the transparent electrode line formed side of the glass substrate so as to cover the transparent electrode, thereby forming a 5-nm-thick HI-1 film (i.e., a hole injecting layer).

Next, on the HI-1 film, the compound HT-3 shown below (i.e., a first hole transporting material) was deposited, thereby forming an 80-nm-thick HT-3 film (i.e., a first hole transporting layer).

Subsequently, on the HT-3 film, a compound HT-4 shown below was deposited, thereby forming a 15-nm-thick HT-4 film (i.e., a second hole transporting layer).

Further, on the HT-4 film, a compound BH-2 was deposited, thereby forming a 25-nm-thick emitting layer. Simultaneously, the compound 1 (i.e., a fluorescent material) was co-deposited. A concentration of the compound 1 was 5.0 mass %. This co-deposited film works as the emitting layer.

On the emitting layer, a compound ET-2 shown below was deposited, thereby forming a 20-nm-thick ET-2 film (i.e., a first electron transporting layer).

Next, on the first electron transporting layer, a compound ET-3 shown below was deposited, thereby forming a 5-nm-thick ET-3 film (i.e., a second electron transporting layer).

Subsequently, on the ET-3 film, LiF was deposited at a film-forming speed of 0.1 Å/min, thereby forming a 1-nm-thick LiF film (i.e., an electron-injecting electrode, namely a cathode).

Further, on the LiF film, Al metal was deposited, thereby forming an 80-nm thick Al metal film (i.e., a metal (Al) cathode).

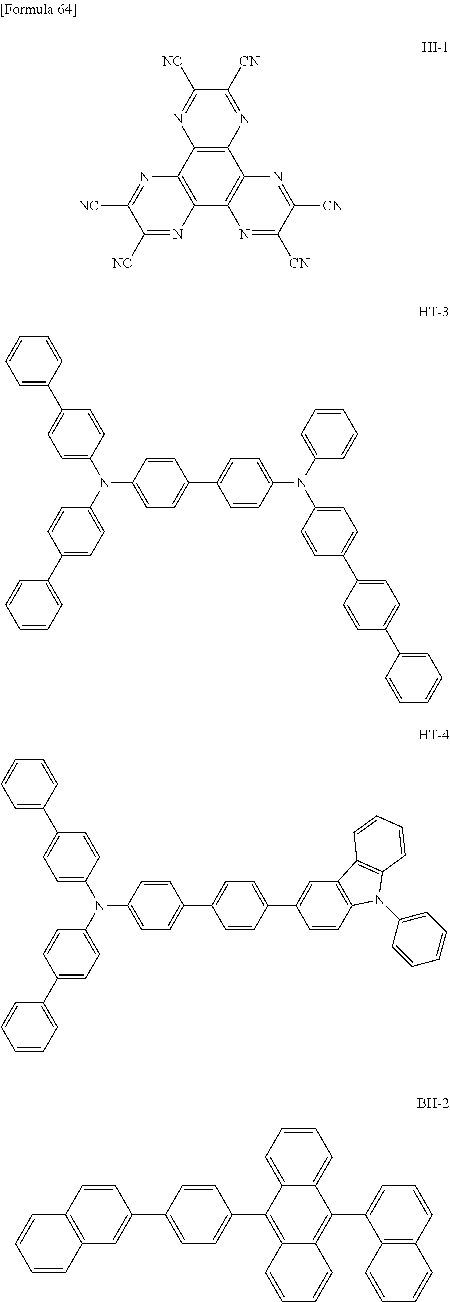

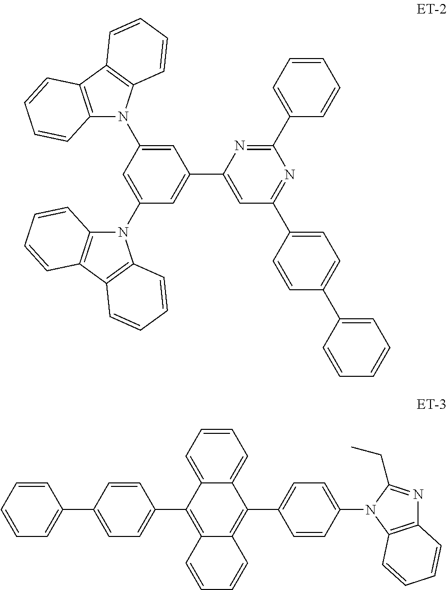 [SMILES: c1ccc(-c2ccc(-c3cc(-c4cc(-n5c6ccccc6c6ccccc65)cc(-n5c6ccccc6c6ccccc65)c4)nc(-c4ccccc4)n3)cc2)cc1 ; CCc1nc2ccccc2n1-c1ccc(-c2c3ccccc3c(-c3ccc(-c4ccccc4)cc3)c3ccccc23)cc1]

### Evaluation of Organic EL Device

Voltage was applied to the manufactured organic EL device with a current density becoming 10 mA/cm² and an external quantum efficiency (EQE), an emission main peak wavelength λₚ, and a time elapsed until a luminescence intensity decreased by 20% when the device was driven with a constant current having a current density of 50 mA/cm² (i.e., luminance-to-80% lifetime). The results are shown in Table 78.

### Examples 3 to 9 and Comparative Example

Organic EL devices of Examples 3 to 9 were manufactured in the same manner as in Example 2 except that compounds listed in Table 78 were used in place of the compound 1 in Example 2, and were evaluated.

An organic EL device of Comparative Example was manufactured in the same manner as in Example 2 except that the following comparative compound was used in place of the compound 1 in Example 2, and was evaluated.

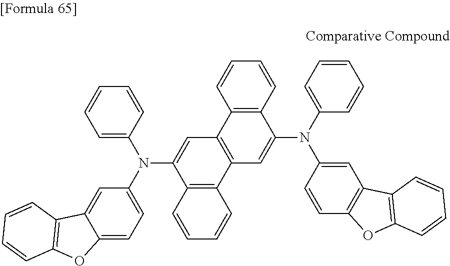 [SMILES: c1ccc(N(c2ccc3oc4ccccc4c3c2)c2cc3c4ccccc4c(N(c4ccccc4)c4ccc5oc6ccccc6c5c4)cc3c3ccccc23)cc1]

TABLE 78

| | | | Emission | Luminance-to-80% |
|---|---|---|---|---|
| | Fluorescent | EQE | Wavelength | Lifetime |
| | Material | (%) | (nm) | (h) |
| Ex. 2 | Compound 1 | 7.6 | 452 | 200 |
| Ex. 3 | Compound 9 | 7.6 | 451 | 170 |
| Ex. 4 | Compound 14 | 7.3 | 448 | 140 |
| Ex. 5 | Compound 15 | 7.3 | 449 | 150 |
| Ex. 6 | Compound 16 | 7.4 | 449 | 160 |
| Ex. 7 | Compound 17 | 7.3 | 450 | 150 |
| Ex. 8 | Compound 18 | 7.4 | 449 | 150 |
| Ex. 9 | Compound 19 | 7.6 | 454 | 130 |
| Comp. | Comparative | 7.3 | 458 | 120 |
| | Compound | | | |

As shown above, compared with the organic EL device of Comparative Example 1 using the comparative compound, the organic EL devices of Examples 2 to 9, each of which was manufactured by using the aromatic amine derivative according to the invention as a dopant material for the emitting layer, had a shorter emission wavelength and emitted a deeper blue light. Further, the organic EL devices of Examples 2 to 9 each emitted light with an external quantum efficiency substantially equal to or higher than that of the organic EL device of Comparative Example. In view of the above, it can be concluded that the organic EL device using the aromatic amine derivative according to the invention has a higher efficiency and emits a deeper blue light as compared with the organic EL device of Comparative Example.

### INDUSTRIAL APPLICABILITY

The organic EL device according to the exemplary embodiment is usable, for instance, for: a wall-mountable planar light-emitting device such as a flat panel display; a light source for a copier, a printer, a backlight for a liquid crystal display, or meters, gauges or the like; an indicator board; and a marker lamp.

### EXPLANATION OF CODES

1 . . . organic EL device, 3 . . . anode, 4 . . . cathode, 7 . . . emitting layer, 10 . . . organic compound layer

1. An aromatic amine derivative of a formula (1) below, 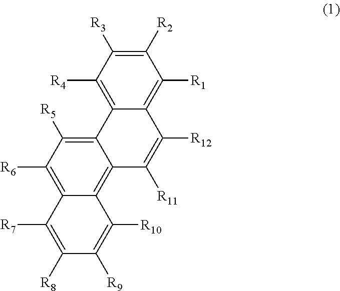
where:
R₁ to R₅ and R₇ to R₁₁ are each independently a hydrogen atom, a deuterium atom, a halogen atom, a cyano group, a substituted or unsubstituted aryl group having 6 to 30 ring carbon atoms, a substituted or unsubstituted heterocyclic group having 5 to 30 ring atoms, a substituted or unsubstituted alkyl group having 1 to 30 carbon atoms, a substituted or unsubstituted alkenyl group having 2 to 30 carbon atoms, a substituted or unsubstituted alkynyl group having 2 to 30 carbon atoms, a substituted or unsubstituted alkylsilyl group having 3 to 30 carbon atoms, a substituted or unsubstituted arylsilyl group having 6 to 30 ring carbon atoms, a substituted or unsubstituted alkoxy group having 1 to 30 carbon atoms, a substituted or unsubstituted aralkyl group having 6 to 30 ring carbon atoms, or a substituted or unsubstituted aryloxy group having 6 to 30 ring carbon atoms; and
R₆ and R₁₂ are each independently represented by a formula (2) below, 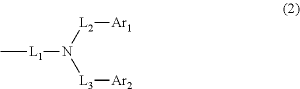
where:
L₁, L₂ and L₃ are each independently a single bond, a divalent residue of a substituted or unsubstituted aryl group having 6 to 30 ring carbon atoms, or a divalent residue of a substituted or unsubstituted heterocyclic group having 5 to 30 ring atoms;
Ar₁ is a monovalent substituent represented by a formula (3) below;
Ar₂ is a substituted or unsubstituted aryl group having 6 to 30 ring carbon atoms, a substituted or unsubstituted heterocyclic group having 5 to 30 ring atoms, or a monovalent residue derived from a ring structure of a formula (4) below; and
a substituent for the aryl group or the heterocyclic group for Ar₂ is a deuterium atom, a halogen atom, a cyano group, a substituted or unsubstituted aryl group having 6 to 30 ring carbon atoms, a substituted or unsubstituted heterocyclic group having 5 to 30 ring atoms, a substituted or unsubstituted alkyl group having 1 to 30 carbon atoms, a substituted or unsubstituted alkenyl group having 2 to 30 carbon atoms, a substituted or unsubstituted alkynyl group having 2 to 30 carbon atoms, a substituted or unsubstituted alkylsilyl group having 3 to 30 carbon atoms, a substituted or unsubstituted arylsilyl group having 6 to 30 ring carbon atoms, a substituted or unsubstituted alkoxy group having 1 to 30 carbon atoms, a substituted or unsubstituted aralkyl group having 6 to 30 ring carbon atoms, or a substituted or unsubstituted aryloxy group having 6 to 30 ring carbon atoms, 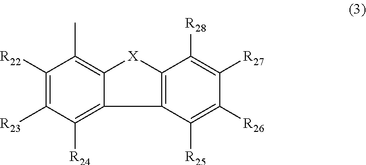
where:
X is an oxygen atom or a sulfur atom;
R₂₂ to R₂₈ are each independently a hydrogen atom, a deuterium atom, a halogen atom, a cyano group, a substituted or unsubstituted aryl group having 6 to 30 ring carbon atoms, a substituted or unsubstituted heterocyclic group having 5 to 30 ring atoms, a substituted or unsubstituted alkyl group having 1 to 30 carbon atoms, a substituted or unsubstituted alkenyl group having 2 to 30 carbon atoms, a substituted or unsubstituted alkynyl group having 2 to 30 carbon atoms, a substituted or unsubstituted alkylsilyl group having 3 to 30 carbon atoms, a substituted or unsubstituted arylsilyl group having 6 to 30 ring carbon atoms, a substituted or unsubstituted alkoxy group having 1 to 30 carbon atoms, a substituted or unsubstituted aralkyl group having 6 to 30 ring carbon atoms, or a substituted or unsubstituted aryloxy group having 6 to 30 ring carbon atoms;
at least one combination of R₂₂ and R₂₃, R₂₃ and R₂₄, R₂₅ and R₂₆, R₂₆ and R₂₇, and R₂₇ and R₂₈ optionally forms a saturated or unsaturated ring; and
the monovalent substituent of the formula (3) is bonded to L₂ at a bond where R₂₂ to R₂₈ are not bonded, 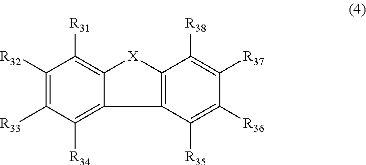
where:
X is an oxygen atom or a sulfur atom;
R₃₁ to R₃₈ are each independently a hydrogen atom,
a deuterium atom, a halogen atom, a cyano group, a substituted or unsubstituted aryl group having 6 to 30 ring carbon atoms, a substituted or unsubstituted heterocyclic group having 5 to 30 ring atoms, a substituted or unsubstituted alkyl group having 1 to 30 carbon atoms, a substituted or unsubstituted alkenyl group having 2 to 30 carbon atoms, a substituted or unsubstituted alkynyl group having 2 to 30 carbon atoms, a substituted or unsubstituted alkylsilyl group having 3 to 30 carbon atoms, a substituted or unsubstituted arylsilyl group having 6 to 30 ring carbon atoms, a substituted or unsubstituted alkoxy group having 1 to 30 carbon atoms, a substituted or unsubstituted aralkyl group having 6 to 30 ring carbon atoms, or a substituted or unsubstituted aryloxy group having 6 to 30 ring carbon atoms;
at least one combination of R₃₁ and R₃₂, R₃₂ and R₃₃, R₃₃ and R₃₄, R₃₅ and R₃₆, R₃₆ and R₃₇, and R₃₇ and R₃₈ optionally forms a saturated or unsaturated ring; and
one of R₃₁ to R₃₈ is a single bond to L₃.

2. The aromatic amine derivative according to claim 1, wherein Ar₂ in the formula (2) is a substituted or unsubstituted aryl group having 6 to 30 ring carbon atoms.

3. The aromatic amine derivative according to claim 1, wherein Ar₂ in the formula (2) is a monovalent residue derived from a ring structure of the formula (4).

4. The aromatic amine derivative according to claim 1, wherein X in the formula (3) is an oxygen atom.

5. The aromatic amine derivative according to claim 1, wherein at least one of R₂₂ to R₂₈ in the formula (3) is a substituted or unsubstituted aryl group having 6 to 30 ring carbon atoms, a substituted or unsubstituted heterocyclic group having 5 to 30 ring atoms, a substituted or unsubstituted alkyl group having 1 to 30 carbon atoms, a substituted or unsubstituted alkylsilyl group having 3 to 30 carbon atoms, a substituted or unsubstituted arylsilyl group having 6 to 30 ring carbon atoms, or a substituted or unsubstituted aralkyl group having 6 to 30 ring carbon atoms.

6. The aromatic amine derivative according to claim 1, wherein R₂₈ in the formula (3) is a substituted or unsubstituted aryl group having 6 to 30 ring carbon atoms, a substituted or unsubstituted heterocyclic group having 5 to 30 ring atoms, a substituted or unsubstituted alkyl group having 1 to 30 carbon atoms, a substituted or unsubstituted alkylsilyl group having 3 to 30 carbon atoms, a substituted or unsubstituted arylsilyl group having 6 to 30 ring carbon atoms, or a substituted or unsubstituted aralkyl group having 6 to 30 ring carbon atoms.

7. The aromatic amine derivative according to claim 1, wherein Ar₂ in the formula (2) is a phenyl group comprising an alkyl group in a para position.

8. The aromatic amine derivative according to claim 1, wherein Ar₂ in the formula (2) is a phenyl group comprising an aryl group in a meta position.

9. The aromatic amine derivative according to claim 1, wherein Ar₂ in the formula (2) is a phenyl group comprising an alkyl group in an ortho position.

10. The aromatic amine derivative according to claim 1, wherein L₁ in the formula (2) is a single bond.

11. The aromatic amine derivative according to claim 1, wherein L₂ in the formula (2) is a single bond.

12. The aromatic amine derivative according to claim 1, wherein L₃ in the formula (2) is a single bond.

13. An organic electroluminescence device comprising:
a cathode;
an anode; and
an organic compound layer being provided between the cathode and the anode, the organic compound layer comprising the aromatic amine derivative according to claim 1.

14. An organic electroluminescence device comprising:
a cathode;
an anode; and
one or more organic thin-film layers being interposed between the cathode and the anode, the organic thin-film layers comprising at least an emitting layer, the organic thin-film layers comprising at least one layer that comprises the aromatic amine derivative according to claim 1.

15. An organic electroluminescence device comprising:
a cathode;
an anode; and
one or more organic thin-film layers being interposed between the cathode and the anode, the organic thin-film layers comprising at least an emitting layer, the organic thin-film layers comprising at least one layer that comprises the aromatic amine derivative according to claim 1 and an anthracene derivative of a formula (20) below, 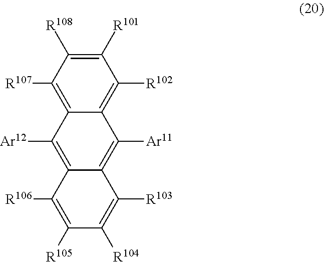
where:
Ar¹¹ and Ar¹¹ are each independently a substituted or unsubstituted monocyclic group having 5 to 30 ring atoms, a substituted or unsubstituted fused ring group having 8 to 30 ring atoms, or a group formed by combining the monocyclic group and the fused ring group; and
R¹⁰¹ to R¹⁰⁸ are each independently a hydrogen atom, a halogen atom, a cyano group, a substituted or unsubstituted monocyclic group having 5 to 30 ring atoms, a substituted or unsubstituted fused ring group having 8 to 30 ring atoms, a group formed by combining the monocyclic group and the fused ring group, a substituted or unsubstituted alkyl group having 1 to 30 carbon atoms, a substituted or unsubstituted cycloalkyl group having 3 to 30 ring carbon atoms, a substituted or unsubstituted alkoxy group having 1 to 30 carbon atoms, a substituted or unsubstituted aralkyl group having 7 to 30 carbon atoms, a substituted or unsubstituted aryloxy group having 6 to 30 ring carbon atoms, or a substituted or unsubstituted silyl group.

16. The organic electroluminescence device according to claim 15, wherein Ar¹¹ and Ar¹² in the formula (20) are each independently a substituted or unsubstituted fused ring group having 10 to 30 ring atoms.

17. The organic electroluminescence device according to claim 15, wherein while one of Ar¹¹ and Ar¹² in the formula (20) is a substituted or unsubstituted monocyclic group having 5 to 30 ring atoms, the other of Ar¹¹ and Ar¹² is a substituted or unsubstituted fused ring group having 10 to 30 ring atoms.

18. The organic electroluminescence device according to claim 15, wherein Ar¹² in the formula (20) is selected from among a naphthyl group, a phenanthryl group, a benzanthryl group and a dibenzofuranyl group, while Ar¹¹ is a substituted or unsubstituted phenyl group or a substituted or unsubstituted fluorenyl group.

19. The organic electroluminescence device according to claim 15, wherein Ar¹² in the formula (20) is a substituted or unsubstituted fused ring group having 8 to 30 ring atoms, while Ar¹¹ is an unsubstituted phenyl group.

20. The organic electroluminescence device according to claim 15, wherein Ar¹¹ and Ar¹² in the formula (20) are each independently a substituted or unsubstituted monocyclic group having 5 to 30 ring atoms.

21. The organic electroluminescence device according to claim 15, wherein Ar¹¹ and Ar¹² in the formula (20) are each independently a substituted or unsubstituted phenyl group.

22. The organic electroluminescence device according to claim 15, wherein Ar¹¹ in the formula (20) is an unsubstituted phenyl group, while Ar¹² is a phenyl group comprising at least one of a monocyclic group and a fused ring group as a substituent.

23. The organic electroluminescence device according to claim 15, wherein Ar¹¹ and Ar¹² in the formula (20) are each independently a phenyl group comprising at least one of a monocyclic group and a fused ring group as a substituent.
